(19) United States
(12) Patent Application Publication
(10) Pub. No.: US 2022/0318459 A1
(43) Pub. Date: Oct. 6, 2022

(54) ROBOTIC TACTILE SENSING

(71) Applicant: NVIDIA Corporation, Santa Clara, CA (US)

(72) Inventors: Yashraj Shyam Narang, Seattle, WA (US); Balakumar Sundaralingam, Milpitas, CA (US); Karl Van Wyk, Lynnwood, WA (US); Arsalan Mousavian, Seattle, WA (US); Miles Macklin, Auckland (NZ); Dieter Fox, Seattle, WA (US)

(21) Appl. No.: 17/213,062

(22) Filed: Mar. 25, 2021

(51) Int. Cl. G06F 30/23; G06F 30/27; G06N 3/08

(52) U.S. Cl. CPC G06F 30/23; G06F 30/27; G06N 3/08

(57) ABSTRACT

Apparatuses, systems, and techniques to model a tactile force sensor. In at least one embodiment, output of tactile sensor is predicted from a modeled force and shape imposed on the sensor. In at least one embodiment, a shape of the surface of the tactile sensor is determined based at least in part on electrical signals received from the sensor.

### TECHNICAL FIELD

At least one embodiment pertains to robotic control systems. For example, at least one embodiment pertains to techniques that utilize tactile sensing as a source of feedback in robotic control systems.

### BACKGROUND

Robotic control systems allow for the automation of many tasks involving the manipulation of objects. However, many present systems are limited in that they rely almost exclusively on visual feedback when performing a manipulation. When manipulating objects, one advantage humans have over robots is that humans have a highly developed sense of touch that allows fine manipulation. However, development of an effective tactile sensing system has been elusive.

### BRIEF DESCRIPTION OF DRAWINGS

FIG. 1 illustrates an example of techniques used to evaluate tactile robotic feedback, in at least one embodiment;

FIG. 2 illustrates an example of objects used to calibrate a tactile sensor, in at least one embodiment;

FIG. 3 illustrates an example of a fixture used to calibrate a tactile sensor, in at least one embodiment;

FIG. 4 illustrates an example of a mechanical registration apparatus, in at least one embodiment;

FIG. 5 illustrates an example of a simulation used to calibrate a tactile sensor, in at least one embodiment;

FIG. 6 illustrates an example of a tactile sensor, in at least one embodiment;

FIG. 7 illustrates an example of contact locations for a tactile sensor, in at least one embodiment;

FIG. 8 illustrates an example of force values, in at least one embodiment;

FIG. 9 illustrates an example of electrode values, in at least one embodiment;

FIG. 10 illustrates an example of finite element model deformation for a skin of a tactile force sensor, in at least one embodiment;

FIG. 11 illustrates an example of finite element mesh motion, in at least one embodiment;

FIG. 12 illustrates an example of finite element model calibration, in at least one embodiment;

FIG. 13 illustrates an example of finite element model validation, in at least one embodiment;

FIG. 14 illustrates an example of tactile contact estimation errors, in at least one embodiment;

FIG. 15 illustrates an example of contact location estimation, in at least one embodiment;

FIG. 16 illustrates an example of tactile force estimation errors, in at least one embodiment;

FIG. 17 illustrates an example of force vector estimation for unseen trajectories, in at least one embodiment;

FIG. 18 illustrates a first set of examples of finite element nodal displacement estimation, in at least one embodiment;

FIG. 19 illustrates a second set of examples of finite element nodal displacement estimation, in at least one embodiment;

FIG. 20 illustrates an example of electrode value estimation for unseen trajectories, in at least one embodiment;

FIG. 21 illustrates an example of a 3D finite element (“FEM”) model of a tactile sensor, in at least one embodiment;

FIG. 22 illustrates an example of deformable modeling of a tactile sensor, in at least one embodiment;

FIG. 23 illustrates an example of learning structure that maps between FEM deformations and electrode signals of a tactile sensor, in at least one embodiment;

FIG. 24 illustrates an example of electrode prediction results, in at least one embodiment;

FIG. 25 illustrates an example of root mean square (“RMS”) error for a set of electrodes of a tactile sensor, in at least one embodiment;

FIG. 26 illustrates an example of a coverage plot, with L1 distance to ground-truth, in at least one embodiment;

FIG. 27 illustrates an example of contact patch estimation, in at least one embodiment;

FIG. 28 illustrates an example of a process that, as a result of being performed by a computer system, trains a machine-learned model to estimate behavior of a tactile sensor, in at least one embodiment;

FIG. 29A illustrates inference and/or training logic, according to at least one embodiment;

FIG. 29B illustrates inference and/or training logic, according to at least one embodiment;

FIG. 30 illustrates training and deployment of a neural network, according to at least one embodiment;

FIG. 31 illustrates an example data center system, according to at least one embodiment;

FIG. 32A illustrates an example of an autonomous vehicle, according to at least one embodiment;

FIG. 32B illustrates an example of camera locations and fields of view for the autonomous vehicle of FIG. 32A, according to at least one embodiment;

FIG. 32C is a block diagram illustrating an example system architecture for the autonomous vehicle of FIG. 32A, according to at least one embodiment;

FIG. 32D is a diagram illustrating a system for communication between cloud-based server(s) and the autonomous vehicle of FIG. 32A, according to at least one embodiment;

FIG. 33 is a block diagram illustrating a computer system, according to at least one embodiment;

FIG. 34 is a block diagram illustrating a computer system, according to at least one embodiment;

FIG. 35 illustrates a computer system, according to at least one embodiment;

FIG. 36 illustrates a computer system, according to at least one embodiment;

FIG. 37A illustrates a computer system, according to at least one embodiment;

FIG. 37B illustrates a computer system, according to at least one embodiment;

FIG. 37C illustrates a computer system, according to at least one embodiment;

FIG. 37D illustrates a computer system, according to at least one embodiment;

FIGS. 37E and 37F illustrate a shared programming model, according to at least one embodiment;

FIG. 38 illustrates exemplary integrated circuits and associated graphics processors, according to at least one embodiment;

FIGS. 39A-39B illustrate exemplary integrated circuits and associated graphics processors, according to at least one embodiment;

FIGS. 40A-40B illustrate additional exemplary graphics processor logic according to at least one embodiment;

FIG. 41 illustrates a computer system, according to at least one embodiment;

FIG. 42A illustrates a parallel processor, according to at least one embodiment;

FIG. 42B illustrates a partition unit, according to at least one embodiment;

FIG. 42C illustrates a processing cluster, according to at least one embodiment;

FIG. 42D illustrates a graphics multiprocessor, according to at least one embodiment;

FIG. 43 illustrates a multi-graphics processing unit (GPU) system, according to at least one embodiment;

FIG. 44 illustrates a graphics processor, according to at least one embodiment;

FIG. 45 is a block diagram illustrating a processor micro-architecture for a processor, according to at least one embodiment;

FIG. 46 illustrates a deep learning application processor, according to at least one embodiment;

FIG. 47 is a block diagram illustrating an example neuromorphic processor, according to at least one embodiment;

FIG. 48 illustrates at least portions of a graphics processor, according to one or more embodiments;

FIG. 49 illustrates at least portions of a graphics processor, according to one or more embodiments;

FIG. 50 illustrates at least portions of a graphics processor, according to one or more embodiments;

FIG. 51 is a block diagram of a graphics processing engine of a graphics processor in accordance with at least one embodiment;

FIG. 52 is a block diagram of at least portions of a graphics processor core, according to at least one embodiment;

FIGS. 53A-53B illustrate thread execution logic including an array of processing elements of a graphics processor core according to at least one embodiment;

FIG. 54 illustrates a parallel processing unit (“PPU”), according to at least one embodiment;

FIG. 55 illustrates a general processing cluster (“GPC”), according to at least one embodiment;

FIG. 56 illustrates a memory partition unit of a parallel processing unit (“PPU”), according to at least one embodiment;

FIG. 57 illustrates a streaming multi-processor, according to at least one embodiment.

FIG. 58 is an example data flow diagram for an advanced computing pipeline, in accordance with at least one embodiment;

FIG. 59 is a system diagram for an example system for training, adapting, instantiating and deploying machine learning models in an advanced computing pipeline, in accordance with at least one embodiment;

FIG. 60 includes an example illustration of an advanced computing pipeline 5910A for processing imaging data, in accordance with at least one embodiment;

FIG. 61A includes an example data flow diagram of a virtual instrument supporting an ultrasound device, in accordance with at least one embodiment;

FIG. 61B includes an example data flow diagram of a virtual instrument supporting a CT scanner, in accordance with at least one embodiment;

FIG. 62A illustrates a data flow diagram for a process to train a machine learning model, in accordance with at least one embodiment; and

FIG. 62B is an example illustration of a client-server architecture to enhance annotation tools with pre-trained annotation models, in accordance with at least one embodiment.

### DETAILED DESCRIPTION

The present document describes systems and methods to improve tactile sensing in robotic control systems. In at least one embodiment, techniques described herein provide for automated creation of a tactile dataset for a tactile sensor over diverse physical interactions. At least one embodiment provides a 3D finite element (“FE”) model of a tactile sensor, which can be used to provide high-resolution, distributed contact data. In at least one embodiment, a neural network is trained to map electrical signals from a tactile sensor to low-dimensional data and high-density FE deformation fields. For example, in at least one embodiment, a flexible gel membrane surrounds a tactile sensor. In at least one embodiment, techniques described herein train a neural network to map signals obtained from the tactile sensor to a deformed shape of the membrane. In at least one embodiment, the techniques described herein can accomplish the reverse, predicting the output of a tactile force sensor given a deformation pattern of the membrane. In at least one embodiment, such techniques provide a far greater quantity of interpretable information for grasping and manipulation algorithms than previously accessible.

In at least one embodiment, there are at least three major sensing modalities used in robotic grasping and manipulation: proprioception, vision, and tactile sensing. In at least one embodiment, among these modalities, tactile sensing can provide direct information about the physical properties of the object during interaction, including mass, moment of inertia, stiffness, friction, surface texture, temperature, and thermal conductivity, as well as information about contact locations and forces. In at least one embodiment, such information may be leveraged to perform low-level perceptual and control tasks, such as object classification, dynamics parameter estimation, slip detection, contour following, and peg-in-hole insertion.

In at least one embodiment, tactile sensing is useful for grasping and manipulation in the presence of visual occlusions, including robot self-occlusions, deep object concavities, and environmental clutter. Examples of tasks under occlusion include extracting a coin from a wallet, pulling keys out of a pocket, or rummaging through a bag. In at least one embodiment, tactile sensing is useful for the safe handling of brittle and delicate objects, such as eggs, biscuits, glassware, fresh fruit, human tissue during surgery, and living organisms.

Various tactile sensors may be used in or more embodiments. Examples of tactile sensors include the GelSight (Yuan et al. (2017)), TacTip (Ward-Cherrier et al. (2018)), Soft-bubble (Alspach et al. (2019)), DIGIT (Lambeta et al. (2020)), overlapping optical signal sensors (Piacenza et al. (2020)), and commercial offerings from SynTouch, Pressure Profile Systems, ATI Industrial Automation, and OnRobot. Using the techniques described herein, important challenges when using one of such sensors to accomplish low-level or long-horizon control tasks are addressed.

At least one embodiment estimates low-dimensional tactile features, such as 3D contact location and net force vector, from raw tactile signals. In at least one embodiment, these features facilitate classical grasping and manipulation methods, such as assessing grasp stability and planning hand-finger trajectories for manipulating rigid objects. At least one embodiment estimates high-resolution surface deformations of the tactile sensor (tactile fields) from raw tactile signals. In at least one embodiment, these tactile fields provide high-density information useful for interacting with small, geometrically-irregular, fragile, or compliant objects. At least one embodiment accurately synthesizes raw tactile signals from tactile features or fields. In at least one embodiment, synthesis of such signals enables training of real-world control policies fully in simulation.

At least one embodiment described herein addresses these questions for a SynTouch BioTac tactile sensor. The BioTac is a commercially-available fingertip-shaped sensor that consists of a flexible rubber skin, an ionically-conductive fluidic layer, and a rigid core. The primary measurement device within the sensor is an array of 19 sensing electrodes and four excitation electrodes located on the outer surface of the core. In at least one embodiment, a tactile sensor can produce other forms of signals such as optical, electrical, capacitive, or tactile signals that represent contact with the sensor. In at least one embodiment, although electrode signals of the BioTac are discussed here, for other types of tactile sensors, the corresponding type of signal may be used. In at least one embodiment, as the tactile sensor contacts an object, a fluidic layer around the sensor changes shape, altering the voltages measured at the sensing electrodes ( [symbol] ¹⁹). In at least one embodiment, these voltages have a complex relationship with the surface deformations and distributed forces on the rubber skin. In at least one embodiment described herein, a BioTac was selected due to its high spatial resolution and sensitivity, low stiffness and hysteresis, compact form factor, and widespread use in research.

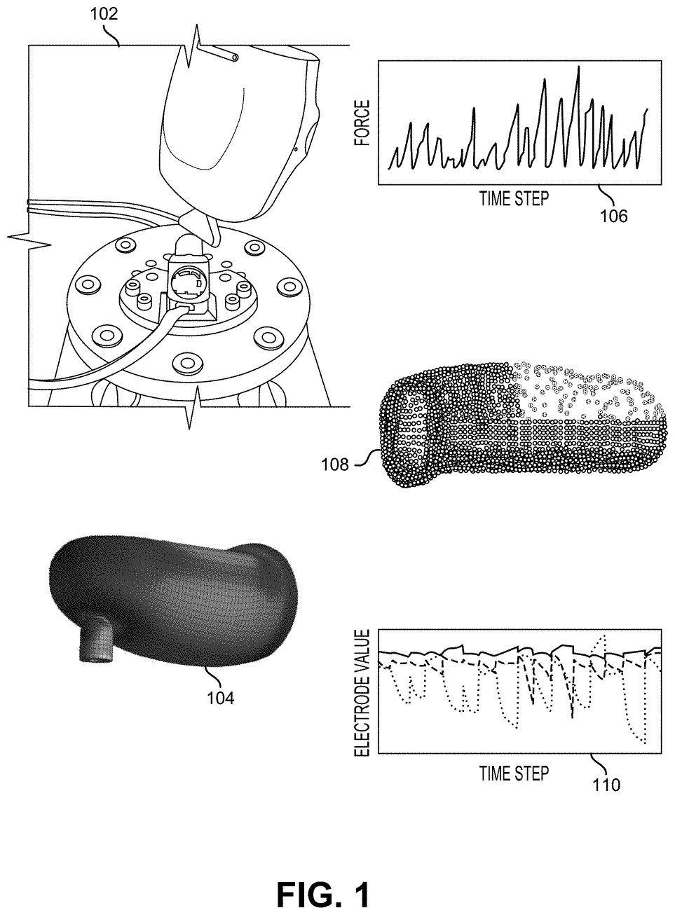

FIG. 1 illustrates an example of techniques used to evaluate tactile robotic feedback, in at least one embodiment. In at least one embodiment, a test fixture 102 is used to impose calibrated forces on a tactile sensor to produce an experimental data set. In at least one embodiment, deformations of a membrane surrounding the tactile sensor are modeled using a finite element model 104. In at least one embodiment, other types of physics models may be used to model the tactile sensor such as ridged body models, mass-spring models, or position-based dynamics models. In at least one embodiment, a physics model is a mathematical model that allows for the modeling of a physical object in which the parameters of the model can be adjusted to match a physical object. In at least one embodiment, experimental data is used to produce a regression to low-density tactile features, including 3-D net force vectors 106. In at least one embodiment, a regression to high-density tactile fields is produced, illustrating deformations 108 of the membrane surrounding the tactile sensor. In at least one embodiment, given a set of deformations, synthesis of predicted electrode signals 110 can be produced from a trained model.

In at least one embodiment, a novel experimental dataset containing 3D contact locations, 3D net force vectors, and tactile sensor electrode values is generated. In at least one embodiment, the data set is collected from 9 robot-controlled indenters interacting with three tactile sensors, with over 400 unique indentation trajectories, 800 total trajectories, and 50k data points after subsampling. In at least one embodiment, contact location is accurately measured through careful design and calibration of a testbed. In at least one embodiment, approximately 70% of the trajectories are designed to induce shear forces, and important mechanical phenomenon in grasping and manipulation. In the present document, the dataset is hereafter referred to as the purely experimental dataset.

In at least one embodiment, a 3D finite-element (“FE”) model of the tactile sensor is provided. Although previous studies have hypothesized that the deflection of the rubber skin of a tactile sensor is almost impossible to model, the FE model described herein captures this behavior and its underlying mechanical phenomena. In at least one embodiment, this model is validated against experimental 3D net force vectors and generalized over the wide range of indenters and indentation trajectories; thus, the model can be used to predict the mechanical behavior of the tactile sensor in diverse conditions. In at least one embodiment, a second dataset is provided that contains FE predictions of tactile sensor surface deformations, aligned with the previously-described experimental data. In the present document, this dataset is referred to as the mixed dataset.

In at least one embodiment, a neural-network provides a mapping from A) electrode signals to tactile features (such as experimental 3D contact locations and net force vectors), and B) electrode signals to tactile fields (such as FE surface deformations). In at least one embodiment, mapping A can be used to implement classical grasping and manipulation methods using raw tactile data. In at least one embodiment, mapping B is a first-of-its-kind, high-density version of mapping A, which can inform control in far greater detail, as well as enable the implementation of algorithms that leverage such high-resolution information.

In at least one embodiment, analyses and detailed visualizations of the experimental and simulation datasets are provided, including the distributions of contact locations, forces, electrode values, and FE deformations. At least one embodiment provides an ablation study that compares how accurately multilayer perceptrons (MLP), 3D voxel-grid-based convolutional neural networks (CNN), and point-cloud-based neural networks can regress to tactile features. At least one embodiment provides a more detailed analysis of the accuracy of the tactile feature regressions when applied not only to unseen trajectories, but also to unseen indenters and tactile sensors. This analysis elucidates how well learning-based methods can generalize, in at least one embodiment. At least one embodiment provides neural-network mappings from tactile fields to raw electrode signals. In at least one embodiment, these mappings outperform previous efforts to synthesize electrode signals.

In summary, the most comprehensive studies performed manual indentation of a single Tactile sensor, imprecisely measured contact location, and/or applied forces in the normal direction. From the highest-quality datasets, the state-of-the-art in tactile feature estimation from Tactile sensor electrode data is 1) an RMS contact location error of 2-3 mm, 2) a median force magnitude error of 0.3-0.5 N, and 3) a median force direction error of 0.07 rad. In contrast, an aim of research is to generate a more diverse, higher-quality dataset and meet or exceed these estimation benchmarks.

At least one embodiment estimates electrode signals from simulated tactile fields and does so with improved accuracy, facilitating simulation-based training of control policies that are precise and able to leverage high-density data.

In at least one embodiment, to automatically collect high-quality ground-truth 3D contact locations and net force vectors from a tactile sensor, a custom experimental setup is utilized and carefully calibrated. In at least one embodiment, the setup includes three major components: 1) an ABB YuMi bimanual robotic manipulator, 2) 3D-printed indenters attached to the distal links of the manipulator, and 3) a mount that rigidly coupled the tactile sensor to a Weiss Robotics KMS40 6-axis strain-gauge-based F/T sensor. In at least one embodiment, the YuMi is used due to its high positional repeatability (0.02 mm) and large dexterous workspace achieved by its two 7-DOF arms. In at least one embodiment, the indenters are designed to capture primitive geometry of everyday household objects. In at least one embodiment, indenters can be 3D-printed using a Prusa i3 MK3 desktop printer at fine resolution (0.05 mm) and attached to the distal links of the YuMi using precision alignment pins and metal screws. Although descriptions herein may refer to an implementation using a YuMi robot, those skilled in the art will appreciate that the described techniques are equally applicable to other forms of robot or positioning device including other types of articulated robots, factory automation machines, autonomous vehicles, or mechanical actuators.

In at least one embodiment, the mount itself can be constructed of four parts 1) a 3D-printed fixture into which the tactile sensor is inserted, 2) a 3D-printed circular plate that couples the tactile sensor fixture to the Weiss F/T sensor, 3) the F/T sensor itself, and 4) a 3D-printed base plate that allows the F/T sensor to be stably coupled to a benchtop using external C-clamps. In at least one embodiment, the tactile sensor achieves an interference fit within its fixture and is secured at a predefined depth using a set screw. In at least one embodiment, the fixture, circular plate, F/T sensor, and base plate are coupled together using precision dowel pins and metal fasteners.

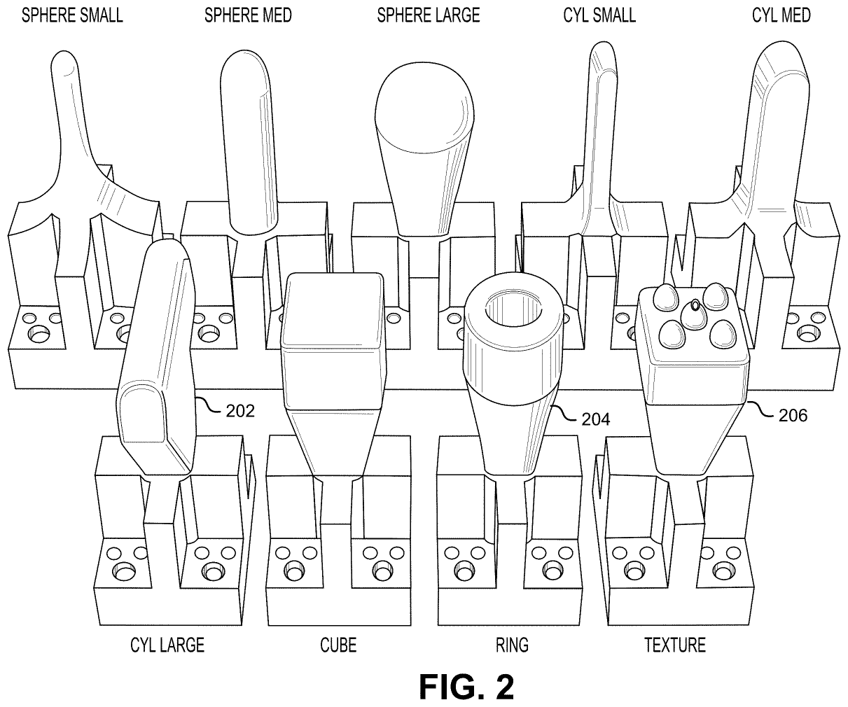

FIG. 2 illustrates an example of indenters used to calibrate a tactile sensor, in at least one embodiment. In at least one embodiment, nine indenters represent the geometry of everyday objects and surfaces. In at least one embodiment, example representations include the cylinder long indenter 202, which models table and object edges, the ring indenter 204, which models bottle openings, and the texture indenter 206, which models scattered grains and debris on kitchen surfaces. In at least one embodiment, dimensions of the indenters are scaled to approximately half, equal, or double the radius of the tactile sensor.

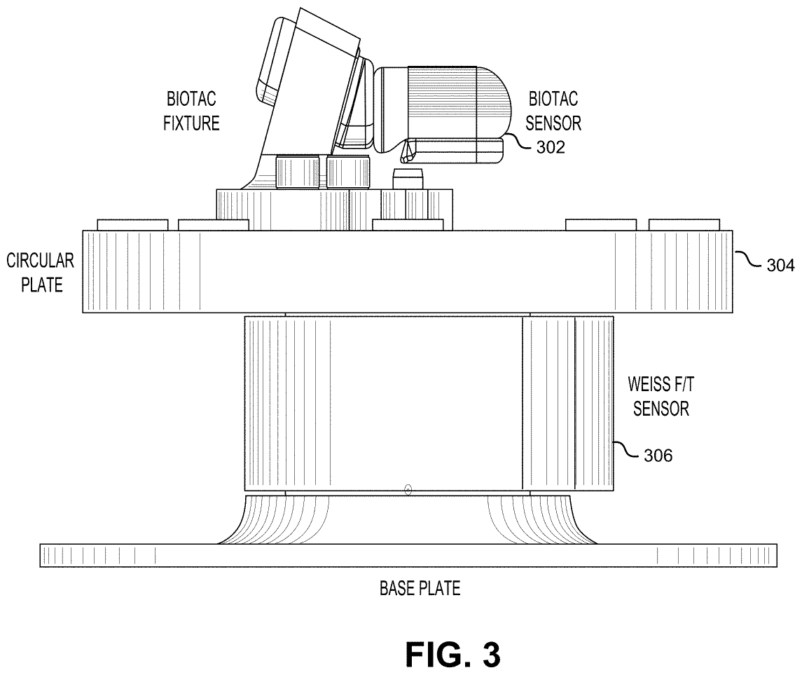

FIG. 3 illustrates an example of a fixture used to calibrate a tactile sensor 302, in at least one embodiment. In at least one embodiment, fixture includes a 3D-printed circular plate 304 that couples the tactile sensor fixture to a Weiss Robotics force/torque sensor 306, the force/torque sensor itself, and a 3D-printed base plate that allowed the force/torque sensor to be coupled to a benchtop. In at least one embodiment, signals from the force/torque sensor mounted to the fixture are used to adjust the finite element model of the tactile sensor.

In at least one embodiment, to spatially register the 6D pose of the robot end-effectors with respect to the BioTac, a mechanical registration apparatus is utilized. In at least one embodiment, the apparatus includes two major components: diamond-head shoulder-style metal alignment pins attached to the distal links of the two arms of the YuMi, and metal hole liners that are press-fit into corresponding holes along the circumference of the circular plate. In at least one embodiment, the worst-case clearance between the alignment pins and hole liners is approximately 0.3 mm. in at least one embodiment, metal shims are temporarily inserted between the circular plate and the F/T sensor to prevent large loads during registration from pitching the plate.

In at least one embodiment, during registration, lead-through mode on the YuMi is enabled, and the alignment pin for a given arm is manually guided into a metal hole liner until the bottom face of the pin's shoulder rests flush against the top face of the hole liner. In at least one embodiment, upon contact, the end-effector position is recorded in a robot-fixed coordinate frame R as vector p₁^{R} (using a forward kinematic model of the YuMi and alignment pin) and in a tactile-sensor-fixed coordinate frame B as vector q₁^{B} (using a CAD model of the undeformed tactile sensor and experimental mount). In at least one embodiment, this this operation is repeated for two additional hole liners, resulting in measurements p^{R}={p₁^{R},p₂^{R},p₃^{R}} and q^{B}={q₁^{B},q₂^{B},q₃^{B}}. In at least one embodiment, p^{R} and q^{B} correspond to two physically distinct sets of non-collinear position vectors, where the endpoints of a given p₁^{R} and q₁^{B} are coincident.

In at least one embodiment, vectors v₁^{R}=p₂^{R}−p₁^{R} and v₂^{R}=p₃^{R}−p₁^{R} are computed for R, and vectors v₁^{B}=p₂^{B}−p₁^{B} and v₂^{B}=p₃^{B}−p₁^{B} are computed for B. In at least one embodiment, v^{R}={v₁^{R},₂^{R}} and v^{B}={v₁^{B},v₂^{B}} correspond to a physically similar set of 2 non-orthonormal basis vectors for a common intermediate frame I, expressed in R and B, respectively. In at least one embodiment, using sequences of cross products, orthonormal basis vectors x^{R}={\hat{x}^{R},ŷ^{R},\hat{z}^{R}} are generated for I from v^{R}, and physically identical vectors x^{B}={\hat{x}^{B},ŷ^{B},\hat{Z}^{B}} are generated from v^{B}. In at least one embodiment, x^{R} and x^{B} are used to define homogeneous transformation matrices _{I}^{R}H and _{I}^{B}H, respectively. In at least one embodiment, the desired transformation matrix from the robot-fixed coordinate frame to the tactile sensor-fixed coordinate frame is:

_{R}^{B}H=_{I}^{B}H(₁^{R}H)⁻¹ (2)

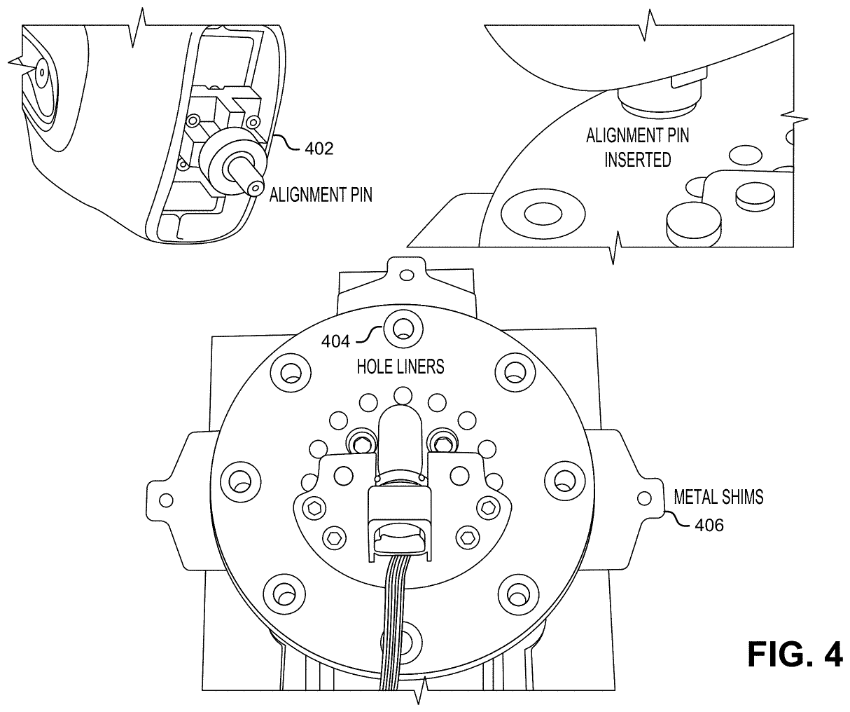

FIG. 4 illustrates an example of a mechanical registration apparatus, in at least one embodiment. In at least one embodiment, a precision alignment pin 402 is attached to the distal link of one of the arms of a YuMi robot. In at least one embodiment, an overhead view of the apparatus, illustrating precision metal hole liners 404 and temporarily-inserted metal shims 406 assists in alignment of the tactile sensor with an indenter. In at least one embodiment, the alignment pin 402 is inserted into a hole liner 404 during the registration procedure.

In at least one embodiment, to ensure robustness to measurement error, the previous procedure is repeated for all 3-hole combinations of four different hole liners on the circular plate. In at least one embodiment, the transformation matrices for all combinations are averaged to produce a final transformation matrix. In at least one embodiment, registration error between the robot and tactile sensor is observed to be between 0.5-1.5 mm over the full range of robot joint configurations and end-effector positions traversed during testing. In at least one embodiment, a mechanical registration procedure is applied to the right and left arms of the YuMi independently.

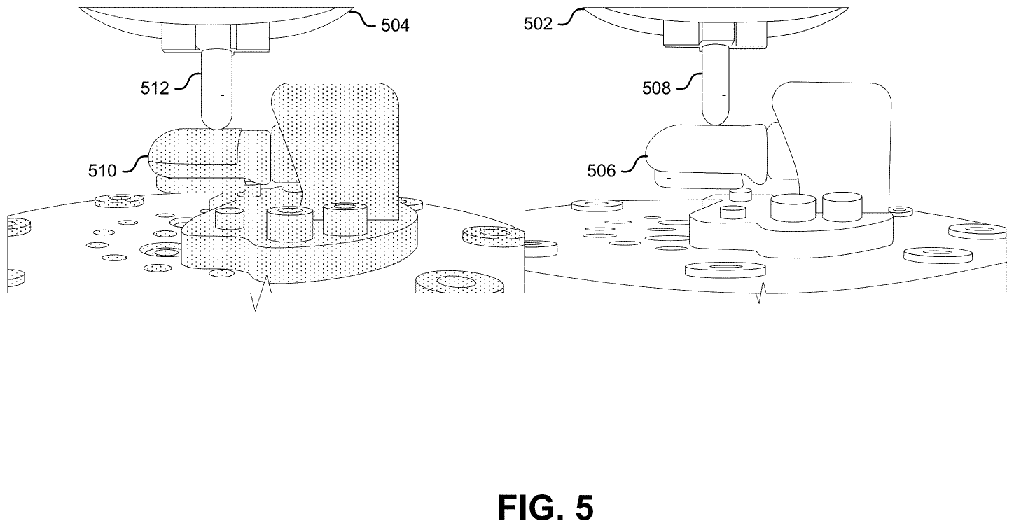

FIG. 5 illustrates an example of a simulation used to calibrate a tactile sensor, in at least one embodiment. In at least one embodiment, a simulated calibration apparatus 504 is created that mirrors a physical apparatus 502. In at least one embodiment, the physical apparatus 502 includes an alignment fixture containing a tactile sensor 506, and an indenter 508. In at least one embodiment, simulation 504 includes a simulated tactile sensor 510 and a simulated indenter 512. In at least one embodiment, poses performed on the physical apparatus 502 are also performed using the simulated calibration apparatus 504.

In at least one embodiment, for each indenter used, 10 unique points are randomly sampled from a subsection of the ventral surface of the tactile sensor, referred to herein as the sampled region. In at least one embodiment, with respect to the long axis of the tactile sensor, points on the side closer to the right arm of the YuMi are assigned to that arm for indentation, and vice versa for points closer to the left arm. In at least one embodiment, for each point, an indentation trajectory was generated normal to the surface. In at least one embodiment, four angled trajectories were generated along lines oriented at 30 deg from the surface normal in order to purposely induce shear loading. In at least one embodiment, note that due to the width of the indenters, as well as the angles of the trajectories, contact with the tactile sensor may occur well outside the sampled region.

In at least one embodiment, each trajectory was designed to begin 3 mm away from the surface of the tactile sensor and ultimately indent the sensor by approximately 3 mm (for normal indentations) or approximately 1.5 mm (for angled indentations) past the point of initial contact. In at least one embodiment, each trajectory is divided into 0.1 mm displacement increments, with 5 sec allotted to each increment in order to allow fluid-structure interaction dynamics in the tactile sensor to settle. In at least one embodiment, trajectories and joint commands are generated using Riemannian Motion Policies (“RMP”), which are well suited to position-control applications requiring high accuracy, avoidance of self-collisions, and avoidance of specific obstacles. In at least one embodiment, trajectories are simulated using the ROS rviz package, and specific trajectories are eliminated that could not be achieved with sufficiently high end-effector accuracy (i.e., 0.01 mm or better, according to a forward kinematic model of the YuMi and indenter) or resulted in unexpected collisions with the tactile sensor mount.

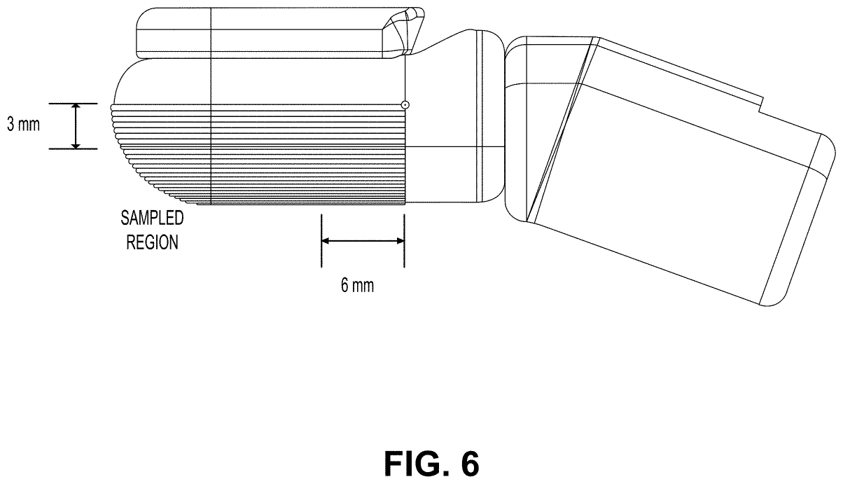

FIG. 6 illustrates an example of a tactile sensor, in at least one embodiment. In at least one embodiment, target points are sampled from the indicated region, with dimensions defined with respect to the bounds of the tactile sensor fingerprints. In at least one embodiment, due to the width of the indenters and the angular orientations of the trajectories, contact may occur well outside the sampled region.

In at least one embodiment, prior to execution of the trajectories on the real-world experimental setup, the tactile sensor is connected to power and left untouched for approximately 30 min. In at least one embodiment, conductivity of the tactile sensor fluid and the corresponding electrode values are dependent on temperature, and this waiting period allows the tactile sensor to reach thermal equilibrium. In at least one embodiment, trajectories are then executed, and the experiments are repeated for three different tactile sensors. In at least one embodiment, joint angles from the active YuMi arm ( [symbol] ⁷), net force/torque data from the Weiss F/T sensor ( [symbol] ⁶) and electrode values from the tactile sensor ( [symbol] ¹⁹) are continuously acquired at a minimum of 100 Hz using ROS. In at least one embodiment, joint angles are converted to indenter tip positions ( [symbol] ³) using a forward kinematic model of the YuMi and indenter. In at least one embodiment, 3D contact locations are defined as tip positions after contact with the tactile sensor. In at least one embodiment, electrode values are normalized from a raw 12-bit range to a [0,1] interval. In at least one embodiment, tip positions, force/torque data, and electrode values are time-stamped and recorded. In at least one embodiment, for later subsampling, time stamps are also separately recorded at the end of each 0.1 mm displacement increment within each trajectory.

In at least one embodiment, the following post-processing steps are performed on the experimental data to produce the purely experimental dataset:
1. To reduce the dataset size (>1.5e6 samples) and mitigate redundancy, the indenter tip positions, force/torque data, and electrode values are subsampled at the final time step of each 0.1 mm displacement increment within each trajectory.
2. To mitigate drift, force/torque values and tactile sensor electrode values for each indentation are tared against their respective values at the first time step of the trajectory (i.e., before contact between the tactile sensor and indenter had occurred).
3. Due to noise on the F/T sensor readings, a 1st-order Butterworth low-pass filter with a cutoff frequency of 5 Hz is applied forward and backward to the force data. However, at net force magnitudes below 0.5 N, substantial noise may persist. Therefore, experimental data corresponding to forces below this threshold may be filtered out. After filtering, initial experimental data points corresponded to force magnitudes slightly higher than 0.5 N; to facilitate later alignment with simulation data, linear interpolation may be used to prepend experimental data points corresponding to exactly 0.5 N.

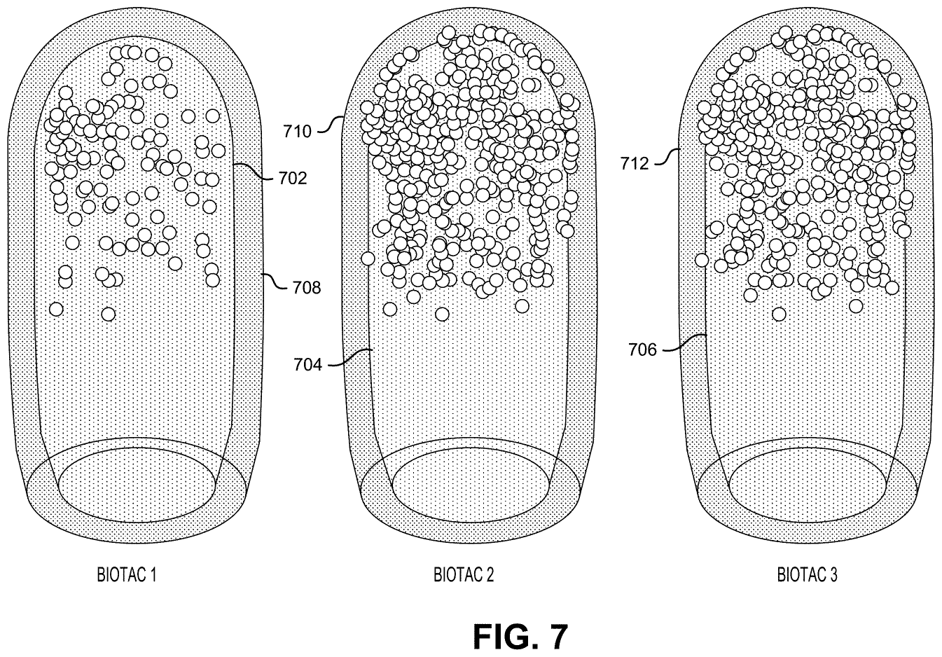

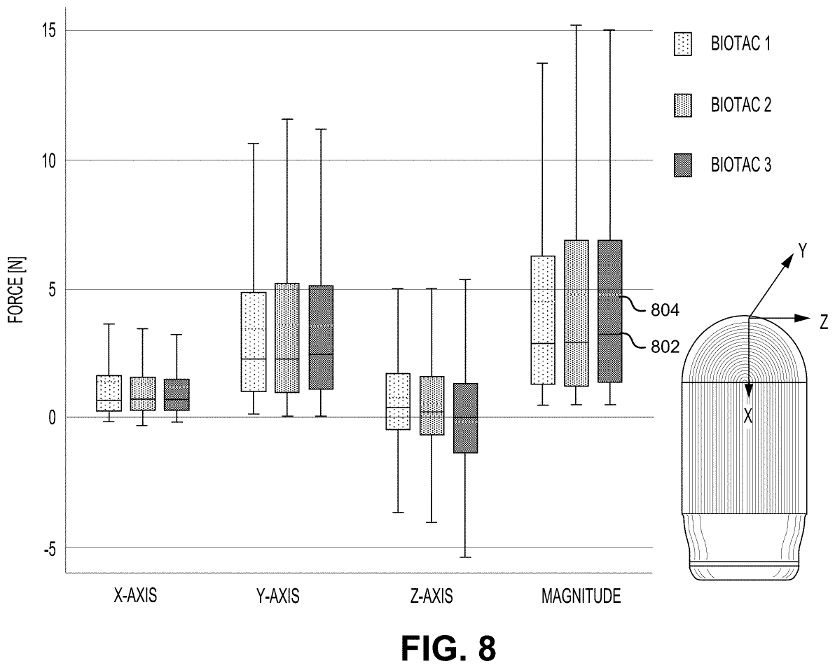

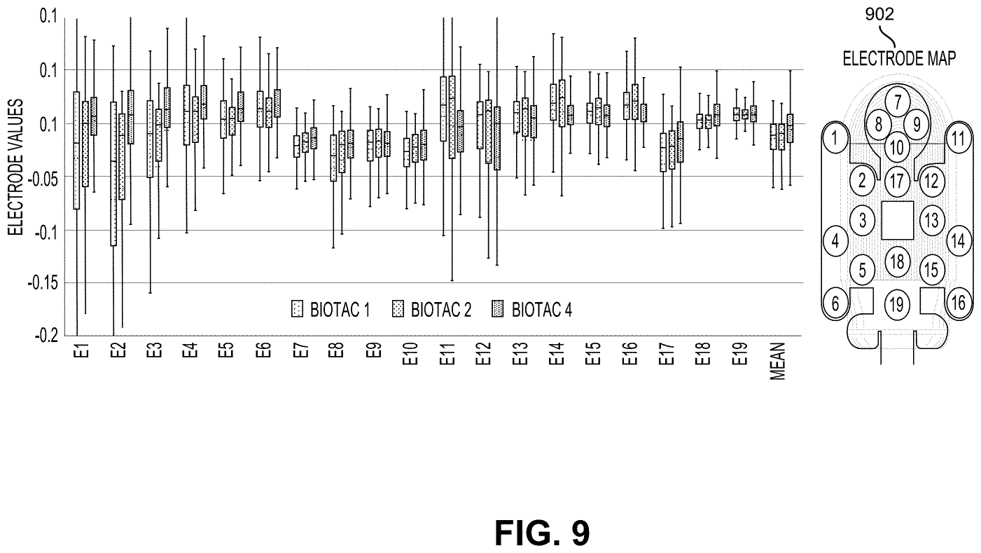

In at least one embodiment, after post-processing, the dataset includes 411 unique trajectories, 889 total trajectories, 17703 time steps, and 53109 data points. FIG. 7, FIG. 8, and FIG. 9 illustrate the distributions of the 3D contact locations, 3D force vectors, and electrode values. In at least one embodiment, as depicted, a diverse set of interactions is explored, and a broad range of sensor values is collected. In at least one embodiment, the contact locations and force values are highly consistent from one tactile sensor to another, whereas electrode values are less consistent. In at least one embodiment, this lack of consistency in experimental results likely reflects electronic manufacturing variability within the tactile sensor tactile sensors used, complicating the task of transfer learning from one device to another.

FIG. 7 illustrates an example of contact locations for a tactile sensor, in at least one embodiment. In at least one embodiment, inner 702, 704, 706 and outer 708, 710, 712 ventral surfaces of the undeformed tactile sensor skin are shown. In at least one embodiment, circular marks indicate contact locations and are given for the final displacement increment of each trajectory.

FIG. 8 illustrates an example of force values, in at least one embodiment. In at least one embodiment, the solid and dotted horizontal lines (such as 802 and 804 respectively) in the boxes indicate the median and mean. In at least one embodiment, box height is equal to the interquartile range (“IQR”). In at least one embodiment, fence length is equal to 1.5*IQR, rounded down to the nearest data point. In at least one embodiment, the maximum force magnitudes (not pictured) for tactile sensor 1, 2, and 3 were 23.4, 32.1, and 29.0 N, respectively.

In at least one embodiment, for tactile fields, such as surface deformations on the tactile sensor and distributed forces transmitted across the tactile sensor-object interface, real-world ground-truth data is prohibitively difficult to acquire. In at least one embodiment, to generate near-ground-truth data for such quantities, a finite element (“FE”) model was developed.

A brief overview is provided here. In the context of the present document, the FE method is a numerical technique for solving partial differential equations (“PDEs”). As an example relevant to at least one embodiment described herein, the PDEs for the deformation of a 3D solid object that 1) is in static equilibrium, 2) has a linear stress-strain relation, and 3) experiences small deformations, can be written concisely as

σ_{ji,j}+fᵢ=0 (3)

σᵢⱼ=C_{ijklϵkl} (4)

ϵᵢⱼ=1/2(u_{i,j}+u_{j,i}) (5)

where Equation 3 expresses the static equilibrium equations (σ is the 2nd-order stress tensor; f is the body force per volume; i, j, k, and l denote spatial axes; the comma denotes a partial derivative; and Einstein summation convention is used. In at least one embodiment, equation 4 expresses the linear stress-strain equations, also known as Hooke's Law (ϵ is the 2nd-order strain tensor, and C is the 4th-order stiffness tensor that relates σ to ϵ); and Equation 5 expresses the small-deformation strain-displacement equations (u is displacement). In at least one embodiment, these systems of PDEs can often be condensed into a single governing PDE for particular problems (e.g., bending beams). In at least one embodiment, additional equations are added to apply boundary conditions (i.e., geometric constraints or loading conditions).

In at least one embodiment, such PDEs are challenging to solve analytically. In at least one embodiment, for the 3D deformable solid, solving a governing PDE to compute a displacement field uᵢ along a spatial axis i is only tractable for the simplest boundary conditions. In at least one embodiment, a basic numerical approach would attempt to approximate the solution as a linear combination of functions, such as

$${u}_{i} = {\sum }_{m}^{N} {c}_{m} {ϕ}_{m} \qquad ( 6 )$$

where ϕₘ are basis functions to be chosen (e.g., polynomials); cₘ are unknown coefficients to be solved for; m is not a spatial axis, but an arbitrary index; and N is a finite positive integer, which determines the number of points at which the PDE is to be satisfied. In at least one embodiment, for a given PDE, boundary conditions, ϕₘ, and solution points, there may be no exact solution for the cₘ; furthermore, even exact solutions may result in uᵢ that are inaccurate over most of the spatial domain.

In at least one embodiment, to address these issues, a weighted-integral formulation may be used, such as

∫ᵥwₘR(uᵢ)dV=0 (7)

where R is the residual of a PDE (i.e., a simple rearrangement), wₘ are weight functions to be chosen (e.g., could be polynomials as well), and V is volume. In at least one embodiment, the approximation for the solution to the PDE (e.g., Equation 6) can be substituted into R, and the cₘ can be solved for once again. In at least one embodiment, intuitively, the PDE is now satisfied on average over the entire spatial domain, according to multiple weight distributions determined by the wₘ. In at least one embodiment, such integrals may be difficult to evaluate; furthermore, for an arbitrary problem with complex geometry and boundary conditions, determining reasonable ϕₘ and wₘ may be challenging.

In at least one embodiment, The FE method approaches this issue by dividing a complex geometrical domain (e.g., the tactile sensor) into simple geometric subregions. In at least one embodiment, the subregions are typically referred to as elements, and the vertices of the elements as nodes; all elements and nodes collectively define a mesh. In at least one embodiment, for 3D geometries, the elements often have a tetrahedral or hexahedral shape. In at least one embodiment, the weighted-integral equations are now formulated for each element (specifically, the weak form of these equations, which reduces differentiability requirements for the ϕₘ). In at least one embodiment, typically, N is assigned to be the number of degrees of freedom of the element along a spatial axis (i.e., the number of nodes); the cₘ are assigned to be the unknown nodal positions uₘ; the ϕₘ, are assigned to be polynomials that ensure that uᵢ=uₘ at each node; and the wₘ are chosen to be identical to the ϕₘ.

In at least one embodiment, as displacements are continuous from element to element, the weighted-integral equations cannot be solved for each element individually. In at least one embodiment, a system of coupled equations for all elements is assembled, which has form

$${K}_{qr} {u}_{r} + {C}_{qr} \frac{\partial {u}_{r}}{\partial t} = {M}_{qr} \frac{{\partial }^{2} u r}{\partial {t}^{2}} \qquad ( 8 )$$

where K, C, and M are referred to as the stiffness, damping, and mass matrices, respectively; u is the vector of all nodal positions; and q and r denote spatial axes. In at least one embodiment, this system of equations can be solved via numerical linear algebra techniques. In at least one embodiment, in essence, the FE method transforms PDEs into large sets of algebraic equations that resemble mass-spring-damper equations, with a systematic approach for determining the matrix coefficients. In at least one embodiment, with high mesh density and sufficiently small time steps, predictions for the deformation of solids can be extremely accurate, even for highly nontraditional mechanical systems.

FIG. 9 illustrates an example of electrode values, in at least one embodiment. In at least one embodiment, box plots are shown for the electrodes of a number of tactile sensors. In at least one embodiment, electrodes are denoted by the E prefix on the x-axis, and electrode values are normalized and tared as described in Section 3.3 and Section 3.4. In at least one embodiment, solid horizontal lines in the boxes indicate the median. In at least one embodiment, the box height is equal to the interquartile range. In at least one embodiment, the fence length is equal to 1.5*IQR, rounded down to the nearest data point. In at least one embodiment, the full range of electrode values (not pictured) for three tactile sensors 1,2, and 3 were [−0.65,0.13], [−0.78,0.11], and [−0.51,0.17], respectively, where the theoretical maximum span was 1. In at least one embodiment, higher IQR for certain electrodes does not necessarily indicate that greater or more frequent deformation was experienced near those electrodes, as electrode value has a highly nonlinear relationship with deformation that varies from electrode to electrode. In at least one embodiment, an electrode map 902 of electrodes on a tactile sensor is also illustrated. In at least one embodiment, an unwrapped electrode map is shown superimposed on a rounded ventral view of the tactile sensor.

In at least one embodiment, the FE model was developed and simulated using ANSYS Mechanical v19.1, an industry-standard nonlinear FE software. In at least one embodiment, to match the quasi-static conditions of the real-world experiments, static structural simulations were performed.

In at least one embodiment, geometrically, the FE model includes four components: 1) the tactical sensor skin, 2) the tactile sensor core, 3) the fluid between the skin and the core, and 4) the indenter in contact with the tactile sensor. In at least one embodiment, the initial CAD models of the skin and core were acquired from the manufacturer; however, the asperities on the interior and exterior surface of the skin (fingerprints) were removed to facilitate meshing and expedite convergence. In at least one embodiment, four-node shell elements (SHELL181) were selected for the skin due to their high efficiency and accuracy for modeling large, nonlinear deformation of thin and thick membranes. In at least one embodiment, the core was defined as a rigid body, and hydrostatic fluid elements (HSFLD242) were used for the fluid layer to enforce efficiently physically realistic incompressibility (conservation of the fluidic volume). In at least one embodiment, rather than defining the indenter as a rigid body, 4-node shell elements were used to enable extraction of distributed loads. In at least one embodiment, large-deformation analysis is enabled, allowing the strain-displacement relations of Equation 5 to be complemented with terms that are quadratic in the partial derivatives of u.

In at least one embodiment, the stress-strain relations for the tactile sensor skin are then defined, as well as the material properties of the fluid. The tactile sensor skin is made of silicone rubber; the stress-strain behavior of such a material is highly nonlinear, and consequently, is difficult to accurately model with linear relations, such as those of Equation 4. In at least one embodiment, rubber is modeled with a hyperelastic material model, in which the stress-strain relationship is nonlinear, but energy is conserved during loading.

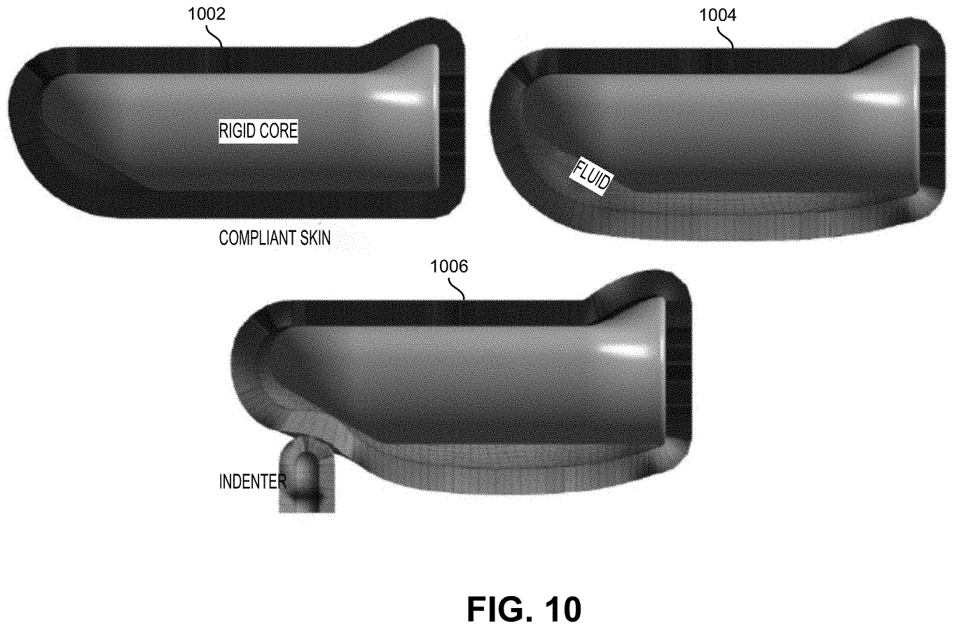

FIG. 10 illustrates an example of finite element model deformation for a skin of a tactile force sensor, in at least one embodiment. In at least one embodiment, FIG. 10 illustrates a cross-sectional view during an example simulation, prior to pressurization 1002, after pressurization 1004, and during indentation 1006.

In at least one embodiment, for mathematical convenience, the stress-strain relations for a hyperelastic material are often defined indirectly in terms of an energy density function W (Cᵢⱼ), where C is the right Cauchy-Green deformation tensor, a deformation metric that describes how the squares of distances change during deformation. In at least one embodiment, note that the deformation at any point in the material can be expressed as extensions or compressions along three principal axes. In at least one embodiment, as energy density does not change with the coordinate frame, W can be rewritten as a function of the tensor invariants of Cᵢⱼ, which themselves are functions of the principal stretches λ₁,λ₂, and λ₃; these λᵢ are strain-like quantities that describe the length of the principal axes after deformation, normalized by original length. In at least one embodiment, from the work-energy principle, the stress-strain relations along the principal axes can be derived as

$${σ}_{i} + \frac{1}{{λ}_{j} {λ}_{k}} \frac{\partial W}{\partial {λ}_{i}} \qquad ( 9 )$$

where i, j, and k are arbitrary principal axes, with i≠j≠k.

In at least one embodiment, due to its mathematical simplicity and accuracy, the incompressible Neo-Hookean energy density function was chosen for the skin. In at least one embodiment, this function can be written as

$$W = \frac{{μ}_{NH}}{2} ( {λ}_{1}^{2} + {λ}_{2}^{2} + {λ}_{3}^{2} ) \qquad ( 10 )$$

where μ_{N H} is a specified stiffness parameter (assigned in Section 3.8 via optimization), and stretches λᵢ satisfy the incompressibility constraint λ₁λ₂λ₃=1 (Treloar (1974)). In at least one embodiment, as for the fluid, although the tactile sensor may be approximated as isothermal after an initial waiting period, an arbitrary volumetric thermal expansion coefficient β_{T}=0.01C⁻¹ was defined as a simple means to later adjust the fluidic volume (as described later in this section).

In at least one embodiment, from simulation and physical considerations, three spatial boundary conditions are defined: 1) grounding of the rigid core, which removes rigid-body modes from the simulation, 2) anchoring together the proximal (i.e., right, in FIG. 10) surfaces of the skin and core, which models the effect of the circumferential tactile sensor clamp, and 3) anchoring together the dorsal (i.e., top, in FIG. 10) surfaces of the skin and core, which models the effect of the tactile sensor nail. In at least one embodiment, two contact boundary conditions are defined: frictionless contact between the skin and core (due to lubrication provided by the fluid), and frictional contact between the indenter and the skin. In at least one embodiment, the normal-Lagrange contact formulation is selected to minimize interpenetration. In at least one embodiment, a mesh refinement study is used to prescribe a maximum mesh dimension of 0.5 mm; less than this value, changes in simulation results were negligible.

In at least one embodiment, two load steps are applied: 1) a pressurization step, in which the volume of fluid between the skin and core is gradually increased over 5 equal time steps (FIG. 10B), and 2) an indentation step, in which displacements were applied to the indenter over 20 equal time steps (FIG. 10C). In at least one embodiment, the pressurization step is used because the manufacturer provides CAD models of the unpressurized tactile sensor (no fluid); in simulation, the temperature of the fluid is increased until the total sensor thickness matched the manufacturer's specification of 15.1 mm. In at least one embodiment, for step 2, the indentation trajectories are specified to match exactly the target trajectories in the real-world experiments. In at least one embodiment, an asymmetric Newton-Raphson solver is selected to facilitate convergence for frictional contact between the indenter and the skin.

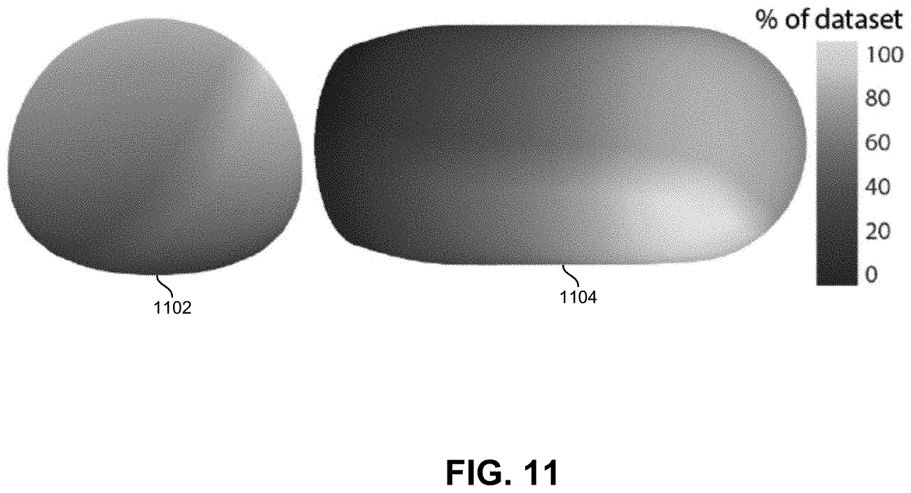

In at least one embodiment, the simulation is executed using 6 CPUs. In at least one embodiment, two primary quantities are extracted: 1) nodal coordinates at the end of step 1, which served as reference coordinates, and 2) nodal displacements throughout step 2, relative to the reference coordinates. In at least one embodiment, for later validation, the preceding simulation and data extraction procedure is repeated for every indenter and target trajectory examined in the real-world experiments, taking an average of 7 min per trajectory. In at least one embodiment, FIG. 11 illustrates the frequency of motion of each point on the tactile sensor mesh over all simulations. In at least one embodiment, the broad distribution reflects the high diversity of interactions.

FIG. 11 illustrates an example of finite element mesh motion, in at least one embodiment. In at least one embodiment, a front view 1102 and ventral view 1104 of the undeformed tactile sensor mesh are shown. In at least one embodiment, for each point on the mesh, the shade indicates how frequently that point exhibited significant motion, expressed as a percentage of all the time steps in the dataset. In FIG. 11, significant motion is defined as a displacement magnitude greater than 0.1 mm.

In at least one embodiment, experimental and simulation data is compared and combined for FE model calibration, FE model validation, and estimation of tactile fields. In at least one embodiment, experimental and simulation data exhibit structural differences, and post-processing may be used to ensure that the data is appropriately compared. In at least one embodiment, the following steps were performed to produce the mixed dataset (i.e., simulations aligned with experiments):
1. All trajectories generated in Section 3.3 were executed in simulation. However, as noted in the same section, some of these trajectories were disqualified for experimental testing due to anticipated inaccuracy or collisions. Furthermore, a very small number of trajectories failed in the real world due to spurious sensor saturation. All trajectories common to both experiment and simulation were compared.
2. For consistency with the experimental data (see Section 3.4), simulation data corresponding to net force magnitudes below 0.5 N were filtered out, and linear interpolation was used to prepend simulation data points corresponding to exactly 0.5 N. Thus, the starting points of the experimental and simulation datasets were exactly aligned according to force.
3. During contact between the skin and the internal rigid core, simulations often diverged due to the high stiffness of the incompressible rubber, combined with the moderately-large time steps used to ensure a reasonable simulation time. Simulation data at or following these divergence points were filtered out.
4. For a given trajectory, starting at the data points corresponding to 0.5 N, the total experimental and simulation indenter displacements were often slightly different, primarily due to simulation divergence. The minimum final displacement of the experimental and simulation trajectories was determined, and experimental and simulation data beyond that point were disregarded.
5. After the preceding steps were completed, experimental and simulation data were both linearly interpolated along 20 evenly spaced indenter displacement increments. Thus, the datasets could now be readily compared.

In at least one embodiment, as FE models express the laws of physics, they are highly constrained in comparison to data-driven approaches to predicting physical systems. In at least one embodiment, however, a small number of free parameters still need to be measured or estimated. In at least one embodiment, the current model has 4 parameters: 1) the thickness of the skin tₛₖ, which was geometrically modified to remove surface asperities (and thus, requires tuning to achieve accurate deformation relative to the original CAD model), 2) the coefficient μ_{N H} in the Neo-Hookean energy density function (Equation 10), 3) the coefficient of friction μfᵣ between the indenter and the skin, and 4) the temperature of the fluid T_{fl} that, given parameters 1 and 2, achieves a desired sensor thickness of 15.1 mm at the end of the first load step.

In at least one embodiment, to calibrate the values of these parameters, the net contact force on the tactile sensor was compared between FE simulations and corresponding experiments, and the parameters were tuned to minimize the mean squared error (MSE) over all time steps. In at least one embodiment, due to the small number of parameters, minimizing force error for a single indentation trajectory may produce parameters that generalize well across all indentations. In at least one embodiment, a specific angled trajectory of the sphere medium indenter may be selected due to its moderate contact area, localized deformation, and generation of both normal and shear stresses.

In at least one embodiment, a sequential least-squares programming (“SLSQP”) optimizer is used to minimize the following cost function:

$$\begin{matrix}{J}_{total} = {w}_{1} {J}_{force} + {w}_{2} {J}_{thick} \\ = {w}_{1} {\sum }_{i = 1}^{3} \sqrt{\frac{1}{N} {\sum }_{j = 1}^{N} {( {F}_{ij}^{sim} - {F}_{ij}^{ex p} )}^{2}} + {w}_{2} ( {t}_{sn}^{sim} - 0.0151 )\end{matrix} \qquad ( 11 )$$

where w₁ and w₂ are hand-selected weights; J_{force} is the sum of the RMS contact force error for each spatial axis; J_{thick} is a cost function ensuring that the total sensor thickness after pressurization matches the manufacturer's specification; N is the total number of samples (i.e., product of number of sensors and time steps per sensor); Fᵢⱼ^{sim} and Fᵢⱼ^{exp} are the simulated and experimental force, respectively, for spatial axis i and sample number j; tₛₙ^{sim} is the simulated total sensor thickness; and 0.0151 m is the manufacturer-specified thickness. In at least one embodiment, Fᵢⱼ^{sim} and tₛₙ^{sim} are functions of simulation parameters tₛ, μ_{N H}, μ_{fr}, and T_{fi}.

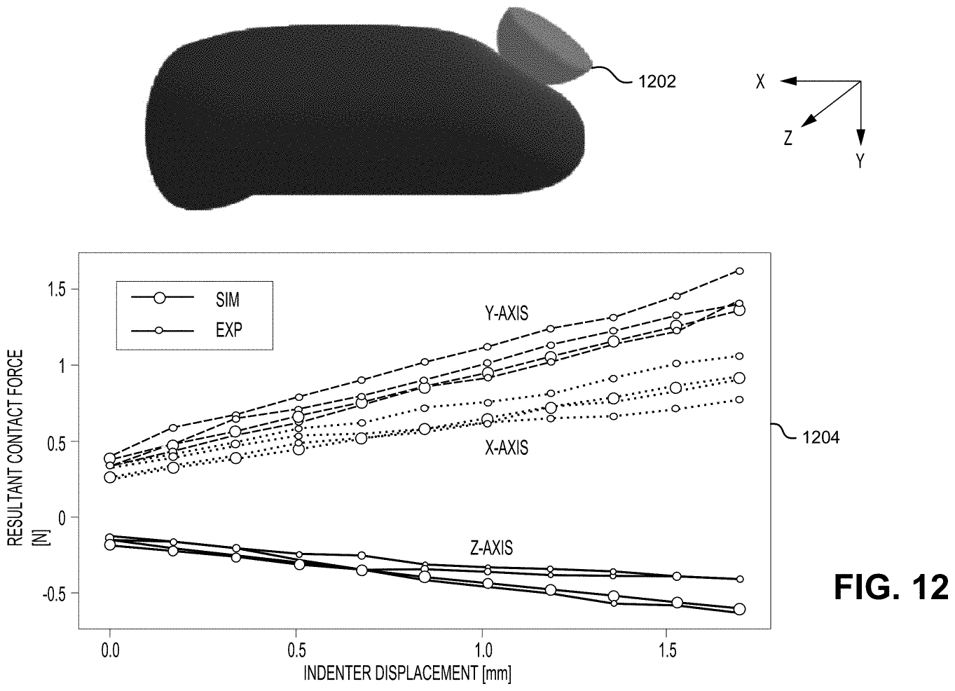

FIG. 12 illustrates an example of finite element model calibration, in at least one embodiment. In at least one embodiment, FIG. 12 illustrates the angled trajectory 1202 used for the calibration of finite element parameters. In at least one embodiment, the corresponding simulation and experimental data 1204 is shown for the net contact force acting on the tactile sensor along each spatial axis. Simulation data after optimization is also shown.

In at least one embodiment, weights w₁ and w₁ were selected to be 1 and 1e4, respectively, such that J_{force} was approximately one order of magnitude higher than J_{thick} throughout optimization. In at least one embodiment, from physical consideration of the components comprising the tactile sensor, upper and lower bounds on the simulation parameters were chosen to represent large, but realistic ranges. In at least one embodiment, the bounds, as well as the optimized values of the parameters, are given in Table 1. In at least one embodiment, FE predictions and experimental values for the net force after optimization are illustrated in FIG. 12.

TABLE 1
Optimization parameters. Upper and
lower bounds for the parameters are
given, as well as optimized values.

| | | μ_{N H} | | |
|---|---|---|---|---|
| | tₛ[m] | [Pa] | μ_{fr} | T_{fl} [° C.] |
| lower | 1e−3 | 1e5 | 0.1 | 25 |
| upper | 2e−3 | 1e6 | 1.0 | 35 |
| optimal | 1.57e−3 | 2.80e5 | 0.186 | 29.19 |

In at least one embodiment, to validate the calibrated FE model, the net contact force predicted by simulation was compared to corresponding experimental values as illustrated in FIG. 12, but now for every possible indenter and trajectory in the datasets.

In at least one embodiment, two tactile features (i.e., 3D contact location and 3D net force vector) are estimated from tactile sensor electrode values using neural networks. In at least one embodiment, the purely experimental dataset is used. In at least one embodiment, data from three tactile sensors is for training and testing. In at least one embodiment, the dataset is split, with approximately 70% of the indentation trajectories randomly apportioned to training, 20% to validation, and 10% to testing. In at least one embodiment, to properly evaluate generalizability, data from each trajectory is kept contiguous during apportionment. In at least one embodiment, the test set includes only data points from trajectories that were not present in the training set. In at least one embodiment, input data was normalized to zero mean and unit variance.

In at least one embodiment, three different network architectures are tested: MLP, 3D voxel-grid-based CNN, and PointNet++. At least one embodiment utilizes MLPs and a 3D voxel-grid-based CNN with sparse occupancy. At least one embodiment uses PointNet++, which directly consumes point cloud data, learns spatial encodings of each point, and hierarchically captures local structure. In at least one embodiment, although conceived for vision, this architecture is conceptually suitable for tactile sensor electrode values and FE nodal displacements, as these constitute point sets that are sparse, highly nonuniform, or both. Nevertheless, in at least one embodiment, all three architectures are directly compared quantitatively.

In at least one embodiment, for the MLP, regressions are independently performed from electrode values ( [symbol] ¹⁹) to contact location ( [symbol] ³) and force vector ( [symbol] ³). In at least one embodiment, no information about electrode locations is provided to the network. In at least one embodiment, the MLP is a fully connected network with layer dimensions [256, 128, 128]. In at least one embodiment, for the 3D CNN, identical regressions are performed. In at least one embodiment, information about electrode locations is provided by discretizing the tactile sensor into a uniform voxel grid with dimensions [16, 16, 8] and placing the input electrode values at their corresponding locations. In at least one embodiment, the 3D CNN includes two 3D convolutional layers with channels [64,256], followed by a 2D convolutional layer with 512 channels, and then regression is done with fully connected layers with channels [256,128]. In at least one embodiment, for PointNet++, regressions are independently performed from electrode values and electrode coordinates ( [symbol] ^{19×3}), used as features for each of the points, to contact location and force vector. In at least one embodiment, the network includes three set abstraction layers followed by two fully connected layers with channels [256,128]. In at least one embodiment, the abstraction layers downsampled the number of points to 32, 8, and 1 by considering points within a radius of 2.5 mm, 7 mm, and ∞, respectively. In at least one embodiment, to extract feature representations, fully connected layers were applied to the features of each point and others within its radius. In at least one embodiment, each set abstraction layer used three fully connected layers with dimensions of [64, 64, 128], [128, 128, 256], and [256, 256, 512], respectively.

In at least one embodiment, all networks were implemented in TensorFlow. In at least one embodiment, for tactile feature estimation, the networks are reimplemented and refined in PyTorch. In at least one embodiment, training is conducted on an NVIDIA GPU Cloud (“NGC”) instance.

In at least one embodiment, FE nodal displacement fields (displacements of each node of the tactile sensor skin mesh, relative to their undeformed locations) are estimated from electrode data using neural networks. In at least one embodiment, procedures are nearly identical to those used for tactile features. In at least one embodiment, the mixed dataset (simulations aligned with experiments) is used. In at least one embodiment, only the PointNet++ architecture is applied. In at least one embodiment, regressions are performed from both electrode values and electrode coordinates to FE nodal displacements ( [symbol] ^{N×3}, where N is the number of selected nodes) on the tactile sensor skin mesh. In at least one embodiment, the skin mesh includes over 4000 total nodes in each simulation; for efficiency, 128 nodes are selected by randomly sampling along the ventral surface of the skin. In at least one embodiment, the TensorFlow networks are used.

In at least one embodiment, tactile sensor electrode values are estimated from FE nodal field data. In at least one embodiment, the PointNet++ architecture is applied. In at least one embodiment, regressions are performed from both FE nodal displacements and FE nodal coordinates (i.e., undeformed locations of each node of the tactile sensor skin mesh) ( [symbol] ^{N×3}) to electrode values. In at least one embodiment, networks are implemented in PyTorch. In at least one embodiment, the mixed dataset was used.

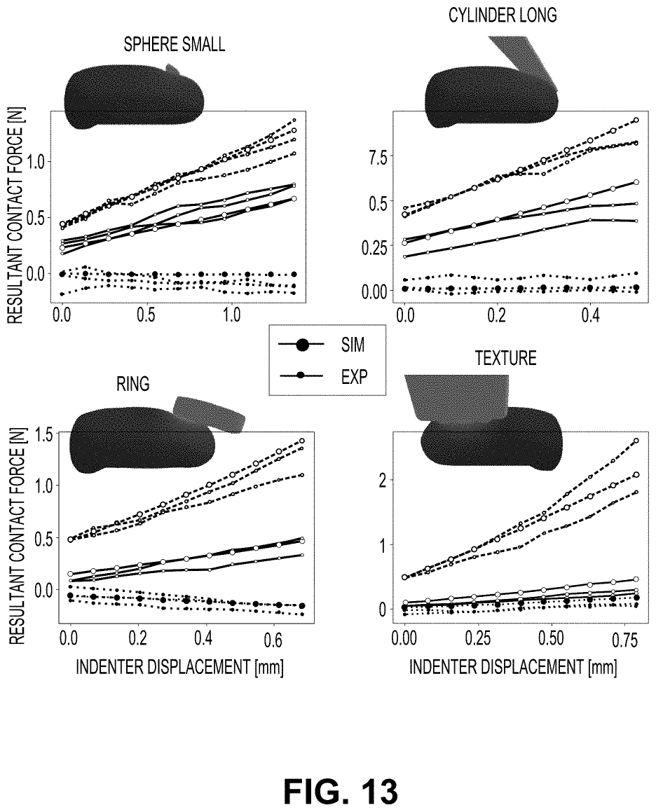

In at least one embodiment, the free parameters in the FE model are calibrated by minimizing the error between predicted and experimental net forces for a single angled trajectory of the sphere medium indenter. In at least one embodiment, following calibration, simulation predictions are compared to experimental data over the set of indenters and many trajectories. In at least one embodiment, for each trajectory, RMS error is computed using Equation 11. In at least one embodiment, this process is repeated for all trajectories corresponding to a particular indenter, and the RMS errors were then averaged across the trajectories. In at least one embodiment, the average RMS error ranges from a minimum of 0.226 N for the texture indenter to a maximum of 0.486 N for the ring indenter, with a median of 0.260 N over the set of indenters. In at least one embodiment, different indenters tend to impart different force levels; when the RMS error for each trajectory was divided by the maximum force magnitude for that trajectory (typically between 1-10 N) to compute a relative RMS error, the average error was a minimum for the cylinder small indenter and a maximum for the sphere small indenter. FIG. 13 illustrates FE predictions and experimental data for four high-deformation trajectories from randomly selected indenters, in an embodiment.

In at least one embodiment, given the multiple possible sources of experimental variation and error (tactile sensor mechanical variability, F/T sensor noise, and registration error), as well as the minimal calibration procedure (using data from a single indentation out of 700+ possible trajectories), the low RMS error across the wide set of indenters and indentations demonstrates that the FE model is accurate and highly generalizable to novel objects and interactions.

FIG. 13 illustrates an example of finite element model validation, in at least one embodiment. In at least one embodiment, simulation and experimental data are shown for the net contact force acting on the tactile sensor along each spatial axis. In at least one embodiment, experimental data is shown for three different tactile sensors. In at least one embodiment, these comparisons are provided for four high-deformation indentation trajectories, each from a randomly selected indenter. In at least one embodiment, y-axis ranges are different across plots, and force-deformation derivatives (i.e., stiffnesses) vary strongly with indenter type and contact location.

In at least one embodiment, as described in Section 3.10, two tactile features (i.e., 3D contact location and 3D net force vector) are estimated using 3 different network architectures: MLP, 3D voxel-grid-based CNN (referred to in figures as Voxel), and PointNet++ (referred to in figures as PointNet). In at least one embodiment, for each tactile feature, the following are presented:
1. Estimation results for the case of unseen trajectory (i.e., the training set and test set both contained data from all indenters, but the test set contained no data points from trajectories that were present in the training set). These results evaluate how well the trained networks can generalize to novel interactions.
2. Estimation results for the case of unseen indenter (i.e., the training set contained data from 8 of the 9 indenters, whereas the test set contained data from only the remaining indenter). Since the tactile sensor 1 dataset contained fewer indenters (see Section 3.3), this case was only examined for tactile sensor 2 and 3. These results evaluate how well the trained networks can generalize to novel objects.
3. Estimation results for the case of unseen tactile sensor (i.e., the training set contained data from 1 or 2 tactile sensors, whereas the test set contained data from a different tactile sensor). These results evaluate how well the trained networks can directly transfer to another tactile sensor.

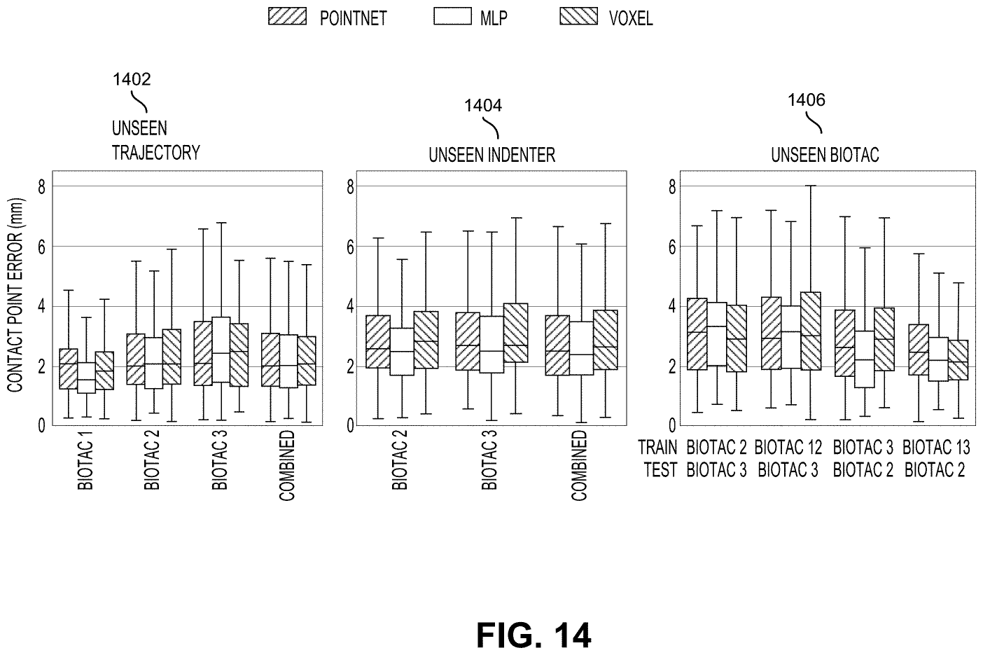

In at least one embodiment, for estimating contact location, three network architectures performed comparably across unseen trajectory, unseen indenter, and unseen tactile sensor as shown in FIG. 14. In at least one embodiment, in very few instances, MLP performed better than the other architectures. In at least one embodiment, for training and testing with MLP on data from multiple tactile sensors, the mean and median errors in contact location were {1.8, 1.5} mm for sensor 1, {2.1, 2.0} mm for sensor 2, {2.6, 2.4} mm for sensor 3, and {2.2, 2.0} mm for all sensors combined. In at least one embodiment, for unseen indenter, mean and median errors for MLP on sensor 2, 3, and all sensors combined were {2.6, 2.4} mm, {2.8, 2.5} mm, and {2.7, 2.35} mm, respectively.

In at least one embodiment, the trained networks may be used for object identification and manipulation of small finger-held objects. In at least one embodiment, increasing indentation intensity can lead to more accurate contact location estimates. In at least one embodiment, the error on the test dataset can be filtered in two different ways: 1) removing all data corresponding to force magnitudes below 8 N, and 2) removing all data corresponding to force magnitudes above 2 N. The high-force dataset has a lower error compared to the low-force dataset as shown in at least one embodiment, in real-world applications, location estimation may be improved by applying greater force to the object.

In at least one embodiment, the average median error for all examined datasets is {2.0} mm for unseen trajectory, {2.4} mm for unseen indenter, and {2.7} mm for unseen Tactile sensor. In at least one embodiment, as expected, there is a substantial increase in error from unseen trajectory to the more challenging cases of unseen indenter and unseen Tactile sensor. In at least one embodiment, for unseen indenter, the location estimates are accurate when the indenter was geometrically similar to others in the training set (e.g., for a sphere or cylinder indenter), but declined when the indenter was geometrically unique (e.g., for the ring indenter, which did not resemble any of the others). In at least one embodiment, firmly generalizing the prediction of tactile quantities to arbitrary object geometries may require training on an even greater number of indenters. In at least one embodiment, the electrical behavior of the Tactile sensor varied greatly from sensor to sensor, likely due to manufacturing variability in the Tactile sensor's electronic components. In at least one embodiment, such variations complicate the direct transfer of trained networks from one Tactile sensor to another.

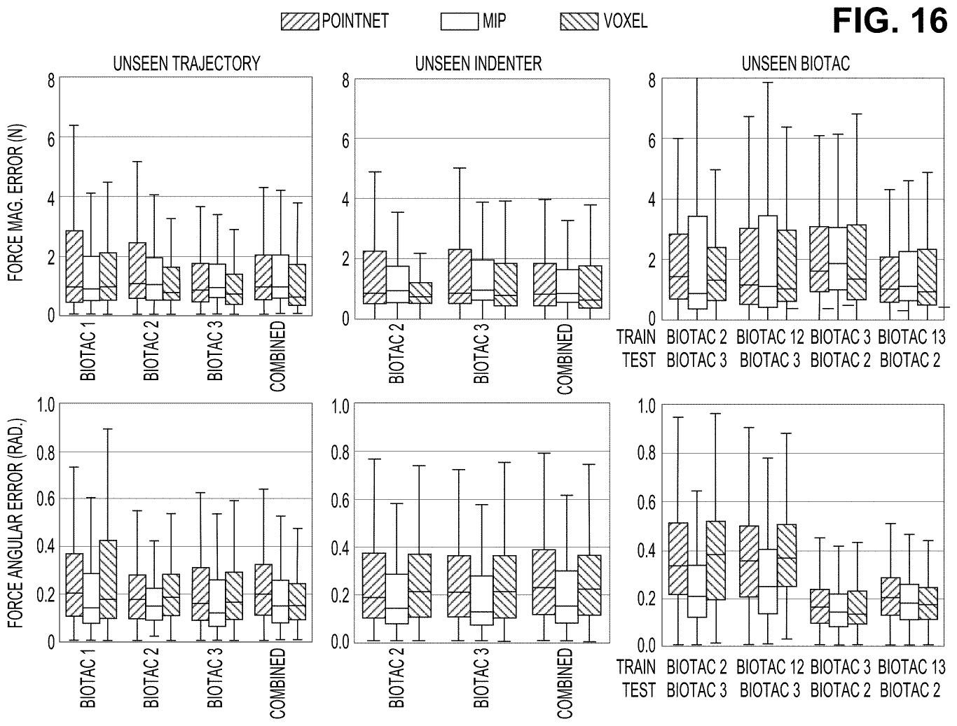

In at least one embodiment, for estimating force vector (magnitude and angle), a preferred network architecture is 3D voxel-grid-based CNN for force magnitude and MLP for force angle across unseen trajectory, unseen indenter, and unseen tactile sensor as shown in FIG. 16. In at least one embodiment, for training and testing on the set of tactile sensors and combined data (unseen trajectory), the median errors in force magnitude were {0.96, 0.78, 0.73, 0.64} N, respectively. In at least one embodiment, normalized by the standard deviation of the force magnitudes, these values are {0.22, 0.16, 0.16, 0.14}. In at least one embodiment, mean errors tend to be higher due to the high peak force levels examined throughout data collection (i.e., 23-32 N). In at least one embodiment, median angular cosine errors were {0.14, 0.15, 0.12, 0.15} rad, respectively. In at least one embodiment, for unseen indenter, median force magnitude errors for Voxel on tactile sensor 1, 2, 3, and all tactile sensors were {0.75, 0.78, 0.64} N, respectively, and median angular cosine errors for MLP were {0.14, 0.13, 0.15} rad.

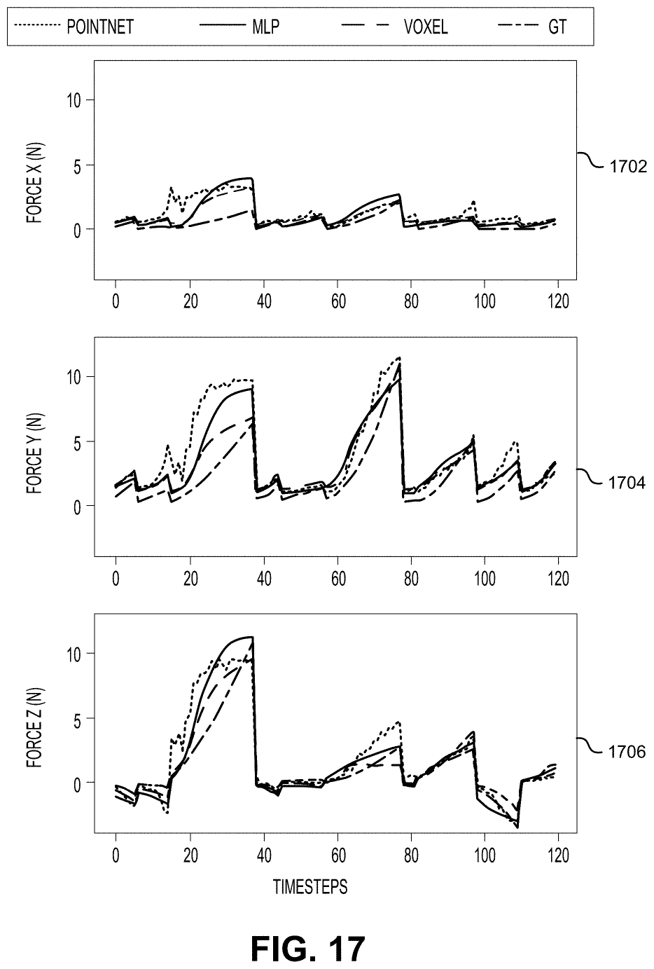

In at least one embodiment, 3D voxel-grid-based CNN and MLP tend to outperform PointNet++ on the given datasets. In at least one embodiment, Voxel and MLP had an order-of-magnitude greater and an order-of-magnitude fewer parameters than PointNet++, respectively, suggesting that performance differences reflected structure rather than capacity. In at least one embodiment, comparing Voxel to PointNet++, the former has a fixed spatial grid, whereas the latter was designed for point clouds with irregular structure; Voxel may present advantages for the data, as the electrode locations are fixed in the tactile sensor coordinate frame. In at least one embodiment, comparing MLP to PointNet++, the former enables information exchange among all inputs at the shallowest levels of the network; such a structure may be advantageous as well, as the incompressibility of the fluid within the tactile sensor causes an electrical response at one location of the sensor to immediately induce a complementary response at a distance. In at least one embodiment, PointNet++ tends to generate substantially noisier estimates than the other architectures as seen in FIG. 17.

In at least one embodiment, performance across the different unseen cases shows the average median force magnitude and angular cosine errors for all examined datasets were {0.78, 0.14} for unseen trajectory, {0.72, 0.14} for unseen indenter, and {1.1, 0.19} for unseen tactile sensor. In at least one embodiment, unlike for contact location, there is not a substantial increase in error from unseen trajectory to unseen indenter, and there is a small increase in error to unseen tactile sensor. In at least one embodiment, trained networks for force may generalize across objects and tactile sensors. In at least one embodiment, from a physical perspective, generalization of force may be easier than contact location, as force is primarily a function of the sum of electrical responses, whereas contact location depends heavily on the shape of the distribution as well.

FIG. 14 illustrates an example of tactile contact estimation errors, in at least one embodiment. In at least one embodiment, tactile contact estimation errors for unseen {trajectory 1402, indenter 1404, tactile sensor 1406} are illustrated. In at least one embodiment, the solid lines in the boxes indicate the median. In at least one embodiment, the box height is equal to the interquartile range (IQR). In at least one embodiment, the fence length is equal to 1:5*IQR, rounded down to the nearest data point.

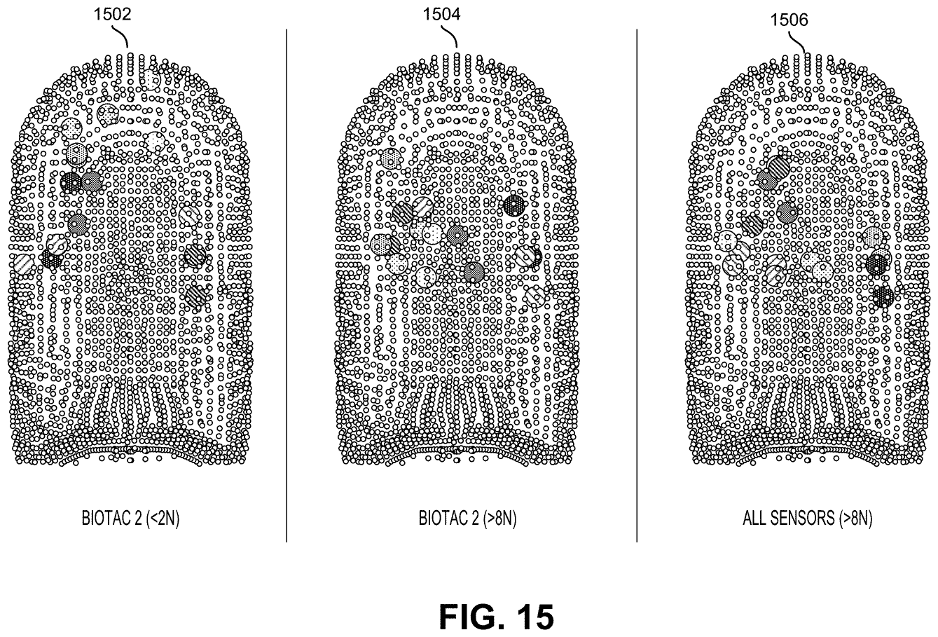

FIG. 15 illustrates an example of contact location estimation, in at least one embodiment. In at least one embodiment, a ventral view of the undeformed tactile sensor mesh is shown, with 8 contact location estimates randomly sampled from interactions in the test set with force magnitudes less than 2 N for 1502, and greater than 8 N for 1504. In at least one embodiment, the corresponding network is trained and tested on data from a single tactile sensor. Same patterns denote target-prediction pairs. In at least one embodiment, eight additional estimates for a network trained and tested on data from all tactile sensors combined (force magnitude greater than 8N) are shown at 1506.

In at least one embodiment, nodal displacement fields are estimated using PointNet++. In at least one embodiment, estimation results are presented for the case of unseen trajectory. In at least one embodiment, for training and testing on a set of tactile sensors, and combined data, mean nodal displacement errors are {0.21, 0.20, 0.25, 0.22} mm, respectively. In at least one embodiment, fingertip deformation fields were well-predicted over the dataset. In at least one embodiment, complex deformations were captured, and for moderate-to-high indenter displacements (and thus, strong electrode signals), many deformation fields are indistinguishable from FE predictions.

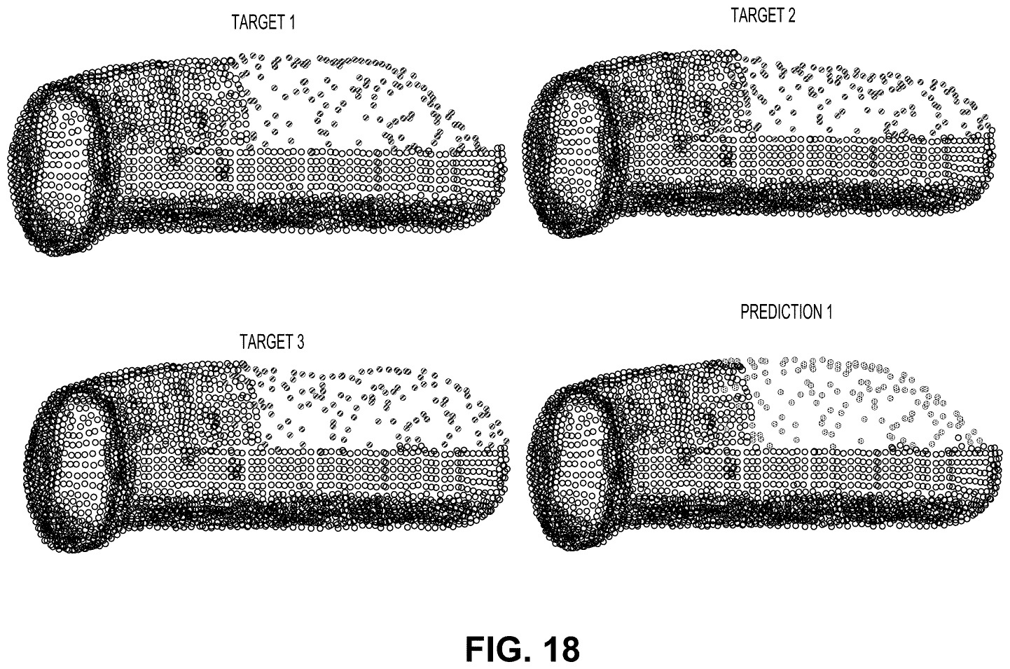

In at least one embodiment, results reflect a notable departure from prior studies; rather than a low-dimensional quantity (e.g., center-of-pressure or resultant force vector), high-resolution deformation fields are predicted. In at least one embodiment, the ability to predict these fields shows that the tactile sensor electrode signals do, in fact, contain this high-density information. In at least one embodiment, such information enables the perception of geometric features such as flat surfaces, edges, corners, and divots, as visible in several of the deformed surfaces shown in FIG. 18. In at least one embodiment, the generation of these fields provides much greater interpretability of the tactile sensor's complex electrical response to contact interactions, facilitating the debugging and further development of control algorithms that consume the raw electrode data.

In at least one embodiment, like the nodal displacement fields, tactile sensor electrode values are estimated using PointNet++ for the case of unseen trajectory. In at least one embodiment, electrode values are normalized and tared. In at least one embodiment, for training and testing on the set of tactile sensors, the median and mean electrode value errors are {0.055, 0.068}, {0.04, 0.057}, and {0.04, 0.05}, respectively; converting to raw 12-bit digital output, these values become {225, 279}, {166, 236}, and {161, 223}. In at least one embodiment, median [symbol] ² distance between predicted and ground-truth electrode value arrays ( [symbol] ¹⁹) are also provided in Table 2.

FIG. 16 illustrates an example of tactile force estimation errors, in at least one embodiment. In at least one embodiment, tactile force estimation errors for unseen {trajectory, indenter, tactile sensor). In at least one embodiment, the solid lines in the boxes indicate the median. In at least one embodiment, the box height is equal to the interquartile range (IQR). In at least one embodiment, the fence length is equal to 1.5*IQR, rounded down to the nearest data point.

In at least one embodiment, using a less sophisticated FE simulator improves results further. In at least one embodiment, the new simulator does not impose strict convergence criteria on the simulations, preventing early divergence and allowing FE simulation data to be aligned with experimental data over a greater range of indenter displacements. In at least one embodiment, the dataset used for synthesizing electrode values can be expanded, enabling more accurate predictions.

TABLE 2
Median [symbol] ² distance between predicted and ground-truth electrode
signals in sensor's measurement range (0-4095)

| | BioTac | BioTac | BioTac |
|---|---|---|---|
| | 1 | 2 | 3 |
| Unseen | 225 | 166 | 187 |
| Trajectory | | | |
| Unseen | N/A | 161 | 274 |
| Indenter | | | |

In at least one embodiment, data from each indentation trajectory is kept contiguous when apportioning the training and test datasets (the test set only contained data from unseen trajectories). In at least one embodiment, as a sanity check, the non-contiguous case is also considered, where individual data points are randomly sampled when apportioning the datasets (the test set contained data points from trajectories that were explored in the training set). In at least one embodiment, estimation accuracy on the test set dramatically improves: mean contact location error decreased by 10× (to approx. 0.2 mm), median force magnitude and angular error decreased by 3× (to approx. 0.15 N and 0.05 rad, respectively), and mean nodal displacement error decreased by 2.5× (to approx. 0.08 mm). In at least one embodiment, in real-world scenarios, one may typically not have access to prior data from trajectories executed at test time. In at least one embodiment, low errors reiterate the advantage of careful dataset construction when estimating tactile quantities.

At least one embodiment advances the interpretation and prediction of robotic tactile signals, focusing on the SynTouch BioTac due to its favorable performance metrics and widespread use in research. At least one embodiment, contributes a precise, diverse experimental dataset for the BioTac, in which nine indenters interacted with three BioTacs. In at least one embodiment, the dataset includes over 400 unique indentation trajectories, 800 total trajectories, and 50k data points after subsampling; additionally, approximately 70% of trajectories are designed to induce shear. At least one embodiment provides a 3D FE model of the BioTac, which accurately predicts the mechanical behavior of the tactile sensor. In at least one embodiment, the model utilizes a hyper-elastic material law for the skin, captures fluidic incompressibility, and simulates frictional contact. In at least one embodiment, despite being calibrated using data from a single indentation, the model generalized strongly across multiple tactile sensors, as well as a diverse range of objects and interactions. In at least one embodiment, the model is accompanied by a second dataset that contains the previous experimental data aligned with corresponding FE predictions. In at least one embodiment, a third contribution is a set of neural-network mappings that accurately estimates 3D contact location and force vector, and also predicts tactile fields (nodal displacement fields) from tactile sensor electrode values. At least one embodiment adds a set of learned mappings that can synthesize tactile sensor electrode values.

At least one embodiment advances robotic tactile sensing for multiple reasons. In at least one embodiment, the experimental dataset captures diverse contact interactions beyond existing efforts. In at least one embodiment, most real-world objects have wide geometric diversity, and shear is highly critical for slip detection, inertial estimation, palpation, and sliding or spreading objects. In at least one embodiment, knowledge of contact location is important for grasping and dexterous manipulation. In at least one embodiment, as recently initiated for vision-based tactile sensors, an accurate FE model of the BioTac enables previously-intractable assessments to be performed. In at least one embodiment, the model can be used to predict deformation fields of the tactile sensor and object, as well as contact force distributions transmitted through the tactile-sensor-object interface. In at least one embodiment, these predictions can be leveraged to predict grasp stability with soft contact, anticipate damage to brittle or delicate materials (like eggs, fruit, or living tissue), and guide reshaping strategies for elastoplastic materials (e.g., the flattening of dough). In at least one embodiment, the ability to regress to tactile fields directly from tactile sensor electrode values enables the high-density information in the FE model to be accessible from raw signals at runtime. In at least one embodiment, the aforementioned tasks can be accomplished in an online, adaptive, and closed-loop manner. In at least one embodiment, the ability to synthesize tactile sensor electrode values enables training of control policies in simulation (via reinforcement learning) that can accept raw sensor signals as input. In at least one embodiment, such policies may be transferable to the real world without extensive domain adaptation.

In at least one embodiment, the fully-supervised learning approach uses a carefully-calibrated experimental setup to augment the existing dataset with additional data. At least one embodiment provides an open-access, GPU-based FE model of the tactile sensor that is 75× faster, and presents a semi-supervised learning approach that leverages large amounts of unlabeled tactile data to improve the accuracy and generalizability of regressions.

In at least one embodiment, the mechanical behavior of tactile sensors is consistent, and the FE model to predict this behavior generalizes strongly across tactile sensors. In at least one embodiment, the electrical behavior of tactile sensors may vary strongly from sensor to sensor. In at least one embodiment although some network-based mappings maintain sufficient accuracy when applied to unseen sensors (for force estimation), others do not (for contact location estimation). In at least one embodiment, the experimental dataset, FE model, and learned mappings do not transfer naturally to other widely-used tactile sensors, such as the GelSight. In at least one embodiment, for transfer to other tactile sensors, a first solution is to complement a network trained on a particular tactile sensor with additional layers, which can then be fine-tuned for another sensor using a small amount of supervised data. In at least one embodiment, techniques are adapted to use unlabeled data for the unseen sensor, as well as applying domain randomization during policy training to ensure robustness to transfer error. In at least one embodiment, for transfer to non-tactile sensor sensors, collecting new experimental data, constructing a new FE model, and retraining networks may be unavoidable requirements. In at least one embodiment, tactile sensors harness markedly different physical phenomena; furthermore, unlike cameras, observing an object or the environment with a tactile sensor changes the behavior of the sensor itself through deformation of a compliant interface. In at least one embodiment, shared representations of tactile data may exist across sensors of multiple modalities; identification of such representations may greatly facilitate transfer of methods and results from one to another.

At least one embodiment demonstrates a method to calibrate a 3D finite element model of the tactile sensor to its mechanical behavior during real world interaction and also study its electrical behavior via learning with a large scale dataset spanning multiple units of tactile sensor. At least one embodiment serves as a concrete approach for modeling existing robotic tactile sensors and also aids in the design of new tactile sensors.

FIG. 17 illustrates an example of force vector estimation for unseen trajectories, in at least one embodiment. In at least one embodiment, force component estimates 1702, 1704, 1706, are shown for a randomly-sampled contiguous slice of multiple trajectories from the test set. In at least one embodiment, the corresponding network was trained and tested on data from a single tactile sensor. In at least one embodiment, each spike corresponds to the maximum displacement increment during a particular trajectory. Label GT denotes ground truth.

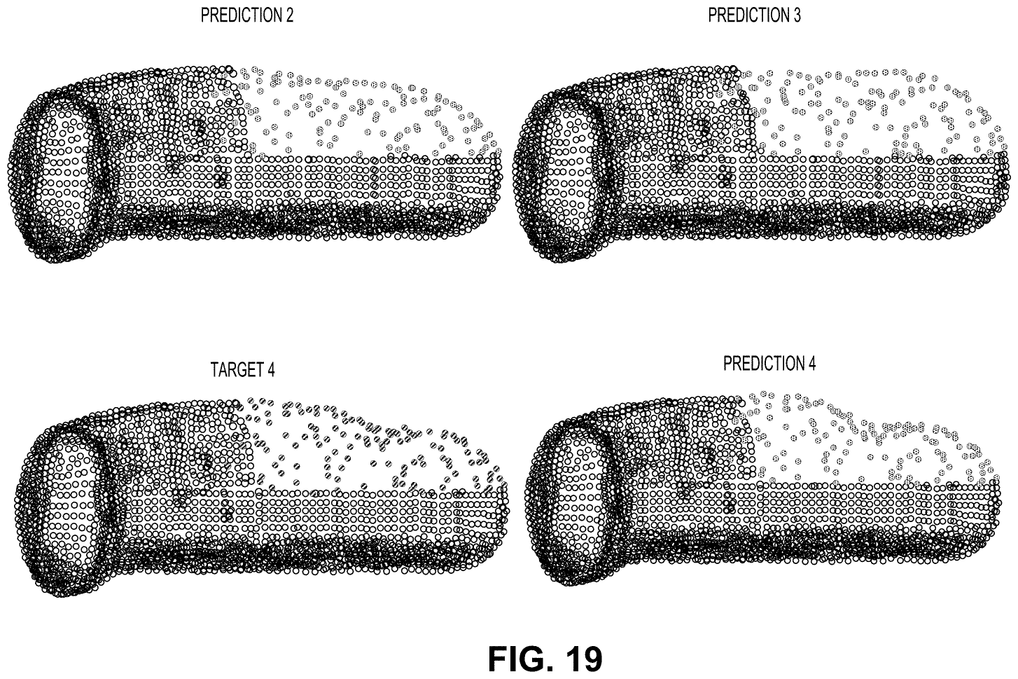

FIG. 18 and FIG. 19 illustrate examples of finite element nodal displacement estimation, in at least one embodiment. In at least one embodiment, displacement fields are shown for the maximum displacement increments of randomly-sampled trajectories from the test set. In at least one embodiment, the corresponding network for each target-pair prediction was trained and tested on a distinct subset of the data. In at least one embodiment, most predicted fields are indistinguishable from targets; several other cases are shown here, illustrating minor discrepancies for extreme deformations.

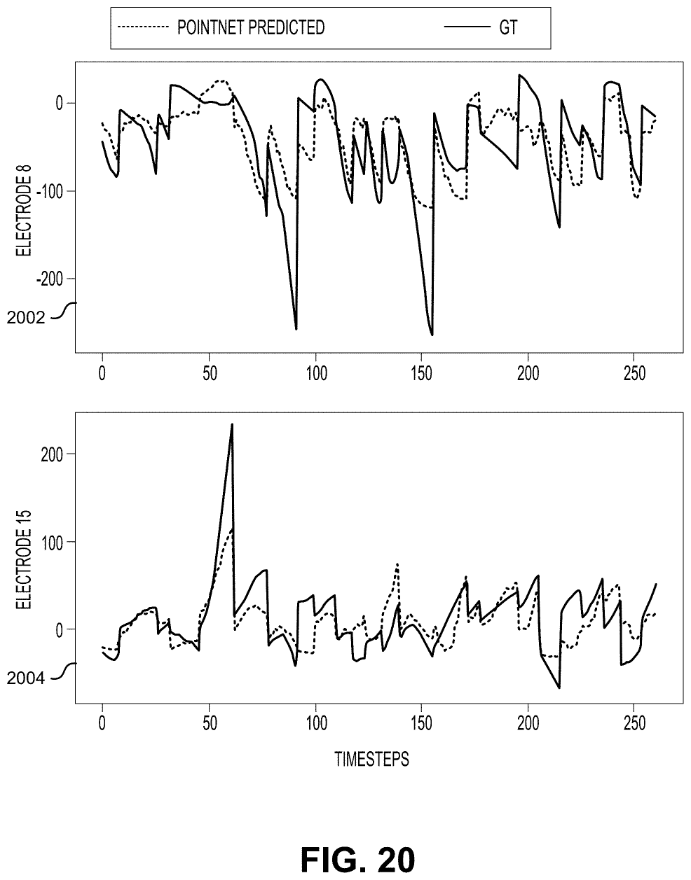

FIG. 20 illustrates an example of electrode value estimation for unseen trajectories, in at least one embodiment. In at least one embodiment, synthesized electrode values are shown for two different electrodes, located at opposite ends of the tactile sensor. Label GT denotes ground truth.

In at least one embodiment, tactile sensing is critical for robotic grasping and manipulation of objects under visual occlusion. In at least one embodiment, in contrast to simulations of robot arms and cameras, current simulations of tactile sensors have limited accuracy, speed, and utility. In at least one embodiment, an efficient 3D finite element method (FEM) model of a tactile sensor using an open-access, GPU-based robotics simulator is provided. In at least one embodiment, simulations closely reproduce results from an experimentally-validated model in an industry-standard, CPU-based simulator, but at 75× the speed. At least one embodiment learns latent representations for simulated tactile sensor deformations and real-world electrical output through self-supervision, as well as a projection between the latent spaces using a small supervised dataset. In at least one embodiment, by combining FEM simulation with the learned projection, real-world tactile sensor electrical output and contact patches are estimated, both for unseen contact interactions. At least one embodiment contributes an efficient, FEM model of the tactile sensor and comprises one of the first efforts to combine self-supervision, cross-modal transfer, and sim-to-real for tactile sensors.

In at least one embodiment, tactile sensing is important to grasping and manipulation under visual occlusion, as well as for handling delicate objects. In at least one embodiment, for example, humans leverage tactile sensing when retrieving keys from a bag, striking a match against a matchbox, holding a wine glass, and grasping a fresh fruit without damage. In at least one embodiment, in robotics, researchers are actively developing a wide variety of tactile sensors. In at least one embodiment, these sensors are used for tasks such as slip detection, object classification, parameter estimation, force estimation, and contour following.

In at least one embodiment, for other aspects of robotics, such as robot kinematics, dynamics, and cameras, accurate and efficient simulators have advanced the state-of-the-art in task performance. In at least one embodiment, simulators enable accurate testing of algorithms for perception, localization, planning, and control; generation of synthetic datasets for learning such algorithms; efficient training of control policies via reinforcement learning (RL); and execution of online algorithms, with the simulator as a model. In at least one embodiment, these capabilities reduce the need for costly, time-consuming, dangerous, or intractable experiments.

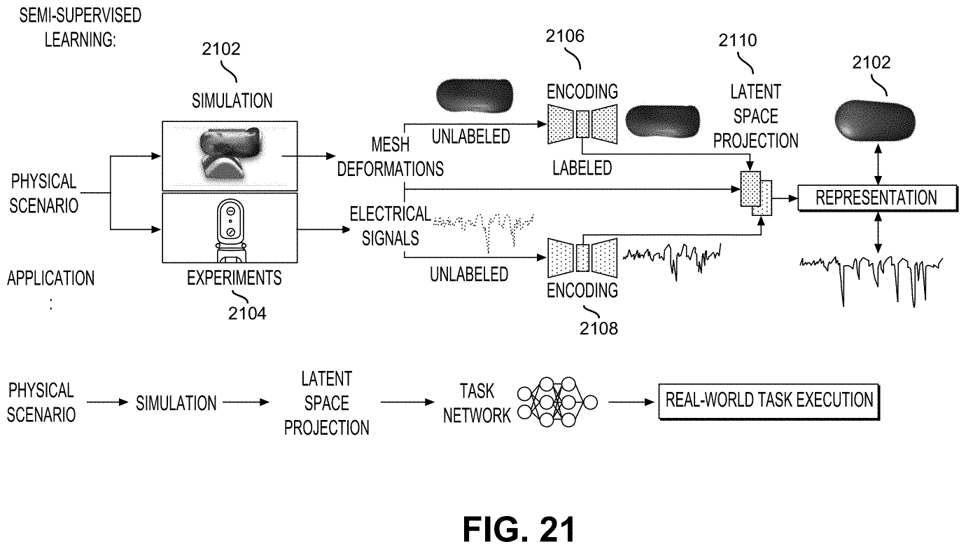

FIG. 21 illustrates an example of a 3D finite element (“FEM”) model of a tactile sensor, in at least one embodiment. In at least one embodiment, an efficient 3D FEM model of a tactile sensor 2102 to simulate contact interactions is provided, and similar real-world experiments 2104 are conducted. In at least one embodiment, in a learning phase, unlabeled FEM deformations and real-world electrical signals are processed via auto-encoders 2106 and 2108. In at least one embodiment, adding a small amount of labeled data, a projection between the FEM and electrical latent spaces 2110 is learned. In at least one embodiment, this learned latent projection can generate representations of new FEM and electrical data that allow cross-modal transfer for unseen contact interactions. In at least one embodiment, during application, the representations can be used to 1) accurately synthesize tactile sensor electrical signals, and 2) estimate the shape and location of contact patches, facilitating real-world task execution.

At least one embodiment addresses the forward problem of synthesizing sensor output, and accurately generalizes to diverse contact scenarios. In at least one embodiment, forward simulation is invaluable for simulation-based training, which coupled with domain adaptation, can facilitate real-time policy execution.

In at least one embodiment, accurate tactile sensor simulators must model numerous contacts, complex geometries, and elastic deformation, which can be computationally difficult. In at least one embodiment, simulators must also capture multiphysics behavior, as tactile sensors are cross-modal: for instance, the tactile sensor transduces skin deformations to fluidic impedances. In at least one embodiment, whereas a small parameter set (camera intrinsics) can describe variation among visual sensors, equivalent parameter sets are not readily available for tactile sensors. In at least one embodiment, due to manufacturing variability, even sensors of the same type can behave disparately.

At least one embodiment addresses forward simulation and sim-to-real transfer for a tactile sensor, such as the tactile sensor. At least one embodiment develops a 3D finite element method (“FEM”) simulation of a tactile sensor using a GPU-based robotics simulator. In at least one embodiment, the FEM simulations predict contact forces and deformation fields for the sensor for arbitrary contact interactions. In at least one embodiment, simulations are designed to reproduce results from a previously-described 3D FEM model, which uses an industry-standard, commercial, CPU-based simulator and is carefully validated against real-world experiments. At least one embodiment uses a GPU-based simulator and executes its model 75× faster than the previously described CPU-based implementation.

At least one embodiment maps FEM output to real-world tactile sensor electrical signals by leveraging recent methods in self-supervised representation learning. At least one embodiment collects a large unlabeled dataset of sensor deformation fields from simulation, as well as a smaller dataset of electrical signals from real-world experiments, and then learns latent representations for each modality using variational auto-encoders (“VAEs”). At least one embodiment learns a cross-modal projection between the latent spaces using a small amount of supervised data. In at least one embodiment, this learned latent projection allows the system to accurately predict tactile sensor electrical signals from simulated deformation fields for unseen contact interactions, including unseen objects. At least one embodiment executes the inverse mapping (from signals to deformations) with high fidelity, illustrated via a contact-patch estimator.

At least one embodiment makes one or more of the following contributions: an accurate, efficient, and freely-accessible 3D FEM-based simulation model for a tactile sensor, a novel application of self-supervision and learned latent-space projections for facilitating cross-modal transfer between FEM and electrical data, and demonstrations of sim-to-real through accurate synthesis of tactile sensor electrical data and estimation of contact patches, both for unseen contact interactions

At least one embodiment provides an efficient FEM model, conducts simulations and experiments with 17 objects, regresses to continuous electrical signals, and demonstrates accurate predictions for unseen objects.

At least one embodiment learns latent representations of FEM and tactile sensor electrical data via self-supervision with auto-encoders for cross-modal transfer. At least one embodiment learns modality-specific representations, reducing training time and eliminating zero-inputs for non-present modalities. At least one embodiment does not formulate a joint representation, but instead learns a projection between the latent spaces using a small amount of supervised data. To encode tactile sensor data electrical data, at least one embodiment uses VAEs.

In at least one embodiment, a 3D FEM model predicts tactile sensor contact forces and deformation fields for arbitrary contact interactions. At least one embodiment implements self-supervision and latent-space projection, which can synthesize tactile sensor electrical output from unlabeled FEM output and predict contact patches from electrical input. At least one embodiment uses simulations and experiments to collect the FEM and electrical data used in implemented these techniques.

In at least one embodiment, FEM is a variational numerical formulation that 1) divides complex global geometries into simple subdomains, 2) solves the weak form of the governing PDEs in each subdomain, and 3) assembles the solutions into a global one. In 3D FEM, objects are represented as volumetric meshes, which consist of 3D elements (e.g., tetrahedrons or hexahedrons) and their associated nodes. With careful model design, high-quality meshes, and small timesteps, FEM predictions for deformable bodies can be exceptionally accurate.

At least one embodiment performs 3D FEM using NVIDIA's GPU-based Isaac Gym simulator. In at least one embodiment, Isaac Gym models the internal dynamics of deformable bodies using a co-rotational linear-elastic constitutive model. In at least one embodiment, these bodies interact with external rigid objects via an isotropic Coulomb contact model. In at least one embodiment, the resulting nonlinear complementarity problem is solved via implicit time integration using a GPU-based Newton solver. In at least one embodiment, at each timestep, Isaac Gym returns nodal positions (deformation fields), nodal contact forces (used to compute resultant forces), and element stress tensors.

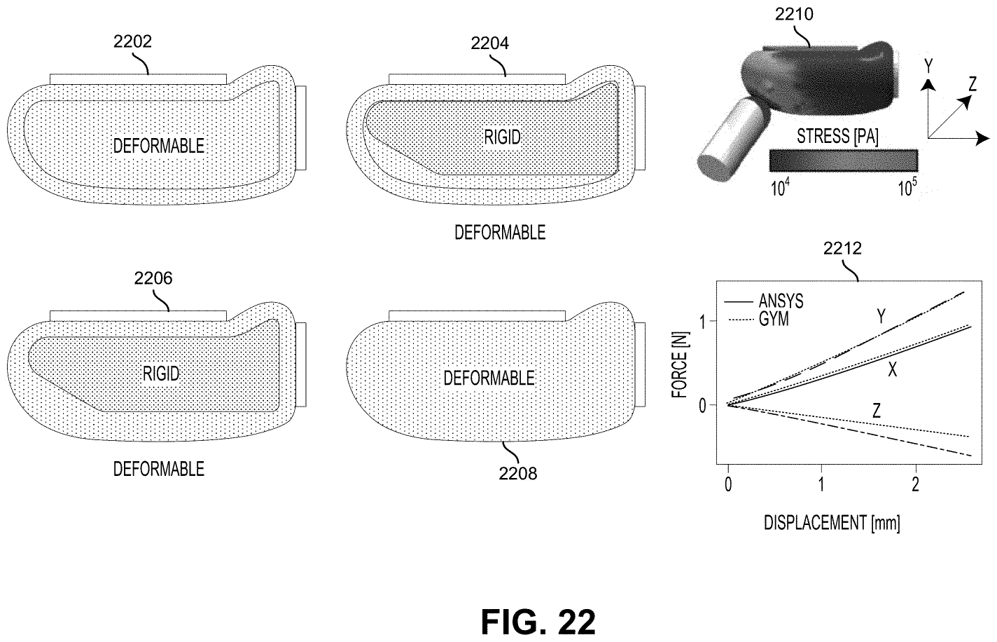

FIG. 22 illustrates an example of deformable modeling of a tactile sensor, in at least one embodiment. FIG. 22 illustrates four geometric representations of a tactile sensor. In at least one embodiment, a tactile sensor is represented as a deformable shell 2202 that models the real-world rubber skin. In at least one embodiment, a tactile sensor is represented as a deformable shell with rigid core 2204, modeling the skin and real-world plastic core. In at least one embodiment, a tactile sensor is represented as a deformable solid with rigid core 2206. In at least one embodiment, a tactile sensor is represented as a Deformable solid 2208. In at least one embodiment, grey rigid bodies are used to apply fixed boundary conditions. In at least one embodiment, optimization results for FEM model are provided. In at least one embodiment, the material parameters of representation D were tuned in Isaac Gym to reproduce the force profile 2212 of a shear-rich indentation from ANSYS. In at least one embodiment, the von Mises stress distribution is visualized 2210 for the indentation midpoint. In at least one embodiment, the mean [symbol] ²-norm of the force error vector is 0.125N. In at least one embodiment, indenter displacement is relative to the point of initial contact.

In at least one embodiment, to create the FEM model for the tactile sensor, high-resolution triangular meshes for the external and internal surfaces of the tactile sensor skin are extracted from the ANSYS model and simplified via quadric edge collapse decimation in MeshLab. In at least one embodiment, a volumetric mesh is then generated through fTetWild. In at least one embodiment, since the ANSYS model and the current model used 4-node shell elements and 3D tetrahedrons, respectively, to model the skin, the current model had 6× as many elements. In at least one embodiment, fixed boundary conditions (“BCs”) were applied to two sides of the skin to model the tactile sensor nail and clamp, respectively. In at least one embodiment, these BCs were implemented by introducing thin rigid bodies at the corresponding locations (visible in FIG. 22), which were attached to adjacent nodes on the skin. In at least one embodiment, external rigid objects (indenters) were driven into the tactile sensor via a stiff proportional controller.

In at least one embodiment, relative to the experimentally-validated ANSYS model, the Isaac Gym model makes three important approximations: 1) collisions are resolved via boundary-layer expanded meshes, rather than a normal-Lagrange method, 2) a compressible linear-elastic model is used for the skin, rather than a Neo-Hookean model, and 3) the internal fluid is not modeled. In at least one embodiment, the effects of the first approximation are mitigated by using small collision thicknesses and small timesteps (1e−4s). In at least one embodiment, however, the second and third approximations are mitigated by endowing the present model with a small number of highly-expressive free parameters, and then performing optimization to generate an equivalent model.

In at least one embodiment, 359 unique indentations (contact interactions) that were investigated with ANSYS using 8 different indenters were all resimulated with Isaac Gym. In at least one embodiment, four geometric representations of a tactile sensor were developed (FIG. 22 2202, 2204, 2206, and 2208). In at least one embodiment, for each representation, the elastic modulus E, Poisson's ratio v, and coefficient of friction μ of the tactile sensor skin is optimized via sequential least-squares programming to reproduce the force-deflection profile of 1 shear-rich indentation. In at least one embodiment, the cost is defined as the RMS of the [symbol] ²-norm of the force error vector over all timesteps. In at least one embodiment, the performance of each optimized representation is evaluated by comparing force-deflection profiles over the remaining 358 indentations.

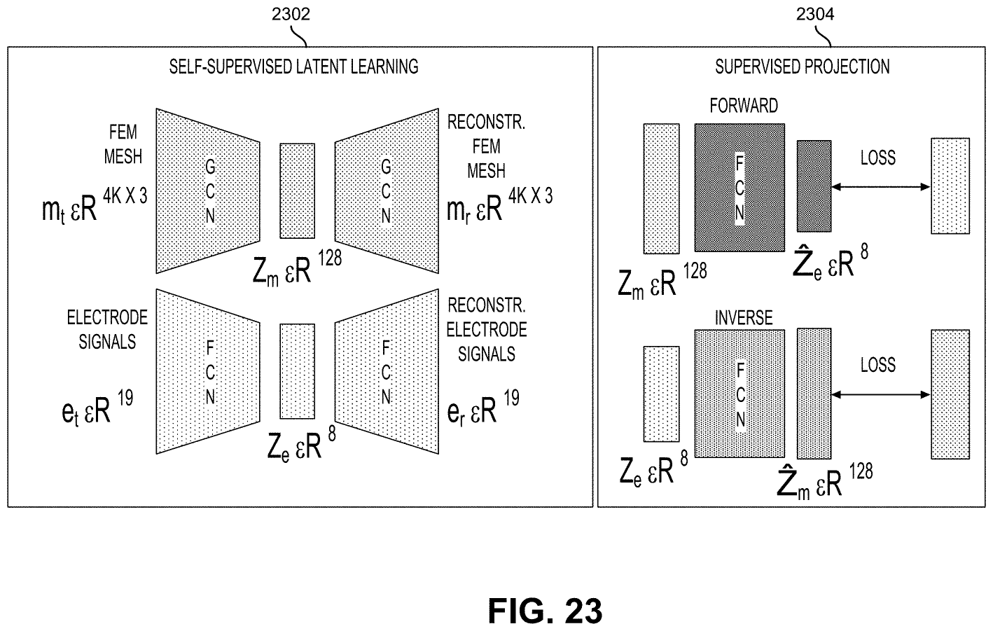

FIG. 23 illustrates an example of learning structure that maps between FEM deformations and electrode signals of a tactile sensor, in at least one embodiment. In at least one embodiment, to map between FEM deformations and tactile sensor electrode signals, self-supervision 2302 is used to learn modality-specific latent representations. At least one embodiment uses graph convolutional networks to compress deformed meshes with 4k nodes to a 128-dim. latent space, and fully-connected networks (FCN) to compress the 19 electrode signals to an 8-dim. latent space. At least one embodiment uses FCNs on a small supervised dataset to learn forward and inverse projections 2304 between the latent spaces.

In at least one embodiment, among the four representations, the deformable solid 2208 produced the lowest cost during optimization; however, the deformable shell with rigid core 2204 produced the lowest cost during evaluation and was thus selected. In at least one embodiment, for this representation, the optimal values of E, v, and μ were 1.55e6Pa, 0.316, and 0.783, respectively; the mean [symbol] ²-norm of the force error vector was 0.125N (FIG. 2E). In at least one embodiment, in comparison, the optimal values for the ANSYS model were 2.80e5Pa, 0.5, and 0.186, indicating that the Isaac Gym model compensated for its linearity and lack of fluid by increasing elastic modulus, compressibility, and friction.

In at least one embodiment, although FEM captures the effects of contact interactions on tactile sensor deformations, the tactile sensor transduces deformations to fluidic impedances measured at electrodes. In at least one embodiment, simulating the mapping between the FEM deformation and electrode modalities is complex; instead, this mapping is learned. At least one embodiment uses self-supervision to learn modality-specific latent spaces, which captures domain-specific features, facilitates compression, and reduces training time. At least one embodiment learns a projection between the latent spaces, enabling cross-modal feature transfer and mitigating domain-specific noise (FIG. 23).

In at least one embodiment, to learn a latent space for the FEM deformations, at least one embodiment uses convolutional mesh auto-encoders. In at least one embodiment, these auto-encoders represent deformed meshes as a graph and apply graph convolutional networks (“GCNs”), which compress mesh data from 4246 nodal positions ( [symbol] ^{4k×3}) to 128 units. In at least one embodiment, to learn a latent space for real-world tactile sensor electrode signals, at least one embodiment trains an auto-encoder composed of FCNs, which reduces electrode data from 19 impedance values to 8 units. At least one embodiment trains both networks as VAEs to generate smooth mappings to the latent space.

To learn the projections between the latent spaces, at least one embodiment trains two FCNs. In at least one embodiment, the first network projects forward from the FEM mesh latent space zₘ to the tactile sensor electrode latent space zₑ, whereas the second network projects inversely from zₑ to zₘ.

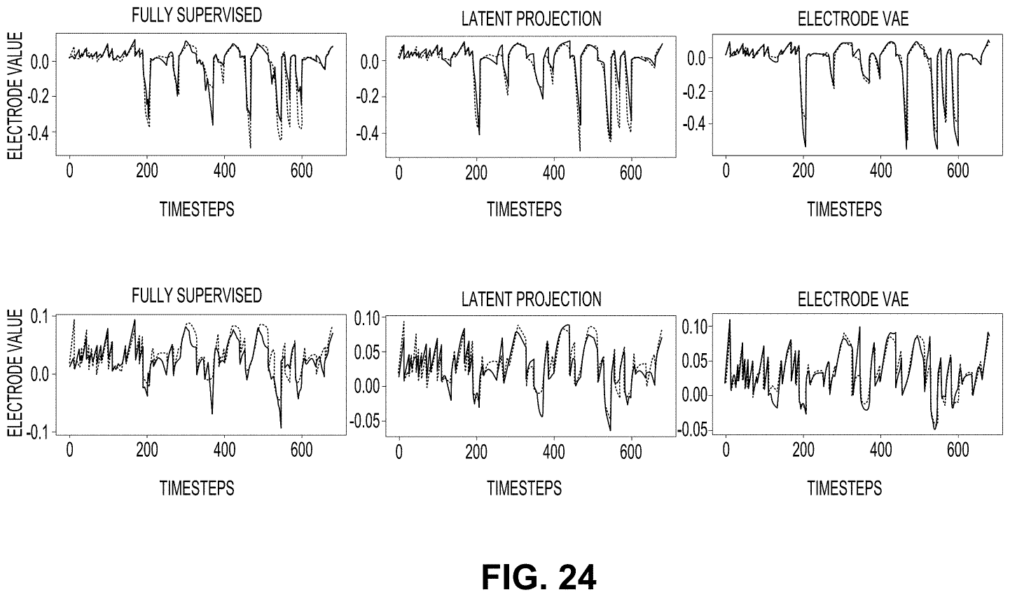

FIG. 24 illustrates an example of electrode prediction results, in at least one embodiment. FIG. 24 illustrates an example of visual comparisons for two high-magnitude, high-variation electrodes over numerous interactions with an unseen object, in at least one embodiment. In at least one embodiment, dashed and solid lines indicate ground-truth and prediction, respectively. In at least one embodiment, a latent projection (“LP”) approach can predict peaks more accurately than a fully-supervised (“FS”) baseline, and often outperforms the VAE used in training.

During training, at least one embodiment freezes the previously-described VAEs and provide them with supervised data in order to generate latent pairs of zₘ and zₑ. In at least one embodiment, these pairs are used to train the projection networks with an RMS loss.

At least one embodiment applies exponential linear unit (“ELU”) activations, which outperform RELU. At least one embodiment uses the Adam optimizer with an initial learning rate of 1e−3 and a decay of 0.95. In at least one embodiment, in the FEM deformation VAE, the encoder consists of an initial convolution with filter size 128, four “convolve+downsample” layers with sizes [128, 128, 256, 64] and downsampling factors [4, 4, 4, 2], a convolution with size 64, and two fully-connected layers with dimensions [512, 128]. In at least one embodiment, the decoder is symmetric with the encoder, using “upsample+convolve” instead of “convolve+downsample”. In at least one embodiment, in the tactile sensor electrode VAE, the encoder consists of four fully connected layers with [256, 128, 64, 8] neurons, respectively. In at least one embodiment, the decoder is again symmetric with the encoder. In at least one embodiment, the forward and inverse projection networks include three fully connected layers with [256, 128, 128] and [128, 128, 256] neurons, respectively, and dropout (0.3) between each layer.

In at least one embodiment, for the preceding learning steps, data is collected in both simulation and the real world. In at least one embodiment, for the self-supervised latent-space learning, a large amount of unlabeled mesh data was collected by using Isaac Gym to simulate kinematically-randomized interactions with 6 different pegs and 3 table features (surfaces, edges, and corners); a smaller amount of unlabeled experimental electrode data was collected by manually conducting indentations. In at least one embodiment, for the supervised projection learning, labeled data was collected by using Isaac Gym to resimulate 359 contact interactions over 8 different indenters, and aligning the FEM output with experimental electrode data from the paper. In at least one embodiment, 2.6k unique contact interactions were executed and 50k timesteps of FEM data were sampled.

In at least one embodiment, as described earlier, force-deflection profiles produced by the optimized model in Isaac Gym Re compared to those produced by ANSYS over 358 indentations distributed across 8 indenters. In at least one embodiment, mean [symbol] ²-norm of the force error vectors over all indentations ranges from 0.0876N for a medium-sized cylindrical indenter (less than the training error of 0.125N) to 0.259N for a medium-sized spherical indenter, with a mean of 0.153N across all indenters. In at least one embodiment, despite being optimized using force-deflection data from only a single indentation, the Isaac Gym model strongly generalized across a diverse range of objects and indentations.

In at least one embodiment, corresponding FEM deformation fields (i.e., the nodal positions of the deformed FEM meshes) are compared between Isaac Gym and ANSYS. In at least one embodiment, for each dataset, the maximum and mean [symbol] ²-norms of the nodal displacement vectors were computed over all indentations. In at least one embodiment, the mean error between the maximum norms across all indenters was 1.41e−4m, and the mean error between the mean norms was 1.81e−5m. In at least one embodiment, the Isaac Gym model is shown to strongly generalize. In at least one embodiment, these low errors are important, as the nodal deformation fields from Isaac Gym are used as input for subsequent learning.

In at least one embodiment, simulation speed is compared between the Isaac Gym and ANSYS models. In at least one embodiment, the total simulation time for all 359 indentations was approximately 42 hours (7.08 minutes per sim) on 6 CPUs in ANSYS, but 33 minutes (5.57 seconds per sim) using 8 parallel environments (1 per indenter) on 1 GPU in Isaac Gym, despite the 6× increase in elements. In at least one embodiment, Isaac Gym can only currently simulate deformable solids with a linear-elastic constitutive model and linear tetrahedral elements; such a model comprises only a small fraction of those that can be simulated within state-of-the-art FEM software such as ANSYS or Abaqus. However, for the current application, Isaac Gym is highly favorable.

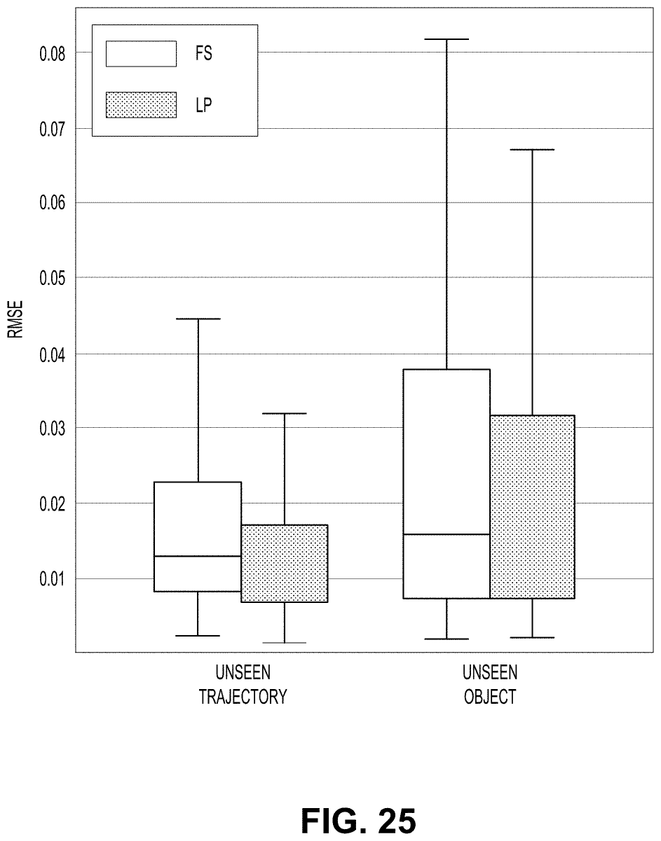

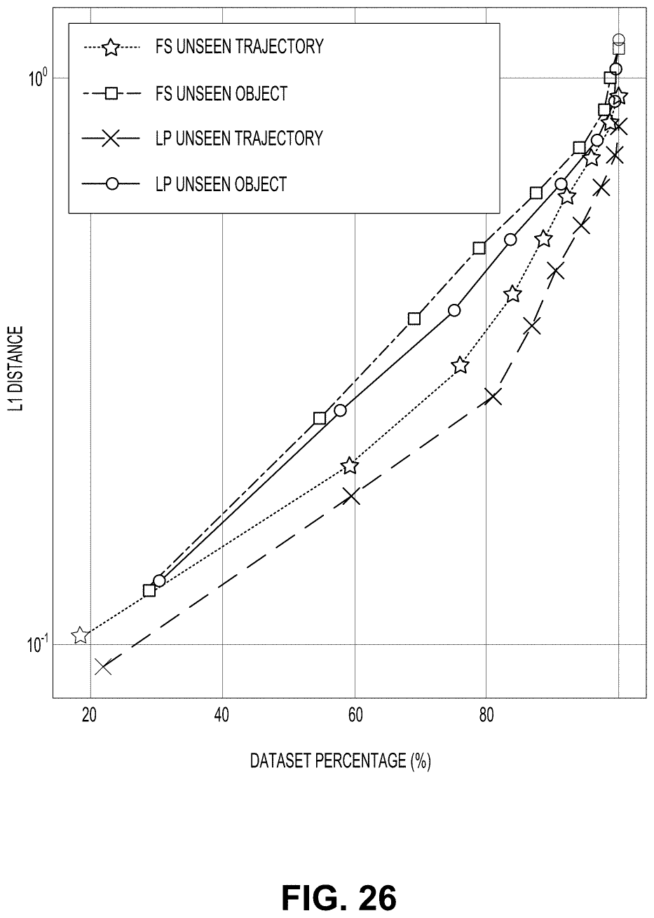

FIG. 25 illustrates an example of root mean square (“RMS”) error for a set of electrodes of a tactile sensor, in at least one embodiment. RMS error over all electrodes and interactions, for both unseen trajectories and objects. At least one embodiment has lower median errors and interquartile ranges than the baseline. FIG. 26 illustrates an example of a coverage plot, with L1 distance to ground-truth, in at least one embodiment. At least one embodiment has lower errors than corresponding baselines over nearly the full data distribution.

In at least one embodiment, for regression from FEM deformations to tactile sensor electrode signals, two learning models were evaluated: 1) one method used in this paper, denoted Latent Projection, which uses unlabeled data for latent representation and labeled data for projection, and 2) a PointNet++ baseline, denoted Fully Supervised, which uses only labeled data, with 128 nodes sampled from the FEM mesh. In at least one embodiment, output of the Electrode VAE is shown, which is used when training Latent Projection.

In at least one embodiment, for both methods, in the labeled dataset, 72% of contact interactions are allocated for training, 18% are allocated for validation, and 10% are allocated for testing. In at least one embodiment, when evaluating generalization to novel objects, networks are trained on all objects except the ring and tested on this indenter; note that the ring has the most unique (and thus challenging) geometry in the dataset. In at least one embodiment, these experiments are denoted with “Unseen Object.” In at least one embodiment, when evaluating generalization to novel contact interactions with seen objects, the already-trained networks are tested on unseen interactions with the other indenters. In at least one embodiment, these experiments are denoted with “Unseen Trajectory.”

In at least one embodiment, a qualitative comparison of regression results between the learning methods is depicted in FIG. 24 for two high-signal, high-variation electrodes over numerous interactions. In at least one embodiment, raw electrode values are between [0, 4095] digital output units and are tared and normalized to [−1, 1]. In at least one embodiment, for the challenging “Unseen Object” case, Latent Projection can predict several signal peaks that Fully Supervised does not capture on multiple electrodes. In at least one embodiment, Latent Projection predictions are consistently noise-free, whereas Fully Supervised ones exhibit low-magnitude high-frequency noise. In at least one embodiment, Latent Projection often outperforms Electrode VAE, showing the importance of preserving mesh information during projection. In at least one embodiment, predictions for the easier “Unseen Trajectory” case have higher fidelity and are thus not shown.

In at least one embodiment, quantitative comparisons between the learning methods are illustrated in FIGS. 25-26. In at least one embodiment, RMS errors over all electrodes and interactions are compared in FIG. 25. In at least one embodiment, the Latent Projection approach performs better than Fully Supervised for both “Unseen Trajectory” and “Unseen Object,” in terms of both median error and interquartile range. Median errors for “Unseen Trajectory” were Fully Supervised: 0.012 (25 raw units) and Latent Projection: 0.010 (20 units), and those for “Unseen Object” were 0.016 (32 units) and 0.015 (31 units), respectively. IA coverage plot of at least one embodiment is shown in FIG. 26, where the [symbol] ¹ distance to the ground-truth electrode signals is depicted. In at least one embodiment, for both “Unseen Trajectory” and “Unseen Object,” Latent Projection outperforms Fully Supervised for nearly the entire distribution of data.

In at least one embodiment, for regression from tactile sensor electrode signals to FEM deformations, Latent Projection is evaluated. In at least one embodiment, for reference, output of the FEM Mesh VAE is shown, which is used when training Latent Projection. In at least one embodiment, for “Unseen Trajectory”, Latent Projection consistently predicted ground-truth, capturing deformation magnitudes and distributions. In at least one embodiment, for “Unseen Object”, Latent Projection consistently captured magnitudes and distributions, but not bimodality. In at least one embodiment, as seen from Mesh VAE, this limit is due to the mesh auto-encoder (specifically, bottleneck size) rather than the projection. In at least one embodiment, results are shown for the most challenging unseen object, the ring.

For at least one embodiment, free-form interactions of the tactile sensor with unseen objects are conducted and estimated contact patches are visualized. In at least one embodiment, for diverse pegs and table features, predicted deformations are visually accurate. In at least one embodiment for instance, contact patch locations are accurately predicted across the full spatial limits of the tactile sensor, and interactions with the corners of a “cuboid” peg and table show high-magnitude, highly-localized patch deformations.

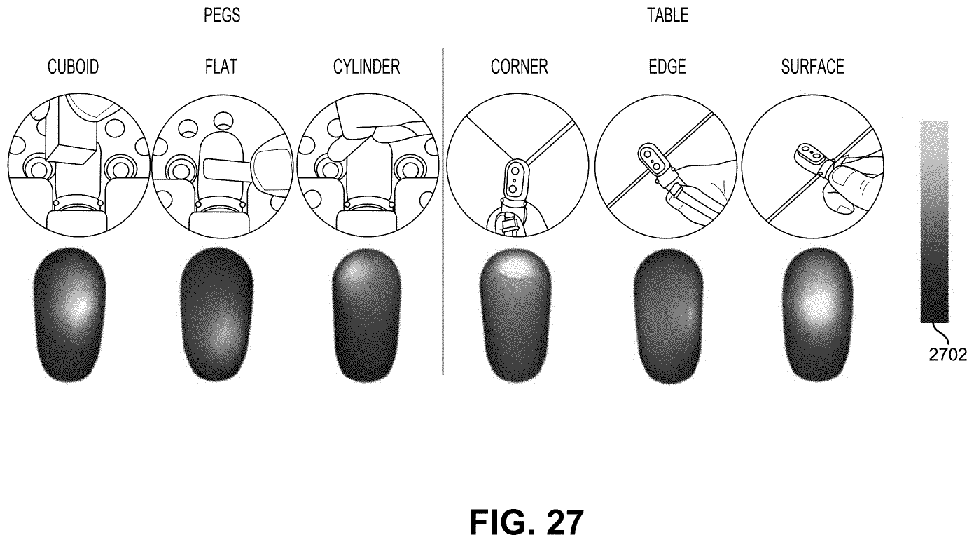

FIG. 27 illustrates an example of contact patch estimation, in at least one embodiment. In at least one embodiment, the shaded bar 2702 shows the Euclidean distance from the undeformed state. In at least one embodiment, the top image shows a real-world contact with various unseen objects and table features. In at least one embodiment, a bottom image shows a predicted contact patch using learned latent projections. In at least one embodiment, contact patches match contacting features; for example, interactions with the corners of the flat peg and table produce highly-localized, high-magnitude deformation.

At least one embodiment provides a framework for synthesizing tactile sensor electrical signals for novel contact interactions. In at least one embodiment, the framework includes 1) a 3D FEM model, which simulates contact between the tactile sensor and objects, and outputs tactile sensor deformation fields, 2) a VAE that outputs a compressed representation of the fields, and 3) a projection network, which was trained via self-supervision to transform the representation in order to efficiently regress electrode signals.

At least one embodiment provides one or more contributions. In at least one embodiment, compared to an experimentally-validated FEM model, the current model is nearly equivalent, available in an open-access robotics simulator, and 75× faster. At least one embodiment presents one of the first applications of cross-modal self-supervision for tactile sensing; we show that this approach outperforms supervised-only methods for regressing to tactile sensor electrical signals. At least one embodiment accurately predicts these signals for unseen interactions, including unseen objects. At least one embodiment reconstructs tactile sensor deformations from real electrical signals with high fidelity.

In at least one embodiment, although the FEM model is substantially faster than previous efforts, it currently takes approximately 5.6 s to simulate 6 mm of indentation, which makes dynamic model-predictive control applications difficult. In at least one embodiment, although networks accurately predict electrode signals for unseen trajectories and objects, evaluation is performed for one tactile sensor; to compensate for manufacturing variation, unlabeled and labeled data from more tactile sensors may be used to fine-tune the VAEs and projection networks. At least one embodiment applies the simulation and learning framework to additional tactile sensors. At least one embodiment provides powerful, generalized representations of tactile data that can serve as the foundation for transfer learning across sensors of entirely different modalities, such as the BioTac and Gel Sight.

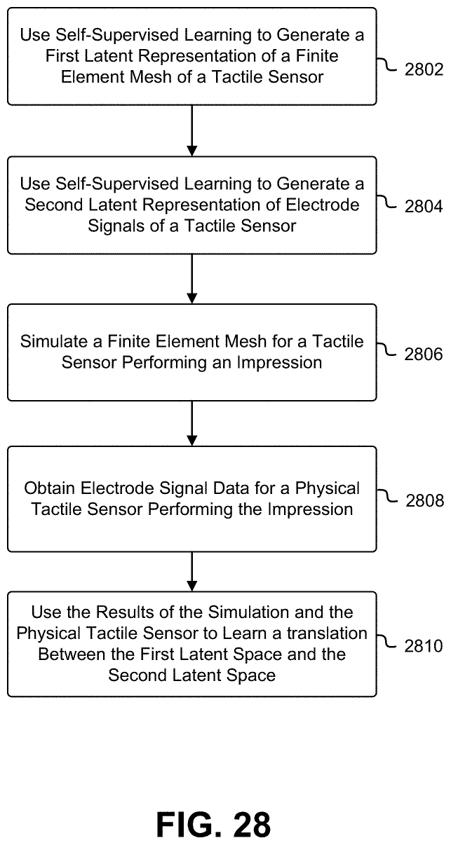

FIG. 28 illustrates an example of a process that, as a result of being performed by a computer system, trains a machine-learned model to estimate behavior of a tactile sensor, in at least one embodiment. In at least one embodiment, at block 2802, the computer system uses self-supervised learning to generate a latent representation of a finite element mesh of a tactile sensor. In at least one embodiment, the latent representation is produced by compressing four thousand nodes of the finite element model into a 128 dimension latent space using a graph convolutional network. In at least one embodiment, at block 2804, the computer system uses self-supervised learning to generate a latent representation of electrode signals generated by tactile sensor. In at least one embodiment, the latent spaces generated by compressing nineteen electrode signals into an 8 dimension latent space using a fully connected network.

In at least one embodiment, at block 2806, the computer system generates a simulation of the skin of a tactile sensor using a finite element mesh, and simulates the performance of an impression of indenter against the tactile sensor. In at least one embodiment, at block 2808, the corresponding experiment is performed with a physical tactile sensor and a corresponding indenter using a test fixture, and electrical signals corresponding to the action are collected from the physical sensor. In at least one embodiment, at block 2810, using supervised learning, results of the experiment and the simulation are used to learn a translation (or projection) between the latent space of the finite element model and the latent space of the electrical signals produced by the tactile sensor. In at least one embodiment, the information collected can be used to produce both forward and inverse projections between the latent spaces, which allows for the transformation between an indentation and a set of signals in either direction. As described above, various embodiments may use different models for the tactile sensor including rigid core and deformable shell, deformable solid, or other models.

In at least one embodiment, a latent space is a set of data within a neural network that represents a compressed version of the inputs to the network and/or the state of the network. In at least one embodiment, information in the latent space of the network is information sufficient to produce the output of the network.

### Inference and Training Logic

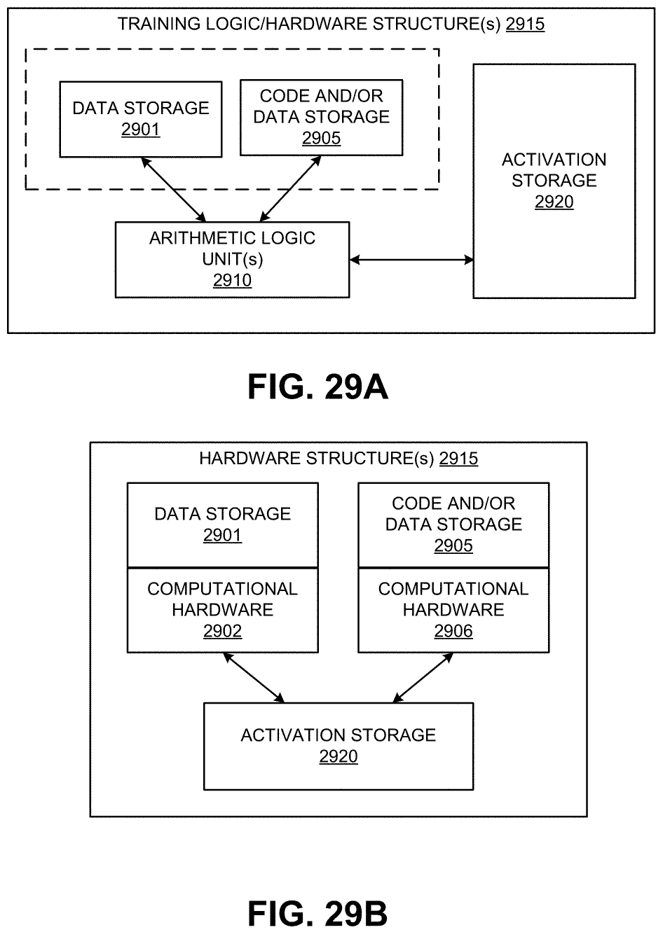

FIG. 29A illustrates inference and/or training logic 2915 used to perform inferencing and/or training operations associated with one or more embodiments. Details regarding inference and/or training logic 2915 are provided below in conjunction with FIGS. 29A and/or 29B.

In at least one embodiment, inference and/or training logic 2915 may include, without limitation, code and/or data storage 2901 to store forward and/or output weight and/or input/output data, and/or other parameters to configure neurons or layers of a neural network trained and/or used for inferencing in aspects of one or more embodiments. In at least one embodiment, training logic 2915 may include, or be coupled to code and/or data storage 2901 to store graph code or other software to control timing and/or order, in which weight and/or other parameter information is to be loaded to configure, logic, including integer and/or floating point units (collectively, arithmetic logic units (ALUs)). In at least one embodiment, code, such as graph code, loads weight or other parameter information into processor ALUs based on an architecture of a neural network to which such code corresponds. In at least one embodiment, code and/or data storage 2901 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of code and/or data storage 2901 may be included with other on-chip or off-chip data storage, including a processor's L1, L2, or L3 cache or system memory.

In at least one embodiment, any portion of code and/or data storage 2901 may be internal or external to one or more processors or other hardware logic devices or circuits. In at least one embodiment, code and/or code and/or data storage 2901 may be cache memory, dynamic randomly addressable memory (“DRAM”), static randomly addressable memory (“SRAM”), non-volatile memory (e.g., flash memory), or other storage. In at least one embodiment, a choice of whether code and/or code and/or data storage 2901 is internal or external to a processor, for example, or comprising DRAM, SRAM, flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 2915 may include, without limitation, a code and/or data storage 2905 to store backward and/or output weight and/or input/output data corresponding to neurons or layers of a neural network trained and/or used for inferencing in aspects of one or more embodiments. In at least one embodiment, code and/or data storage 2905 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, training logic 2915 may include, or be coupled to code and/or data storage 2905 to store graph code or other software to control timing and/or order, in which weight and/or other parameter information is to be loaded to configure, logic, including integer and/or floating point units (collectively, arithmetic logic units (ALUs)).

In at least one embodiment, code, such as graph code, causes the loading of weight or other parameter information into processor ALUs based on an architecture of a neural network to which such code corresponds. In at least one embodiment, any portion of code and/or data storage 2905 may be included with other on-chip or off-chip data storage, including a processor's L1, L2, or L3 cache or system memory. In at least one embodiment, any portion of code and/or data storage 2905 may be internal or external to one or more processors or other hardware logic devices or circuits. In at least one embodiment, code and/or data storage 2905 may be cache memory, DRAM, SRAM, non-volatile memory (e.g., flash memory), or other storage. In at least one embodiment, a choice of whether code and/or data storage 2905 is internal or external to a processor, for example, or comprising DRAM, SRAM, flash memory or some other storage type may depend on available storage on-chip versus off-chip, latency requirements of training and/or inferencing functions being performed, batch size of data used in inferencing and/or training of a neural network, or some combination of these factors.

In at least one embodiment, code and/or data storage 2901 and code and/or data storage 2905 may be separate storage structures. In at least one embodiment, code and/or data storage 2901 and code and/or data storage 2905 may be a combined storage structure. In at least one embodiment, code and/or data storage 2901 and code and/or data storage 2905 may be partially combined and partially separate. In at least one embodiment, any portion of code and/or data storage 2901 and code and/or data storage 2905 may be included with other on-chip or off-chip data storage, including a processor's L1, L2, or L3 cache or system memory.

In at least one embodiment, inference and/or training logic 2915 may include, without limitation, one or more arithmetic logic unit(s) (“ALU(s)”) 2910, including integer and/or floating point units, to perform logical and/or mathematical operations based, at least in part on, or indicated by, training and/or inference code (e.g., graph code), a result of which may produce activations (e.g., output values from layers or neurons within a neural network) stored in an activation storage 2920 that are functions of input/output and/or weight parameter data stored in code and/or data storage 2901 and/or code and/or data storage 2905. In at least one embodiment, activations stored in activation storage 2920 are generated according to linear algebraic and or matrix-based mathematics performed by ALU(s) 2910 in response to performing instructions or other code, wherein weight values stored in code and/or data storage 2905 and/or data storage 2901 are used as operands along with other values, such as bias values, gradient information, momentum values, or other parameters or hyperparameters, any or all of which may be stored in code and/or data storage 2905 or code and/or data storage 2901 or another storage on or off-chip.

In at least one embodiment, ALU(s) 2910 are included within one or more processors or other hardware logic devices or circuits, whereas in another embodiment, ALU(s) 2910 may be external to a processor or other hardware logic device or circuit that uses them (e.g., a co-processor). In at least one embodiment, ALUs 2910 may be included within a processor's execution units or otherwise within a bank of ALUs accessible by a processor's execution units either within same processor or distributed between different processors of different types (e.g., central processing units, graphics processing units, fixed function units, etc.). In at least one embodiment, code and/or data storage 2901, code and/or data storage 2905, and activation storage 2920 may share a processor or other hardware logic device or circuit, whereas in another embodiment, they may be in different processors or other hardware logic devices or circuits, or some combination of same and different processors or other hardware logic devices or circuits. In at least one embodiment, any portion of activation storage 2920 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 2920 may be cache memory, DRAM, SRAM, non-volatile memory (e.g., flash memory), or other storage. In at least one embodiment, activation storage 2920 may be completely or partially within or external to one or more processors or other logical circuits. In at least one embodiment, a choice of whether activation storage 2920 is internal or external to a processor, for example, or comprising DRAM, SRAM, flash memory or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 2915 illustrated in FIG. 29A may be used in conjunction with an application-specific integrated circuit (“ASIC”), such as a TensorFlow® Processing Unit from Google, an inference processing unit (IPU) from Graphcore™, or a Nervana® (e.g., “Lake Crest”) processor from Intel Corp. In at least one embodiment, inference and/or training logic 2915 illustrated in FIG. 29A may be used in conjunction with central processing unit (“CPU”) hardware, graphics processing unit (“GPU”) hardware or other hardware, such as field programmable gate arrays (“FPGAs”).

FIG. 29B illustrates inference and/or training logic 2915, according to at least one embodiment. In at least one embodiment, inference and/or training logic 2915 may include, without limitation, hardware logic in which computational resources are dedicated or otherwise exclusively used in conjunction with weight values or other information corresponding to one or more layers of neurons within a neural network. In at least one embodiment, inference and/or training logic 2915 illustrated in FIG. 29B may be used in conjunction with an application-specific integrated circuit (ASIC), such as TensorFlow® Processing Unit from Google, an inference processing unit (IPU) from Graphcore™, or a Nervana® (e.g., “Lake Crest”) processor from Intel Corp. In at least one embodiment, inference and/or training logic 2915 illustrated in FIG. 29B may be used in conjunction with central processing unit (CPU) hardware, graphics processing unit (GPU) hardware or other hardware, such as field programmable gate arrays (FPGAs). In at least one embodiment, inference and/or training logic 2915 includes, without limitation, code and/or data storage 2901 and code and/or data storage 2905, which may be used to store code (e.g., graph code), weight values and/or other information, including bias values, gradient information, momentum values, and/or other parameter or hyperparameter information. In at least one embodiment illustrated in FIG. 29B, each of code and/or data storage 2901 and code and/or data storage 2905 is associated with a dedicated computational resource, such as computational hardware 2902 and computational hardware 2906, respectively. In at least one embodiment, each of computational hardware 2902 and computational hardware 2906 comprises one or more ALUs that perform mathematical functions, such as linear algebraic functions, only on information stored in code and/or data storage 2901 and code and/or data storage 2905, respectively, result of which is stored in activation storage 2920.

In at least one embodiment, each of code and/or data storage 2901 and 2905 and corresponding computational hardware 2902 and 2906, respectively, correspond to different layers of a neural network, such that resulting activation from one storage/computational pair 2901/2902 of code and/or data storage 2901 and computational hardware 2902 is provided as an input to a next storage/computational pair 2905/2906 of code and/or data storage 2905 and computational hardware 2906, in order to mirror a conceptual organization of a neural network. In at least one embodiment, each of storage/computational pairs 2901/2902 and 2905/2906 may correspond to more than one neural network layer. In at least one embodiment, additional storage/computation pairs (not shown) subsequent to or in parallel with storage/computation pairs 2901/2902 and 2905/2906 may be included in inference and/or training logic 2915.

### Neural Network Training and Deployment

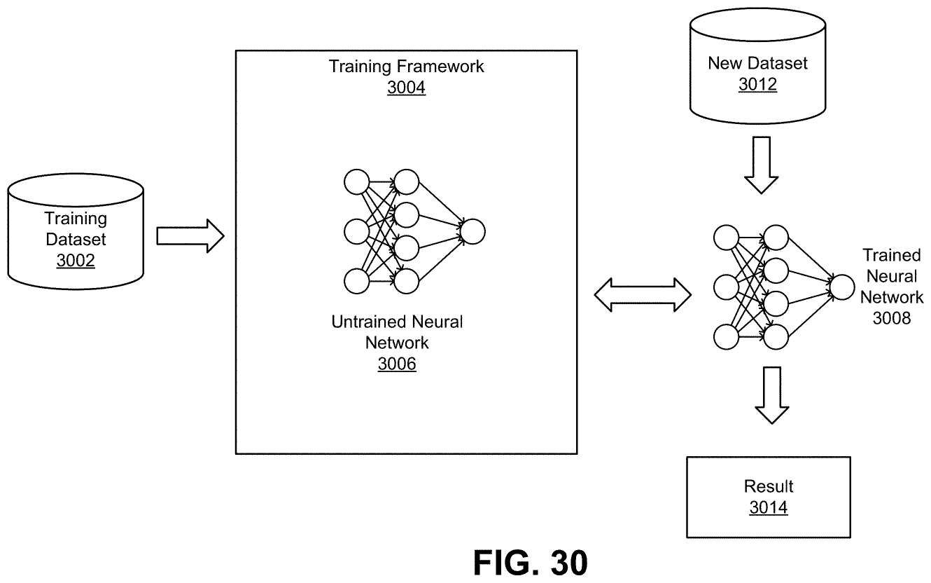

FIG. 30 illustrates training and deployment of a deep neural network, according to at least one embodiment. In at least one embodiment, untrained neural network 3006 is trained using a training dataset 3002. In at least one embodiment, training framework 3004 is a PyTorch framework, whereas in other embodiments, training framework 3004 is a TensorFlow, Boost, Caffe, Microsoft Cognitive Toolkit/CNTK, MXNet, Chainer, Keras, Deeplearning4j, or other training framework. In at least one embodiment, training framework 3004 trains an untrained neural network 3006 and enables it to be trained using processing resources described herein to generate a trained neural network 3008. In at least one embodiment, weights may be chosen randomly or by pre-training using a deep belief network. In at least one embodiment, training may be performed in either a supervised, partially supervised, or unsupervised manner.

In at least one embodiment, untrained neural network 3006 is trained using supervised learning, wherein training dataset 3002 includes an input paired with a desired output for an input, or where training dataset 3002 includes input having a known output and an output of neural network 3006 is manually graded. In at least one embodiment, untrained neural network 3006 is trained in a supervised manner and processes inputs from training dataset 3002 and compares resulting outputs against a set of expected or desired outputs. In at least one embodiment, errors are then propagated back through untrained neural network 3006. In at least one embodiment, training framework 3004 adjusts weights that control untrained neural network 3006. In at least one embodiment, training framework 3004 includes tools to monitor how well untrained neural network 3006 is converging towards a model, such as trained neural network 3008, suitable to generating correct answers, such as in result 3014, based on input data such as a new dataset 3012. In at least one embodiment, training framework 3004 trains untrained neural network 3006 repeatedly while adjust weights to refine an output of untrained neural network 3006 using a loss function and adjustment algorithm, such as stochastic gradient descent. In at least one embodiment, training framework 3004 trains untrained neural network 3006 until untrained neural network 3006 achieves a desired accuracy. In at least one embodiment, trained neural network 3008 can then be deployed to implement any number of machine learning operations.

In at least one embodiment, untrained neural network 3006 is trained using unsupervised learning, wherein untrained neural network 3006 attempts to train itself using unlabeled data. In at least one embodiment, unsupervised learning training dataset 3002 will include input data without any associated output data or “ground truth” data. In at least one embodiment, untrained neural network 3006 can learn groupings within training dataset 3002 and can determine how individual inputs are related to untrained dataset 3002. In at least one embodiment, unsupervised training can be used to generate a self-organizing map in trained neural network 3008 capable of performing operations useful in reducing dimensionality of new dataset 3012. In at least one embodiment, unsupervised training can also be used to perform anomaly detection, which allows identification of data points in new dataset 3012 that deviate from normal patterns of new dataset 3012.

In at least one embodiment, semi-supervised learning may be used, which is a technique in which in training dataset 3002 includes a mix of labeled and unlabeled data. In at least one embodiment, training framework 3004 may be used to perform incremental learning, such as through transferred learning techniques. In at least one embodiment, incremental learning enables trained neural network 3008 to adapt to new dataset 3012 without forgetting knowledge instilled within trained neural network 3008 during initial training.

### Data Center

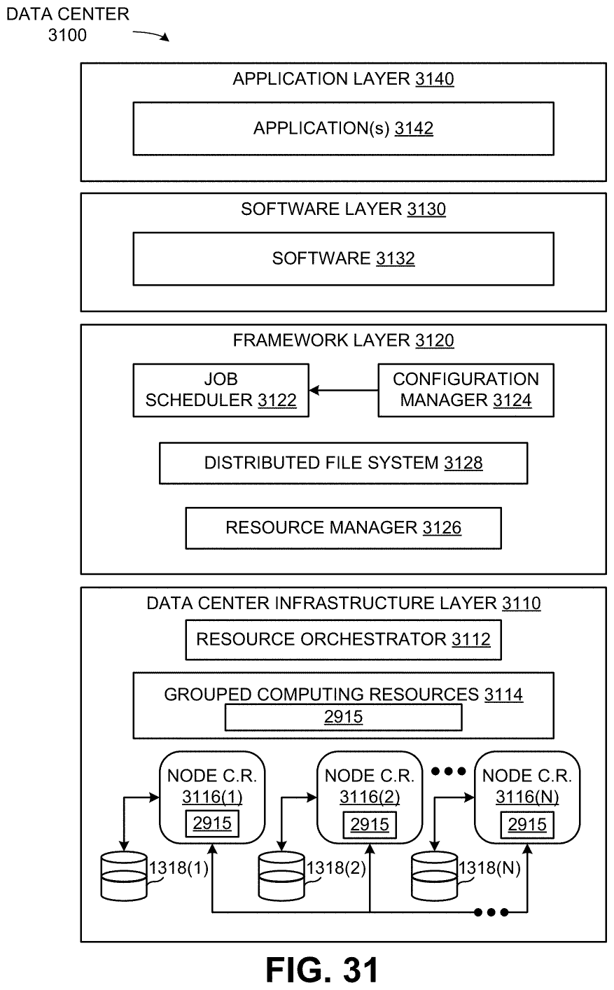

FIG. 31 illustrates an example data center 3100, in which at least one embodiment may be used. In at least one embodiment, data center 3100 includes a data center infrastructure layer 3110, a framework layer 3120, a software layer 3130 and an application layer 3140.

In at least one embodiment, as shown in FIG. 31, data center infrastructure layer 3110 may include a resource orchestrator 3112, grouped computing resources 3114, and node computing resources (“node C.R.s”) 3116(1)-3116(N), where “N” represents a positive integer (which may be a different integer “N” than used in other figures). In at least one embodiment, node C.R.s 3116(1)-3116(N) may include, but are not limited to, any number of central processing units (“CPUs”) or other processors (including accelerators, field programmable gate arrays (FPGAs), graphics processors, etc.), memory storage devices 3118(1)-3118(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 3116(1)-3116(N) may be a server having one or more of above-mentioned computing resources.

In at least one embodiment, grouped computing resources 3114 may include separate groupings of node C.R.s housed within one or more racks (not shown), or many racks housed in data centers at various geographical locations (also not shown). In at least one embodiment, separate groupings of node C.R.s within grouped computing resources 3114 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 3112 may configure or otherwise control one or more node C.R.s 3116(1)-3116(N) and/or grouped computing resources 3114. In at least one embodiment, resource orchestrator 3112 may include a software design infrastructure (“SDI”) management entity for data center 3100. In at least one embodiment, resource orchestrator 2912 may include hardware, software or some combination thereof.

In at least one embodiment, as shown in FIG. 31, framework layer 3120 includes a job scheduler 3122, a configuration manager 3124, a resource manager 3126 and a distributed file system 3128. In at least one embodiment, framework layer 3120 may include a framework to support software 3132 of software layer 3130 and/or one or more application(s) 3142 of application layer 3140. In at least one embodiment, software 3132 or application(s) 3142 may respectively include web-based service software or applications, such as those provided by Amazon Web Services, Google Cloud and Microsoft Azure. In at least one embodiment, framework layer 3120 may be, but is not limited to, a type of free and open-source software web application framework such as Apache Spark™ (hereinafter “Spark”) that may utilize distributed file system 3128 for large-scale data processing (e.g., “big data”). In at least one embodiment, job scheduler 3132 may include a Spark driver to facilitate scheduling of workloads supported by various layers of data center 3100. In at least one embodiment, configuration manager 3124 may be capable of configuring different layers such as software layer 3130 and framework layer 3120 including Spark and distributed file system 3128 for supporting large-scale data processing. In at least one embodiment, resource manager 3126 may be capable of managing clustered or grouped computing resources mapped to or allocated for support of distributed file system 3128 and job scheduler 3122. In at least one embodiment, clustered or grouped computing resources may include grouped computing resources 3114 at data center infrastructure layer 3110. In at least one embodiment, resource manager 3126 may coordinate with resource orchestrator 3112 to manage these mapped or allocated computing resources.

In at least one embodiment, software 3132 included in software layer 3130 may include software used by at least portions of node C.R.s 3116(1)-3116(N), grouped computing resources 3114, and/or distributed file system 3128 of framework layer 3120. In at least one embodiment, one or more types of software may include, but are not limited to, Internet web page search software, e-mail virus scan software, database software, and streaming video content software.

In at least one embodiment, application(s) 3142 included in application layer 3140 may include one or more types of applications used by at least portions of node C.R.s 3116(1)-3116(N), grouped computing resources 3114, and/or distributed file system 3128 of framework layer 3120. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 3124, resource manager 3126, and resource orchestrator 3112 may implement any number and type of self-modifying actions based on any amount and type of data acquired in any technically feasible fashion. In at least one embodiment, self-modifying actions may relieve a data center operator of data center 3100 from making possibly bad configuration decisions and possibly avoiding underutilized and/or poor performing portions of a data center.

In at least one embodiment, data center 3100 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 3100. In at least one embodiment, trained machine learning models corresponding to one or more neural networks may be used to infer or predict information using resources described above with respect to data center 3100 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 31 for inferencing or predicting operations based, at least in part, on weight parameters calculated using neural network training operations, neural network functions and/or architectures, or neural network use cases described herein.

In at least one embodiment, data center 3100 can be used to train or implement a neural network as described herein. In at least one embodiment, for example, data center 3100 can be used to simulate a tactile sensor to generate a latent space using unsupervised learning, and generate a latent space for electrode signals generated by the tactile sensor. In at least one embodiment, data center 3100 can be used to learn a mapping between these two latent spaces, allowing for projection between impressions on a tactile sensor and the signals produced by the sensor itself.

### Autonomous Vehicle

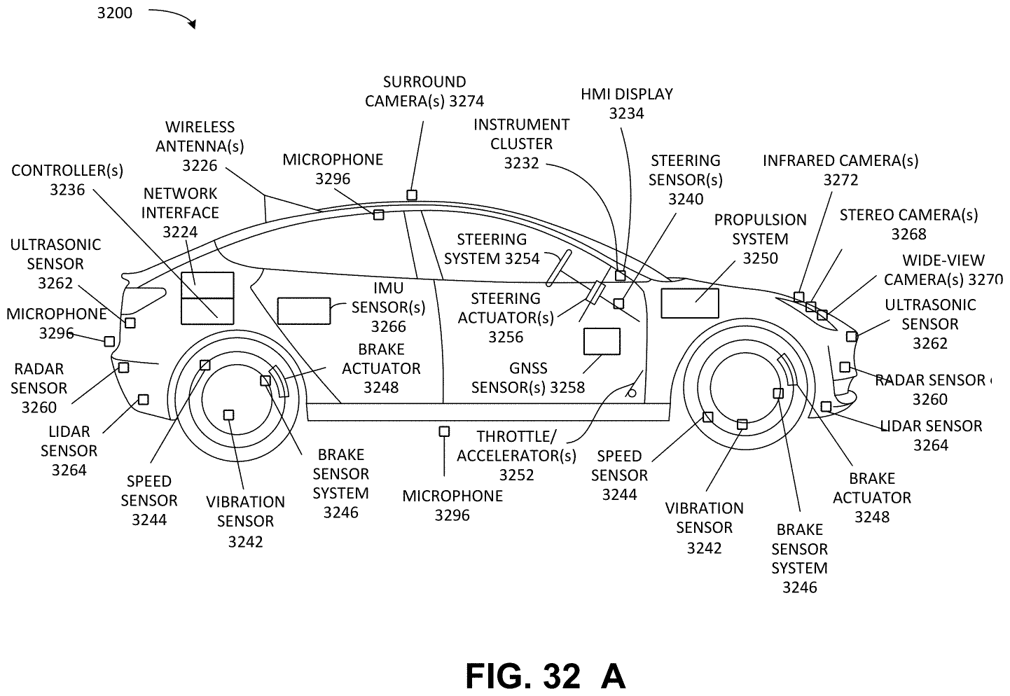

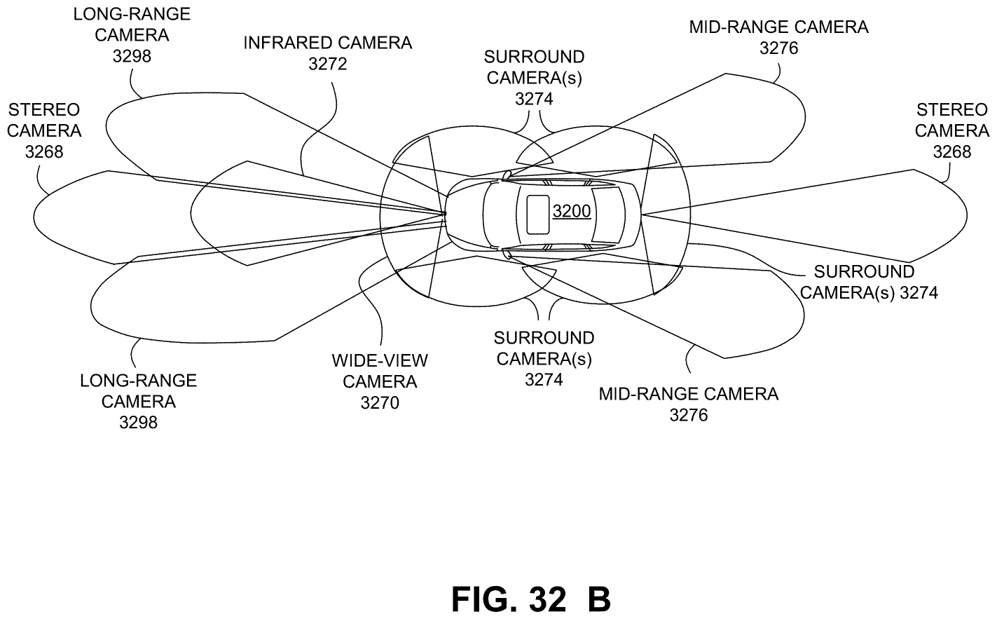

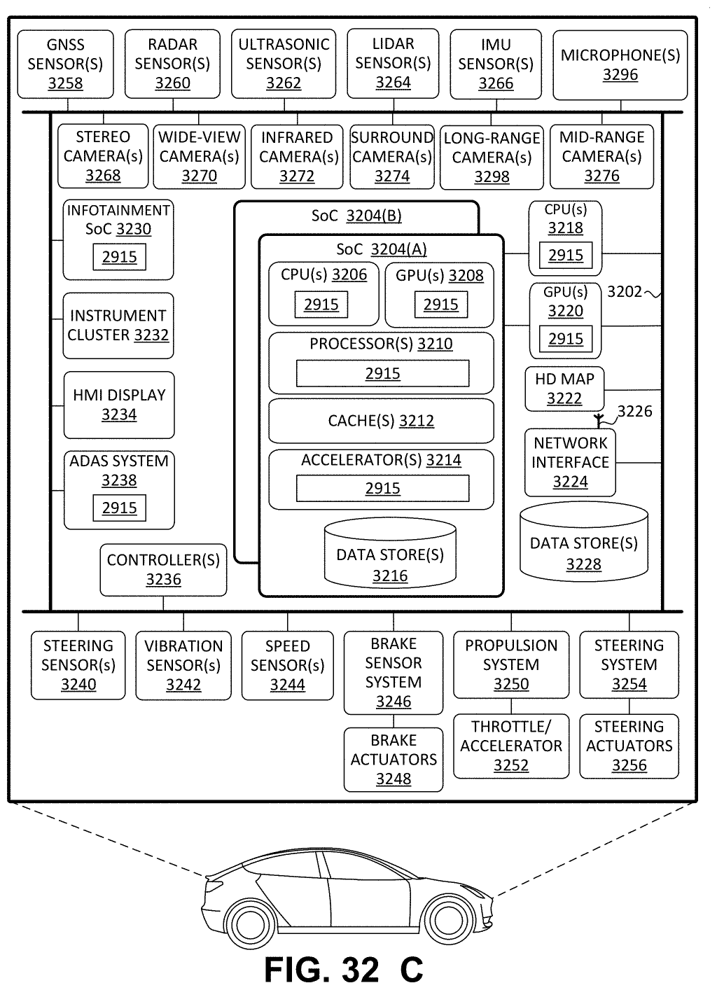

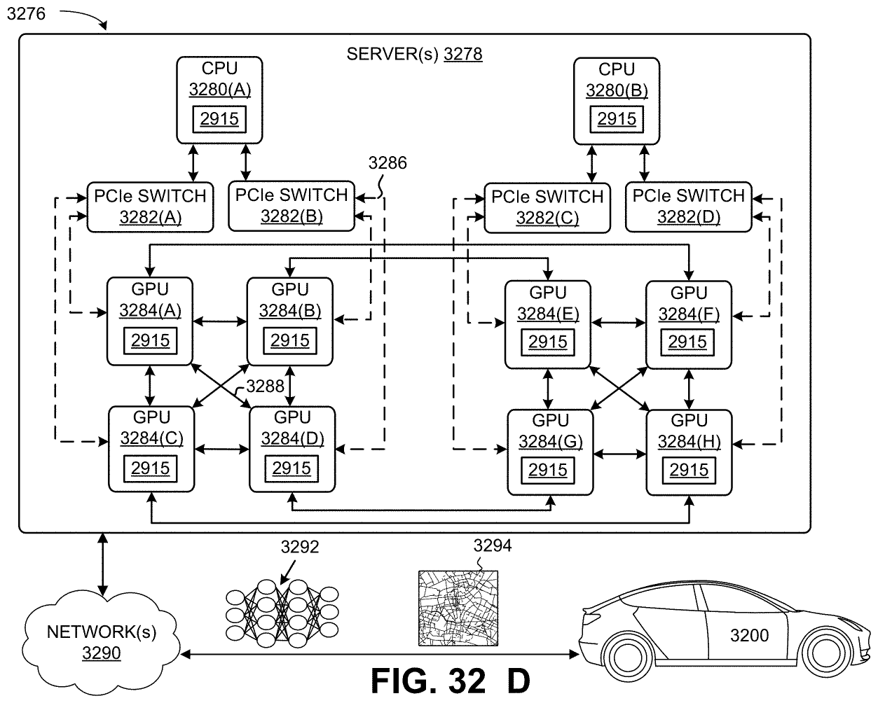

FIG. 32A illustrates an example of an autonomous vehicle 3200, according to at least one embodiment. In at least one embodiment, autonomous vehicle 3200 (alternatively referred to herein as “vehicle 3200”) may be, without limitation, a passenger vehicle, such as a car, a truck, a bus, and/or another type of vehicle that accommodates one or more passengers. In at least one embodiment, vehicle 3200 may be a semi-tractor-trailer truck used for hauling cargo. In at least one embodiment, vehicle 3200 may be an airplane, robotic vehicle, or other kind of vehicle.

Autonomous vehicles may be described in terms of automation levels, defined by National Highway Traffic Safety Administration (“NHTSA”), a division of US Department of Transportation, and Society of Automotive Engineers (“SAE”) “Taxonomy and Definitions for Terms Related to Driving Automation Systems for On-Road Motor Vehicles” (e.g., Standard No. J3016-201806, published on Jun. 15, 2018, Standard No. J3016-201609, published on Sep. 30, 2016, and previous and future versions of this standard). In at least one embodiment, vehicle 3200 may be capable of functionality in accordance with one or more of Level 1 through Level 5 of autonomous driving levels. For example, in at least one embodiment, vehicle 3200 may be capable of conditional automation (Level 3), high automation (Level 4), and/or full automation (Level 5), depending on embodiment.

In at least one embodiment, vehicle 3200 may include, without limitation, components such as a chassis, a vehicle body, wheels (e.g., 2, 4, 6, 8, 18, etc.), tires, axles, and other components of a vehicle. In at least one embodiment, vehicle 3200 may include, without limitation, a propulsion system 3250, such as an internal combustion engine, hybrid electric power plant, an all-electric engine, and/or another propulsion system type. In at least one embodiment, propulsion system 3250 may be connected to a drive train of vehicle 3200, which may include, without limitation, a transmission, to enable propulsion of vehicle 3200. In at least one embodiment, propulsion system 3250 may be controlled in response to receiving signals from a throttle/accelerator(s) 3252.

In at least one embodiment, a steering system 3254, which may include, without limitation, a steering wheel, is used to steer vehicle 3200 (e.g., along a desired path or route) when propulsion system 3250 is operating (e.g., when vehicle 3200 is in motion). In at least one embodiment, steering system 3254 may receive signals from steering actuator(s) 3256. In at least one embodiment, a steering wheel may be optional for full automation (Level 5) functionality. In at least one embodiment, a brake sensor system 3246 may be used to operate vehicle brakes in response to receiving signals from brake actuator(s) 3248 and/or brake sensors.

In at least one embodiment, controller(s) 3236, which may include, without limitation, one or more system on chips (“SoCs”) (not shown in FIG. 32A) and/or graphics processing unit(s) (“GPU(s)”), provide signals (e.g., representative of commands) to one or more components and/or systems of vehicle 3200. For instance, in at least one embodiment, controller(s) 3236 may send signals to operate vehicle brakes via brake actuator(s) 3248, to operate steering system 3254 via steering actuator(s) 3256, to operate propulsion system 3250 via throttle/accelerator(s) 3252. In at least one embodiment, controller(s) 3236 may include one or more onboard (e.g., integrated) computing devices that process sensor signals, and output operation commands (e.g., signals representing commands) to enable autonomous driving and/or to assist a human driver in driving vehicle 3200. In at least one embodiment, controller(s) 3236 may include a first controller for autonomous driving functions, a second controller for functional safety functions, a third controller for artificial intelligence functionality (e.g., computer vision), a fourth controller for infotainment functionality, a fifth controller for redundancy in emergency conditions, and/or other controllers. In at least one embodiment, a single controller may handle two or more of above functionalities, two or more controllers may handle a single functionality, and/or any combination thereof.

In at least one embodiment, controller(s) 3236 provide signals for controlling one or more components and/or systems of vehicle 3200 in response to sensor data received from one or more sensors (e.g., sensor inputs). In at least one embodiment, sensor data may be received from, for example and without limitation, global navigation satellite systems (“GNSS”) sensor(s) 3258 (e.g., Global Positioning System sensor(s)), RADAR sensor(s) 3260, ultrasonic sensor(s) 3262, LIDAR sensor(s) 3264, inertial measurement unit (“IMU”) sensor(s) 3266 (e.g., accelerometer(s), gyroscope(s), a magnetic compass or magnetic compasses, magnetometer(s), etc.), microphone(s) 3296, stereo camera(s) 3268, wide-view camera(s) 3270 (e.g., fisheye cameras), infrared camera(s) 3272, surround camera(s) 3274 (e.g., 360 degree cameras), long-range cameras (not shown in FIG. 32A), mid-range camera(s) (not shown in FIG. 32A), speed sensor(s) 3244 (e.g., for measuring speed of vehicle 3200), vibration sensor(s) 3242, steering sensor(s) 3240, brake sensor(s) (e.g., as part of brake sensor system 3246), and/or other sensor types.

In at least one embodiment, one or more of controller(s) 3236 may receive inputs (e.g., represented by input data) from an instrument cluster 3232 of vehicle 3200 and provide outputs (e.g., represented by output data, display data, etc.) via a human-machine interface (“HMI”) display 3234, an audible annunciator, a loudspeaker, and/or via other components of vehicle 3200. In at least one embodiment, outputs may include information such as vehicle velocity, speed, time, map data (e.g., a High Definition map (not shown in FIG. 32A)), location data (e.g., vehicle's 3200 location, such as on a map), direction, location of other vehicles (e.g., an occupancy grid), information about objects and status of objects as perceived by controller(s) 3236, etc. For example, in at least one embodiment, HMI display 3234 may display information about presence of one or more objects (e.g., a street sign, caution sign, traffic light changing, etc.), and/or information about driving maneuvers vehicle has made, is making, or will make (e.g., changing lanes now, taking exit 34B in two miles, etc.).

In at least one embodiment, vehicle 3200 further includes a network interface 3224 which may use wireless antenna(s) 3226 and/or modem(s) to communicate over one or more networks. For example, in at least one embodiment, network interface 3224 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”) networks, etc. In at least one embodiment, wireless antenna(s) 3226 may also enable communication between objects in environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc. protocols.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 32A for inferencing or predicting operations based, at least in part, on weight parameters calculated using neural network training operations, neural network functions and/or architectures, or neural network use cases described herein.

In at least one embodiment, vehicle 3200 may include one or more computer systems. In at least one embodiment, the one or more computer systems can be used to train or implement a neural network as described herein. In at least one embodiment, for example, the one or more computer systems can be used to simulate a tactile sensor to generate a latent space using unsupervised learning, and generate a latent space for electrode signals generated by the tactile sensor. In at least one embodiment, the one or more computer systems can be used to learn a mapping between these two latent spaces, allowing for projection between impressions on a tactile sensor and the signals produced by the sensor itself.

FIG. 32B illustrates an example of camera locations and fields of view for autonomous vehicle 3200 of FIG. 32A, according to at least one embodiment. In at least one embodiment, cameras and respective fields of view are one example embodiment and are not intended to be limiting. For instance, in at least one embodiment, additional and/or alternative cameras may be included and/or cameras may be located at different locations on vehicle 3200.

In at least one embodiment, camera types for cameras may include, but are not limited to, digital cameras that may be adapted for use with components and/or systems of vehicle 3200. In at least one embodiment, camera(s) may operate at automotive safety integrity level (“ASIL”) B and/or at another ASIL. In at least one embodiment, camera types may be capable of any image capture rate, such as 60 frames per second (fps), 1220 fps, 240 fps, etc., depending on embodiment. In at least one embodiment, cameras may be capable of using rolling shutters, global shutters, another type of shutter, or a combination thereof. In at least one embodiment, color filter array may include a red clear clear clear (“RCCC”) color filter array, a red clear clear blue (“RCCB”) color filter array, a red blue green clear (“RBGC”) color filter array, a Foveon X3 color filter array, a Bayer sensors (“RGGB”) color filter array, a monochrome sensor color filter array, and/or another type of color filter array. In at least one embodiment, clear pixel cameras, such as cameras with an RCCC, an RCCB, and/or an RBGC color filter array, may be used in an effort to increase light sensitivity.

In at least one embodiment, one or more of camera(s) may be used to perform advanced driver assistance systems (“ADAS”) functions (e.g., as part of a redundant or fail-safe design). For example, in at least one embodiment, a Multi-Function Mono Camera may be installed to provide functions including lane departure warning, traffic sign assist and intelligent headlamp control. In at least one embodiment, one or more of camera(s) (e.g., all cameras) may record and provide image data (e.g., video) simultaneously.

In at least one embodiment, one or more camera may be mounted in a mounting assembly, such as a custom designed (three-dimensional (“3D”) printed) assembly, in order to cut out stray light and reflections from within vehicle 3200 (e.g., reflections from dashboard reflected in windshield mirrors) which may interfere with camera image data capture abilities. With reference to wing-mirror mounting assemblies, in at least one embodiment, wing-mirror assemblies may be custom 3D printed so that a camera mounting plate matches a shape of a wing-mirror. In at least one embodiment, camera(s) may be integrated into wing-mirrors. In at least one embodiment, for side-view cameras, camera(s) may also be integrated within four pillars at each corner of a cabin.

In at least one embodiment, cameras with a field of view that include portions of an environment in front of vehicle 3200 (e.g., front-facing cameras) may be used for surround view, to help identify forward facing paths and obstacles, as well as aid in, with help of one or more of controller(s) 3236 and/or control SoCs, providing information critical to generating an occupancy grid and/or determining preferred vehicle paths. In at least one embodiment, front-facing cameras may be used to perform many similar ADAS functions as LIDAR, including, without limitation, emergency braking, pedestrian detection, and collision avoidance. In at least one embodiment, front-facing cameras may also be used for ADAS functions and systems including, without limitation, Lane Departure Warnings (“LDW”), Autonomous Cruise Control (“ACC”), and/or other functions such as traffic sign recognition.

In at least one embodiment, a variety of cameras may be used in a front-facing configuration, including, for example, a monocular camera platform that includes a CMOS (“complementary metal oxide semiconductor”) color imager. In at least one embodiment, a wide-view camera 3270 may be used to perceive objects coming into view from a periphery (e.g., pedestrians, crossing traffic or bicycles). Although only one wide-view camera 3270 is illustrated in FIG. 32B, in other embodiments, there may be any number (including zero) wide-view cameras on vehicle 3200. In at least one embodiment, any number of long-range camera(s) 3298 (e.g., a long-view stereo camera pair) may be used for depth-based object detection, especially for objects for which a neural network has not yet been trained. In at least one embodiment, long-range camera(s) 3298 may also be used for object detection and classification, as well as basic object tracking.

In at least one embodiment, any number of stereo camera(s) 3268 may also be included in a front-facing configuration. In at least one embodiment, one or more of stereo camera(s) 3268 may include an integrated control unit comprising a scalable processing unit, which may provide a programmable logic (“FPGA”) and a multi-core micro-processor with an integrated Controller Area Network (“CAN”) or Ethernet interface on a single chip. In at least one embodiment, such a unit may be used to generate a 3D map of an environment of vehicle 3200, including a distance estimate for all points in an image. In at least one embodiment, one or more of stereo camera(s) 3268 may include, without limitation, compact stereo vision sensor(s) that may include, without limitation, two camera lenses (one each on left and right) and an image processing chip that may measure distance from vehicle 3200 to target object and use generated information (e.g., metadata) to activate autonomous emergency braking and lane departure warning functions. In at least one embodiment, other types of stereo camera(s) 3268 may be used in addition to, or alternatively from, those described herein.

In at least one embodiment, cameras with a field of view that include portions of environment to sides of vehicle 3200 (e.g., side-view cameras) may be used for surround view, providing information used to create and update an occupancy grid, as well as to generate side impact collision warnings. For example, in at least one embodiment, surround camera(s) 3274 (e.g., four surround cameras as illustrated in FIG. 32B) could be positioned on vehicle 3200. In at least one embodiment, surround camera(s) 3274 may include, without limitation, any number and combination of wide-view cameras, fisheye camera(s), 360 degree camera(s), and/or similar cameras. For instance, in at least one embodiment, four fisheye cameras may be positioned on a front, a rear, and sides of vehicle 3200. In at least one embodiment, vehicle 3200 may use three surround camera(s) 3274 (e.g., left, right, and rear), and may leverage one or more other camera(s) (e.g., a forward-facing camera) as a fourth surround-view camera.

In at least one embodiment, cameras with a field of view that include portions of an environment behind vehicle 3200 (e.g., rear-view cameras) may be used for parking assistance, surround view, rear collision warnings, and creating and updating an occupancy grid. In at least one embodiment, a wide variety of cameras may be used including, but not limited to, cameras that are also suitable as a front-facing camera(s) (e.g., long-range cameras 3298 and/or mid-range camera(s) 3276, stereo camera(s) 3268), infrared camera(s) 3272, etc., as described herein.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 32B for inferencing or predicting operations based, at least in part, on weight parameters calculated using neural network training operations, neural network functions and/or architectures, or neural network use cases described herein.

FIG. 32C is a block diagram illustrating an example system architecture for autonomous vehicle 3200 of FIG. 32A, according to at least one embodiment. In at least one embodiment, each of components, features, and systems of vehicle 3200 in FIG. 32C is illustrated as being connected via a bus 3202. In at least one embodiment, bus 3202 may include, without limitation, a CAN data interface (alternatively referred to herein as a “CAN bus”). In at least one embodiment, a CAN may be a network inside vehicle 3200 used to aid in control of various features and functionality of vehicle 3200, such as actuation of brakes, acceleration, braking, steering, windshield wipers, etc. In at least one embodiment, bus 3202 may be configured to have dozens or even hundreds of nodes, each with its own unique identifier (e.g., a CAN ID). In at least one embodiment, bus 3202 may be read to find steering wheel angle, ground speed, engine revolutions per minute (“RPMs”), button positions, and/or other vehicle status indicators. In at least one embodiment, bus 3202 may be a CAN bus that is ASIL B compliant.

In at least one embodiment, in addition to, or alternatively from CAN, FlexRay and/or Ethernet protocols may be used. In at least one embodiment, there may be any number of busses forming bus 3202, which may include, without limitation, zero or more CAN busses, zero or more FlexRay busses, zero or more Ethernet busses, and/or zero or more other types of busses using different protocols. In at least one embodiment, two or more busses may be used to perform different functions, and/or may be used for redundancy. For example, a first bus may be used for collision avoidance functionality and a second bus may be used for actuation control. In at least one embodiment, each bus of bus 3202 may communicate with any of components of vehicle 3200, and two or more busses of bus 3202 may communicate with corresponding components. In at least one embodiment, each of any number of system(s) on chip(s) (“SoC(s)”) 3204 (such as SoC 3204(A) and SoC 3204(B)), each of controller(s) 3236, and/or each computer within vehicle may have access to same input data (e.g., inputs from sensors of vehicle 3200), and may be connected to a common bus, such CAN bus.

In at least one embodiment, vehicle 3200 may include one or more controller(s) 3236, such as those described herein with respect to FIG. 32A. In at least one embodiment, controller(s) 3236 may be used for a variety of functions. In at least one embodiment, controller(s) 3236 may be coupled to any of various other components and systems of vehicle 3200, and may be used for control of vehicle 3200, artificial intelligence of vehicle 3200, infotainment for vehicle 3200, and/or other functions.

In at least one embodiment, vehicle 3200 may include any number of SoCs 3204. In at least one embodiment, each of SoCs 3204 may include, without limitation, central processing units (“CPU(s)”) 3206, graphics processing units (“GPU(s)”) 3208, processor(s) 3210, cache(s) 3212, accelerator(s) 3214, data store(s) 3216, and/or other components and features not illustrated. In at least one embodiment, SoC(s) 3204 may be used to control vehicle 3200 in a variety of platforms and systems. For example, in at least one embodiment, SoC(s) 3204 may be combined in a system (e.g., system of vehicle 3200) with a High Definition (“HD”) map 3222 which may obtain map refreshes and/or updates via network interface 3224 from one or more servers (not shown in FIG. 32C).

In at least one embodiment, CPU(s) 3206 may include a CPU cluster or CPU complex (alternatively referred to herein as a “CCPLEX”). In at least one embodiment, CPU(s) 3206 may include multiple cores and/or level two (“L2”) caches. For instance, in at least one embodiment, CPU(s) 3206 may include eight cores in a coherent multi-processor configuration. In at least one embodiment, CPU(s) 3206 may include four dual-core clusters where each cluster has a dedicated L2 cache (e.g., a 2 megabyte (MB) L2 cache). In at least one embodiment, CPU(s) 3206 (e.g., CCPLEX) may be configured to support simultaneous cluster operations enabling any combination of clusters of CPU(s) 3206 to be active at any given time.

In at least one embodiment, one or more of CPU(s) 3206 may implement power management capabilities that include, without limitation, one or more of following features: individual hardware blocks may be clock-gated automatically when idle to save dynamic power; each core clock may be gated when such core is not actively executing instructions due to execution of Wait for Interrupt (“WFI”)/Wait for Event (“WFE”) instructions; each core may be independently power-gated; each core cluster may be independently clock-gated when all cores are clock-gated or power-gated; and/or each core cluster may be independently power-gated when all cores are power-gated. In at least one embodiment, CPU(s) 3206 may further implement an enhanced algorithm for managing power states, where allowed power states and expected wakeup times are specified, and hardware/microcode determines which best power state to enter for core, cluster, and CCPLEX. In at least one embodiment, processing cores may support simplified power state entry sequences in software with work offloaded to microcode.

In at least one embodiment, GPU(s) 3208 may include an integrated GPU (alternatively referred to herein as an “iGPU”). In at least one embodiment, GPU(s) 3208 may be programmable and may be efficient for parallel workloads. In at least one embodiment, GPU(s) 3208 may use an enhanced tensor instruction set. In at least one embodiment, GPU(s) 3208 may include one or more streaming microprocessors, where each streaming microprocessor may include a level one (“L1”) cache (e.g., an L1 cache with at least 96 KB storage capacity), and two or more streaming microprocessors may share an L2 cache (e.g., an L2 cache with a 512 KB storage capacity). In at least one embodiment, GPU(s) 3208 may include at least eight streaming microprocessors. In at least one embodiment, GPU(s) 3208 may use compute application programming interface(s) (API(s)). In at least one embodiment, GPU(s) 3208 may use one or more parallel computing platforms and/or programming models (e.g., NVIDIA's CUDA model).

In at least one embodiment, one or more of GPU(s) 3208 may be power-optimized for best performance in automotive and embedded use cases. For example, in at least one embodiment, GPU(s) 3208 could be fabricated on Fin field-effect transistor (“FinFET”) circuitry. In at least one embodiment, each streaming microprocessor may incorporate a number of mixed-precision processing cores partitioned into multiple blocks. For example, and without limitation, 64 PF32 cores and 32 PF64 cores could be partitioned into four processing blocks. In at least one embodiment, each processing block could be allocated 16 FP32 cores, 8 FP64 cores, 16 INT32 cores, two mixed-precision NVIDIA Tensor cores for deep learning matrix arithmetic, a level zero (“L0”) instruction cache, a warp scheduler, a dispatch unit, and/or a 64 KB register file. In at least one embodiment, streaming microprocessors may include independent parallel integer and floating-point data paths to provide for efficient execution of workloads with a mix of computation and addressing calculations. In at least one embodiment, streaming microprocessors may include independent thread scheduling capability to enable finer-grain synchronization and cooperation between parallel threads. In at least one embodiment, streaming microprocessors may include a combined L1 data cache and shared memory unit in order to improve performance while simplifying programming.

In at least one embodiment, one or more of GPU(s) 3208 may include a high bandwidth memory (“HBM”) and/or a 16 GB HBM2 memory subsystem to provide, in some examples, about 900 GB/second peak memory bandwidth. In at least one embodiment, in addition to, or alternatively from, HBM memory, a synchronous graphics random-access memory (“SGRAM”) may be used, such as a graphics double data rate type five synchronous random-access memory (“GDDR5”).

In at least one embodiment, GPU(s) 3208 may include unified memory technology. In at least one embodiment, address translation services (“ATS”) support may be used to allow GPU(s) 3208 to access CPU(s) 3206 page tables directly. In at least one embodiment, embodiment, when a GPU of GPU(s) 3208 memory management unit (“MMU”) experiences a miss, an address translation request may be transmitted to CPU(s) 3206. In response, 2 CPU of CPU(s) 3206 may look in its page tables for a virtual-to-physical mapping for an address and transmit translation back to GPU(s) 3208, in at least one embodiment. In at least one embodiment, unified memory technology may allow a single unified virtual address space for memory of both CPU(s) 3206 and GPU(s) 3208, thereby simplifying GPU(s) 3208 programming and porting of applications to GPU(s) 3208.

In at least one embodiment, GPU(s) 3208 may include any number of access counters that may keep track of frequency of access of GPU(s) 3208 to memory of other processors. In at least one embodiment, access counter(s) may help ensure that memory pages are moved to physical memory of a processor that is accessing pages most frequently, thereby improving efficiency for memory ranges shared between processors.

In at least one embodiment, one or more of SoC(s) 3204 may include any number of cache(s) 3212, including those described herein. For example, in at least one embodiment, cache(s) 3212 could include a level three (“L3”) cache that is available to both CPU(s) 3206 and GPU(s) 3208 (e.g., that is connected to CPU(s) 3206 and GPU(s) 3208). In at least one embodiment, cache(s) 3212 may include a write-back cache that may keep track of states of lines, such as by using a cache coherence protocol (e.g., MEI, MESI, MSI, etc.). In at least one embodiment, a L3 cache may include 4 MB of memory or more, depending on embodiment, although smaller cache sizes may be used.

In at least one embodiment, one or more of SoC(s) 3204 may include one or more accelerator(s) 3214 (e.g., hardware accelerators, software accelerators, or a combination thereof). In at least one embodiment, SoC(s) 3204 may include a hardware acceleration cluster that may include optimized hardware accelerators and/or large on-chip memory. In at least one embodiment, large on-chip memory (e.g., 4 MB of SRAM), may enable a hardware acceleration cluster to accelerate neural networks and other calculations. In at least one embodiment, a hardware acceleration cluster may be used to complement GPU(s) 3208 and to off-load some of tasks of GPU(s) 3208 (e.g., to free up more cycles of GPU(s) 3208 for performing other tasks). In at least one embodiment, accelerator(s) 3214 could be used for targeted workloads (e.g., perception, convolutional neural networks (“CNNs”), recurrent neural networks (“RNNs”), etc.) that are stable enough to be amenable to acceleration. In at least one embodiment, a CNN may include a region-based or regional convolutional neural networks (“RCNNs”) and Fast RCNNs (e.g., as used for object detection) or other type of CNN.

In at least one embodiment, accelerator(s) 3214 (e.g., hardware acceleration cluster) may include one or more deep learning accelerator (“DLA”). In at least one embodiment, DLA(s) may include, without limitation, one or more Tensor processing units (“TPUs”) that may be configured to provide an additional ten trillion operations per second for deep learning applications and inferencing. In at least one embodiment, TPUs may be accelerators configured to, and optimized for, performing image processing functions (e.g., for CNNs, RCNNs, etc.). In at least one embodiment, DLA(s) may further be optimized for a specific set of neural network types and floating point operations, as well as inferencing. In at least one embodiment, design of DLA(s) may provide more performance per millimeter than a typical general-purpose GPU, and typically vastly exceeds performance of a CPU. In at least one embodiment, TPU(s) may perform several functions, including a single-instance convolution function, supporting, for example, INT8, INT16, and FP16 data types for both features and weights, as well as post-processor functions. In at least one embodiment, DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

In at least one embodiment, DLA(s) may perform any function of GPU(s) 3208, and by using an inference accelerator, for example, a designer may target either DLA(s) or GPU(s) 3208 for any function. For example, in at least one embodiment, a designer may focus processing of CNNs and floating point operations on DLA(s) and leave other functions to GPU(s) 3208 and/or accelerator(s) 3214.

In at least one embodiment, accelerator(s) 3214 may include programmable vision accelerator (“PVA”), which may alternatively be referred to herein as a computer vision accelerator. In at least one embodiment, PVA may be designed and configured to accelerate computer vision algorithms for advanced driver assistance system (“ADAS”) 3238, autonomous driving, augmented reality (“AR”) applications, and/or virtual reality (“VR”) applications. In at least one embodiment, PVA may provide a balance between performance and flexibility. For example, in at least one embodiment, each PVA may include, for example and without limitation, any number of reduced instruction set computer (“RISC”) cores, direct memory access (“DMA”), and/or any number of vector processors.

In at least one embodiment, RISC cores may interact with image sensors (e.g., image sensors of any cameras described herein), image signal processor(s), etc. In at least one embodiment, each RISC core may include any amount of memory. In at least one embodiment, RISC cores may use any of a number of protocols, depending on embodiment. In at least one embodiment, RISC cores may execute a real-time operating system (“RTOS”). In at least one embodiment, RISC cores may be implemented using one or more integrated circuit devices, application specific integrated circuits (“ASICs”), and/or memory devices. For example, in at least one embodiment, RISC cores could include an instruction cache and/or a tightly coupled RAM.

In at least one embodiment, DMA may enable components of PVA to access system memory independently of CPU(s) 3206. In at least one embodiment, DMA may support any number of features used to provide optimization to a PVA including, but not limited to, supporting multi-dimensional addressing and/or circular addressing. In at least one embodiment, DMA may support up to six or more dimensions of addressing, which may include, without limitation, block width, block height, block depth, horizontal block stepping, vertical block stepping, and/or depth stepping.

In at least one embodiment, vector processors may be programmable processors that may be designed to efficiently and flexibly execute programming for computer vision algorithms and provide signal processing capabilities. In at least one embodiment, a PVA may include a PVA core and two vector processing subsystem partitions. In at least one embodiment, a PVA core may include a processor subsystem, DMA engine(s) (e.g., two DMA engines), and/or other peripherals. In at least one embodiment, a vector processing subsystem may operate as a primary processing engine of a PVA, and may include a vector processing unit (“VPU”), an instruction cache, and/or vector memory (e.g., “VMEM”). In at least one embodiment, VPU core may include a digital signal processor such as, for example, a single instruction, multiple data (“SIMD”), very long instruction word (“VLIW”) digital signal processor. In at least one embodiment, a combination of SIMD and VLIW may enhance throughput and speed.

In at least one embodiment, each of vector processors may include an instruction cache and may be coupled to dedicated memory. As a result, in at least one embodiment, each of vector processors may be configured to execute independently of other vector processors. In at least one embodiment, vector processors that are included in a particular PVA may be configured to employ data parallelism. For instance, in at least one embodiment, plurality of vector processors included in a single PVA may execute a common computer vision algorithm, but on different regions of an image. In at least one embodiment, vector processors included in a particular PVA may simultaneously execute different computer vision algorithms, on one image, or even execute different algorithms on sequential images or portions of an image. In at least one embodiment, among other things, any number of PVAs may be included in hardware acceleration cluster and any number of vector processors may be included in each PVA. In at least one embodiment, PVA may include additional error correcting code (“ECC”) memory, to enhance overall system safety.

In at least one embodiment, accelerator(s) 3214 may include a computer vision network on-chip and static random-access memory (“SRAM”), for providing a high-bandwidth, low latency SRAM for accelerator(s) 3214. In at least one embodiment, on-chip memory may include at least 4 MB SRAM, comprising, for example and without limitation, eight field-configurable memory blocks, that may be accessible by both a PVA and a DLA. In at least one embodiment, each pair of memory blocks may include an advanced peripheral bus (“APB”) interface, configuration circuitry, a controller, and a multiplexer. In at least one embodiment, any type of memory may be used. In at least one embodiment, a PVA and a DLA may access memory via a backbone that provides a PVA and a DLA with high-speed access to memory. In at least one embodiment, a backbone may include a computer vision network on-chip that interconnects a PVA and a DLA to memory (e.g., using APB).

In at least one embodiment, a computer vision network on-chip may include an interface that determines, before transmission of any control signal/address/data, that both a PVA and a DLA provide ready and valid signals. In at least one embodiment, an interface may provide for separate phases and separate channels for transmitting control signals/addresses/data, as well as burst-type communications for continuous data transfer. In at least one embodiment, an interface may comply with International Organization for Standardization (“ISO”) 26262 or International Electrotechnical Commission (“IEC”) 61508 standards, although other standards and protocols may be used.

In at least one embodiment, one or more of SoC(s) 3204 may include a real-time ray-tracing hardware accelerator. In at least one embodiment, real-time ray-tracing hardware accelerator may be used to quickly and efficiently determine positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses.

In at least one embodiment, accelerator(s) 3214 can have a wide array of uses for autonomous driving. In at least one embodiment, a PVA may be used for key processing stages in ADAS and autonomous vehicles. In at least one embodiment, a PVA's capabilities are a good match for algorithmic domains needing predictable processing, at low power and low latency. In other words, a PVA performs well on semi-dense or dense regular computation, even on small data sets, which might require predictable run-times with low latency and low power. In at least one embodiment, such as in vehicle 3200, PVAs might be designed to run classic computer vision algorithms, as they can be efficient at object detection and operating on integer math.

For example, according to at least one embodiment of technology, a PVA is used to perform computer stereo vision. In at least one embodiment, a semi-global matching-based algorithm may be used in some examples, although this is not intended to be limiting. In at least one embodiment, applications for Level 3-5 autonomous driving use motion estimation/stereo matching on-the-fly (e.g., structure from motion, pedestrian recognition, lane detection, etc.). In at least one embodiment, a PVA may perform computer stereo vision functions on inputs from two monocular cameras.

In at least one embodiment, a PVA may be used to perform dense optical flow. For example, in at least one embodiment, a PVA could process raw RADAR data (e.g., using a 4D Fast Fourier Transform) to provide processed RADAR data. In at least one embodiment, a PVA is used for time of flight depth processing, by processing raw time of flight data to provide processed time of flight data, for example.

In at least one embodiment, a DLA may be used to run any type of network to enhance control and driving safety, including for example and without limitation, a neural network that outputs a measure of confidence for each object detection. In at least one embodiment, confidence may be represented or interpreted as a probability, or as providing a relative “weight” of each detection compared to other detections. In at least one embodiment, a confidence measure enables a system to make further decisions regarding which detections should be considered as true positive detections rather than false positive detections. In at least one embodiment, a system may set a threshold value for confidence and consider only detections exceeding threshold value as true positive detections. In an embodiment in which an automatic emergency braking (“AEB”) system is used, false positive detections would cause vehicle to automatically perform emergency braking, which is obviously undesirable. In at least one embodiment, highly confident detections may be considered as triggers for AEB In at least one embodiment, a DLA may run a neural network for regressing confidence value. In at least one embodiment, neural network may take as its input at least some subset of parameters, such as bounding box dimensions, ground plane estimate obtained (e.g., from another subsystem), output from IMU sensor(s) 3266 that correlates with vehicle 3200 orientation, distance, 3D location estimates of object obtained from neural network and/or other sensors (e.g., LIDAR sensor(s) 3264 or RADAR sensor(s) 3260), among others.

In at least one embodiment, one or more of SoC(s) 3204 may include data store(s) 3216 (e.g., memory). In at least one embodiment, data store(s) 3216 may be on-chip memory of SoC(s) 3204, which may store neural networks to be executed on GPU(s) 3208 and/or a DLA. In at least one embodiment, data store(s) 3216 may be large enough in capacity to store multiple instances of neural networks for redundancy and safety. In at least one embodiment, data store(s) 3216 may comprise L2 or L3 cache(s).

In at least one embodiment, one or more of SoC(s) 3204 may include any number of processor(s) 3210 (e.g., embedded processors). In at least one embodiment, processor(s) 3210 may include a boot and power management processor that may be a dedicated processor and subsystem to handle boot power and management functions and related security enforcement. In at least one embodiment, a boot and power management processor may be a part of a boot sequence of SoC(s) 3204 and may provide runtime power management services. In at least one embodiment, a boot power and management processor may provide clock and voltage programming, assistance in system low power state transitions, management of SoC(s) 3204 thermals and temperature sensors, and/or management of SoC(s) 3204 power states. In at least one embodiment, each temperature sensor may be implemented as a ring-oscillator whose output frequency is proportional to temperature, and SoC(s) 3204 may use ring-oscillators to detect temperatures of CPU(s) 3206, GPU(s) 3208, and/or accelerator(s) 3214. In at least one embodiment, if temperatures are determined to exceed a threshold, then a boot and power management processor may enter a temperature fault routine and put SoC(s) 3204 into a lower power state and/or put vehicle 3200 into a chauffeur to safe stop mode (e.g., bring vehicle 3200 to a safe stop).

In at least one embodiment, processor(s) 3210 may further include a set of embedded processors that may serve as an audio processing engine which may be an audio subsystem that enables full hardware support for multi-channel audio over multiple interfaces, and a broad and flexible range of audio I/O interfaces. In at least one embodiment, an audio processing engine is a dedicated processor core with a digital signal processor with dedicated RAM.

In at least one embodiment, processor(s) 3210 may further include an always-on processor engine that may provide necessary hardware features to support low power sensor management and wake use cases. In at least one embodiment, an always-on processor engine may include, without limitation, a processor core, a tightly coupled RAM, supporting peripherals (e.g., timers and interrupt controllers), various I/O controller peripherals, and routing logic.

In at least one embodiment, processor(s) 3210 may further include a safety cluster engine that includes, without limitation, a dedicated processor subsystem to handle safety management for automotive applications. In at least one embodiment, a safety cluster engine may include, without limitation, two or more processor cores, a tightly coupled RAM, support peripherals (e.g., timers, an interrupt controller, etc.), and/or routing logic. In a safety mode, two or more cores may operate, in at least one embodiment, in a lockstep mode and function as a single core with comparison logic to detect any differences between their operations. In at least one embodiment, processor(s) 3210 may further include a real-time camera engine that may include, without limitation, a dedicated processor subsystem for handling real-time camera management. In at least one embodiment, processor(s) 3210 may further include a high-dynamic range signal processor that may include, without limitation, an image signal processor that is a hardware engine that is part of a camera processing pipeline.

In at least one embodiment, processor(s) 3210 may include a video image compositor that may be a processing block (e.g., implemented on a microprocessor) that implements video post-processing functions needed by a video playback application to produce a final image for a player window. In at least one embodiment, a video image compositor may perform lens distortion correction on wide-view camera(s) 3270, surround camera(s) 3274, and/or on in-cabin monitoring camera sensor(s). In at least one embodiment, in-cabin monitoring camera sensor(s) are preferably monitored by a neural network running on another instance of SoC 3204, configured to identify in cabin events and respond accordingly. In at least one embodiment, an in-cabin system may perform, without limitation, lip reading to activate cellular service and place a phone call, dictate emails, change a vehicle's destination, activate or change a vehicle's infotainment system and settings, or provide voice-activated web surfing. In at least one embodiment, certain functions are available to a driver when a vehicle is operating in an autonomous mode and are disabled otherwise.

In at least one embodiment, a video image compositor may include enhanced temporal noise reduction for both spatial and temporal noise reduction. For example, in at least one embodiment, where motion occurs in a video, noise reduction weights spatial information appropriately, decreasing weights of information provided by adjacent frames. In at least one embodiment, where an image or portion of an image does not include motion, temporal noise reduction performed by video image compositor may use information from a previous image to reduce noise in a current image.

In at least one embodiment, a video image compositor may also be configured to perform stereo rectification on input stereo lens frames. In at least one embodiment, a video image compositor may further be used for user interface composition when an operating system desktop is in use, and GPU(s) 3208 are not required to continuously render new surfaces. In at least one embodiment, when GPU(s) 3208 are powered on and active doing 3D rendering, a video image compositor may be used to offload GPU(s) 3208 to improve performance and responsiveness.

In at least one embodiment, one or more SoC of SoC(s) 3204 may further include a mobile industry processor interface (“MIPI”) camera serial interface for receiving video and input from cameras, a high-speed interface, and/or a video input block that may be used for a camera and related pixel input functions. In at least one embodiment, one or more of SoC(s) 3204 may further include an input/output controller(s) that may be controlled by software and may be used for receiving I/O signals that are uncommitted to a specific role.

In at least one embodiment, one or more Soc of SoC(s) 3204 may further include a broad range of peripheral interfaces to enable communication with peripherals, audio encoders/decoders (“codecs”), power management, and/or other devices. In at least one embodiment, SoC(s) 3204 may be used to process data from cameras (e.g., connected over Gigabit Multimedia Serial Link and Ethernet channels), sensors (e.g., LIDAR sensor(s) 3264, RADAR sensor(s) 3260, etc. that may be connected over Ethernet channels), data from bus 3202 (e.g., speed of vehicle 3200, steering wheel position, etc.), data from GNSS sensor(s) 3258 (e.g., connected over a Ethernet bus or a CAN bus), etc. In at least one embodiment, one or more SoC of SoC(s) 3204 may further include dedicated high-performance mass storage controllers that may include their own DMA engines, and that may be used to free CPU(s) 3206 from routine data management tasks.

In at least one embodiment, SoC(s) 3204 may be an end-to-end platform with a flexible architecture that spans automation Levels 3-5, thereby providing a comprehensive functional safety architecture that leverages and makes efficient use of computer vision and ADAS techniques for diversity and redundancy, and provides a platform for a flexible, reliable driving software stack, along with deep learning tools. In at least one embodiment, SoC(s) 3204 may be faster, more reliable, and even more energy-efficient and space-efficient than conventional systems. For example, in at least one embodiment, accelerator(s) 3214, when combined with CPU(s) 3206, GPU(s) 3208, and data store(s) 3216, may provide for a fast, efficient platform for Level 3-5 autonomous vehicles.

In at least one embodiment, computer vision algorithms may be executed on CPUs, which may be configured using a high-level programming language, such as C, to execute a wide variety of processing algorithms across a wide variety of visual data. However, in at least one embodiment, CPUs are oftentimes unable to meet performance requirements of many computer vision applications, such as those related to execution time and power consumption, for example. In at least one embodiment, many CPUs are unable to execute complex object detection algorithms in real-time, which is used in in-vehicle ADAS applications and in practical Level 3-5 autonomous vehicles.

Embodiments described herein allow for multiple neural networks to be performed simultaneously and/or sequentially, and for results to be combined together to enable Level 3-5 autonomous driving functionality. For example, in at least one embodiment, a CNN executing on a DLA or a discrete GPU (e.g., GPU(s) 3220) may include text and word recognition, allowing reading and understanding of traffic signs, including signs for which a neural network has not been specifically trained. In at least one embodiment, a DLA may further include a neural network that is able to identify, interpret, and provide semantic understanding of a sign, and to pass that semantic understanding to path planning modules running on a CPU Complex.

In at least one embodiment, multiple neural networks may be run simultaneously, as for Level 3, 4, or 5 driving. For example, in at least one embodiment, a warning sign stating “Caution: flashing lights indicate icy conditions,” along with an electric light, may be independently or collectively interpreted by several neural networks. In at least one embodiment, such warning sign itself may be identified as a traffic sign by a first deployed neural network (e.g., a neural network that has been trained), text “flashing lights indicate icy conditions” may be interpreted by a second deployed neural network, which informs a vehicle's path planning software (preferably executing on a CPU Complex) that when flashing lights are detected, icy conditions exist. In at least one embodiment, a flashing light may be identified by operating a third deployed neural network over multiple frames, informing a vehicle's path-planning software of a presence (or an absence) of flashing lights. In at least one embodiment, all three neural networks may run simultaneously, such as within a DLA and/or on GPU(s) 3208.

In at least one embodiment, a CNN for facial recognition and vehicle owner identification may use data from camera sensors to identify presence of an authorized driver and/or owner of vehicle 3200. In at least one embodiment, an always-on sensor processing engine may be used to unlock a vehicle when an owner approaches a driver door and turns on lights, and, in a security mode, to disable such vehicle when an owner leaves such vehicle. In this way, SoC(s) 3204 provide for security against theft and/or carjacking.

In at least one embodiment, a CNN for emergency vehicle detection and identification may use data from microphones 3296 to detect and identify emergency vehicle sirens. In at least one embodiment, SoC(s) 3204 use a CNN for classifying environmental and urban sounds, as well as classifying visual data. In at least one embodiment, a CNN running on a DLA is trained to identify a relative closing speed of an emergency vehicle (e.g., by using a Doppler effect). In at least one embodiment, a CNN may also be trained to identify emergency vehicles specific to a local area in which a vehicle is operating, as identified by GNSS sensor(s) 3258. In at least one embodiment, when operating in Europe, a CNN will seek to detect European sirens, and when in North America, a CNN will seek to identify only North American sirens. In at least one embodiment, once an emergency vehicle is detected, a control program may be used to execute an emergency vehicle safety routine, slowing a vehicle, pulling over to a side of a road, parking a vehicle, and/or idling a vehicle, with assistance of ultrasonic sensor(s) 3262, until emergency vehicles pass.

In at least one embodiment, vehicle 3200 may include CPU(s) 3218 (e.g., discrete CPU(s), or dCPU(s)), that may be coupled to SoC(s) 3204 via a high-speed interconnect (e.g., PCIe). In at least one embodiment, CPU(s) 3218 may include an X86 processor, for example. CPU(s) 3218 may be used to perform any of a variety of functions, including arbitrating potentially inconsistent results between ADAS sensors and SoC(s) 3204, and/or monitoring status and health of controller(s) 3236 and/or an infotainment system on a chip (“infotainment SoC”) 3230, for example.

In at least one embodiment, vehicle 3200 may include GPU(s) 3220 (e.g., discrete GPU(s), or dGPU(s)), that may be coupled to SoC(s) 3204 via a high-speed interconnect (e.g., NVIDIA's NVLINK channel). In at least one embodiment, GPU(s) 3220 may provide additional artificial intelligence functionality, such as by executing redundant and/or different neural networks, and may be used to train and/or update neural networks based at least in part on input (e.g., sensor data) from sensors of a vehicle 3200.

In at least one embodiment, vehicle 3200 may further include network interface 3224 which may include, without limitation, wireless antenna(s) 3226 (e.g., one or more wireless antennas for different communication protocols, such as a cellular antenna, a Bluetooth antenna, etc.). In at least one embodiment, network interface 3224 may be used to enable wireless connectivity to Internet cloud services (e.g., with server(s) and/or other network devices), with other vehicles, and/or with computing devices (e.g., client devices of passengers). In at least one embodiment, to communicate with other vehicles, a direct link may be established between vehicle 320 and another vehicle and/or an indirect link may be established (e.g., across networks and over the Internet). In at least one embodiment, direct links may be provided using a vehicle-to-vehicle communication link. In at least one embodiment, a vehicle-to-vehicle communication link may provide vehicle 3200 information about vehicles in proximity to vehicle 3200 (e.g., vehicles in front of, on a side of, and/or behind vehicle 3200). In at least one embodiment, such aforementioned functionality may be part of a cooperative adaptive cruise control functionality of vehicle 3200.

In at least one embodiment, network interface 3224 may include an SoC that provides modulation and demodulation functionality and enables controller(s) 3236 to communicate over wireless networks. In at least one embodiment, network interface 3224 may include a radio frequency front-end for up-conversion from baseband to radio frequency, and down conversion from radio frequency to baseband. In at least one embodiment, frequency conversions may be performed in any technically feasible fashion. For example, frequency conversions could be performed through well-known processes, and/or using super-heterodyne processes. In at least one embodiment, radio frequency front end functionality may be provided by a separate chip. In at least one embodiment, network interfaces may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

In at least one embodiment, vehicle 3200 may further include data store(s) 3228 which may include, without limitation, off-chip (e.g., off SoC(s) 3204) storage. In at least one embodiment, data store(s) 3228 may include, without limitation, one or more storage elements including RAM, SRAM, dynamic random-access memory (“DRAM”), video random-access memory (“VRAM”), flash memory, hard disks, and/or other components and/or devices that may store at least one bit of data.

In at least one embodiment, vehicle 3200 may further include GNSS sensor(s) 3258 (e.g., GPS and/or assisted GPS sensors), to assist in mapping, perception, occupancy grid generation, and/or path planning functions. In at least one embodiment, any number of GNSS sensor(s) 3258 may be used, including, for example and without limitation, a GPS using a USB connector with an Ethernet-to-Serial (e.g., RS-232) bridge.

In at least one embodiment, vehicle 3200 may further include RADAR sensor(s) 3260. In at least one embodiment, RADAR sensor(s) 3260 may be used by vehicle 3200 for long-range vehicle detection, even in darkness and/or severe weather conditions. In at least one embodiment, RADAR functional safety levels may be ASIL B. In at least one embodiment, RADAR sensor(s) 3260 may use a CAN bus and/or bus 3202 (e.g., to transmit data generated by RADAR sensor(s) 3260) for control and to access object tracking data, with access to Ethernet channels to access raw data in some examples. In at least one embodiment, a wide variety of RADAR sensor types may be used. For example, and without limitation, RADAR sensor(s) 3260 may be suitable for front, rear, and side RADAR use. In at least one embodiment, one or more sensor of RADAR sensors(s) 3260 is a Pulse Doppler RADAR sensor.

In at least one embodiment, RADAR sensor(s) 3260 may include different configurations, such as long-range with narrow field of view, short-range with wide field of view, short-range side coverage, etc. In at least one embodiment, long-range RADAR may be used for adaptive cruise control functionality. In at least one embodiment, long-range RADAR systems may provide a broad field of view realized by two or more independent scans, such as within a 250 m (meter) range. In at least one embodiment, RADAR sensor(s) 3260 may help in distinguishing between static and moving objects, and may be used by ADAS system 3238 for emergency brake assist and forward collision warning. In at least one embodiment, sensors 3260(s) included in a long-range RADAR system may include, without limitation, monostatic multimodal RADAR with multiple (e.g., six or more) fixed RADAR antennae and a high-speed CAN and FlexRay interface. In at least one embodiment, with six antennae, a central four antennae may create a focused beam pattern, designed to record vehicle's 3200 surroundings at higher speeds with minimal interference from traffic in adjacent lanes. In at least one embodiment, another two antennae may expand field of view, making it possible to quickly detect vehicles entering or leaving a lane of vehicle 3200.

In at least one embodiment, mid-range RADAR systems may include, as an example, a range of up to 160 m (front) or 80 m (rear), and a field of view of up to 42 degrees (front) or 150 degrees (rear). In at least one embodiment, short-range RADAR systems may include, without limitation, any number of RADAR sensor(s) 3260 designed to be installed at both ends of a rear bumper. When installed at both ends of a rear bumper, in at least one embodiment, a RADAR sensor system may create two beams that constantly monitor blind spots in a rear direction and next to a vehicle. In at least one embodiment, short-range RADAR systems may be used in ADAS system 3238 for blind spot detection and/or lane change assist.

In at least one embodiment, vehicle 3200 may further include ultrasonic sensor(s) 3262. In at least one embodiment, ultrasonic sensor(s) 3262, which may be positioned at a front, a back, and/or side location of vehicle 3200, may be used for parking assist and/or to create and update an occupancy grid. In at least one embodiment, a wide variety of ultrasonic sensor(s) 3262 may be used, and different ultrasonic sensor(s) 3262 may be used for different ranges of detection (e.g., 2.5 m, 4 m). In at least one embodiment, ultrasonic sensor(s) 3262 may operate at functional safety levels of ASIL B.

In at least one embodiment, vehicle 3200 may include LIDAR sensor(s) 3264. In at least one embodiment, LIDAR sensor(s) 3264 may be used for object and pedestrian detection, emergency braking, collision avoidance, and/or other functions. In at least one embodiment, LIDAR sensor(s) 3264 may operate at functional safety level ASIL B. In at least one embodiment, vehicle 3200 may include multiple LIDAR sensors 3264 (e.g., two, four, six, etc.) that may use an Ethernet channel (e.g., to provide data to a Gigabit Ethernet switch).

In at least one embodiment, LIDAR sensor(s) 3264 may be capable of providing a list of objects and their distances for a 360-degree field of view. In at least one embodiment, commercially available LIDAR sensor(s) 3264 may have an advertised range of approximately 100 m, with an accuracy of 2 cm to 3 cm, and with support for a 100 Mbps Ethernet connection, for example. In at least one embodiment, one or more non-protruding LIDAR sensors may be used. In such an embodiment, LIDAR sensor(s) 3264 may include a small device that may be embedded into a front, a rear, a side, and/or a corner location of vehicle 3200. In at least one embodiment, LIDAR sensor(s) 3264, in such an embodiment, may provide up to a 120-degree horizontal and 35-degree vertical field-of-view, with a 200 m range even for low-reflectivity objects. In at least one embodiment, front-mounted LIDAR sensor(s) 3264 may be configured for a horizontal field of view between 45 degrees and 135 degrees.

In at least one embodiment, LIDAR technologies, such as 3D flash LIDAR, may also be used. In at least one embodiment, 3D flash LIDAR uses a flash of a laser as a transmission source, to illuminate surroundings of vehicle 3200 up to approximately 200 m. In at least one embodiment, a flash LIDAR unit includes, without limitation, a receptor, which records laser pulse transit time and reflected light on each pixel, which in turn corresponds to a range from vehicle 3200 to objects. In at least one embodiment, flash LIDAR may allow for highly accurate and distortion-free images of surroundings to be generated with every laser flash. In at least one embodiment, four flash LIDAR sensors may be deployed, one at each side of vehicle 3200. In at least one embodiment, 3D flash LIDAR systems include, without limitation, a solid-state 3D staring array LIDAR camera with no moving parts other than a fan (e.g., a non-scanning LIDAR device). In at least one embodiment, flash LIDAR device may use a 5 nanosecond class I (eye-safe) laser pulse per frame and may capture reflected laser light as a 3D range point cloud and co-registered intensity data.

In at least one embodiment, vehicle 3200 may further include IMU sensor(s) 3266. In at least one embodiment, IMU sensor(s) 3266 may be located at a center of a rear axle of vehicle 3200. In at least one embodiment, IMU sensor(s) 3266 may include, for example and without limitation, accelerometer(s), magnetometer(s), gyroscope(s), a magnetic compass, magnetic compasses, and/or other sensor types. In at least one embodiment, such as in six-axis applications, IMU sensor(s) 3266 may include, without limitation, accelerometers and gyroscopes. In at least one embodiment, such as in nine-axis applications, IMU sensor(s) 3266 may include, without limitation, accelerometers, gyroscopes, and magnetometers.

In at least one embodiment, IMU sensor(s) 3266 may be implemented as a miniature, high performance GPS-Aided Inertial Navigation System (“GPS/INS”) that combines micro-electro-mechanical systems (“MEMS”) inertial sensors, a high-sensitivity GPS receiver, and advanced Kalman filtering algorithms to provide estimates of position, velocity, and attitude. In at least one embodiment, IMU sensor(s) 3266 may enable vehicle 3200 to estimate its heading without requiring input from a magnetic sensor by directly observing and correlating changes in velocity from a GPS to IMU sensor(s) 3266. In at least one embodiment, IMU sensor(s) 3266 and GNSS sensor(s) 3258 may be combined in a single integrated unit.

In at least one embodiment, vehicle 3200 may include microphone(s) 3296 placed in and/or around vehicle 3200. In at least one embodiment, microphone(s) 3296 may be used for emergency vehicle detection and identification, among other things.

In at least one embodiment, vehicle 3200 may further include any number of camera types, including stereo camera(s) 3268, wide-view camera(s) 3270, infrared camera(s) 3272, surround camera(s) 3274, long-range camera(s) 3298, mid-range camera(s) 3276, and/or other camera types. In at least one embodiment, cameras may be used to capture image data around an entire periphery of vehicle 3200. In at least one embodiment, which types of cameras used depends on vehicle 3200. In at least one embodiment, any combination of camera types may be used to provide necessary coverage around vehicle 3200. In at least one embodiment, a number of cameras deployed may differ depending on embodiment. For example, in at least one embodiment, vehicle 3200 could include six cameras, seven cameras, ten cameras, twelve cameras, or another number of cameras. In at least one embodiment, cameras may support, as an example and without limitation, Gigabit Multimedia Serial Link (“GMSL”) and/or Gigabit Ethernet communications. In at least one embodiment, each camera might be as described with more detail previously herein with respect to FIG. 32A and FIG. 32B.

In at least one embodiment, vehicle 3200 may further include vibration sensor(s) 3242. In at least one embodiment, vibration sensor(s) 3242 may measure vibrations of components of vehicle 3200, such as axle(s). For example, in at least one embodiment, changes in vibrations may indicate a change in road surfaces. In at least one embodiment, when two or more vibration sensors 3242 are used, differences between vibrations may be used to determine friction or slippage of road surface (e.g., when a difference in vibration is between a power-driven axle and a freely rotating axle).

In at least one embodiment, vehicle 3200 may include ADAS system 3238. In at least one embodiment, ADAS system 3238 may include, without limitation, an SoC, in some examples. In at least one embodiment, ADAS system 3238 may include, without limitation, any number and combination of an autonomous/adaptive/automatic cruise control (“ACC”) system, a cooperative adaptive cruise control (“CACC”) system, a forward crash warning (“FCW”) system, an automatic emergency braking (“AEB”) system, a lane departure warning (“LDW)” system, a lane keep assist (“LKA”) system, a blind spot warning (“BSW”) system, a rear cross-traffic warning (“RCTW”) system, a collision warning (“CW”) system, a lane centering (“LC”) system, and/or other systems, features, and/or functionality.

In at least one embodiment, ACC system may use RADAR sensor(s) 3260, LIDAR sensor(s) 3264, and/or any number of camera(s). In at least one embodiment, ACC system may include a longitudinal ACC system and/or a lateral ACC system. In at least one embodiment, a longitudinal ACC system monitors and controls distance to another vehicle immediately ahead of vehicle 3200 and automatically adjusts speed of vehicle 3200 to maintain a safe distance from vehicles ahead. In at least one embodiment, a lateral ACC system performs distance keeping, and advises vehicle 3200 to change lanes when necessary. In at least one embodiment, a lateral ACC is related to other ADAS applications, such as LC and CW.

In at least one embodiment, a CACC system uses information from other vehicles that may be received via network interface 3224 and/or wireless antenna(s) 3226 from other vehicles via a wireless link, or indirectly, over a network connection (e.g., over the Internet). In at least one embodiment, direct links may be provided by a vehicle-to-vehicle (“V2V”) communication link, while indirect links may be provided by an infrastructure-to-vehicle (“I2V”) communication link. In general, V2V communication provides information about immediately preceding vehicles (e.g., vehicles immediately ahead of and in same lane as vehicle 3200), while I2V communication provides information about traffic further ahead. In at least one embodiment, a CACC system may include either or both I2V and V2V information sources. In at least one embodiment, given information of vehicles ahead of vehicle 3200, a CACC system may be more reliable and it has potential to improve traffic flow smoothness and reduce congestion on road.

In at least one embodiment, an FCW system is designed to alert a driver to a hazard, so that such driver may take corrective action. In at least one embodiment, an FCW system uses a front-facing camera and/or RADAR sensor(s) 3260, coupled to a dedicated processor, DSP, FPGA, and/or ASIC, that is electrically coupled to provide driver feedback, such as a display, speaker, and/or vibrating component. In at least one embodiment, an FCW system may provide a warning, such as in form of a sound, visual warning, vibration and/or a quick brake pulse.

In at least one embodiment, an AEB system detects an impending forward collision with another vehicle or other object, and may automatically apply brakes if a driver does not take corrective action within a specified time or distance parameter. In at least one embodiment, AEB system may use front-facing camera(s) and/or RADAR sensor(s) 3260, coupled to a dedicated processor, DSP, FPGA, and/or ASIC. In at least one embodiment, when an AEB system detects a hazard, it will typically first alert a driver to take corrective action to avoid collision and, if that driver does not take corrective action, that AEB system may automatically apply brakes in an effort to prevent, or at least mitigate, an impact of a predicted collision. In at least one embodiment, an AEB system may include techniques such as dynamic brake support and/or crash imminent braking.

In at least one embodiment, an LDW system provides visual, audible, and/or tactile warnings, such as steering wheel or seat vibrations, to alert driver when vehicle 3200 crosses lane markings. In at least one embodiment, an LDW system does not activate when a driver indicates an intentional lane departure, such as by activating a turn signal. In at least one embodiment, an LDW system may use front-side facing cameras, coupled to a dedicated processor, DSP, FPGA, and/or ASIC, that is electrically coupled to provide driver feedback, such as a display, speaker, and/or vibrating component. In at least one embodiment, an LKA system is a variation of an LDW system. In at least one embodiment, an LKA system provides steering input or braking to correct vehicle 3200 if vehicle 3200 starts to exit its lane.

In at least one embodiment, a BSW system detects and warns a driver of vehicles in an automobile's blind spot. In at least one embodiment, a BSW system may provide a visual, audible, and/or tactile alert to indicate that merging or changing lanes is unsafe. In at least one embodiment, a BSW system may provide an additional warning when a driver uses a turn signal. In at least one embodiment, a BSW system may use rear-side facing camera(s) and/or RADAR sensor(s) 3260, coupled to a dedicated processor, DSP, FPGA, and/or ASIC, that is electrically coupled to driver feedback, such as a display, speaker, and/or vibrating component.

In at least one embodiment, an RCTW system may provide visual, audible, and/or tactile notification when an object is detected outside a rear-camera range when vehicle 3200 is backing up. In at least one embodiment, an RCTW system includes an AEB system to ensure that vehicle brakes are applied to avoid a crash. In at least one embodiment, an RCTW system may use one or more rear-facing RADAR sensor(s) 3260, coupled to a dedicated processor, DSP, FPGA, and/or ASIC, that is electrically coupled to provide driver feedback, such as a display, speaker, and/or vibrating component.

In at least one embodiment, conventional ADAS systems may be prone to false positive results which may be annoying and distracting to a driver, but typically are not catastrophic, because conventional ADAS systems alert a driver and allow that driver to decide whether a safety condition truly exists and act accordingly. In at least one embodiment, vehicle 3200 itself decides, in case of conflicting results, whether to heed result from a primary computer or a secondary computer (e.g., a first controller or a second controller of controllers 3236). For example, in at least one embodiment, ADAS system 3238 may be a backup and/or secondary computer for providing perception information to a backup computer rationality module. In at least one embodiment, a backup computer rationality monitor may run redundant diverse software on hardware components to detect faults in perception and dynamic driving tasks. In at least one embodiment, outputs from ADAS system 3238 may be provided to a supervisory MCU. In at least one embodiment, if outputs from a primary computer and outputs from a secondary computer conflict, a supervisory MCU determines how to reconcile conflict to ensure safe operation.

In at least one embodiment, a primary computer may be configured to provide a supervisory MCU with a confidence score, indicating that primary computer's confidence in a chosen result. In at least one embodiment, if that confidence score exceeds a threshold, that supervisory MCU may follow that primary computer's direction, regardless of whether that secondary computer provides a conflicting or inconsistent result. In at least one embodiment, where a confidence score does not meet a threshold, and where primary and secondary computers indicate different results (e.g., a conflict), a supervisory MCU may arbitrate between computers to determine an appropriate outcome.

In at least one embodiment, a supervisory MCU may be configured to run a neural network(s) that is trained and configured to determine, based at least in part on outputs from a primary computer and outputs from a secondary computer, conditions under which that secondary computer provides false alarms. In at least one embodiment, neural network(s) in a supervisory MCU may learn when a secondary computer's output may be trusted, and when it cannot. For example, in at least one embodiment, when that secondary computer is a RADAR-based FCW system, a neural network(s) in that supervisory MCU may learn when an FCW system is identifying metallic objects that are not, in fact, hazards, such as a drainage grate or manhole cover that triggers an alarm. In at least one embodiment, when a secondary computer is a camera-based LDW system, a neural network in a supervisory MCU may learn to override LDW when bicyclists or pedestrians are present and a lane departure is, in fact, a safest maneuver. In at least one embodiment, a supervisory MCU may include at least one of a DLA or a GPU suitable for running neural network(s) with associated memory. In at least one embodiment, a supervisory MCU may comprise and/or be included as a component of SoC(s) 3204.

In at least one embodiment, ADAS system 3238 may include a secondary computer that performs ADAS functionality using traditional rules of computer vision. In at least one embodiment, that secondary computer may use classic computer vision rules (if-then), and presence of a neural network(s) in a supervisory MCU may improve reliability, safety and performance. For example, in at least one embodiment, diverse implementation and intentional non-identity makes an overall system more fault-tolerant, especially to faults caused by software (or software-hardware interface) functionality. For example, in at least one embodiment, if there is a software bug or error in software running on a primary computer, and non-identical software code running on a secondary computer provides a consistent overall result, then a supervisory MCU may have greater confidence that an overall result is correct, and a bug in software or hardware on that primary computer is not causing a material error.

In at least one embodiment, an output of ADAS system 3238 may be fed into a primary computer's perception block and/or a primary computer's dynamic driving task block. For example, in at least one embodiment, if ADAS system 3238 indicates a forward crash warning due to an object immediately ahead, a perception block may use this information when identifying objects. In at least one embodiment, a secondary computer may have its own neural network that is trained and thus reduces a risk of false positives, as described herein.

In at least one embodiment, vehicle 3200 may further include infotainment SoC 3230 (e.g., an in-vehicle infotainment system (IVI)). Although illustrated and described as an SoC, infotainment system SoC 3230, in at least one embodiment, may not be an SoC, and may include, without limitation, two or more discrete components. In at least one embodiment, infotainment SoC 3230 may include, without limitation, a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, WiFi, etc.), and/or information services (e.g., navigation systems, rear-parking assistance, a radio data system, vehicle related information such as fuel level, total distance covered, brake fuel level, oil level, door open/close, air filter information, etc.) to vehicle 3200. For example, infotainment SoC 3230 could include radios, disk players, navigation systems, video players, USB and Bluetooth connectivity, carputers, in-car entertainment, WiFi, steering wheel audio controls, hands free voice control, a heads-up display (“HUD”), HMI display 3234, a telematics device, a control panel (e.g., for controlling and/or interacting with various components, features, and/or systems), and/or other components. In at least one embodiment, infotainment SoC 3230 may further be used to provide information (e.g., visual and/or audible) to user(s) of vehicle 3200, such as information from ADAS system 3238, autonomous driving information such as planned vehicle maneuvers, trajectories, surrounding environment information (e.g., intersection information, vehicle information, road information, etc.), and/or other information.

In at least one embodiment, infotainment SoC 3230 may include any amount and type of GPU functionality. In at least one embodiment, infotainment SoC 3230 may communicate over bus 3202 with other devices, systems, and/or components of vehicle 3200. In at least one embodiment, infotainment SoC 3230 may be coupled to a supervisory MCU such that a GPU of an infotainment system may perform some self-driving functions in event that primary controller(s) 3236 (e.g., primary and/or backup computers of vehicle 3200) fail. In at least one embodiment, infotainment SoC 3230 may put vehicle 3200 into a chauffeur to safe stop mode, as described herein.

In at least one embodiment, vehicle 3200 may further include instrument cluster 3232 (e.g., a digital dash, an electronic instrument cluster, a digital instrument panel, etc.). In at least one embodiment, instrument cluster 3232 may include, without limitation, a controller and/or supercomputer (e.g., a discrete controller or supercomputer). In at least one embodiment, instrument cluster 3232 may include, without limitation, any number and combination of a set of instrumentation such as a speedometer, fuel level, oil pressure, tachometer, odometer, turn indicators, gearshift position indicator, seat belt warning light(s), parking-brake warning light(s), engine-malfunction light(s), supplemental restraint system (e.g., airbag) information, lighting controls, safety system controls, navigation information, etc. In some examples, information may be displayed and/or shared among infotainment SoC 3230 and instrument cluster 3232. In at least one embodiment, instrument cluster 3232 may be included as part of infotainment SoC 3230, or vice versa.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 32C for inferencing or predicting operations based, at least in part, on weight parameters calculated using neural network training operations, neural network functions and/or architectures, or neural network use cases described herein.

FIG. 32D is a diagram of a system 3276 for communication between cloud-based server(s) and autonomous vehicle 3200 of FIG. 32A, according to at least one embodiment. In at least one embodiment, system 3276 may include, without limitation, server(s) 3278, network(s) 3290, and any number and type of vehicles, including vehicle 3200. In at least one embodiment, server(s) 3278 may include, without limitation, a plurality of GPUs 3284(A)-3284(H) (collectively referred to herein as GPUs 3284), PCIe switches 3282(A)-3282(D) (collectively referred to herein as PCIe switches 3282), and/or CPUs 3280(A)-3280(B) (collectively referred to herein as CPUs 3280). In at least one embodiment, GPUs 3284, CPUs 3280, and PCIe switches 3282 may be interconnected with high-speed interconnects such as, for example and without limitation, NVLink interfaces 3288 developed by NVIDIA and/or PCIe connections 3286. In at least one embodiment, GPUs 3284 are connected via an NVLink and/or NVSwitch SoC and GPUs 3284 and PCIe switches 3282 are connected via PCIe interconnects. Although eight GPUs 3284, two CPUs 3280, and four PCIe switches 3282 are illustrated, this is not intended to be limiting. In at least one embodiment, each of server(s) 3278 may include, without limitation, any number of GPUs 3284, CPUs 3280, and/or PCIe switches 3282, in any combination. For example, in at least one embodiment, server(s) 3278 could each include eight, sixteen, thirty-two, and/or more GPUs 3284.

In at least one embodiment, server(s) 3278 may receive, over network(s) 3290 and from vehicles, image data representative of images showing unexpected or changed road conditions, such as recently commenced road-work. In at least one embodiment, server(s) 3278 may transmit, over network(s) 3290 and to vehicles, neural networks 3292, updated or otherwise, and/or map information 3294, including, without limitation, information regarding traffic and road conditions. In at least one embodiment, updates to map information 3294 may include, without limitation, updates for HD map 3222, such as information regarding construction sites, potholes, detours, flooding, and/or other obstructions. In at least one embodiment, neural networks 3292, and/or map information 3294 may have resulted from new training and/or experiences represented in data received from any number of vehicles in an environment, and/or based at least in part on training performed at a data center (e.g., using server(s) 3278 and/or other servers).

In at least one embodiment, server(s) 3278 may be used to train machine learning models (e.g., neural networks) based at least in part on training data. In at least one embodiment, training data may be generated by vehicles, and/or may be generated in a simulation (e.g., using a game engine). In at least one embodiment, any amount of training data is tagged (e.g., where associated neural network benefits from supervised learning) and/or undergoes other pre-processing. In at least one embodiment, any amount of training data is not tagged and/or pre-processed (e.g., where associated neural network does not require supervised learning). In at least one embodiment, once machine learning models are trained, machine learning models may be used by vehicles (e.g., transmitted to vehicles over network(s) 3290), and/or machine learning models may be used by server(s) 3278 to remotely monitor vehicles.

In at least one embodiment, server(s) 3278 may receive data from vehicles and apply data to up-to-date real-time neural networks for real-time intelligent inferencing. In at least one embodiment, server(s) 3278 may include deep-learning supercomputers and/or dedicated AI computers powered by GPU(s) 3284, such as a DGX and DGX Station machines developed by NVIDIA. However, in at least one embodiment, server(s) 3278 may include deep learning infrastructure that uses CPU-powered data centers.

In at least one embodiment, deep-learning infrastructure of server(s) 3278 may be capable of fast, real-time inferencing, and may use that capability to evaluate and verify health of processors, software, and/or associated hardware in vehicle 3200. For example, in at least one embodiment, deep-learning infrastructure may receive periodic updates from vehicle 3200, such as a sequence of images and/or objects that vehicle 3200 has located in that sequence of images (e.g., via computer vision and/or other machine learning object classification techniques). In at least one embodiment, deep-learning infrastructure may run its own neural network to identify objects and compare them with objects identified by vehicle 3200 and, if results do not match and deep-learning infrastructure concludes that AI in vehicle 3200 is malfunctioning, then server(s) 3278 may transmit a signal to vehicle 3200 instructing a fail-safe computer of vehicle 3200 to assume control, notify passengers, and complete a safe parking maneuver.

In at least one embodiment, server(s) 3278 may include GPU(s) 3284 and one or more programmable inference accelerators (e.g., NVIDIA's TensorRT 3 devices). In at least one embodiment, a combination of GPU-powered servers and inference acceleration may make real-time responsiveness possible. In at least one embodiment, such as where performance is less critical, servers powered by CPUs, FPGAs, and other processors may be used for inferencing. In at least one embodiment, hardware structure(s) 2915 are used to perform one or more embodiments. Details regarding hardware structure(x) 2915 are provided herein in conjunction with FIGS. 29A and/or 29B.

### Computer Systems

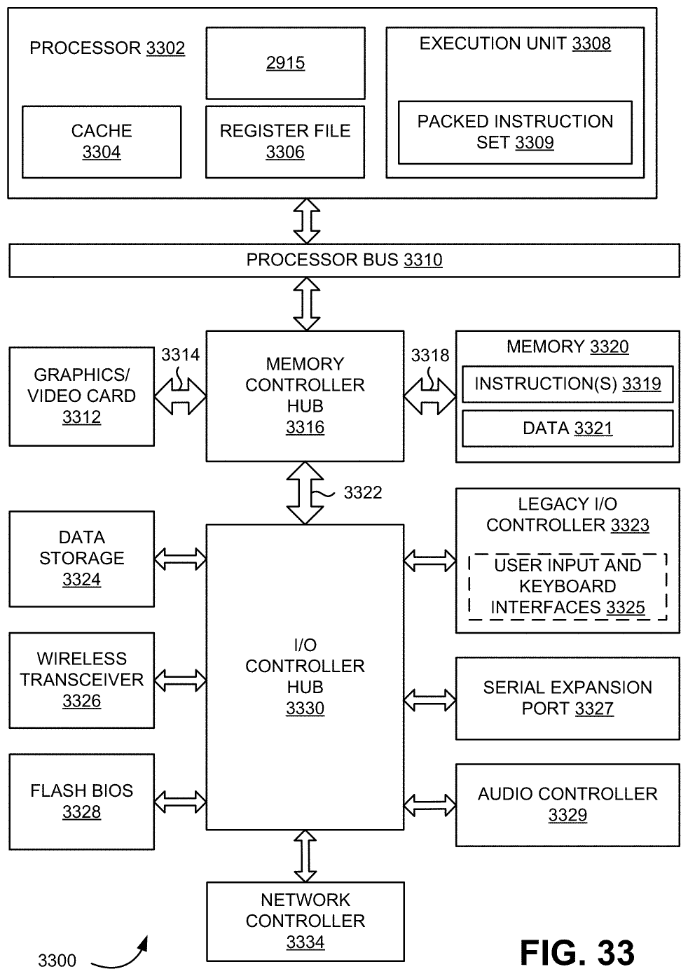

FIG. 33 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 3300 may include, without limitation, a component, such as a processor 3302 to employ execution units including logic to perform algorithms for process data, in accordance with present disclosure, such as in embodiment described herein. In at least one embodiment, computer system 3300 may include processors, such as PENTIUM® Processor family, Xeon™ Itanium®, XScale™ and/or StrongARM™, Intel® Core™, or Intel® Nervana™ microprocessors available from Intel Corporation of Santa Clara, Calif., although other systems (including PCs having other microprocessors, engineering workstations, set-top boxes and like) may also be used. In at least one embodiment, computer system 3300 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 3300 may include, without limitation, processor 3302 that may include, without limitation, one or more execution units 3308 to perform machine learning model training and/or inferencing according to techniques described herein. In at least one embodiment, computer system 3300 is a single processor desktop or server system, but in another embodiment, computer system 3300 may be a multiprocessor system. In at least one embodiment, processor 3302 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 3302 may be coupled to a processor bus 3310 that may transmit data signals between processor 3302 and other components in computer system 3300.

In at least one embodiment, processor 3302 may include, without limitation, a Level 1 (“L1”) internal cache memory (“cache”) 3304. In at least one embodiment, processor 3302 may have a single internal cache or multiple levels of internal cache. In at least one embodiment, cache memory may reside external to processor 3302. Other embodiments may also include a combination of both internal and external caches depending on particular implementation and needs. In at least one embodiment, a register file 3306 may store different types of data in various registers including, without limitation, integer registers, floating point registers, status registers, and an instruction pointer register.

In at least one embodiment, execution unit 3308, including, without limitation, logic to perform integer and floating point operations, also resides in processor 3302. In at least one embodiment, processor 3302 may also include a microcode (“ucode”) read only memory (“ROM”) that stores microcode for certain macro instructions. In at least one embodiment, execution unit 3308 may include logic to handle a packed instruction set 3309. In at least one embodiment, by including packed instruction set 3309 in an instruction set of a general-purpose processor, along with associated circuitry to execute instructions, operations used by many multimedia applications may be performed using packed data in processor 3302. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 3308 may also be used in microcontrollers, embedded processors, graphics devices, DSPs, and other types of logic circuits. In at least one embodiment, computer system 3300 may include, without limitation, a memory 3320. In at least one embodiment, memory 3320 may be a Dynamic Random Access Memory (“DRAM”) device, a Static Random Access Memory (“SRAM”) device, a flash memory device, or another memory device. In at least one embodiment, memory 3320 may store instruction(s) 3319 and/or data 3321 represented by data signals that may be executed by processor 3302.

In at least one embodiment, a system logic chip may be coupled to processor bus 3310 and memory 3320. In at least one embodiment, a system logic chip may include, without limitation, a memory controller hub (“MCH”) 3316, and processor 3302 may communicate with MCH 3316 via processor bus 3310. In at least one embodiment, MCH 3316 may provide a high bandwidth memory path 3318 to memory 3320 for instruction and data storage and for storage of graphics commands, data and textures. In at least one embodiment, MCH 3316 may direct data signals between processor 3302, memory 3320, and other components in computer system 3300 and to bridge data signals between processor bus 3310, memory 3320, and a system I/O interface 3322. In at least one embodiment, a system logic chip may provide a graphics port for coupling to a graphics controller. In at least one embodiment, MCH 3316 may be coupled to memory 3320 through high bandwidth memory path 3318 and a graphics/video card 3312 may be coupled to MCH 3316 through an Accelerated Graphics Port (“AGP”) interconnect 3314.

In at least one embodiment, computer system 3300 may use system I/O interface 3322 as a proprietary hub interface bus to couple MCH 3316 to an I/O controller hub (“ICH”) 3330. In at least one embodiment, ICH 3330 may provide direct connections to some I/O devices via a local I/O bus. In at least one embodiment, a local I/O bus may include, without limitation, a high-speed I/O bus for connecting peripherals to memory 3320, a chipset, and processor 3302. Examples may include, without limitation, an audio controller 3329, a firmware hub (“flash BIOS”) 3328, a wireless transceiver 3326, a data storage 3324, a legacy I/O controller 3323 containing user input and keyboard interfaces 3325, a serial expansion port 3327, such as a Universal Serial Bus (“USB”) port, and a network controller 3334. In at least one embodiment, data storage 3324 may comprise a hard disk drive, a floppy disk drive, a CD-ROM device, a flash memory device, or other mass storage device.

In at least one embodiment, FIG. 33 illustrates a system, which includes interconnected hardware devices or “chips”, whereas in other embodiments, FIG. 33 may illustrate an exemplary SoC. In at least one embodiment, devices illustrated in FIG. 33 may be interconnected with proprietary interconnects, standardized interconnects (e.g., PCIe) or some combination thereof. In at least one embodiment, one or more components of computer system 3300 are interconnected using compute express link (CXL) interconnects.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 33 for inferencing or predicting operations based, at least in part, on weight parameters calculated using neural network training operations, neural network functions and/or architectures, or neural network use cases described herein.

In at least one embodiment, computer system 3300 can be used to train or implement a neural network as described herein. In at least one embodiment, for example, computer system 3300 can be used to simulate a tactile sensor to generate a latent space using unsupervised learning, and generate a latent space for electrode signals generated by the tactile sensor. In at least one embodiment, computer system 3300 can be used to learn a mapping between these two latent spaces, allowing for projection between impressions on a tactile sensor and the signals produced by the sensor itself.

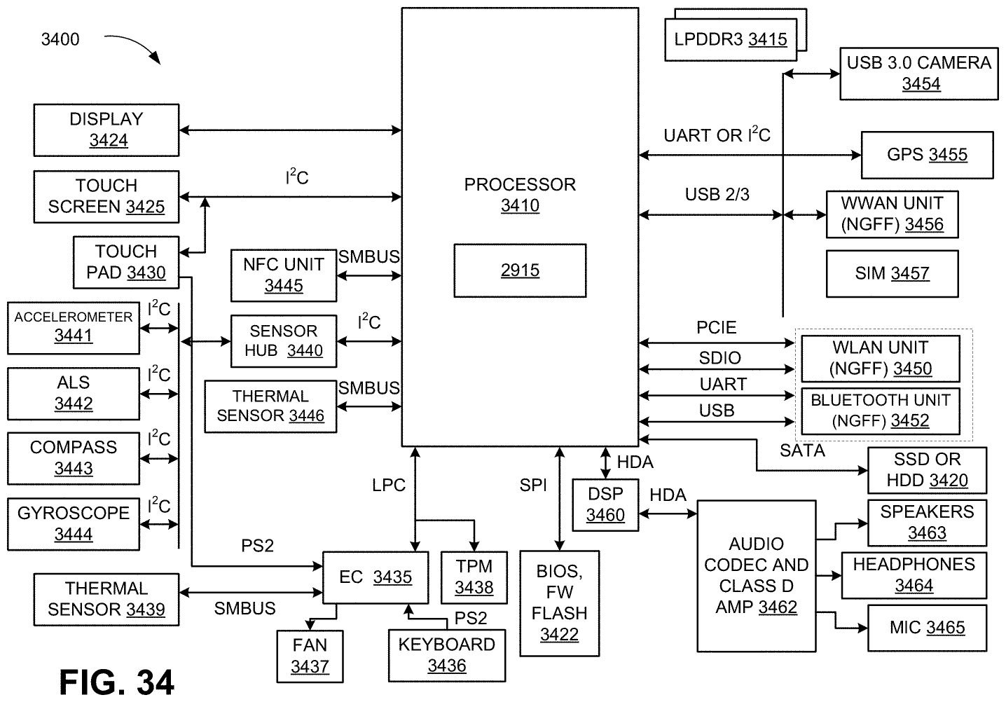

FIG. 34 is a block diagram illustrating an electronic device 3400 for utilizing a processor 3410, according to at least one embodiment. In at least one embodiment, electronic device 3400 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 3400 may include, without limitation, processor 3410 communicatively coupled to any suitable number or kind of components, peripherals, modules, or devices. In at least one embodiment, processor 3410 is coupled using a bus or interface, such as a I²C bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3, etc.), or a Universal Asynchronous Receiver/Transmitter (“UART”) bus. In at least one embodiment, FIG. 34 illustrates a system, which includes interconnected hardware devices or “chips”, whereas in other embodiments, FIG. 34 may illustrate an exemplary SoC. In at least one embodiment, devices illustrated in FIG. 34 may be interconnected with proprietary interconnects, standardized interconnects (e.g., PCIe) or some combination thereof. In at least one embodiment, one or more components of FIG. 34 are interconnected using compute express link (CXL) interconnects.

In at least one embodiment, FIG. 34 may include a display 3424, a touch screen 3425, a touch pad 3430, a Near Field Communications unit (“NFC”) 3445, a sensor hub 3440, a thermal sensor 3446, an Express Chipset (“EC”) 3435, a Trusted Platform Module (“TPM”) 3438, BIOS/firmware/flash memory (“BIOS, FW Flash”) 3422, a DSP 3460, a drive 3420 such as a Solid State Disk (“SSD”) or a Hard Disk Drive (“HDD”), a wireless local area network unit (“WLAN”) 3450, a Bluetooth unit 3452, a Wireless Wide Area Network unit (“WWAN”) 3456, a Global Positioning System (GPS) unit 3455, a camera (“USB 3.0 camera”) 3454 such as a USB 3.0 camera, and/or a Low Power Double Data Rate (“LPDDR”) memory unit (“LPDDR3”) 3415 implemented in, for example, an LPDDR3 standard. These components may each be implemented in any suitable manner.

In at least one embodiment, other components may be communicatively coupled to processor 3410 through components described herein. In at least one embodiment, an accelerometer 3441, an ambient light sensor (“ALS”) 3442, a compass 3443, and a gyroscope 3444 may be communicatively coupled to sensor hub 3440. In at least one embodiment, a thermal sensor 3439, a fan 3437, a keyboard 3436, and touch pad 3430 may be communicatively coupled to EC 3435. In at least one embodiment, speakers 3463, headphones 3464, and a microphone (“mic”) 3465 may be communicatively coupled to an audio unit (“audio codec and class D amp”) 3462, which may in turn be communicatively coupled to DSP 3460. In at least one embodiment, audio unit 3462 may include, for example and without limitation, an audio coder/decoder (“codec”) and a class D amplifier. In at least one embodiment, a SIM card (“SIM”) 3457 may be communicatively coupled to WWAN unit 3456. In at least one embodiment, components such as WLAN unit 3450 and Bluetooth unit 3452, as well as WWAN unit 3456 may be implemented in a Next Generation Form Factor (“NGFF”).

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 34 for inferencing or predicting operations based, at least in part, on weight parameters calculated using neural network training operations, neural network functions and/or architectures, or neural network use cases described herein.

In at least one embodiment, electronic device 3400 can be used to train or implement a neural network as described herein. In at least one embodiment, for example, electronic device 3400 can be used to simulate a tactile sensor to generate a latent space using unsupervised learning, and generate a latent space for electrode signals generated by the tactile sensor. In at least one embodiment, electronic device 3400 can be used to learn a mapping between these two latent spaces, allowing for projection between impressions on a tactile sensor and the signals produced by the sensor itself.

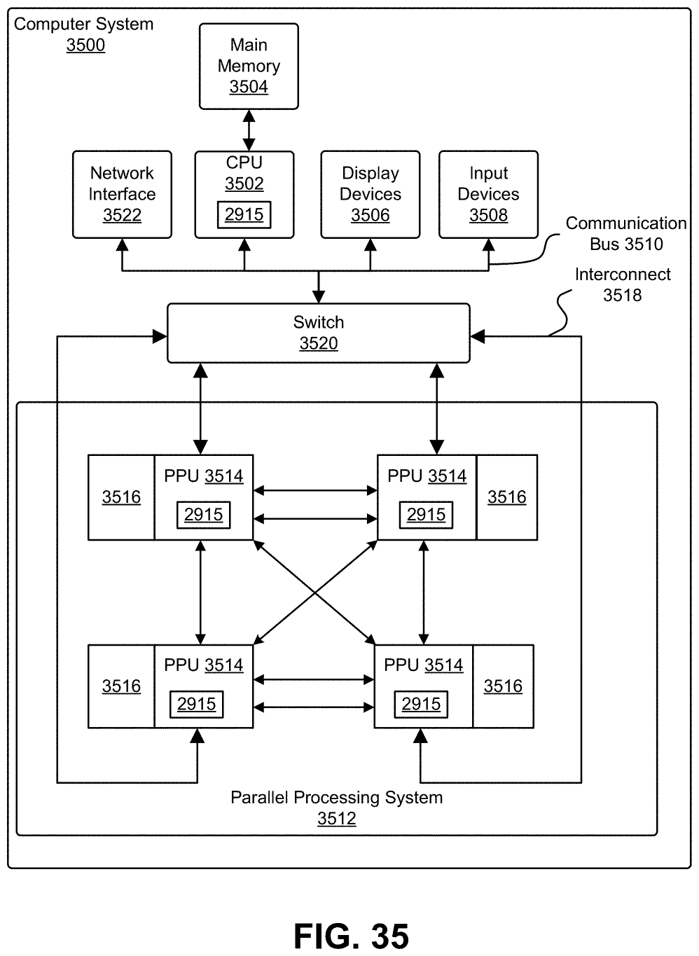

FIG. 35 illustrates a computer system 3500, according to at least one embodiment. In at least one embodiment, computer system 3500 is configured to implement various processes and methods described throughout this disclosure.

In at least one embodiment, computer system 3500 comprises, without limitation, at least one central processing unit (“CPU”) 3502 that is connected to a communication bus 3510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 3500 includes, without limitation, a main memory 3504 and control logic (e.g., implemented as hardware, software, or a combination thereof) and data are stored in main memory 3504, which may take form of random access memory (“RAM”). In at least one embodiment, a network interface subsystem (“network interface”) 3522 provides an interface to other computing devices and networks for receiving data from and transmitting data to other systems with computer system 3500.

In at least one embodiment, computer system 3500, in at least one embodiment, includes, without limitation, input devices 3508, a parallel processing system 3512, and display devices 3506 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 3508 such as keyboard, mouse, touchpad, microphone, etc. In at least one embodiment, each module described herein can be situated on a single semiconductor platform to form a processing system.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 35 for inferencing or predicting operations based, at least in part, on weight parameters calculated using neural network training operations, neural network functions and/or architectures, or neural network use cases described herein.

In at least one embodiment, computer system 3500 can be used to train or implement a neural network as described herein. In at least one embodiment, for example, computer system 3500 can be used to simulate a tactile sensor to generate a latent space using unsupervised learning, and generate a latent space for electrode signals generated by the tactile sensor. In at least one embodiment, computer system 3500 can be used to learn a mapping between these two latent spaces, allowing for projection between impressions on a tactile sensor and the signals produced by the sensor itself.

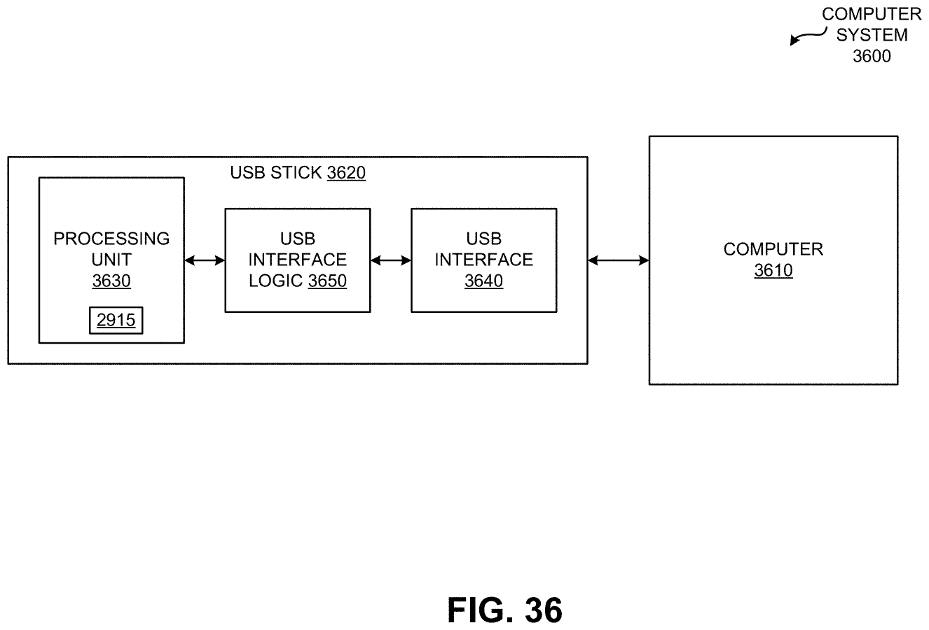

FIG. 36 illustrates a computer system 3600, according to at least one embodiment. In at least one embodiment, computer system 3600 includes, without limitation, a computer 3610 and a USB stick 3620. In at least one embodiment, computer 3610 may include, without limitation, any number and type of processor(s) (not shown) and a memory (not shown). In at least one embodiment, computer 3610 includes, without limitation, a server, a cloud instance, a laptop, and a desktop computer.

In at least one embodiment, USB stick 3620 includes, without limitation, a processing unit 3630, a USB interface 3640, and USB interface logic 3650. In at least one embodiment, processing unit 3630 may be any instruction execution system, apparatus, or device capable of executing instructions. In at least one embodiment, processing unit 3630 may include, without limitation, any number and type of processing cores (not shown). In at least one embodiment, processing unit 3630 comprises an application specific integrated circuit (“ASIC”) that is optimized to perform any amount and type of operations associated with machine learning. For instance, in at least one embodiment, processing unit 3630 is a tensor processing unit (“TPC”) that is optimized to perform machine learning inference operations. In at least one embodiment, processing unit 3630 is a vision processing unit (“VPU”) that is optimized to perform machine vision and machine learning inference operations.

In at least one embodiment, USB interface 3640 may be any type of USB connector or USB socket. For instance, in at least one embodiment, USB interface 3640 is a USB 3.0 Type-C socket for data and power. In at least one embodiment, USB interface 3640 is a USB 3.0 Type-A connector. In at least one embodiment, USB interface logic 3650 may include any amount and type of logic that enables processing unit 3630 to interface with devices (e.g., computer 3610) via USB connector 3640.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 36 for inferencing or predicting operations based, at least in part, on weight parameters calculated using neural network training operations, neural network functions and/or architectures, or neural network use cases described herein.

In at least one embodiment, computer system 3600 can be used to train or implement a neural network as described herein. In at least one embodiment, for example, computer system 3600 can be used to simulate a tactile sensor to generate a latent space using unsupervised learning, and generate a latent space for electrode signals generated by the tactile sensor. In at least one embodiment, computer system 3600 can be used to learn a mapping between these two latent spaces, allowing for projection between impressions on a tactile sensor and the signals produced by the sensor itself.

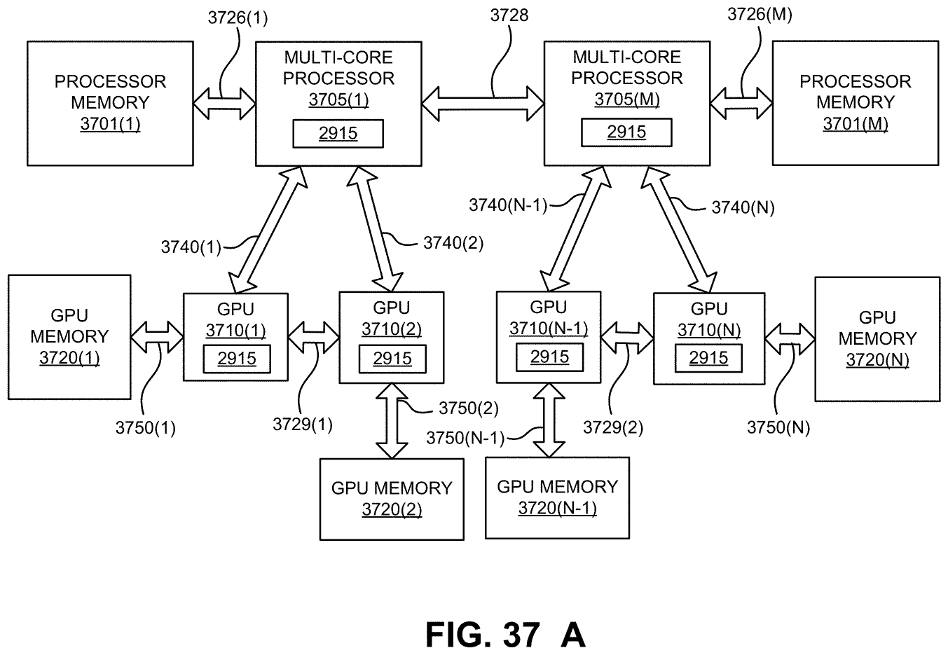

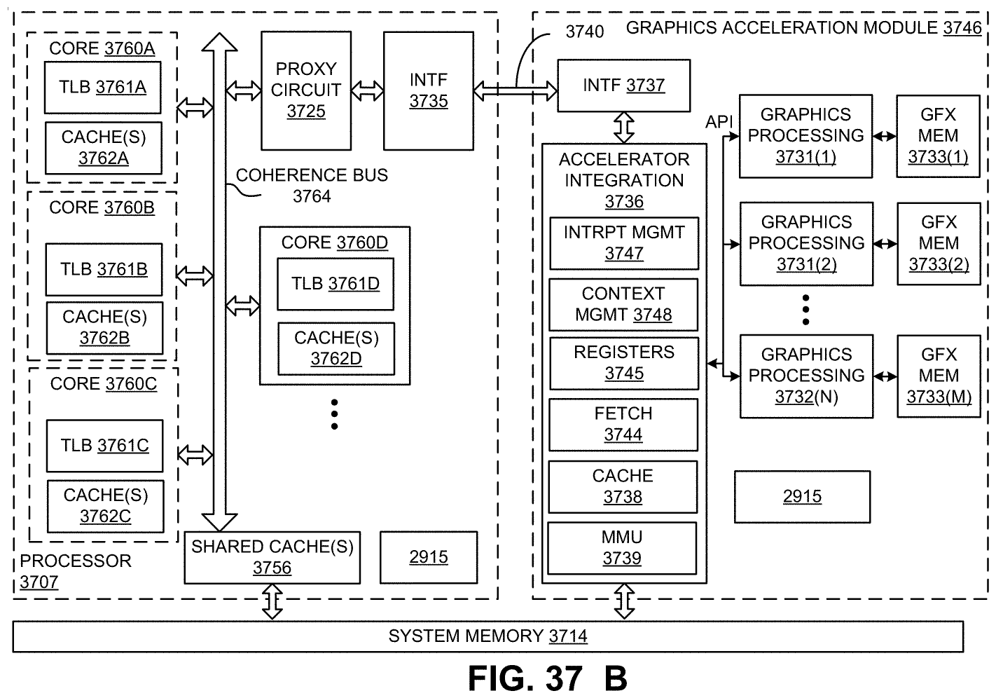

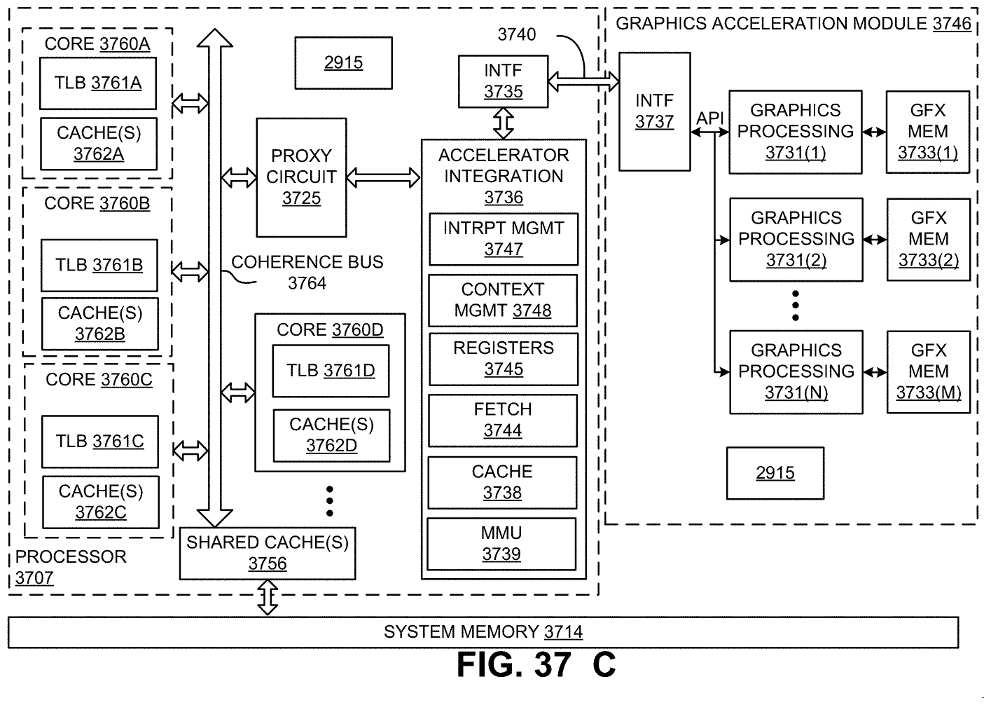

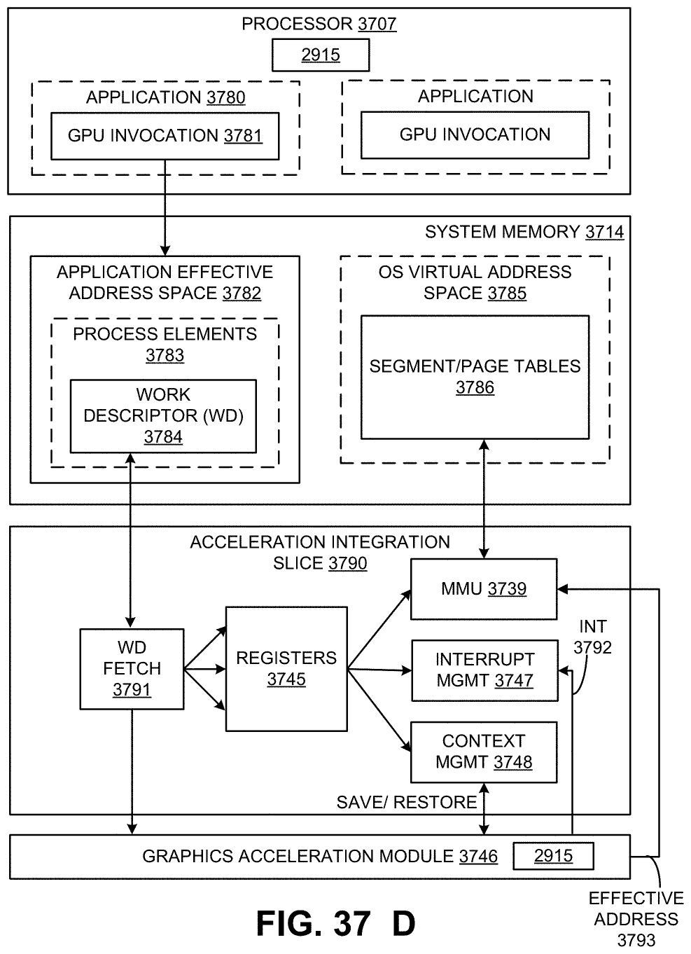

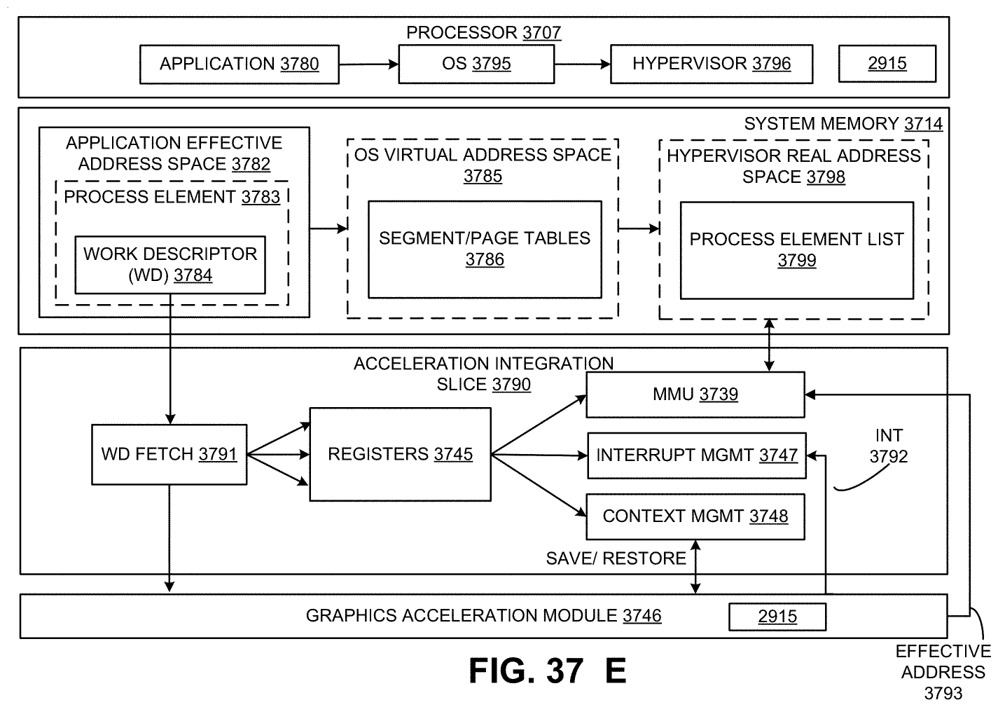

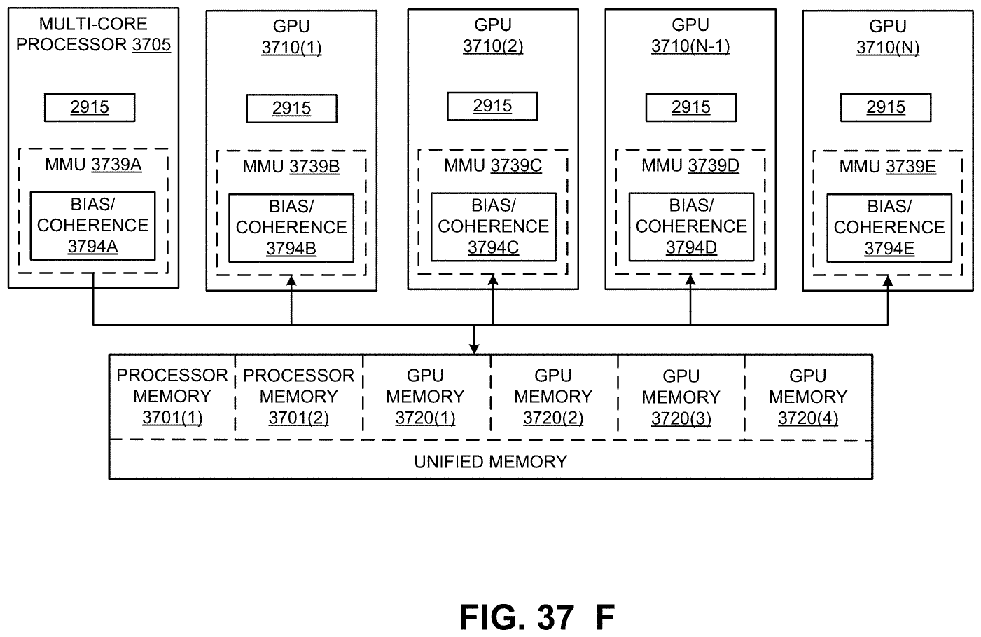

FIG. 37A illustrates an exemplary architecture in which a plurality of GPUs 3710(1)-3710(N) is communicatively coupled to a plurality of multi-core processors 3705(1)-3705(M) over high-speed links 3740(1)-3740(N) (e.g., buses, point-to-point interconnects, etc.). In at least one embodiment, high-speed links 3740(1)-3740(N) support a communication throughput of 4 GB/s, 30 GB/s, 80 GB/s or higher. In at least one embodiment, various interconnect protocols may be used including, but not limited to, PCIe 4.0 or 5.0 and NVLink 2.0. In various figures, “N” and “M” represent positive integers, values of which may be different from figure to figure.

In addition, and in at least one embodiment, two or more of GPUs 3710 are interconnected over high-speed links 3729(1)-3729(2), which may be implemented using similar or different protocols/links than those used for high-speed links 3740(1)-3740(N). Similarly, two or more of multi-core processors 3705 may be connected over a high-speed link 3728 which may be symmetric multi-processor (SMP) buses operating at 20 GB/s, 30 GB/s, 120 GB/s or higher. Alternatively, all communication between various system components shown in FIG. 37A may be accomplished using similar protocols/links (e.g., over a common interconnection fabric).

In at least one embodiment, each multi-core processor 3705 is communicatively coupled to a processor memory 3701(1)-3701(M), via memory interconnects 3726(1)-3726(M), respectively, and each GPU 3710(1)-3710(N) is communicatively coupled to GPU memory 3720(1)-3720(N) over GPU memory interconnects 3750(1)-3750(N), respectively. In at least one embodiment, memory interconnects 3726 and 3750 may utilize similar or different memory access technologies. By way of example, and not limitation, processor memories 3701(1)-3701(M) and GPU memories 3720 may be volatile memories such as dynamic random access memories (DRAMs) (including stacked DRAMs), Graphics DDR SDRAM (GDDR) (e.g., GDDR5, GDDR6), or High Bandwidth Memory (HBM) and/or may be non-volatile memories such as 3D XPoint or Nano-Ram. In at least one embodiment, some portion of processor memories 3701 may be volatile memory and another portion may be non-volatile memory (e.g., using a two-level memory (2LM) hierarchy).

As described herein, although various multi-core processors 3705 and GPUs 3710 may be physically coupled to a particular memory 3701, 3720, respectively, and/or a unified memory architecture may be implemented in which a virtual system address space (also referred to as “effective address” space) is distributed among various physical memories. For example, processor memories 3701(1)-3701(M) may each comprise 64 GB of system memory address space and GPU memories 3720(1)-3720(N) may each comprise 32 GB of system memory address space resulting in a total of 256 GB addressable memory when M=2 and N=4. Other values for N and M are possible.

FIG. 37B illustrates additional details for an interconnection between a multi-core processor 3707 and a graphics acceleration module 3746 in accordance with one exemplary embodiment. In at least one embodiment, graphics acceleration module 3746 may include one or more GPU chips integrated on a line card which is coupled to processor 3707 via high-speed link 3740 (e.g., a PCIe bus, NVLink, etc.). In at least one embodiment, graphics acceleration module 3746 may alternatively be integrated on a package or chip with processor 3707.

In at least one embodiment, processor 3707 includes a plurality of cores 3760A-3760D, each with a translation lookaside buffer (“TLB”) 3761A-3761D and one or more caches 3762A-3762D. In at least one embodiment, cores 3760A-3760D may include various other components for executing instructions and processing data that are not illustrated. In at least one embodiment, caches 3762A-3762D may comprise Level 1 (L1) and Level 2 (L2) caches. In addition, one or more shared caches 3756 may be included in caches 3762A-3762D and shared by sets of cores 3760A-3760D. For example, one embodiment of processor 3707 includes 24 cores, each with its own L1 cache, twelve shared L2 caches, and twelve shared L3 caches. In this embodiment, one or more L2 and L3 caches are shared by two adjacent cores. In at least one embodiment, processor 3707 and graphics acceleration module 3746 connect with system memory 3714, which may include processor memories 3701(1)-3701(M) of FIG. 37A.

In at least one embodiment, coherency is maintained for data and instructions stored in various caches 3762A-3762D, 3756 and system memory 3714 via inter-core communication over a coherence bus 3764. In at least one embodiment, for example, each cache may have cache coherency logic/circuitry associated therewith to communicate to over coherence bus 3764 in response to detected reads or writes to particular cache lines. In at least one embodiment, a cache snooping protocol is implemented over coherence bus 3764 to snoop cache accesses.

In at least one embodiment, a proxy circuit 3725 communicatively couples graphics acceleration module 3746 to coherence bus 3764, allowing graphics acceleration module 3746 to participate in a cache coherence protocol as a peer of cores 3760A-3760D. In particular, in at least one embodiment, an interface 3735 provides connectivity to proxy circuit 3725 over high-speed link 3740 and an interface 3737 connects graphics acceleration module 3746 to high-speed link 3740.

In at least one embodiment, an accelerator integration circuit 3736 provides cache management, memory access, context management, and interrupt management services on behalf of a plurality of graphics processing engines 3731(1)-3731(N) of graphics acceleration module 3746. In at least one embodiment, graphics processing engines 3731(1)-3731(N) may each comprise a separate graphics processing unit (GPU). In at least one embodiment, graphics processing engines 3731(1)-3731(N) alternatively may comprise different types of graphics processing engines within a GPU, such as graphics execution units, media processing engines (e.g., video encoders/decoders), samplers, and blit engines. In at least one embodiment, graphics acceleration module 3746 may be a GPU with a plurality of graphics processing engines 3731(1)-3731(N) or graphics processing engines 3731(1)-3731(N) may be individual GPUs integrated on a common package, line card, or chip.

In at least one embodiment, accelerator integration circuit 3736 includes a memory management unit (MMU) 3739 for performing various memory management functions such as virtual-to-physical memory translations (also referred to as effective-to-real memory translations) and memory access protocols for accessing system memory 3714. In at least one embodiment, MMU 3739 may also include a translation lookaside buffer (TLB) (not shown) for caching virtual/effective to physical/real address translations. In at least one embodiment, a cache 3738 can store commands and data for efficient access by graphics processing engines 3731(1)-3731(N). In at least one embodiment, data stored in cache 3738 and graphics memories 3733(1)-3733(M) is kept coherent with core caches 3762A-3762D, 3756 and system memory 3714, possibly using a fetch unit 3744. As mentioned, this may be accomplished via proxy circuit 3725 on behalf of cache 3738 and memories 3733(1)-3733(M) (e.g., sending updates to cache 3738 related to modifications/accesses of cache lines on processor caches 3762A-3762D, 3756 and receiving updates from cache 3738).

In at least one embodiment, a set of registers 3745 store context data for threads executed by graphics processing engines 3731(1)-3731(N) and a context management circuit 3748 manages thread contexts. For example, context management circuit 3748 may perform save and restore operations to save and restore contexts of various threads during contexts switches (e.g., where a first thread is saved and a second thread is stored so that a second thread can be execute by a graphics processing engine). For example, on a context switch, context management circuit 3748 may store current register values to a designated region in memory (e.g., identified by a context pointer). It may then restore register values when returning to a context. In at least one embodiment, an interrupt management circuit 3747 receives and processes interrupts received from system devices.

In at least one embodiment, virtual/effective addresses from a graphics processing engine 3731 are translated to real/physical addresses in system memory 3714 by MMU 3739. In at least one embodiment, accelerator integration circuit 3736 supports multiple (e.g., 4, 8, 16) graphics accelerator modules 3746 and/or other accelerator devices. In at least one embodiment, graphics accelerator module 3746 may be dedicated to a single application executed on processor 3707 or may be shared between multiple applications. In at least one embodiment, a virtualized graphics execution environment is presented in which resources of graphics processing engines 3731(1)-3731(N) are shared with multiple applications or virtual machines (VMs). In at least one embodiment, resources may be subdivided into “slices” which are allocated to different VMs and/or applications based on processing requirements and priorities associated with VMs and/or applications.

In at least one embodiment, accelerator integration circuit 3736 performs as a bridge to a system for graphics acceleration module 3746 and provides address translation and system memory cache services. In addition, in at least one embodiment, accelerator integration circuit 3736 may provide virtualization facilities for a host processor to manage virtualization of graphics processing engines 3731(1)-3731(N), interrupts, and memory management.

In at least one embodiment, because hardware resources of graphics processing engines 3731(1)-3731(N) are mapped explicitly to a real address space seen by host processor 3707, any host processor can address these resources directly using an effective address value. In at least one embodiment, one function of accelerator integration circuit 3736 is physical separation of graphics processing engines 3731(1)-3731(N) so that they appear to a system as independent units.

In at least one embodiment, one or more graphics memories 3733(1)-3733(M) are coupled to each of graphics processing engines 3731(1)-3731(N), respectively and N=M. In at least one embodiment, graphics memories 3733(1)-3733(M) store instructions and data being processed by each of graphics processing engines 3731(1)-3731(N). In at least one embodiment, graphics memories 3733(1)-3733(M) may be volatile memories such as DRAMs (including stacked DRAMs), GDDR memory (e.g., GDDR5, GDDR6), or HBM, and/or may be non-volatile memories such as 3D XPoint or Nano-Ram.

In at least one embodiment, to reduce data traffic over high-speed link 3740, biasing techniques can be used to ensure that data stored in graphics memories 3733(1)-3733(M) is data that will be used most frequently by graphics processing engines 3731(1)-3731(N) and preferably not used by cores 3760A-3760D (at least not frequently). Similarly, in at least one embodiment, a biasing mechanism attempts to keep data needed by cores (and preferably not graphics processing engines 3731(1)-3731(N)) within caches 3762A-3762D, 3756 and system memory 3714.

FIG. 37C illustrates another exemplary embodiment in which accelerator integration circuit 3736 is integrated within processor 3707. In this embodiment, graphics processing engines 3731(1)-3731(N) communicate directly over high-speed link 3740 to accelerator integration circuit 3736 via interface 3737 and interface 3735 (which, again, may be any form of bus or interface protocol). In at least one embodiment, accelerator integration circuit 3736 may perform similar operations as those described with respect to FIG. 37B, but potentially at a higher throughput given its close proximity to coherence bus 3764 and caches 3762A-3762D, 3756. In at least one embodiment, an accelerator integration circuit supports different programming models including a dedicated-process programming model (no graphics acceleration module virtualization) and shared programming models (with virtualization), which may include programming models which are controlled by accelerator integration circuit 3736 and programming models which are controlled by graphics acceleration module 3746.

In at least one embodiment, graphics processing engines 3731(1)-3731(N) are dedicated to a single application or process under a single operating system. In at least one embodiment, a single application can funnel other application requests to graphics processing engines 3731(1)-3731(N), providing virtualization within a VM/partition.

In at least one embodiment, graphics processing engines 3731(1)-3731(N), may be shared by multiple VM/application partitions. In at least one embodiment, shared models may use a system hypervisor to virtualize graphics processing engines 3731(1)-3731(N) to allow access by each operating system. In at least one embodiment, for single-partition systems without a hypervisor, graphics processing engines 3731(1)-3731(N) are owned by an operating system. In at least one embodiment, an operating system can virtualize graphics processing engines 3731(1)-3731(N) to provide access to each process or application.

In at least one embodiment, graphics acceleration module 3746 or an individual graphics processing engine 3731(1)-3731(N) selects a process element using a process handle. In at least one embodiment, process elements are stored in system memory 3714 and are addressable using an effective address to real address translation technique described herein. In at least one embodiment, a process handle may be an implementation-specific value provided to a host process when registering its context with graphics processing engine 3731(1)-3731(N) (that is, calling system software to add a process element to a process element linked list). In at least one embodiment, a lower 16-bits of a process handle may be an offset of a process element within a process element linked list.

FIG. 37D illustrates an exemplary accelerator integration slice 3790. In at least one embodiment, a “slice” comprises a specified portion of processing resources of accelerator integration circuit 3736. In at least one embodiment, an application is effective address space 3782 within system memory 3714 stores process elements 3783. In at least one embodiment, process elements 3783 are stored in response to GPU invocations 3781 from applications 3780 executed on processor 3707. In at least one embodiment, a process element 3783 contains process state for corresponding application 3780. In at least one embodiment, a work descriptor (WD) 3784 contained in process element 3783 can be a single job requested by an application or may contain a pointer to a queue of jobs. In at least one embodiment, WD 3784 is a pointer to a job request queue in an application's effective address space 3782.

In at least one embodiment, graphics acceleration module 3746 and/or individual graphics processing engines 3731(1)-3731(N) can be shared by all or a subset of processes in a system. In at least one embodiment, an infrastructure for setting up process states and sending a WD 3784 to a graphics acceleration module 3746 to start a job in a virtualized environment may be included.

In at least one embodiment, a dedicated-process programming model is implementation-specific. In at least one embodiment, in this model, a single process owns graphics acceleration module 3746 or an individual graphics processing engine 3731. In at least one embodiment, when graphics acceleration module 3746 is owned by a single process, a hypervisor initializes accelerator integration circuit 3736 for an owning partition and an operating system initializes accelerator integration circuit 3736 for an owning process when graphics acceleration module 3746 is assigned.

In at least one embodiment, in operation, a WD fetch unit 3791 in accelerator integration slice 3790 fetches next WD 3784, which includes an indication of work to be done by one or more graphics processing engines of graphics acceleration module 3746. In at least one embodiment, data from WD 3784 may be stored in registers 3745 and used by MMU 3739, interrupt management circuit 3747 and/or context management circuit 3748 as illustrated. For example, one embodiment of MMU 3739 includes segment/page walk circuitry for accessing segment/page tables 3786 within an OS virtual address space 3785. In at least one embodiment, interrupt management circuit 3747 may process interrupt events 3792 received from graphics acceleration module 3746. In at least one embodiment, when performing graphics operations, an effective address 3793 generated by a graphics processing engine 3731(1)-3731(N) is translated to a real address by MMU 3739.

In at least one embodiment, registers 3745 are duplicated for each graphics processing engine 3731(1)-3731(N) and/or graphics acceleration module 3746 and may be initialized by a hypervisor or an operating system. In at least one embodiment, each of these duplicated registers may be included in an accelerator integration slice 3790. Exemplary registers that may be initialized by a hypervisor are shown in Table 1.

TABLE 1
Hypervisor Initialized Registers

| Register # | Description |
|---|---|
| 1 | Slice Control Register |
| 2 | Real Address (RA) Scheduled Processes Area Pointer |
| 3 | Authority Mask Override Register |
| 4 | Interrupt Vector Table Entry Offset |
| 5 | Interrupt Vector Table Entry Limit |
| 6 | State Register |
| 7 | Logical Partition ID |
| 8 | Real address (RA) Hypervisor Accelerator Utilization |
| | Record Pointer |
| 9 | Storage Description Register |

Exemplary registers that may be initialized by an operating system are shown in Table 2.

TABLE 2
Operating System Initialized Registers

| Register # | Description |
|---|---|
| 1 | Process and Thread Identification |
| 2 | Effective Address (EA) Context Save/Restore Pointer |
| 3 | Virtual Address (VA) Accelerator Utilization |
| | Record Pointer |
| 4 | Virtual Address (VA) Storage Segment Table Pointer |
| 5 | Authority Mask |
| 6 | Work descriptor |

In at least one embodiment, each WD 3784 is specific to a particular graphics acceleration module 3746 and/or graphics processing engines 3731(1)-3731(N). In at least one embodiment, it contains all information required by a graphics processing engine 3731(1)-3731(N) to do work, or it can be a pointer to a memory location where an application has set up a command queue of work to be completed.

FIG. 37E illustrates additional details for one exemplary embodiment of a shared model. This embodiment includes a hypervisor real address space 3798 in which a process element list 3799 is stored. In at least one embodiment, hypervisor real address space 3798 is accessible via a hypervisor 3796 which virtualizes graphics acceleration module engines for operating system 3795.

In at least one embodiment, shared programming models allow for all or a subset of processes from all or a subset of partitions in a system to use a graphics acceleration module 3746. In at least one embodiment, there are two programming models where graphics acceleration module 3746 is shared by multiple processes and partitions, namely time-sliced shared and graphics directed shared.

In at least one embodiment, in this model, system hypervisor 3796 owns graphics acceleration module 3746 and makes its function available to all operating systems 3795. In at least one embodiment, for a graphics acceleration module 3746 to support virtualization by system hypervisor 3796, graphics acceleration module 3746 may adhere to certain requirements, such as (1) an application's job request must be autonomous (that is, state does not need to be maintained between jobs), or graphics acceleration module 3746 must provide a context save and restore mechanism, (2) an application's job request is guaranteed by graphics acceleration module 3746 to complete in a specified amount of time, including any translation faults, or graphics acceleration module 3746 provides an ability to preempt processing of a job, and (3) graphics acceleration module 3746 must be guaranteed fairness between processes when operating in a directed shared programming model.

In at least one embodiment, application 3780 is required to make an operating system 3795 system call with a graphics acceleration module type, a work descriptor (WD), an authority mask register (AMR) value, and a context save/restore area pointer (CSRP). In at least one embodiment, graphics acceleration module type describes a targeted acceleration function for a system call. In at least one embodiment, graphics acceleration module type may be a system-specific value. In at least one embodiment, WD is formatted specifically for graphics acceleration module 3746 and can be in a form of a graphics acceleration module 3746 command, an effective address pointer to a user-defined structure, an effective address pointer to a queue of commands, or any other data structure to describe work to be done by graphics acceleration module 3746.

In at least one embodiment, an AMR value is an AMR state to use for a current process. In at least one embodiment, a value passed to an operating system is similar to an application setting an AMR. In at least one embodiment, if accelerator integration circuit 3736 (not shown) and graphics acceleration module 3746 implementations do not support a User Authority Mask Override Register (UAMOR), an operating system may apply a current UAMOR value to an AMR value before passing an AMR in a hypervisor call. In at least one embodiment, hypervisor 3796 may optionally apply a current Authority Mask Override Register (AMOR) value before placing an AMR into process element 3783. In at least one embodiment, CSRP is one of registers 3745 containing an effective address of an area in an application's effective address space 3782 for graphics acceleration module 3746 to save and restore context state. In at least one embodiment, this pointer is optional if no state is required to be saved between jobs or when a job is preempted. In at least one embodiment, context save/restore area may be pinned system memory.

Upon receiving a system call, operating system 3795 may verify that application 3780 has registered and been given authority to use graphics acceleration module 3746. In at least one embodiment, operating system 3795 then calls hypervisor 3796 with information shown in Table 3.

TABLE 3
OS to Hypervisor Call Parameters

| Parameter # | Description |
|---|---|
| 1 | A work descriptor (WD) |
| 2 | An Authority Mask Register (AMR) value (potentially |
| | masked) |
| 3 | An effective address (EA) Context Save/Restore Area |
| | Pointer (CSRP) |
| 4 | A process ID (PID) and optional thread ID (TID) |
| 5 | A virtual address (VA) accelerator utilization record |
| | pointer (AURP) |
| 6 | Virtual address of storage segment table pointer (SSTP) |
| 7 | A logical interrupt service number (LISN) |

In at least one embodiment, upon receiving a hypervisor call, hypervisor 3796 verifies that operating system 3795 has registered and been given authority to use graphics acceleration module 3746. In at least one embodiment, hypervisor 3796 then puts process element 3783 into a process element linked list for a corresponding graphics acceleration module 3746 type. In at least one embodiment, a process element may include information shown in Table 4.

TABLE 4
Process Element Information

| Element # | Description |
|---|---|
| 1 | A work descriptor (WD) |
| 2 | An Authority Mask Register (AMR) value (potentially |
| | masked). |
| 3 | An effective address (EA) Context Save/Restore Area |
| | Pointer (CSRP) |
| 4 | A process ID (PID) and optional thread ID (TID) |
| 5 | A virtual address (VA) accelerator utilization record |
| | pointer (AURP) |
| 6 | Virtual address of storage segment table pointer (SSTP) |
| 7 | A logical interrupt service number (LISN) |
| 8 | Interrupt vector table, derived from hypervisor call |
| | parameters |
| 9 | A state register (SR) value |
| 10 | A logical partition ID (LPID) |
| 11 | A real address (RA) hypervisor accelerator utilization |
| | record pointer |
| 12 | Storage Descriptor Register (SDR) |

In at least one embodiment, hypervisor initializes a plurality of accelerator integration slice 3790 registers 3745.

As illustrated in FIG. 37F, in at least one embodiment, a unified memory is used, addressable via a common virtual memory address space used to access physical processor memories 3701(1)-3701(N) and GPU memories 3720(1)-3720(N). In this implementation, operations executed on GPUs 3710(1)-3710(N) utilize a same virtual/effective memory address space to access processor memories 3701(1)-3701(M) and vice versa, thereby simplifying programmability. In at least one embodiment, a first portion of a virtual/effective address space is allocated to processor memory 3701(1), a second portion to second processor memory 3701(N), a third portion to GPU memory 3720(1), and so on. In at least one embodiment, an entire virtual/effective memory space (sometimes referred to as an effective address space) is thereby distributed across each of processor memories 3701 and GPU memories 3720, allowing any processor or GPU to access any physical memory with a virtual address mapped to that memory.

In at least one embodiment, bias/coherence management circuitry 3794A-3794E within one or more of MMUs 3739A-3739E ensures cache coherence between caches of one or more host processors (e.g., 3705) and GPUs 3710 and implements biasing techniques indicating physical memories in which certain types of data should be stored. In at least one embodiment, while multiple instances of bias/coherence management circuitry 3794A-3794E are illustrated in FIG. 37F, bias/coherence circuitry may be implemented within an MMU of one or more host processors 3705 and/or within accelerator integration circuit 3736.

One embodiment allows GPU memories 3720 to be mapped as part of system memory, and accessed using shared virtual memory (SVM) technology, but without suffering performance drawbacks associated with full system cache coherence. In at least one embodiment, an ability for GPU memories 3720 to be accessed as system memory without onerous cache coherence overhead provides a beneficial operating environment for GPU offload. In at least one embodiment, this arrangement allows software of host processor 3705 to setup operands and access computation results, without overhead of tradition I/O DMA data copies. In at least one embodiment, such traditional copies involve driver calls, interrupts and memory mapped I/O (MMIO) accesses that are all inefficient relative to simple memory accesses. In at least one embodiment, an ability to access GPU memories 3720 without cache coherence overheads can be critical to execution time of an offloaded computation. In at least one embodiment, in cases with substantial streaming write memory traffic, for example, cache coherence overhead can significantly reduce an effective write bandwidth seen by a GPU 3710. In at least one embodiment, efficiency of operand setup, efficiency of results access, and efficiency of GPU computation may play a role in determining effectiveness of a GPU offload.

In at least one embodiment, selection of GPU bias and host processor bias is driven by a bias tracker data structure. In at least one embodiment, a bias table may be used, for example, which may be a page-granular structure (e.g., controlled at a granularity of a memory page) that includes 1 or 2 bits per GPU-attached memory page. In at least one embodiment, a bias table may be implemented in a stolen memory range of one or more GPU memories 3720, with or without a bias cache in a GPU 3710 (e.g., to cache frequently/recently used entries of a bias table). Alternatively, in at least one embodiment, an entire bias table may be maintained within a GPU.

In at least one embodiment, a bias table entry associated with each access to a GPU attached memory 3720 is accessed prior to actual access to a GPU memory, causing following operations. In at least one embodiment, local requests from a GPU 3710 that find their page in GPU bias are forwarded directly to a corresponding GPU memory 3720. In at least one embodiment, local requests from a GPU that find their page in host bias are forwarded to processor 3705 (e.g., over a high-speed link as described herein). In at least one embodiment, requests from processor 3705 that find a requested page in host processor bias complete a request like a normal memory read. Alternatively, requests directed to a GPU-biased page may be forwarded to a GPU 3710. In at least one embodiment, a GPU may then transition a page to a host processor bias if it is not currently using a page. In at least one embodiment, a bias state of a page can be changed either by a software-based mechanism, a hardware-assisted software-based mechanism, or, for a limited set of cases, a purely hardware-based mechanism.

In at least one embodiment, one mechanism for changing bias state employs an API call (e.g., OpenCL), which, in turn, calls a GPU's device driver which, in turn, sends a message (or enqueues a command descriptor) to a GPU directing it to change a bias state and, for some transitions, perform a cache flushing operation in a host. In at least one embodiment, a cache flushing operation is used for a transition from host processor 3705 bias to GPU bias, but is not for an opposite transition.

In at least one embodiment, cache coherency is maintained by temporarily rendering GPU-biased pages uncacheable by host processor 3705. In at least one embodiment, to access these pages, processor 3705 may request access from GPU 3710, which may or may not grant access right away. In at least one embodiment, thus, to reduce communication between processor 3705 and GPU 3710 it is beneficial to ensure that GPU-biased pages are those which are required by a GPU but not host processor 3705 and vice versa.

Hardware structure(s) 2915 are used to perform one or more embodiments. Details regarding a hardware structure(s) 2915 may be provided herein in conjunction with FIGS. 29A and/or 29B.

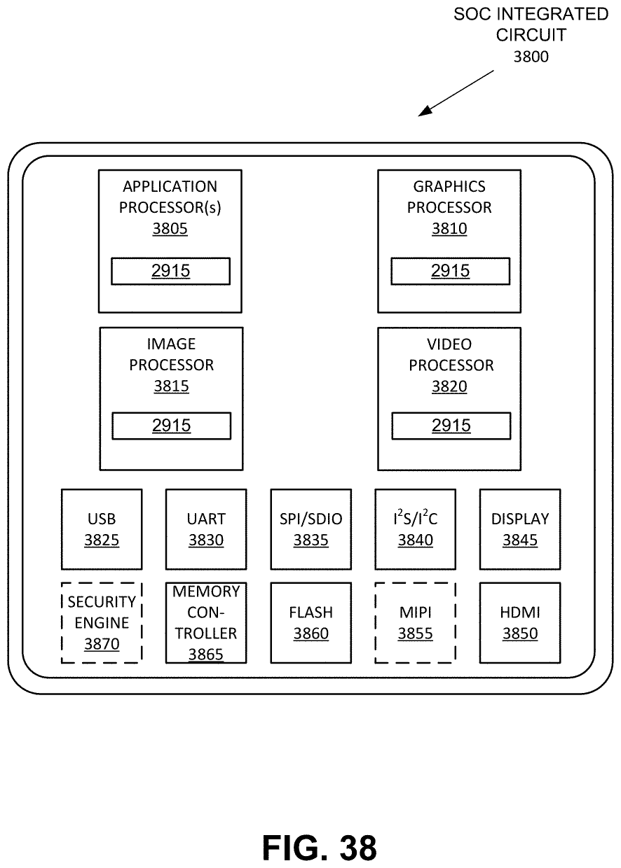

FIG. 38 illustrates exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIG. 38 is a block diagram illustrating an exemplary system on a chip integrated circuit 3800 that may be fabricated using one or more IP cores, according to at least one embodiment. In at least one embodiment, integrated circuit 3800 includes one or more application processor(s) 3805 (e.g., CPUs), at least one graphics processor 3810, and may additionally include an image processor 3815 and/or a video processor 3820, any of which may be a modular IP core. In at least one embodiment, integrated circuit 3800 includes peripheral or bus logic including a USB controller 3825, a UART controller 3830, an SPI/SDIO controller 3835, and an I²2S/I²2C controller 3840. In at least one embodiment, integrated circuit 3800 can include a display device 3845 coupled to one or more of a high-definition multimedia interface (HDMI) controller 3850 and a mobile industry processor interface (MIPI) display interface 3855. In at least one embodiment, storage may be provided by a flash memory subsystem 3860 including flash memory and a flash memory controller. In at least one embodiment, a memory interface may be provided via a memory controller 3865 for access to SDRAM or SRAM memory devices. In at least one embodiment, some integrated circuits additionally include an embedded security engine 3870.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in integrated circuit 3800 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as GPU 3710. In at least one embodiment, a computer system includes physical memory storing executable instructions that, as a result of being executed by GPU 3710, cause a computer system to implement the machine learning systems described herein. In at least one embodiment, GPU 3710 may execute instructions that cause a computer system to generate a projection between two latent spaces, for example.

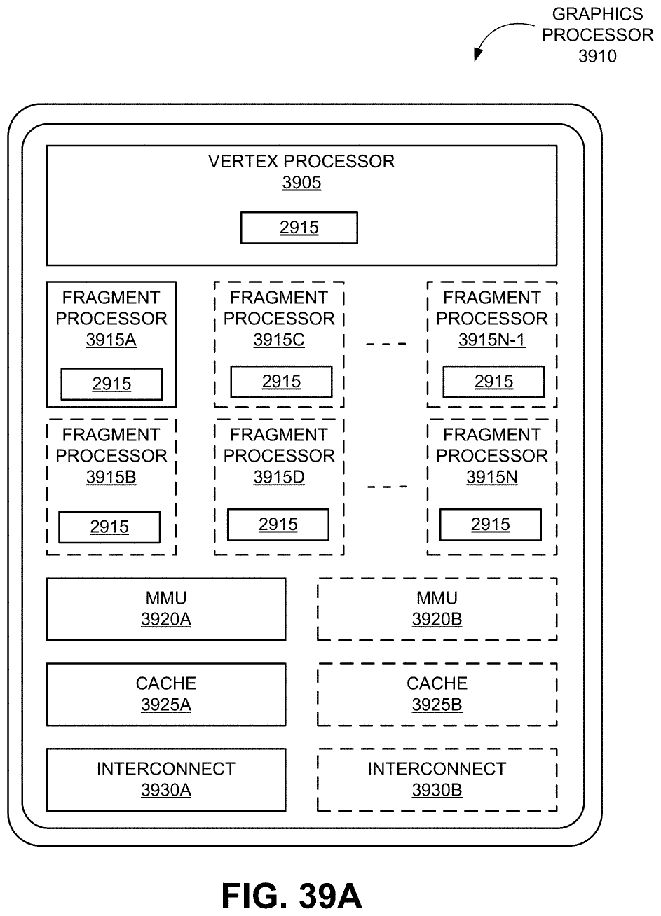

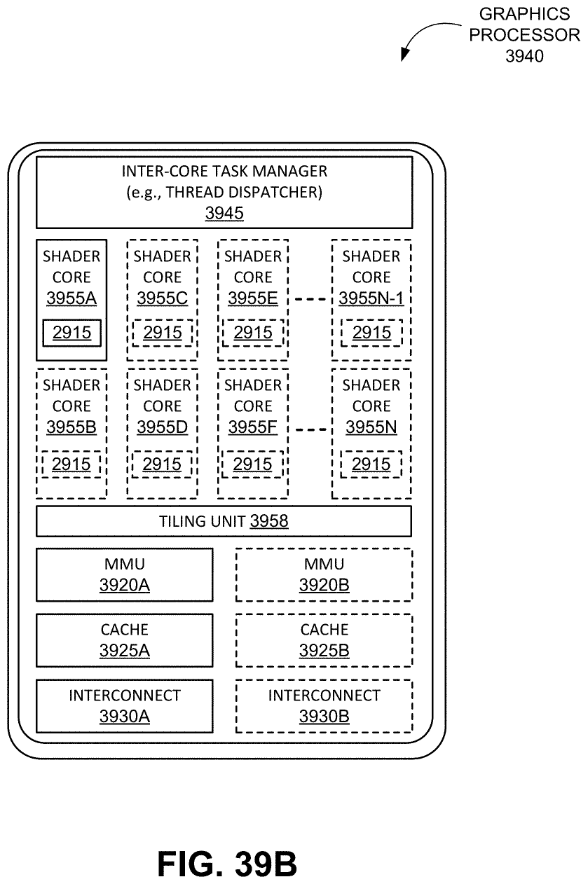

FIGS. 39A-39B illustrate exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIGS. 39A-39B are block diagrams illustrating exemplary graphics processors for use within an SoC, according to embodiments described herein. FIG. 39A illustrates an exemplary graphics processor 3910 of a system on a chip integrated circuit that may be fabricated using one or more IP cores, according to at least one embodiment. FIG. 39B illustrates an additional exemplary graphics processor 3940 of a system on a chip integrated circuit that may be fabricated using one or more IP cores, according to at least one embodiment. In at least one embodiment, graphics processor 3910 of FIG. 39A is a low power graphics processor core. In at least one embodiment, graphics processor 3940 of FIG. 39B is a higher performance graphics processor core. In at least one embodiment, each of graphics processors 3910, 3940 can be variants of graphics processor 3810 of FIG. 38.

In at least one embodiment, graphics processor 3910 includes a vertex processor 3905 and one or more fragment processor(s) 3915A-3915N (e.g., 3915A, 3915B, 3915C, 3915D, through 3915N-1, and 3915N). In at least one embodiment, graphics processor 3910 can execute different shader programs via separate logic, such that vertex processor 3905 is optimized to execute operations for vertex shader programs, while one or more fragment processor(s) 3915A-3915N execute fragment (e.g., pixel) shading operations for fragment or pixel shader programs. In at least one embodiment, vertex processor 3905 performs a vertex processing stage of a 3D graphics pipeline and generates primitives and vertex data. In at least one embodiment, fragment processor(s) 3915A-3915N use primitive and vertex data generated by vertex processor 3905 to produce a framebuffer that is displayed on a display device. In at least one embodiment, fragment processor(s) 3915A-3915N are optimized to execute fragment shader programs as provided for in an OpenGL API, which may be used to perform similar operations as a pixel shader program as provided for in a Direct 3D API.

In at least one embodiment, graphics processor 3910 additionally includes one or more memory management units (MMUs) 3920A-3920B, cache(s) 3925A-3925B, and circuit interconnect(s) 3930A-3930B. In at least one embodiment, one or more MMU(s) 3920A-3920B provide for virtual to physical address mapping for graphics processor 3910, including for vertex processor 3905 and/or fragment processor(s) 3915A-3915N, which may reference vertex or image/texture data stored in memory, in addition to vertex or image/texture data stored in one or more cache(s) 3925A-3925B. In at least one embodiment, one or more MMU(s) 3920A-3920B may be synchronized with other MMUs within a system, including one or more MMUs associated with one or more application processor(s) 3805, image processors 3815, and/or video processors 3820 of FIG. 38, such that each processor 3805-3820 can participate in a shared or unified virtual memory system. In at least one embodiment, one or more circuit interconnect(s) 3930A-3930B enable graphics processor 3910 to interface with other IP cores within SoC, either via an internal bus of SoC or via a direct connection.

In at least one embodiment, graphics processor 3940 includes one or more shader core(s) 3955A-3955N (e.g., 3955A, 3955B, 3955C, 3955D, 3955E, 3955F, through 3955N-1, and 3955N) as shown in FIG. 39B, which provides for a unified shader core architecture in which a single core or type or core can execute all types of programmable shader code, including shader program code to implement vertex shaders, fragment shaders, and/or compute shaders. In at least one embodiment, a number of shader cores can vary. In at least one embodiment, graphics processor 3940 includes an inter-core task manager 3945, which acts as a thread dispatcher to dispatch execution threads to one or more shader cores 3955A-3955N and a tiling unit 3958 to accelerate tiling operations for tile-based rendering, in which rendering operations for a scene are subdivided in image space, for example to exploit local spatial coherence within a scene or to optimize use of internal caches.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in integrated circuit 39A and/or 39B for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics processor 3940. In at least one embodiment, a computer system includes physical memory storing executable instructions that, as a result of being executed by graphics processor 3940, cause a computer system to implement the machine learning systems described herein. In at least one embodiment, graphics processor 3940 may execute instructions that cause a computer system to generate a projection between two latent spaces, for example.

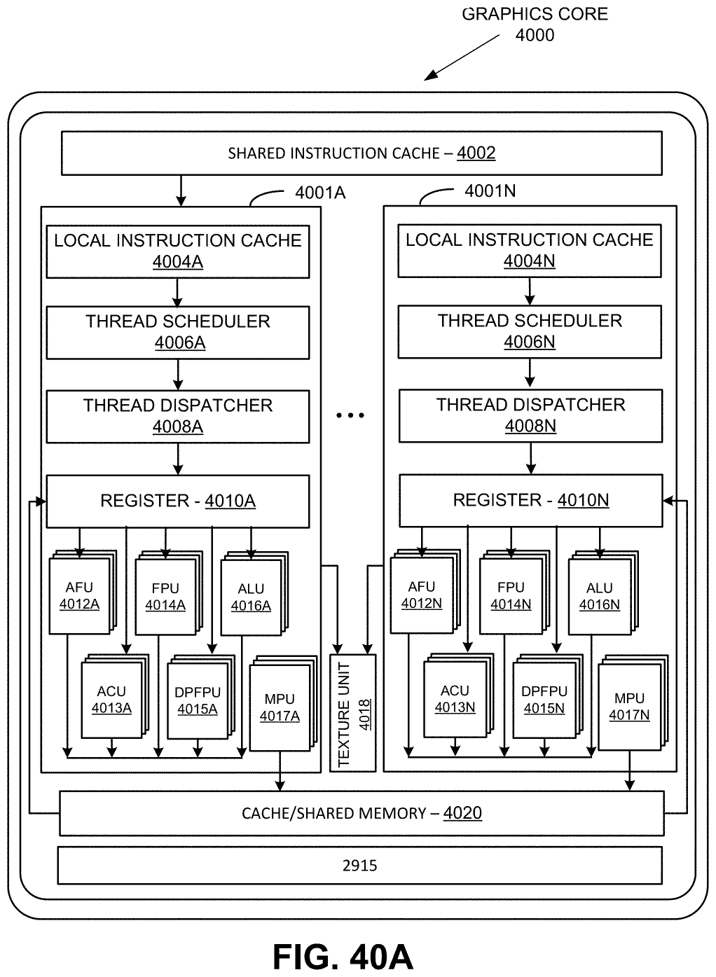

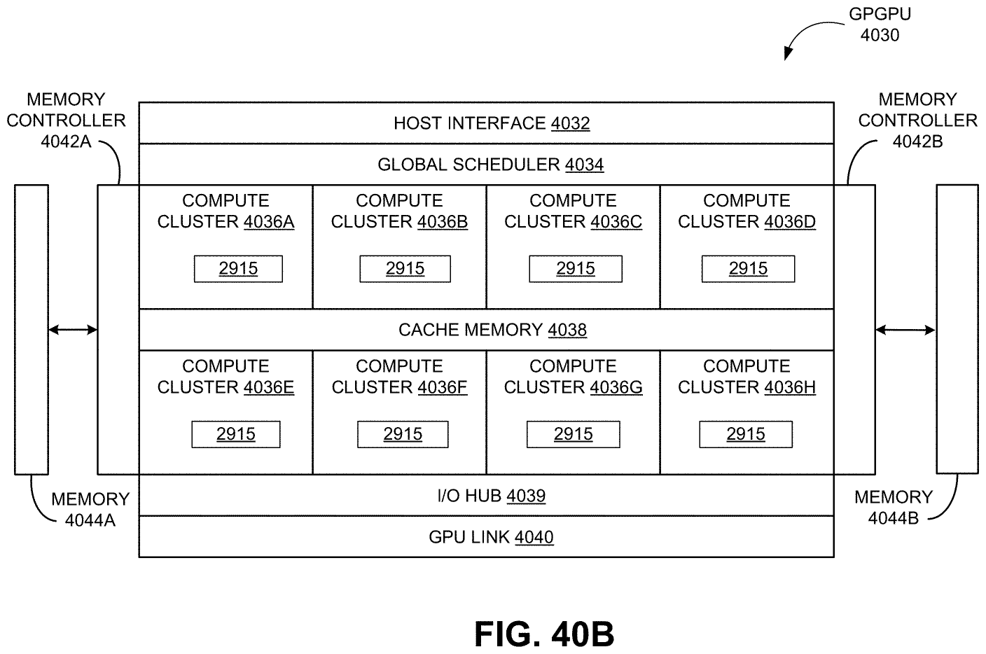

FIGS. 40A-40B illustrate additional exemplary graphics processor logic according to embodiments described herein. FIG. 40A illustrates a graphics core 4000 that may be included within graphics processor 3810 of FIG. 38, in at least one embodiment, and may be a unified shader core 3955A-3955N as in FIG. 39B in at least one embodiment. FIG. 40B illustrates a highly-parallel general-purpose graphics processing unit (“GPGPU”) 4030 suitable for deployment on a multi-chip module in at least one embodiment.

In at least one embodiment, graphics core 4000 includes a shared instruction cache 4002, a texture unit 4018, and a cache/shared memory 4020 that are common to execution resources within graphics core 4000. In at least one embodiment, graphics core 4000 can include multiple slices 4001A-4001N or a partition for each core, and a graphics processor can include multiple instances of graphics core 4000. In at least one embodiment, slices 4001A-4001N can include support logic including a local instruction cache 4004A-4004N, a thread scheduler 4006A-4006N, a thread dispatcher 4008A-4008N, and a set of registers 4010A-4010N. In at least one embodiment, slices 4001A-4001N can include a set of additional function units (AFUs 4012A-4012N), floating-point units (FPUs 4014A-4014N), integer arithmetic logic units (ALUs 4016A-4016N), address computational units (ACUs 4013A-4013N), double-precision floating-point units (DPFPUs 4015A-4015N), and matrix processing units (MPUs 4017A-4017N).

In at least one embodiment, FPUs 4014A-4014N can perform single-precision (32-bit) and half-precision (16-bit) floating point operations, while DPFPUs 4015A-4015N perform double precision (64-bit) floating point operations. In at least one embodiment, ALUs 4016A-4016N can perform variable precision integer operations at 8-bit, 16-bit, and 32-bit precision, and can be configured for mixed precision operations. In at least one embodiment, MPUs 4017A-4017N can also be configured for mixed precision matrix operations, including half-precision floating point and 8-bit integer operations. In at least one embodiment, MPUs 4017-4017N can perform a variety of matrix operations to accelerate machine learning application frameworks, including enabling support for accelerated general matrix to matrix multiplication (GEMM). In at least one embodiment, AFUs 4012A-4012N can perform additional logic operations not supported by floating-point or integer units, including trigonometric operations (e.g., sine, cosine, etc.).

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in graphics core 4000 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics core 4000. In at least one embodiment, a computer system includes physical memory storing executable instructions that, as a result of being executed by graphics core 4000, cause a computer system to implement the machine learning systems described herein. In at least one embodiment, graphics core 4000 may execute instructions that cause a computer system to generate a projection between two latent spaces, for example.

FIG. 40B illustrates a general-purpose processing unit (GPGPU) 4030 that can be configured to enable highly-parallel compute operations to be performed by an array of graphics processing units, in at least one embodiment. In at least one embodiment, GPGPU 4030 can be linked directly to other instances of GPGPU 4030 to create a multi-GPU cluster to improve training speed for deep neural networks. In at least one embodiment, GPGPU 4030 includes a host interface 4032 to enable a connection with a host processor. In at least one embodiment, host interface 4032 is a PCI Express interface. In at least one embodiment, host interface 4032 can be a vendor-specific communications interface or communications fabric. In at least one embodiment, GPGPU 4030 receives commands from a host processor and uses a global scheduler 4034 to distribute execution threads associated with those commands to a set of compute clusters 4036A-4036H. In at least one embodiment, compute clusters 4036A-4036H share a cache memory 4038. In at least one embodiment, cache memory 4038 can serve as a higher-level cache for cache memories within compute clusters 4036A-4036H.

In at least one embodiment, GPGPU 4030 includes memory 4044A-4044B coupled with compute clusters 4036A-4036H via a set of memory controllers 4042A-4042B. In at least one embodiment, memory 4044A-4044B can include various types of memory devices including dynamic random access memory (DRAM) or graphics random access memory, such as synchronous graphics random access memory (SGRAM), including graphics double data rate (GDDR) memory.

In at least one embodiment, compute clusters 4036A-4036H each include a set of graphics cores, such as graphics core 4000 of FIG. 40A, which can include multiple types of integer and floating point logic units that can perform computational operations at a range of precisions including suited for machine learning computations. For example, in at least one embodiment, at least a subset of floating point units in each of compute clusters 4036A-4036H can be configured to perform 16-bit or 32-bit floating point operations, while a different subset of floating point units can be configured to perform 64-bit floating point operations.

In at least one embodiment, multiple instances of GPGPU 4030 can be configured to operate as a compute cluster. In at least one embodiment, communication used by compute clusters 4036A-4036H for synchronization and data exchange varies across embodiments. In at least one embodiment, multiple instances of GPGPU 4030 communicate over host interface 4032. In at least one embodiment, GPGPU 4030 includes an I/O hub 4039 that couples GPGPU 4030 with a GPU link 4040 that enables a direct connection to other instances of GPGPU 4030. In at least one embodiment, GPU link 4040 is coupled to a dedicated GPU-to-GPU bridge that enables communication and synchronization between multiple instances of GPGPU 4030. In at least one embodiment, GPU link 4040 couples with a high-speed interconnect to transmit and receive data to other GPGPUs or parallel processors. In at least one embodiment, multiple instances of GPGPU 4030 are located in separate data processing systems and communicate via a network device that is accessible via host interface 4032. In at least one embodiment GPU link 4040 can be configured to enable a connection to a host processor in addition to or as an alternative to host interface 4032.

In at least one embodiment, GPGPU 4030 can be configured to train neural networks. In at least one embodiment, GPGPU 4030 can be used within an inferencing platform. In at least one embodiment, in which GPGPU 4030 is used for inferencing, GPGPU 4030 may include fewer compute clusters 4036A-4036H relative to when GPGPU 4030 is used for training a neural network. In at least one embodiment, memory technology associated with memory 4044A-4044B may differ between inferencing and training configurations, with higher bandwidth memory technologies devoted to training configurations. In at least one embodiment, an inferencing configuration of GPGPU 4030 can support inferencing specific instructions. For example, in at least one embodiment, an inferencing configuration can provide support for one or more 8-bit integer dot product instructions, which may be used during inferencing operations for deployed neural networks.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in GPGPU 4030 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as GPGPU 4030. In at least one embodiment, a computer system includes physical memory storing executable instructions that, as a result of being executed by GPGPU 4030, cause a computer system to implement the machine learning systems described herein. In at least one embodiment, GPGPU 4030 may execute instructions that cause a computer system to generate a projection between two latent spaces, for example.

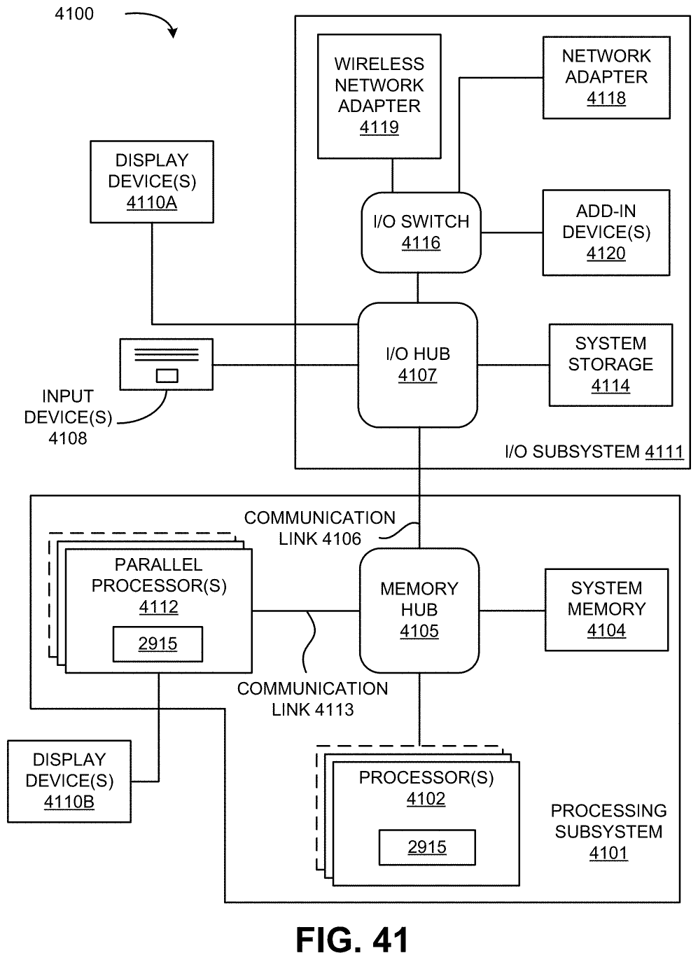

FIG. 41 is a block diagram illustrating a computing system 4100 according to at least one embodiment. In at least one embodiment, computing system 4100 includes a processing subsystem 4101 having one or more processor(s) 4102 and a system memory 4104 communicating via an interconnection path that may include a memory hub 4105. In at least one embodiment, memory hub 4105 may be a separate component within a chipset component or may be integrated within one or more processor(s) 4102. In at least one embodiment, memory hub 4105 couples with an I/O subsystem 4111 via a communication link 4106. In at least one embodiment, I/O subsystem 4111 includes an I/O hub 4107 that can enable computing system 4100 to receive input from one or more input device(s) 4108. In at least one embodiment, I/O hub 4107 can enable a display controller, which may be included in one or more processor(s) 4102, to provide outputs to one or more display device(s) 4110A. In at least one embodiment, one or more display device(s) 4110A coupled with I/O hub 4107 can include a local, internal, or embedded display device.

In at least one embodiment, processing subsystem 4101 includes one or more parallel processor(s) 4112 coupled to memory hub 4105 via a bus or other communication link 4113. In at least one embodiment, communication link 4113 may use one of any number of standards based communication link technologies or protocols, such as, but not limited to PCI Express, or may be a vendor-specific communications interface or communications fabric. In at least one embodiment, one or more parallel processor(s) 4112 form a computationally focused parallel or vector processing system that can include a large number of processing cores and/or processing clusters, such as a many-integrated core (MIC) processor. In at least one embodiment, some or all of parallel processor(s) 4112 form a graphics processing subsystem that can output pixels to one of one or more display device(s) 4110A coupled via I/O Hub 4107. In at least one embodiment, parallel processor(s) 4112 can also include a display controller and display interface (not shown) to enable a direct connection to one or more display device(s) 4110B.

In at least one embodiment, a system storage unit 4114 can connect to I/O hub 4107 to provide a storage mechanism for computing system 4100. In at least one embodiment, an I/O switch 4116 can be used to provide an interface mechanism to enable connections between I/O hub 4107 and other components, such as a network adapter 4118 and/or a wireless network adapter 4119 that may be integrated into platform, and various other devices that can be added via one or more add-in device(s) 4120. In at least one embodiment, network adapter 4118 can be an Ethernet adapter or another wired network adapter. In at least one embodiment, wireless network adapter 4119 can include one or more of a Wi-Fi, Bluetooth, near field communication (NFC), or other network device that includes one or more wireless radios.

In at least one embodiment, computing system 4100 can include other components not explicitly shown, including USB or other port connections, optical storage drives, video capture devices, and like, may also be connected to I/O hub 4107. In at least one embodiment, communication paths interconnecting various components in FIG. 41 may be implemented using any suitable protocols, such as PCI (Peripheral Component Interconnect) based protocols (e.g., PCI-Express), or other bus or point-to-point communication interfaces and/or protocol(s), such as NV-Link high-speed interconnect, or interconnect protocols.

In at least one embodiment, parallel processor(s) 4112 incorporate circuitry optimized for graphics and video processing, including, for example, video output circuitry, and constitutes a graphics processing unit (GPU). In at least one embodiment, parallel processor(s) 4112 incorporate circuitry optimized for general purpose processing. In at least embodiment, components of computing system 4100 may be integrated with one or more other system elements on a single integrated circuit. For example, in at least one embodiment, parallel processor(s) 4112, memory hub 4105, processor(s) 4102, and I/O hub 4107 can be integrated into a system on chip (SoC) integrated circuit. In at least one embodiment, components of computing system 4100 can be integrated into a single package to form a system in package (SIP) configuration. In at least one embodiment, at least a portion of components of computing system 4100 can be integrated into a multi-chip module (MCM), which can be interconnected with other multi-chip modules into a modular computing system.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in system FIG. 4100 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as parallel processor(s) 4112. In at least one embodiment, a computer system includes physical memory storing executable instructions that, as a result of being executed by parallel processor(s) 4112, cause a computer system to implement the machine learning systems described herein. In at least one embodiment, parallel processor(s) 4112 may execute instructions that cause a computer system to generate a projection between two latent spaces, for example.

### Processors

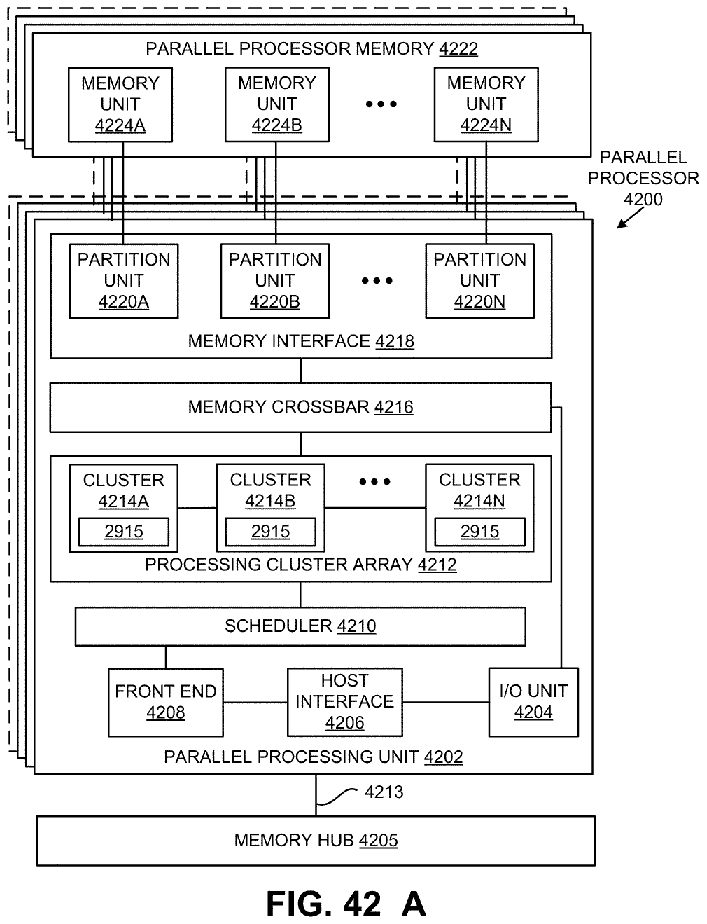

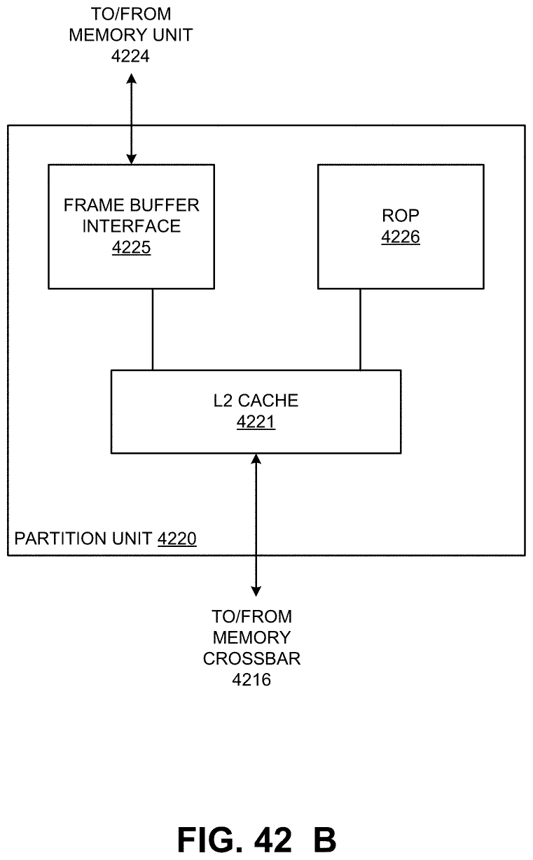

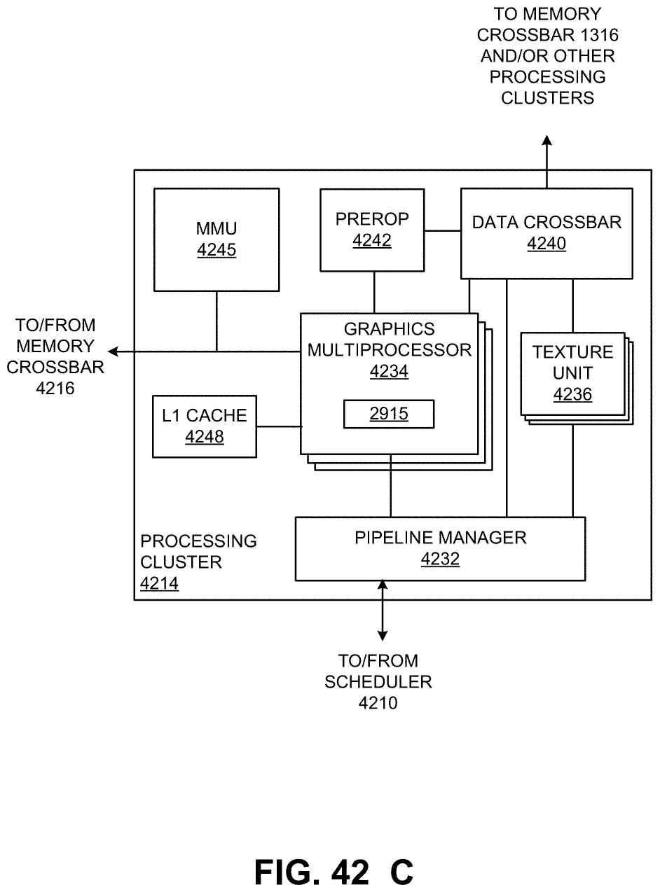

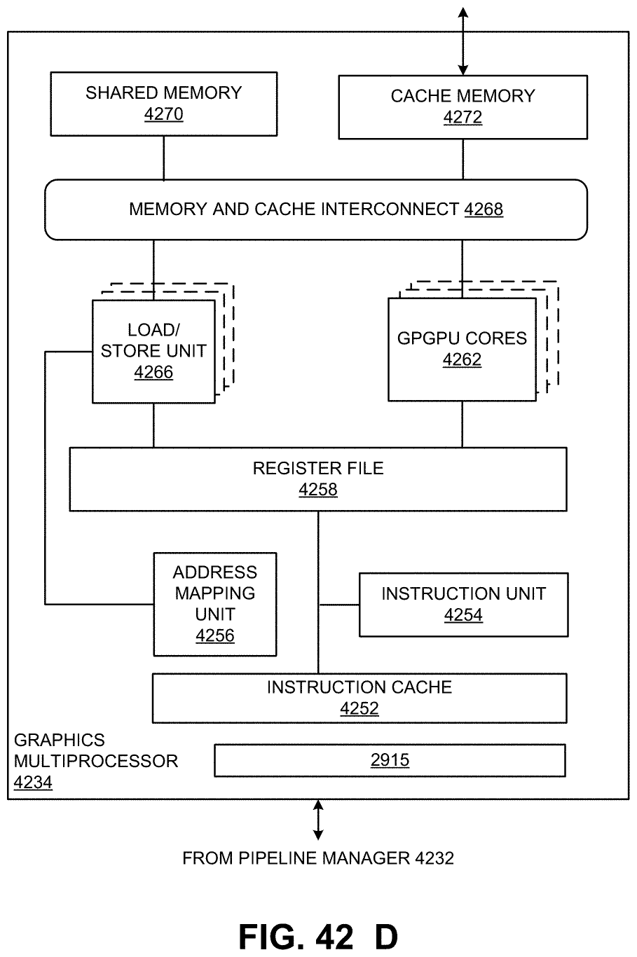

FIG. 42A illustrates a parallel processor 4200 according to at least one embodiment. In at least one embodiment, various components of parallel processor 4200 may be implemented using one or more integrated circuit devices, such as programmable processors, application specific integrated circuits (ASICs), or field programmable gate arrays (FPGA). In at least one embodiment, illustrated parallel processor 4200 is a variant of one or more parallel processor(s) 4112 shown in FIG. 41 according to an exemplary embodiment.

In at least one embodiment, parallel processor 4200 includes a parallel processing unit 4202. In at least one embodiment, parallel processing unit 4202 includes an I/O unit 4204 that enables communication with other devices, including other instances of parallel processing unit 4202. In at least one embodiment, I/O unit 4204 may be directly connected to other devices. In at least one embodiment, I/O unit 4204 connects with other devices via use of a hub or switch interface, such as a memory hub 4205. In at least one embodiment, connections between memory hub 4205 and I/O unit 4204 form a communication link 4213. In at least one embodiment, I/O unit 4204 connects with a host interface 4206 and a memory crossbar 4216, where host interface 4206 receives commands directed to performing processing operations and memory crossbar 4216 receives commands directed to performing memory operations.

In at least one embodiment, when host interface 4206 receives a command buffer via I/O unit 4204, host interface 4206 can direct work operations to perform those commands to a front end 4208. In at least one embodiment, front end 4208 couples with a scheduler 4210, which is configured to distribute commands or other work items to a processing cluster array 4212. In at least one embodiment, scheduler 4210 ensures that processing cluster array 4212 is properly configured and in a valid state before tasks are distributed to a cluster of processing cluster array 4212. In at least one embodiment, scheduler 4210 is implemented via firmware logic executing on a microcontroller. In at least one embodiment, microcontroller implemented scheduler 4210 is configurable to perform complex scheduling and work distribution operations at coarse and fine granularity, enabling rapid preemption and context switching of threads executing on processing array 4212. In at least one embodiment, host software can prove workloads for scheduling on processing cluster array 4212 via one of multiple graphics processing paths. In at least one embodiment, workloads can then be automatically distributed across processing array cluster 4212 by scheduler 4210 logic within a microcontroller including scheduler 4210.

In at least one embodiment, processing cluster array 4212 can include up to “N” processing clusters (e.g., cluster 4214A, cluster 4214B, through cluster 4214N), where “N” represents a positive integer (which may be a different integer “N” than used in other figures). In at least one embodiment, each cluster 4214A-4214N of processing cluster array 4212 can execute a large number of concurrent threads. In at least one embodiment, scheduler 4210 can allocate work to clusters 4214A-4214N of processing cluster array 4212 using various scheduling and/or work distribution algorithms, which may vary depending on workload arising for each type of program or computation. In at least one embodiment, scheduling can be handled dynamically by scheduler 4210, or can be assisted in part by compiler logic during compilation of program logic configured for execution by processing cluster array 4212. In at least one embodiment, different clusters 4214A-4214N of processing cluster array 4212 can be allocated for processing different types of programs or for performing different types of computations.

In at least one embodiment, processing cluster array 4212 can be configured to perform various types of parallel processing operations. In at least one embodiment, processing cluster array 4212 is configured to perform general-purpose parallel compute operations. For example, in at least one embodiment, processing cluster array 4212 can include logic to execute processing tasks including filtering of video and/or audio data, performing modeling operations, including physics operations, and performing data transformations.

In at least one embodiment, processing cluster array 4212 is configured to perform parallel graphics processing operations. In at least one embodiment, processing cluster array 4212 can include additional logic to support execution of such graphics processing operations, including but not limited to, texture sampling logic to perform texture operations, as well as tessellation logic and other vertex processing logic. In at least one embodiment, processing cluster array 4212 can be configured to execute graphics processing related shader programs such as, but not limited to, vertex shaders, tessellation shaders, geometry shaders, and pixel shaders. In at least one embodiment, parallel processing unit 4202 can transfer data from system memory via I/O unit 4204 for processing. In at least one embodiment, during processing, transferred data can be stored to on-chip memory (e.g., parallel processor memory 4222) during processing, then written back to system memory.

In at least one embodiment, when parallel processing unit 4202 is used to perform graphics processing, scheduler 4210 can be configured to divide a processing workload into approximately equal sized tasks, to better enable distribution of graphics processing operations to multiple clusters 4214A-4214N of processing cluster array 4212. In at least one embodiment, portions of processing cluster array 4212 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 4214A-4214N may be stored in buffers to allow intermediate data to be transmitted between clusters 4214A-4214N for further processing.

In at least one embodiment, processing cluster array 4212 can receive processing tasks to be executed via scheduler 4210, which receives commands defining processing tasks from front end 4208. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 4210 may be configured to fetch indices corresponding to tasks or may receive indices from front end 4208. In at least one embodiment, front end 4208 can be configured to ensure processing cluster array 4212 is configured to a valid state before a workload specified by incoming command buffers (e.g., batch-buffers, push buffers, etc.) is initiated.

In at least one embodiment, each of one or more instances of parallel processing unit 4202 can couple with a parallel processor memory 4222. In at least one embodiment, parallel processor memory 4222 can be accessed via memory crossbar 4216, which can receive memory requests from processing cluster array 4212 as well as I/O unit 4204. In at least one embodiment, memory crossbar 4216 can access parallel processor memory 4222 via a memory interface 4218. In at least one embodiment, memory interface 4218 can include multiple partition units (e.g., partition unit 4220A, partition unit 4220B, through partition unit 4220N) that can each couple to a portion (e.g., memory unit) of parallel processor memory 4222. In at least one embodiment, a number of partition units 4220A-4220N is configured to be equal to a number of memory units, such that a first partition unit 4220A has a corresponding first memory unit 4224A, a second partition unit 4220B has a corresponding memory unit 4224B, and an N-th partition unit 4220N has a corresponding N-th memory unit 4224N. In at least one embodiment, a number of partition units 4220A-4220N may not be equal to a number of memory units.

In at least one embodiment, memory units 4224A-4224N can include various types of memory devices, including dynamic random access memory (DRAM) or graphics random access memory, such as synchronous graphics random access memory (SGRAM), including graphics double data rate (GDDR) memory. In at least one embodiment, memory units 4224A-4224N may also include 3D stacked memory, including but not limited to high bandwidth memory (HBM). In at least one embodiment, render targets, such as frame buffers or texture maps may be stored across memory units 4224A-4224N, allowing partition units 4220A-4220N to write portions of each render target in parallel to efficiently use available bandwidth of parallel processor memory 4222. In at least one embodiment, a local instance of parallel processor memory 4222 may be excluded in favor of a unified memory design that utilizes system memory in conjunction with local cache memory.

In at least one embodiment, any one of clusters 4214A-4214N of processing cluster array 4212 can process data that will be written to any of memory units 4224A-4224N within parallel processor memory 4222. In at least one embodiment, memory crossbar 4216 can be configured to transfer an output of each cluster 4214A-4214N to any partition unit 4220A-4220N or to another cluster 4214A-4214N, which can perform additional processing operations on an output. In at least one embodiment, each cluster 4214A-4214N can communicate with memory interface 4218 through memory crossbar 4216 to read from or write to various external memory devices. In at least one embodiment, memory crossbar 4216 has a connection to memory interface 4218 to communicate with I/O unit 4204, as well as a connection to a local instance of parallel processor memory 4222, enabling processing units within different processing clusters 4214A-4214N to communicate with system memory or other memory that is not local to parallel processing unit 4202. In at least one embodiment, memory crossbar 4216 can use virtual channels to separate traffic streams between clusters 4214A-4214N and partition units 4220A-4220N.

In at least one embodiment, multiple instances of parallel processing unit 4202 can be provided on a single add-in card, or multiple add-in cards can be interconnected. In at least one embodiment, different instances of parallel processing unit 4202 can be configured to interoperate even if different instances have different numbers of processing cores, different amounts of local parallel processor memory, and/or other configuration differences. For example, in at least one embodiment, some instances of parallel processing unit 4202 can include higher precision floating point units relative to other instances. In at least one embodiment, systems incorporating one or more instances of parallel processing unit 4202 or parallel processor 4200 can be implemented in a variety of configurations and form factors, including but not limited to desktop, laptop, or handheld personal computers, servers, workstations, game consoles, and/or embedded systems.

FIG. 42B is a block diagram of a partition unit 4220 according to at least one embodiment. In at least one embodiment, partition unit 4220 is an instance of one of partition units 4220A-4220N of FIG. 42A. In at least one embodiment, partition unit 4220 includes an L2 cache 4221, a frame buffer interface 4225, and a ROP 4226 (raster operations unit). In at least one embodiment, L2 cache 4221 is a read/write cache that is configured to perform load and store operations received from memory crossbar 4216 and ROP 4226. In at least one embodiment, read misses and urgent write-back requests are output by L2 cache 4221 to frame buffer interface 4225 for processing. In at least one embodiment, updates can also be sent to a frame buffer via frame buffer interface 4225 for processing. In at least one embodiment, frame buffer interface 4225 interfaces with one of memory units in parallel processor memory, such as memory units 4224A-4224N of FIG. 42 (e.g., within parallel processor memory 4222).

In at least one embodiment, ROP 4226 is a processing unit that performs raster operations such as stencil, z test, blending, etc. In at least one embodiment, ROP 4226 then outputs processed graphics data that is stored in graphics memory. In at least one embodiment, ROP 4226 includes compression logic to compress depth or color data that is written to memory and decompress depth or color data that is read from memory. In at least one embodiment, compression logic can be lossless compression logic that makes use of one or more of multiple compression algorithms. In at least one embodiment, a type of compression that is performed by ROP 4226 can vary based on statistical characteristics of data to be compressed. For example, in at least one embodiment, delta color compression is performed on depth and color data on a per-tile basis.

In at least one embodiment, ROP 4226 is included within each processing cluster (e.g., cluster 4214A-4214N of FIG. 42A) instead of within partition unit 4220. In at least one embodiment, read and write requests for pixel data are transmitted over memory crossbar 4216 instead of pixel fragment data. In at least one embodiment, processed graphics data may be displayed on a display device, such as one of one or more display device(s) 4110 of FIG. 41, routed for further processing by processor(s) 4102, or routed for further processing by one of processing entities within parallel processor 4200 of FIG. 42A.

FIG. 42C is a block diagram of a processing cluster 4214 within a parallel processing unit according to at least one embodiment. In at least one embodiment, a processing cluster is an instance of one of processing clusters 4214A-4214N of FIG. 42A. In at least one embodiment, processing cluster 4214 can be configured to execute many threads in parallel, where “thread” refers to an instance of a particular program executing on a particular set of input data. In at least one embodiment, single-instruction, multiple-data (SIMD) instruction issue techniques are used to support parallel execution of a large number of threads without providing multiple independent instruction units. In at least one embodiment, single-instruction, multiple-thread (SIMT) techniques are used to support parallel execution of a large number of generally synchronized threads, using a common instruction unit configured to issue instructions to a set of processing engines within each one of processing clusters.

In at least one embodiment, operation of processing cluster 4214 can be controlled via a pipeline manager 4232 that distributes processing tasks to SIMT parallel processors. In at least one embodiment, pipeline manager 4232 receives instructions from scheduler 4210 of FIG. 42A and manages execution of those instructions via a graphics multiprocessor 4234 and/or a texture unit 4236. In at least one embodiment, graphics multiprocessor 4234 is an exemplary instance of a SIMT parallel processor. However, in at least one embodiment, various types of SIMT parallel processors of differing architectures may be included within processing cluster 4214. In at least one embodiment, one or more instances of graphics multiprocessor 4234 can be included within a processing cluster 4214. In at least one embodiment, graphics multiprocessor 4234 can process data and a data crossbar 4240 can be used to distribute processed data to one of multiple possible destinations, including other shader units. In at least one embodiment, pipeline manager 4232 can facilitate distribution of processed data by specifying destinations for processed data to be distributed via data crossbar 4240.

In at least one embodiment, each graphics multiprocessor 4234 within processing cluster 4214 can include an identical set of functional execution logic (e.g., arithmetic logic units, load-store units, etc.). In at least one embodiment, functional execution logic can be configured in a pipelined manner in which new instructions can be issued before previous instructions are complete. In at least one embodiment, functional execution logic supports a variety of operations including integer and floating point arithmetic, comparison operations, Boolean operations, bit-shifting, and computation of various algebraic functions. In at least one embodiment, same functional-unit hardware can be leveraged to perform different operations and any combination of functional units may be present.

In at least one embodiment, instructions transmitted to processing cluster 4214 constitute a thread. In at least one embodiment, a set of threads executing across a set of parallel processing engines is a thread group. In at least one embodiment, a thread group executes a common program on different input data. In at least one embodiment, each thread within a thread group can be assigned to a different processing engine within a graphics multiprocessor 4234. In at least one embodiment, a thread group may include fewer threads than a number of processing engines within graphics multiprocessor 4234. In at least one embodiment, when a thread group includes fewer threads than a number of processing engines, one or more of processing engines may be idle during cycles in which that thread group is being processed. In at least one embodiment, a thread group may also include more threads than a number of processing engines within graphics multiprocessor 4234. In at least one embodiment, when a thread group includes more threads than number of processing engines within graphics multiprocessor 4234, processing can be performed over consecutive clock cycles. In at least one embodiment, multiple thread groups can be executed concurrently on a graphics multiprocessor 4234.

In at least one embodiment, graphics multiprocessor 4234 includes an internal cache memory to perform load and store operations. In at least one embodiment, graphics multiprocessor 4234 can forego an internal cache and use a cache memory (e.g., L1 cache 4248) within processing cluster 4214. In at least one embodiment, each graphics multiprocessor 4234 also has access to L2 caches within partition units (e.g., partition units 4220A-4220N of FIG. 42A) that are shared among all processing clusters 4214 and may be used to transfer data between threads. In at least one embodiment, graphics multiprocessor 4234 may also access off-chip global memory, which can include one or more of local parallel processor memory and/or system memory. In at least one embodiment, any memory external to parallel processing unit 4202 may be used as global memory. In at least one embodiment, processing cluster 4214 includes multiple instances of graphics multiprocessor 4234 and can share common instructions and data, which may be stored in L1 cache 4248.

In at least one embodiment, each processing cluster 4214 may include an MMU 4245 (memory management unit) that is configured to map virtual addresses into physical addresses. In at least one embodiment, one or more instances of MMU 4245 may reside within memory interface 4218 of FIG. 42A. In at least one embodiment, MMU 4245 includes a set of page table entries (PTEs) used to map a virtual address to a physical address of a tile and optionally a cache line index. In at least one embodiment, MMU 4245 may include address translation lookaside buffers (TLB) or caches that may reside within graphics multiprocessor 4234 or L1 4248 cache or processing cluster 4214. In at least one embodiment, a physical address is processed to distribute surface data access locally to allow for efficient request interleaving among partition units. In at least one embodiment, a cache line index may be used to determine whether a request for a cache line is a hit or miss.

In at least one embodiment, a processing cluster 4214 may be configured such that each graphics multiprocessor 4234 is coupled to a texture unit 4236 for performing texture mapping operations, e.g., determining texture sample positions, reading texture data, and filtering texture data. In at least one embodiment, texture data is read from an internal texture L1 cache (not shown) or from an L1 cache within graphics multiprocessor 4234 and is fetched from an L2 cache, local parallel processor memory, or system memory, as needed. In at least one embodiment, each graphics multiprocessor 4234 outputs processed tasks to data crossbar 4240 to provide processed task to another processing cluster 4214 for further processing or to store processed task in an L2 cache, local parallel processor memory, or system memory via memory crossbar 4216. In at least one embodiment, a preROP 4242 (pre-raster operations unit) is configured to receive data from graphics multiprocessor 4234, and direct data to ROP units, which may be located with partition units as described herein (e.g., partition units 4220A-4220N of FIG. 42A). In at least one embodiment, preROP 4242 unit can perform optimizations for color blending, organizing pixel color data, and performing address translations.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in graphics processing cluster 4214 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as processing cluster 4214. In at least one embodiment, a computer system includes physical memory storing executable instructions that, as a result of being executed by processing cluster 4214, cause a computer system to implement the machine learning systems described herein. In at least one embodiment, processing cluster 4214 may execute instructions that cause a computer system to generate a projection between two latent spaces, for example.

FIG. 42D shows a graphics multiprocessor 4234 according to at least one embodiment. In at least one embodiment, graphics multiprocessor 4234 couples with pipeline manager 4232 of processing cluster 4214. In at least one embodiment, graphics multiprocessor 4234 has an execution pipeline including but not limited to an instruction cache 4252, an instruction unit 4254, an address mapping unit 4256, a register file 4258, one or more general purpose graphics processing unit (GPGPU) cores 4262, and one or more load/store units 4266. In at least one embodiment, GPGPU cores 4262 and load/store units 4266 are coupled with cache memory 4272 and shared memory 4270 via a memory and cache interconnect 4268.

In at least one embodiment, instruction cache 4252 receives a stream of instructions to execute from pipeline manager 4232. In at least one embodiment, instructions are cached in instruction cache 4252 and dispatched for execution by an instruction unit 4254. In at least one embodiment, instruction unit 4254 can dispatch instructions as thread groups (e.g., warps), with each thread of thread group assigned to a different execution unit within GPGPU cores 4262. In at least one embodiment, an instruction can access any of a local, shared, or global address space by specifying an address within a unified address space. In at least one embodiment, address mapping unit 4256 can be used to translate addresses in a unified address space into a distinct memory address that can be accessed by load/store units 4266.

In at least one embodiment, register file 4258 provides a set of registers for functional units of graphics multiprocessor 4234. In at least one embodiment, register file 4258 provides temporary storage for operands connected to data paths of functional units (e.g., GPGPU cores 4262, load/store units 4266) of graphics multiprocessor 4234. In at least one embodiment, register file 4258 is divided between each of functional units such that each functional unit is allocated a dedicated portion of register file 4258. In at least one embodiment, register file 4258 is divided between different warps being executed by graphics multiprocessor 4234.

In at least one embodiment, GPGPU cores 4262 can each include floating point units (FPUs) and/or integer arithmetic logic units (ALUs) that are used to execute instructions of graphics multiprocessor 4234. In at least one embodiment, GPGPU cores 4262 can be similar in architecture or can differ in architecture. In at least one embodiment, a first portion of GPGPU cores 4262 include a single precision FPU and an integer ALU while a second portion of GPGPU cores include a double precision FPU. In at least one embodiment, FPUs can implement IEEE 754-2008 standard floating point arithmetic or enable variable precision floating point arithmetic. In at least one embodiment, graphics multiprocessor 4234 can additionally include one or more fixed function or special function units to perform specific functions such as copy rectangle or pixel blending operations. In at least one embodiment, one or more of GPGPU cores 4262 can also include fixed or special function logic.

In at least one embodiment, GPGPU cores 4262 include SIMD logic capable of performing a single instruction on multiple sets of data. In at least one embodiment, GPGPU cores 4262 can physically execute SIMD4, SIMD8, and SIMD16 instructions and logically execute SIMD1, SIMD2, and SIMD32 instructions. In at least one embodiment, SIMD instructions for GPGPU cores can be generated at compile time by a shader compiler or automatically generated when executing programs written and compiled for single program multiple data (SPMD) or SIMT architectures. In at least one embodiment, multiple threads of a program configured for an SIMT execution model can executed via a single SIMD instruction. For example, in at least one embodiment, eight SIMT threads that perform same or similar operations can be executed in parallel via a single SIMD8 logic unit.

In at least one embodiment, memory and cache interconnect 4268 is an interconnect network that connects each functional unit of graphics multiprocessor 4234 to register file 4258 and to shared memory 4270. In at least one embodiment, memory and cache interconnect 4268 is a crossbar interconnect that allows load/store unit 4266 to implement load and store operations between shared memory 4270 and register file 4258. In at least one embodiment, register file 4258 can operate at a same frequency as GPGPU cores 4262, thus data transfer between GPGPU cores 4262 and register file 4258 can have very low latency. In at least one embodiment, shared memory 4270 can be used to enable communication between threads that execute on functional units within graphics multiprocessor 4234. In at least one embodiment, cache memory 4272 can be used as a data cache for example, to cache texture data communicated between functional units and texture unit 4236. In at least one embodiment, shared memory 4270 can also be used as a program managed cache. In at least one embodiment, threads executing on GPGPU cores 4262 can programmatically store data within shared memory in addition to automatically cached data that is stored within cache memory 4272.

In at least one embodiment, a parallel processor or GPGPU as described herein is communicatively coupled to host/processor cores to accelerate graphics operations, machine-learning operations, pattern analysis operations, and various general purpose GPU (GPGPU) functions. In at least one embodiment, a GPU may be communicatively coupled to host processor/cores over a bus or other interconnect (e.g., a high-speed interconnect such as PCIe or NVLink). In at least one embodiment, a GPU may be integrated on a package or chip as cores and communicatively coupled to cores over an internal processor bus/interconnect internal to a package or chip. In at least one embodiment, regardless a manner in which a GPU is connected, processor cores may allocate work to such GPU in a form of sequences of commands/instructions contained in a work descriptor. In at least one embodiment, that GPU then uses dedicated circuitry/logic for efficiently processing these commands/instructions.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in graphics multiprocessor 4234 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics multiprocessor 4234. In at least one embodiment, a computer system includes physical memory storing executable instructions that, as a result of being executed by graphics multiprocessor 4234, cause a computer system to implement the machine learning systems described herein. In at least one embodiment, graphics multiprocessor 4234 may execute instructions that cause a computer system to generate a projection between two latent spaces, for example.

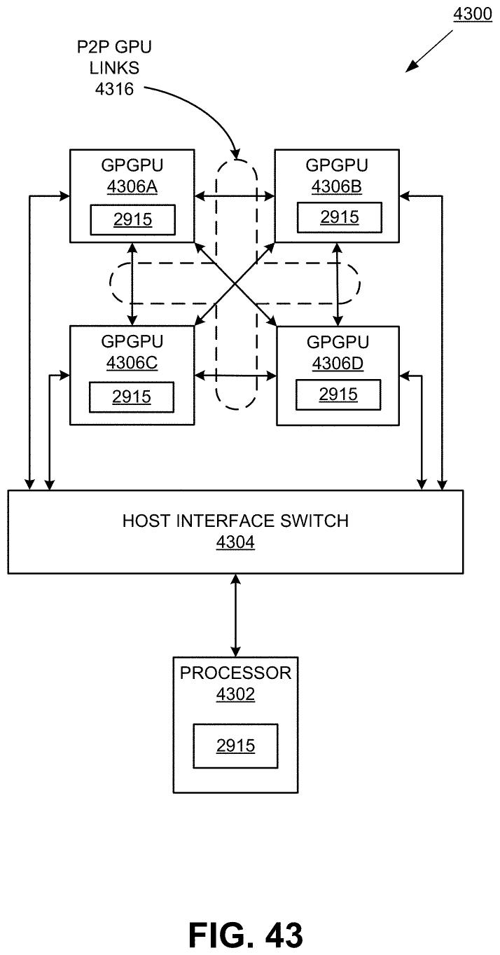

FIG. 43 illustrates a multi-GPU computing system 4300, according to at least one embodiment. In at least one embodiment, multi-GPU computing system 4300 can include a processor 4302 coupled to multiple general purpose graphics processing units (GPGPUs) 4306A-D via a host interface switch 4304. In at least one embodiment, host interface switch 4304 is a PCI express switch device that couples processor 4302 to a PCI express bus over which processor 4302 can communicate with GPGPUs 4306A-D. In at least one embodiment, GPGPUs 4306A-D can interconnect via a set of high-speed point-to-point GPU-to-GPU links 4316. In at least one embodiment, GPU-to-GPU links 4316 connect to each of GPGPUs 4306A-D via a dedicated GPU link. In at least one embodiment, P2P GPU links 4316 enable direct communication between each of GPGPUs 4306A-D without requiring communication over host interface bus 4304 to which processor 4302 is connected. In at least one embodiment, with GPU-to-GPU traffic directed to P2P GPU links 4316, host interface bus 4304 remains available for system memory access or to communicate with other instances of multi-GPU computing system 4300, for example, via one or more network devices. While in at least one embodiment GPGPUs 4306A-D connect to processor 4302 via host interface switch 4304, in at least one embodiment processor 4302 includes direct support for P2P GPU links 4316 and can connect directly to GPGPUs 4306A-D.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in multi-GPU computing system 4300 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics multiprocessor 4234. In at least one embodiment, a computer system includes physical memory storing executable instructions that, as a result of being executed by graphics multiprocessor 4234, cause a computer system to implement the machine learning systems described herein. In at least one embodiment, graphics multiprocessor 4234 may execute instructions that cause a computer system to generate a projection between two latent spaces, for example.

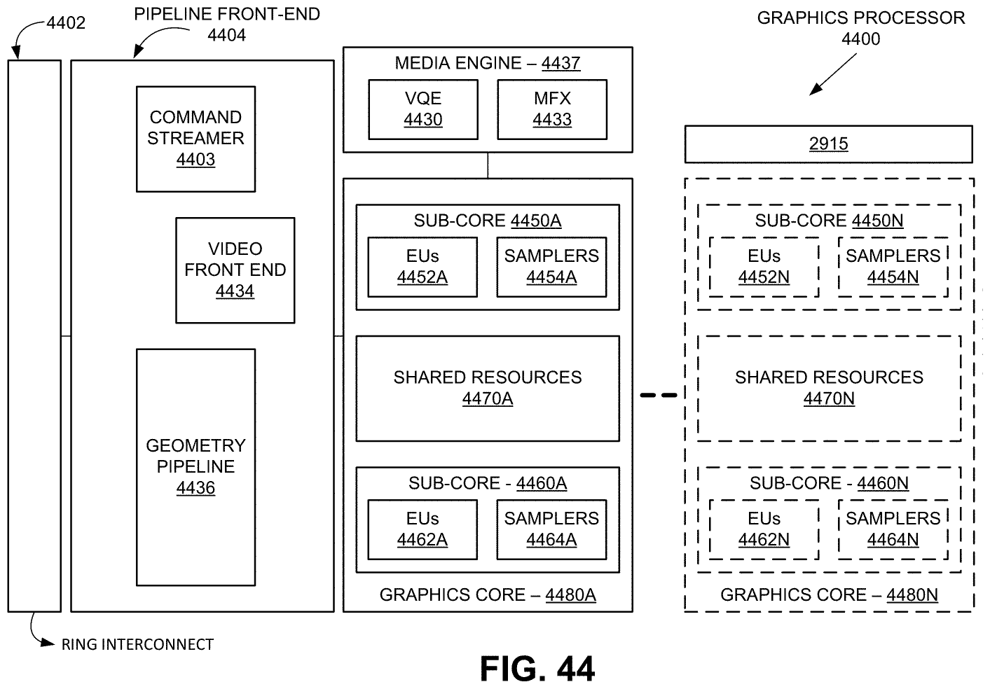

FIG. 44 is a block diagram of a graphics processor 4400, according to at least one embodiment. In at least one embodiment, graphics processor 4400 includes a ring interconnect 4402, a pipeline front-end 4404, a media engine 4437, and graphics cores 4480A-4480N. In at least one embodiment, ring interconnect 4402 couples graphics processor 4400 to other processing units, including other graphics processors or one or more general-purpose processor cores. In at least one embodiment, graphics processor 4400 is one of many processors integrated within a multi-core processing system.

In at least one embodiment, graphics processor 4400 receives batches of commands via ring interconnect 4402. In at least one embodiment, incoming commands are interpreted by a command streamer 4403 in pipeline front-end 4404. In at least one embodiment, graphics processor 4400 includes scalable execution logic to perform 3D geometry processing and media processing via graphics core(s) 4480A-4480N. In at least one embodiment, for 3D geometry processing commands, command streamer 4403 supplies commands to geometry pipeline 4436. In at least one embodiment, for at least some media processing commands, command streamer 4403 supplies commands to a video front end 4434, which couples with media engine 4437. In at least one embodiment, media engine 4437 includes a Video Quality Engine (VQE) 4430 for video and image post-processing and a multi-format encode/decode (MFX) 4433 engine to provide hardware-accelerated media data encoding and decoding. In at least one embodiment, geometry pipeline 4436 and media engine 4437 each generate execution threads for thread execution resources provided by at least one graphics core 4480.

In at least one embodiment, graphics processor 4400 includes scalable thread execution resources featuring graphics cores 4480A-4480N (which can be modular and are sometimes referred to as core slices), each having multiple sub-cores 4450A-50N, 4460A-4460N (sometimes referred to as core sub-slices). In at least one embodiment, graphics processor 4400 can have any number of graphics cores 4480A. In at least one embodiment, graphics processor 4400 includes a graphics core 4480A having at least a first sub-core 4450A and a second sub-core 4460A. In at least one embodiment, graphics processor 4400 is a low power processor with a single sub-core (e.g., 4450A). In at least one embodiment, graphics processor 4400 includes multiple graphics cores 4480A-4480N, each including a set of first sub-cores 4450A-4450N and a set of second sub-cores 4460A-4460N. In at least one embodiment, each sub-core in first sub-cores 4450A-4450N includes at least a first set of execution units 4452A-4452N and media/texture samplers 4454A-4454N. In at least one embodiment, each sub-core in second sub-cores 4460A-4460N includes at least a second set of execution units 4462A-4462N and samplers 4464A-4464N. In at least one embodiment, each sub-core 4450A-4450N, 4460A-4460N shares a set of shared resources 4470A-4470N. In at least one embodiment, shared resources include shared cache memory and pixel operation logic.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, inference and/or training logic 2915 may be used in graphics processor 4400 for inferencing or predicting operations based, at least in part, on weight parameters calculated using neural network training operations, neural network functions and/or architectures, or neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics processor 4400. In at least one embodiment, a computer system includes physical memory storing executable instructions that, as a result of being executed by graphics processor 4400, cause a computer system to implement the machine learning systems described herein. In at least one embodiment, graphics processor 4400 may execute instructions that cause a computer system to generate a projection between two latent spaces, for example.

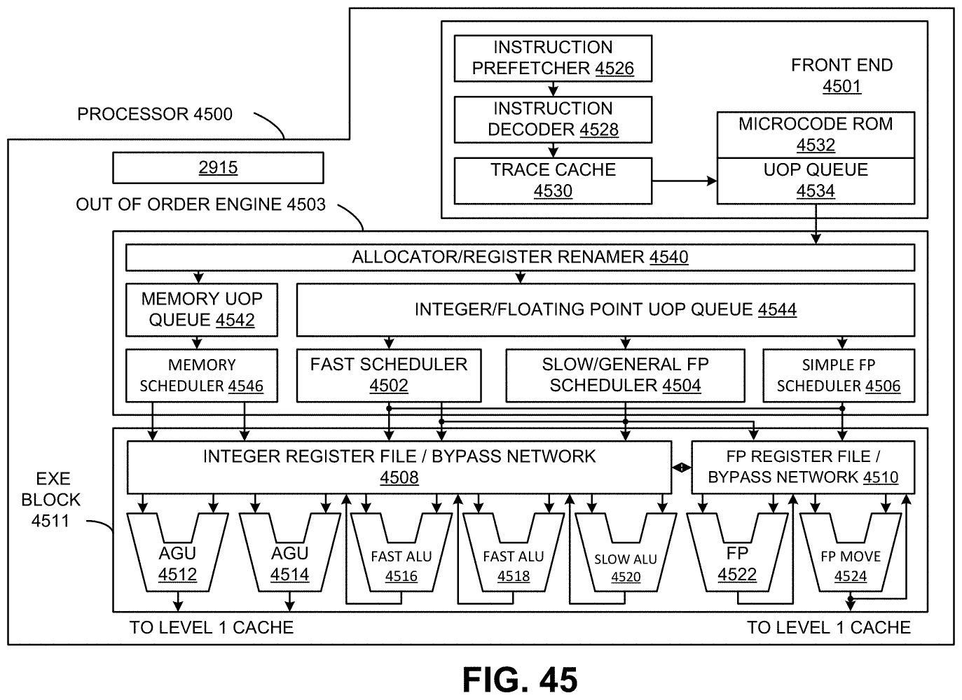

FIG. 45 is a block diagram illustrating micro-architecture for a processor 4500 that may include logic circuits to perform instructions, according to at least one embodiment. In at least one embodiment, processor 4500 may perform instructions, including x86 instructions, ARM instructions, specialized instructions for application-specific integrated circuits (ASICs), etc. In at least one embodiment, processor 4500 may include registers to store packed data, such as 64-bit wide MMX™ registers in microprocessors enabled with MMX technology from Intel Corporation of Santa Clara, Calif. In at least one embodiment, MMX registers, available in both integer and floating point forms, may operate with packed data elements that accompany single instruction, multiple data (“SIMD”) and streaming SIMD extensions (“SSE”) instructions. In at least one embodiment, 128-bit wide XMM registers relating to SSE2, SSE3, SSE4, AVX, or beyond (referred to generically as “SSEx”) technology may hold such packed data operands. In at least one embodiment, processor 4500 may perform instructions to accelerate machine learning or deep learning algorithms, training, or inferencing.

In at least one embodiment, processor 4500 includes an in-order front end (“front end”) 4501 to fetch instructions to be executed and prepare instructions to be used later in a processor pipeline. In at least one embodiment, front end 4501 may include several units. In at least one embodiment, an instruction prefetcher 4526 fetches instructions from memory and feeds instructions to an instruction decoder 4528 which in turn decodes or interprets instructions. For example, in at least one embodiment, instruction decoder 4528 decodes a received instruction into one or more operations called “micro-instructions” or “micro-operations” (also called “micro ops” or “uops”) that a machine may execute. In at least one embodiment, instruction decoder 4528 parses an instruction into an opcode and corresponding data and control fields that may be used by micro-architecture to perform operations in accordance with at least one embodiment. In at least one embodiment, a trace cache 4530 may assemble decoded uops into program ordered sequences or traces in a uop queue 4534 for execution. In at least one embodiment, when trace cache 4530 encounters a complex instruction, a microcode ROM 4532 provides uops needed to complete an operation.

In at least one embodiment, some instructions may be converted into a single micro-op, whereas others need several micro-ops to complete full operation. In at least one embodiment, if more than four micro-ops are needed to complete an instruction, instruction decoder 4528 may access microcode ROM 4532 to perform that instruction. In at least one embodiment, an instruction may be decoded into a small number of micro-ops for processing at instruction decoder 4528. In at least one embodiment, an instruction may be stored within microcode ROM 4532 should a number of micro-ops be needed to accomplish such operation. In at least one embodiment, trace cache 4530 refers to an entry point programmable logic array (“PLA”) to determine a correct micro-instruction pointer for reading microcode sequences to complete one or more instructions from microcode ROM 4532 in accordance with at least one embodiment. In at least one embodiment, after microcode ROM 4532 finishes sequencing micro-ops for an instruction, front end 4501 of a machine may resume fetching micro-ops from trace cache 4530.

In at least one embodiment, out-of-order execution engine (“out of order engine”) 4503 may prepare instructions for execution. In at least one embodiment, out-of-order execution logic has a number of buffers to smooth out and re-order flow of instructions to optimize performance as they go down a pipeline and get scheduled for execution. In at least one embodiment, out-of-order execution engine 4503 includes, without limitation, an allocator/register renamer 4540, a memory uop queue 4542, an integer/floating point uop queue 4544, a memory scheduler 4546, a fast scheduler 4502, a slow/general floating point scheduler (“slow/general FP scheduler”) 4504, and a simple floating point scheduler (“simple FP scheduler”) 4506. In at least one embodiment, fast schedule 4502, slow/general floating point scheduler 4504, and simple floating point scheduler 4506 are also collectively referred to herein as “uop schedulers 4502, 4504, 4506.” In at least one embodiment, allocator/register renamer 4540 allocates machine buffers and resources that each uop needs in order to execute. In at least one embodiment, allocator/register renamer 4540 renames logic registers onto entries in a register file. In at least one embodiment, allocator/register renamer 4540 also allocates an entry for each uop in one of two uop queues, memory uop queue 4542 for memory operations and integer/floating point uop queue 4544 for non-memory operations, in front of memory scheduler 4546 and uop schedulers 4502, 4504, 4506. In at least one embodiment, uop schedulers 4502, 4504, 4506, determine when a uop is ready to execute based on readiness of their dependent input register operand sources and availability of execution resources uops need to complete their operation. In at least one embodiment, fast scheduler 4502 may schedule on each half of a main clock cycle while slow/general floating point scheduler 4504 and simple floating point scheduler 4506 may schedule once per main processor clock cycle. In at least one embodiment, uop schedulers 4502, 4504, 4506 arbitrate for dispatch ports to schedule uops for execution.

In at least one embodiment, execution block 4511 includes, without limitation, an integer register file/bypass network 4508, a floating point register file/bypass network (“FP register file/bypass network”) 4510, address generation units (“AGUs”) 4512 and 4514, fast Arithmetic Logic Units (ALUs) (“fast ALUs”) 4516 and 4518, a slow Arithmetic Logic Unit (“slow ALU”) 4520, a floating point ALU (“FP”) 4522, and a floating point move unit (“FP move”) 4524. In at least one embodiment, integer register file/bypass network 4508 and floating point register file/bypass network 4510 are also referred to herein as “register files 4508, 4510.” In at least one embodiment, AGUSs 4512 and 4514, fast ALUs 4516 and 4518, slow ALU 4520, floating point ALU 4522, and floating point move unit 4524 are also referred to herein as “execution units 4512, 4514, 4516, 4518, 4520, 4522, and 4524.” In at least one embodiment, execution block 4511 may include, without limitation, any number (including zero) and type of register files, bypass networks, address generation units, and execution units, in any combination.

In at least one embodiment, register networks 4508, 4510 may be arranged between uop schedulers 4502, 4504, 4506, and execution units 4512, 4514, 4516, 4518, 4520, 4522, and 4524. In at least one embodiment, integer register file/bypass network 4508 performs integer operations. In at least one embodiment, floating point register file/bypass network 4510 performs floating point operations. In at least one embodiment, each of register networks 4508, 4510 may include, without limitation, a bypass network that may bypass or forward just completed results that have not yet been written into a register file to new dependent uops. In at least one embodiment, register networks 4508, 4510 may communicate data with each other. In at least one embodiment, integer register file/bypass network 4508 may include, without limitation, two separate register files, one register file for a low-order thirty-two bits of data and a second register file for a high order thirty-two bits of data. In at least one embodiment, floating point register file/bypass network 4510 may include, without limitation, 128-bit wide entries because floating point instructions typically have operands from 64 to 128 bits in width.

In at least one embodiment, execution units 4512, 4514, 4516, 4518, 4520, 4522, 4524 may execute instructions. In at least one embodiment, register networks 4508, 4510 store integer and floating point data operand values that micro-instructions need to execute. In at least one embodiment, processor 4500 may include, without limitation, any number and combination of execution units 4512, 4514, 4516, 4518, 4520, 4522, 4524. In at least one embodiment, floating point ALU 4522 and floating point move unit 4524, may execute floating point, MMX, SIMD, AVX and SSE, or other operations, including specialized machine learning instructions. In at least one embodiment, floating point ALU 4522 may include, without limitation, a 64-bit by 64-bit floating point divider to execute divide, square root, and remainder micro ops. In at least one embodiment, instructions involving a floating point value may be handled with floating point hardware. In at least one embodiment, ALU operations may be passed to fast ALUs 4516, 4518. In at least one embodiment, fast ALUS 4516, 4518 may execute fast operations with an effective latency of half a clock cycle. In at least one embodiment, most complex integer operations go to slow ALU 4520 as slow ALU 4520 may include, without limitation, integer execution hardware for long-latency type of operations, such as a multiplier, shifts, flag logic, and branch processing. In at least one embodiment, memory load/store operations may be executed by AGUs 4512, 4514. In at least one embodiment, fast ALU 4516, fast ALU 4518, and slow ALU 4520 may perform integer operations on 64-bit data operands. In at least one embodiment, fast ALU 4516, fast ALU 4518, and slow ALU 4520 may be implemented to support a variety of data bit sizes including sixteen, thirty-two, 128, 256, etc. In at least one embodiment, floating point ALU 4522 and floating point move unit 4524 may be implemented to support a range of operands having bits of various widths, such as 128-bit wide packed data operands in conjunction with SIMD and multimedia instructions.

In at least one embodiment, uop schedulers 4502, 4504, 4506 dispatch dependent operations before a parent load has finished executing. In at least one embodiment, as uops may be speculatively scheduled and executed in processor 4500, processor 4500 may also include logic to handle memory misses. In at least one embodiment, if a data load misses in a data cache, there may be dependent operations in flight in a pipeline that have left a scheduler with temporarily incorrect data. In at least one embodiment, a replay mechanism tracks and re-executes instructions that use incorrect data. In at least one embodiment, dependent operations might need to be replayed and independent ones may be allowed to complete. In at least one embodiment, schedulers and a replay mechanism of at least one embodiment of a processor may also be designed to catch instruction sequences for text string comparison operations.

In at least one embodiment, “registers” may refer to on-board processor storage locations that may be used as part of instructions to identify operands. In at least one embodiment, registers may be those that may be usable from outside of a processor (from a programmer's perspective). In at least one embodiment, registers might not be limited to a particular type of circuit. Rather, in at least one embodiment, a register may store data, provide data, and perform functions described herein. In at least one embodiment, registers described herein may be implemented by circuitry within a processor using any number of different techniques, such as dedicated physical registers, dynamically allocated physical registers using register renaming, combinations of dedicated and dynamically allocated physical registers, etc. In at least one embodiment, integer registers store 32-bit integer data. A register file of at least one embodiment also contains eight multimedia SIMD registers for packed data.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment portions or all of inference and/or training logic 2915 may be incorporated into execution block 4511 and other memory or registers shown or not shown. For example, in at least one embodiment, training and/or inferencing techniques described herein may use one or more of ALUs illustrated in execution block 4511. Moreover, weight parameters may be stored in on-chip or off-chip memory and/or registers (shown or not shown) that configure ALUs of execution block 4511 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as processor 4500. In at least one embodiment, a computer system includes physical memory storing executable instructions that, as a result of being executed by processor 4500, cause a computer system to implement the machine learning systems described herein. In at least one embodiment, processor 4500 may execute instructions that cause a computer system to generate a projection between two latent spaces, for example.

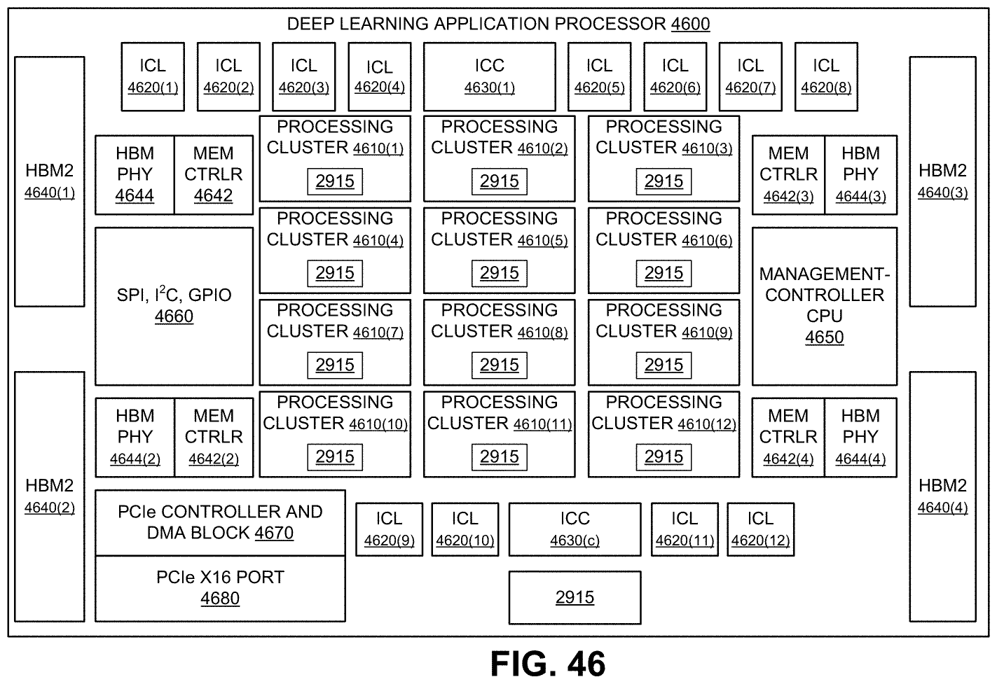

FIG. 46 illustrates a deep learning application processor 4600, according to at least one embodiment. In at least one embodiment, deep learning application processor 4600 uses instructions that, if executed by deep learning application processor 4600, cause deep learning application processor 4600 to perform some or all of processes and techniques described throughout this disclosure. In at least one embodiment, deep learning application processor 4600 is an application-specific integrated circuit (ASIC). In at least one embodiment, application processor 4600 performs matrix multiply operations either “hard-wired” into hardware as a result of performing one or more instructions or both. In at least one embodiment, deep learning application processor 4600 includes, without limitation, processing clusters 4610(1)-4610(12), Inter-Chip Links (“ICLs”) 4620(1)-4620(12), Inter-Chip Controllers (“ICCs”) 4630(1)-4630(2), high-bandwidth memory second generation (“HBM2”) 4640(1)-4640(4), memory controllers (“Mem Ctrlrs”) 4642(1)-4642(4), high bandwidth memory physical layer (“HBM PHY”) 4644(1)-4644(4), a management-controller central processing unit (“management-controller CPU”) 4650, a Serial Peripheral Interface, Inter-Integrated Circuit, and General Purpose Input/Output block (“SPI, I²C, GPIO”) 4660, a peripheral component interconnect express controller and direct memory access block (“PCIe Controller and DMA”) 4670, and a sixteen-lane peripheral component interconnect express port (“PCI Express×16”) 4680.

In at least one embodiment, processing clusters 4610 may perform deep learning operations, including inference or prediction operations based on weight parameters calculated one or more training techniques, including those described herein. In at least one embodiment, each processing cluster 4610 may include, without limitation, any number and type of processors. In at least one embodiment, deep learning application processor 4600 may include any number and type of processing clusters 4600. In at least one embodiment, Inter-Chip Links 4620 are bi-directional. In at least one embodiment, Inter-Chip Links 4620 and Inter-Chip Controllers 4630 enable multiple deep learning application processors 4600 to exchange information, including activation information resulting from performing one or more machine learning algorithms embodied in one or more neural networks. In at least one embodiment, deep learning application processor 4600 may include any number (including zero) and type of ICLs 4620 and ICCs 4630.

In at least one embodiment, HBM2s 4640 provide a total of 32 Gigabytes (GB) of memory. In at least one embodiment, HBM2 4640(i) is associated with both memory controller 4642(i) and HBM PHY 4644(i) where “i” is an arbitrary integer. In at least one embodiment, any number of HBM2s 4640 may provide any type and total amount of high bandwidth memory and may be associated with any number (including zero) and type of memory controllers 4642 and HBM PHYs 4644. In at least one embodiment, SPI, I²C, GPIO 4660, PCIe Controller and DMA 4670, and/or PCIe 4680 may be replaced with any number and type of blocks that enable any number and type of communication standards in any technically feasible fashion.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, deep learning application processor is used to train a machine learning model, such as a neural network, to predict or infer information provided to deep learning application processor 4600. In at least one embodiment, deep learning application processor 4600 is used to infer or predict information based on a trained machine learning model (e.g., neural network) that has been trained by another processor or system or by deep learning application processor 4600. In at least one embodiment, processor 4600 may be used to perform one or more neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as processor 4600. In at least one embodiment, a computer system includes physical memory storing executable instructions that, as a result of being executed by processor 4600, cause a computer system to implement the machine learning systems described herein. In at least one embodiment, processor 4600 may execute instructions that cause a computer system to generate a projection between two latent spaces, for example.

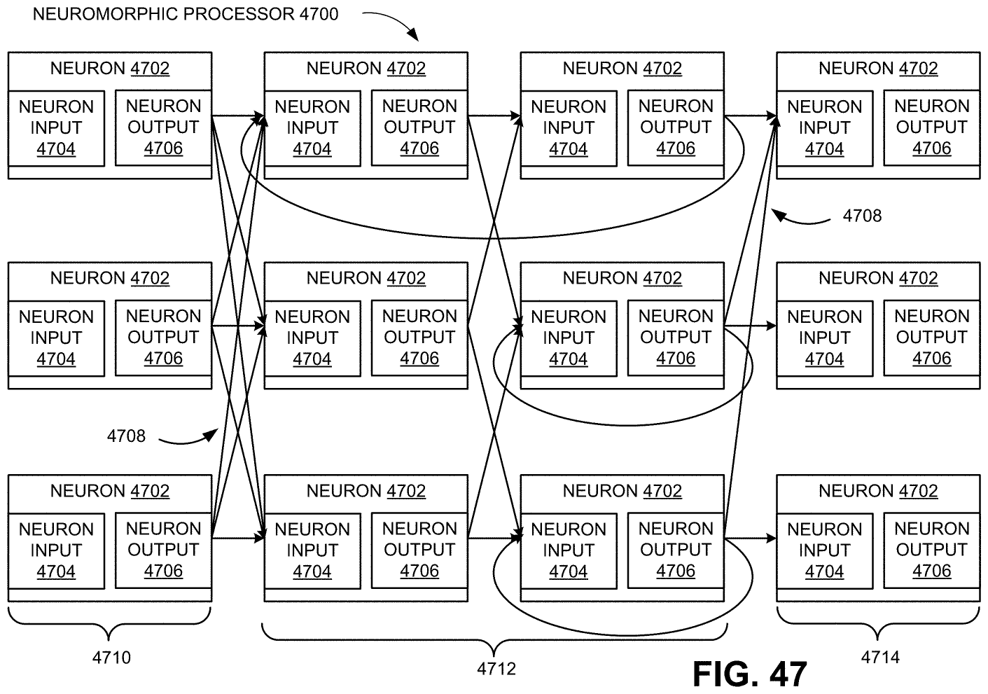

FIG. 47 is a block diagram of a neuromorphic processor 4700, according to at least one embodiment. In at least one embodiment, neuromorphic processor 4700 may receive one or more inputs from sources external to neuromorphic processor 4700. In at least one embodiment, these inputs may be transmitted to one or more neurons 4702 within neuromorphic processor 4700. In at least one embodiment, neurons 4702 and components thereof may be implemented using circuitry or logic, including one or more arithmetic logic units (ALUs). In at least one embodiment, neuromorphic processor 4700 may include, without limitation, thousands or millions of instances of neurons 4702, but any suitable number of neurons 4702 may be used. In at least one embodiment, each instance of neuron 4702 may include a neuron input 4704 and a neuron output 4706. In at least one embodiment, neurons 4702 may generate outputs that may be transmitted to inputs of other instances of neurons 4702. For example, in at least one embodiment, neuron inputs 4704 and neuron outputs 4706 may be interconnected via synapses 4708.

In at least one embodiment, neurons 4702 and synapses 4708 may be interconnected such that neuromorphic processor 4700 operates to process or analyze information received by neuromorphic processor 4700. In at least one embodiment, neurons 4702 may transmit an output pulse (or “fire” or “spike”) when inputs received through neuron input 4704 exceed a threshold. In at least one embodiment, neurons 4702 may sum or integrate signals received at neuron inputs 4704. For example, in at least one embodiment, neurons 4702 may be implemented as leaky integrate-and-fire neurons, wherein if a sum (referred to as a “membrane potential”) exceeds a threshold value, neuron 4702 may generate an output (or “fire”) using a transfer function such as a sigmoid or threshold function. In at least one embodiment, a leaky integrate-and-fire neuron may sum signals received at neuron inputs 4704 into a membrane potential and may also apply a decay factor (or leak) to reduce a membrane potential. In at least one embodiment, a leaky integrate-and-fire neuron may fire if multiple input signals are received at neuron inputs 4704 rapidly enough to exceed a threshold value (i.e., before a membrane potential decays too low to fire). In at least one embodiment, neurons 4702 may be implemented using circuits or logic that receive inputs, integrate inputs into a membrane potential, and decay a membrane potential. In at least one embodiment, inputs may be averaged, or any other suitable transfer function may be used. Furthermore, in at least one embodiment, neurons 4702 may include, without limitation, comparator circuits or logic that generate an output spike at neuron output 4706 when result of applying a transfer function to neuron input 4704 exceeds a threshold. In at least one embodiment, once neuron 4702 fires, it may disregard previously received input information by, for example, resetting a membrane potential to 0 or another suitable default value. In at least one embodiment, once membrane potential is reset to 0, neuron 4702 may resume normal operation after a suitable period of time (or refractory period).

In at least one embodiment, neurons 4702 may be interconnected through synapses 4708. In at least one embodiment, synapses 4708 may operate to transmit signals from an output of a first neuron 4702 to an input of a second neuron 4702. In at least one embodiment, neurons 4702 may transmit information over more than one instance of synapse 4708. In at least one embodiment, one or more instances of neuron output 4706 may be connected, via an instance of synapse 4708, to an instance of neuron input 4704 in same neuron 4702. In at least one embodiment, an instance of neuron 4702 generating an output to be transmitted over an instance of synapse 4708 may be referred to as a “pre-synaptic neuron” with respect to that instance of synapse 4708. In at least one embodiment, an instance of neuron 4702 receiving an input transmitted over an instance of synapse 4708 may be referred to as a “post-synaptic neuron” with respect to that instance of synapse 4708. Because an instance of neuron 4702 may receive inputs from one or more instances of synapse 4708, and may also transmit outputs over one or more instances of synapse 4708, a single instance of neuron 4702 may therefore be both a “pre-synaptic neuron” and “post-synaptic neuron,” with respect to various instances of synapses 4708, in at least one embodiment.

In at least one embodiment, neurons 4702 may be organized into one or more layers. In at least one embodiment, each instance of neuron 4702 may have one neuron output 4706 that may fan out through one or more synapses 4708 to one or more neuron inputs 4704. In at least one embodiment, neuron outputs 4706 of neurons 4702 in a first layer 4710 may be connected to neuron inputs 4704 of neurons 4702 in a second layer 4712. In at least one embodiment, layer 4710 may be referred to as a “feed-forward layer.” In at least one embodiment, each instance of neuron 4702 in an instance of first layer 4710 may fan out to each instance of neuron 4702 in second layer 4712. In at least one embodiment, first layer 4710 may be referred to as a “fully connected feed-forward layer.” In at least one embodiment, each instance of neuron 4702 in an instance of second layer 4712 may fan out to fewer than all instances of neuron 4702 in a third layer 4714. In at least one embodiment, second layer 4712 may be referred to as a “sparsely connected feed-forward layer.” In at least one embodiment, neurons 4702 in second layer 4712 may fan out to neurons 4702 in multiple other layers, including to neurons 4702 also in second layer 4712. In at least one embodiment, second layer 4712 may be referred to as a “recurrent layer.” In at least one embodiment, neuromorphic processor 4700 may include, without limitation, any suitable combination of recurrent layers and feed-forward layers, including, without limitation, both sparsely connected feed-forward layers and fully connected feed-forward layers.

In at least one embodiment, neuromorphic processor 4700 may include, without limitation, a reconfigurable interconnect architecture or dedicated hard-wired interconnects to connect synapse 4708 to neurons 4702. In at least one embodiment, neuromorphic processor 4700 may include, without limitation, circuitry or logic that allows synapses to be allocated to different neurons 4702 as needed based on neural network topology and neuron fan-in/out. For example, in at least one embodiment, synapses 4708 may be connected to neurons 4702 using an interconnect fabric, such as network-on-chip, or with dedicated connections. In at least one embodiment, synapse interconnections and components thereof may be implemented using circuitry or logic.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as processor 4700. In at least one embodiment, a computer system includes physical memory storing executable instructions that, as a result of being executed by processor 4700, cause a computer system to implement the machine learning systems described herein. In at least one embodiment, processor 4700 may execute instructions that cause a computer system to generate a projection between two latent spaces, for example.

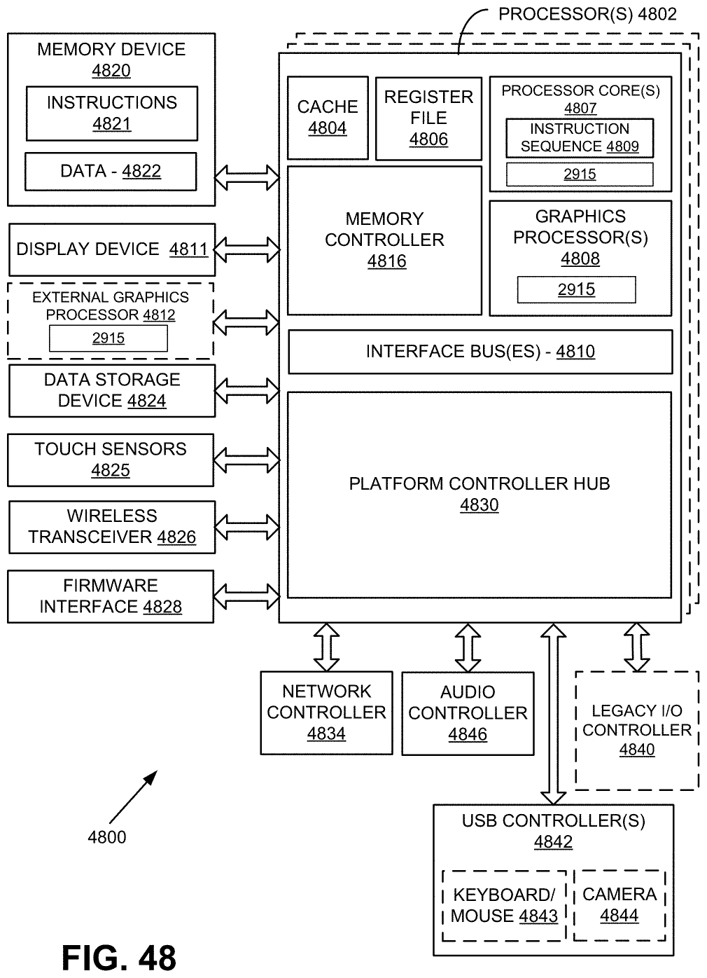

FIG. 48 is a block diagram of a processing system, according to at least one embodiment. In at least one embodiment, system 4800 includes one or more processors 4802 and one or more graphics processors 4808, and may be a single processor desktop system, a multiprocessor workstation system, or a server system having a large number of processors 4802 or processor cores 4807. In at least one embodiment, system 4800 is a processing platform incorporated within a system-on-a-chip (SoC) integrated circuit for use in mobile, handheld, or embedded devices.

In at least one embodiment, system 4800 can include, or be incorporated within a server-based gaming platform, a game console, including a game and media console, a mobile gaming console, a handheld game console, or an online game console. In at least one embodiment, system 4800 is a mobile phone, a smart phone, a tablet computing device or a mobile Internet device. In at least one embodiment, processing system 4800 can also include, couple with, or be integrated within a wearable device, such as a smart watch wearable device, a smart eyewear device, an augmented reality device, or a virtual reality device. In at least one embodiment, processing system 4800 is a television or set top box device having one or more processors 4802 and a graphical interface generated by one or more graphics processors 4808.

In at least one embodiment, one or more processors 4802 each include one or more processor cores 4807 to process instructions which, when executed, perform operations for system and user software. In at least one embodiment, each of one or more processor cores 4807 is configured to process a specific instruction sequence 4809. In at least one embodiment, instruction sequence 4809 may facilitate Complex Instruction Set Computing (CISC), Reduced Instruction Set Computing (RISC), or computing via a Very Long Instruction Word (VLIW). In at least one embodiment, processor cores 4807 may each process a different instruction sequence 4809, which may include instructions to facilitate emulation of other instruction sequences. In at least one embodiment, processor core 4807 may also include other processing devices, such a Digital Signal Processor (DSP).

In at least one embodiment, processor 4802 includes a cache memory 4804. In at least one embodiment, processor 4802 can have a single internal cache or multiple levels of internal cache. In at least one embodiment, cache memory is shared among various components of processor 4802. In at least one embodiment, processor 4802 also uses an external cache (e.g., a Level-3 (L3) cache or Last Level Cache (LLC)) (not shown), which may be shared among processor cores 4807 using known cache coherency techniques. In at least one embodiment, a register file 4806 is additionally included in processor 4802, which may include different types of registers for storing different types of data (e.g., integer registers, floating point registers, status registers, and an instruction pointer register). In at least one embodiment, register file 4806 may include general-purpose registers or other registers.

In at least one embodiment, one or more processor(s) 4802 are coupled with one or more interface bus(es) 4810 to transmit communication signals such as address, data, or control signals between processor 4802 and other components in system 4800. In at least one embodiment, interface bus 4810 can be a processor bus, such as a version of a Direct Media Interface (DMI) bus. In at least one embodiment, interface bus 4810 is not limited to a DMI bus, and may include one or more Peripheral Component Interconnect buses (e.g., PCI, PCI Express), memory busses, or other types of interface busses. In at least one embodiment processor(s) 4802 include an integrated memory controller 4816 and a platform controller hub 4830. In at least one embodiment, memory controller 4816 facilitates communication between a memory device and other components of system 4800, while platform controller hub (PCH) 4830 provides connections to I/O devices via a local I/O bus.

In at least one embodiment, a memory device 4820 can be a dynamic random access memory (DRAM) device, a static random access memory (SRAM) device, flash memory device, phase-change memory device, or some other memory device having suitable performance to serve as process memory. In at least one embodiment, memory device 4820 can operate as system memory for system 4800, to store data 4822 and instructions 4821 for use when one or more processors 4802 executes an application or process. In at least one embodiment, memory controller 4816 also couples with an optional external graphics processor 4812, which may communicate with one or more graphics processors 4808 in processors 4802 to perform graphics and media operations. In at least one embodiment, a display device 4811 can connect to processor(s) 4802. In at least one embodiment, display device 4811 can include one or more of an internal display device, as in a mobile electronic device or a laptop device, or an external display device attached via a display interface (e.g., DisplayPort, etc.). In at least one embodiment, display device 4811 can include a head mounted display (HMD) such as a stereoscopic display device for use in virtual reality (VR) applications or augmented reality (AR) applications.

In at least one embodiment, platform controller hub 4830 enables peripherals to connect to memory device 4820 and processor 4802 via a high-speed I/O bus. In at least one embodiment, I/O peripherals include, but are not limited to, an audio controller 4846, a network controller 4834, a firmware interface 4828, a wireless transceiver 4826, touch sensors 4825, a data storage device 4824 (e.g., hard disk drive, flash memory, etc.). In at least one embodiment, data storage device 4824 can connect via a storage interface (e.g., SATA) or via a peripheral bus, such as a Peripheral Component Interconnect bus (e.g., PCI, PCI Express). In at least one embodiment, touch sensors 4825 can include touch screen sensors, pressure sensors, or fingerprint sensors. In at least one embodiment, wireless transceiver 4826 can be a Wi-Fi transceiver, a Bluetooth transceiver, or a mobile network transceiver such as a 3G, 4G, or Long Term Evolution (LTE) transceiver. In at least one embodiment, firmware interface 4828 enables communication with system firmware, and can be, for example, a unified extensible firmware interface (UEFI). In at least one embodiment, network controller 4834 can enable a network connection to a wired network. In at least one embodiment, a high-performance network controller (not shown) couples with interface bus 4810. In at least one embodiment, audio controller 4846 is a multi-channel high definition audio controller. In at least one embodiment, system 4800 includes an optional legacy I/O controller 4840 for coupling legacy (e.g., Personal System 2 (PS/2)) devices to system 4800. In at least one embodiment, platform controller hub 4830 can also connect to one or more Universal Serial Bus (USB) controllers 4842 connect input devices, such as keyboard and mouse 4843 combinations, a camera 4844, or other USB input devices.

In at least one embodiment, an instance of memory controller 4816 and platform controller hub 4830 may be integrated into a discreet external graphics processor, such as external graphics processor 4812. In at least one embodiment, platform controller hub 4830 and/or memory controller 4816 may be external to one or more processor(s) 4802. For example, in at least one embodiment, system 4800 can include an external memory controller 4816 and platform controller hub 4830, which may be configured as a memory controller hub and peripheral controller hub within a system chipset that is in communication with processor(s) 4802.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment portions or all of inference and/or training logic 2915 may be incorporated into graphics processor 4800. For example, in at least one embodiment, training and/or inferencing techniques described herein may use one or more of ALUs embodied in a 3D pipeline. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs of graphics processor 4800 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics processor 4800. In at least one embodiment, a computer system includes physical memory storing executable instructions that, as a result of being executed by graphics processor 4800], cause a computer system to implement the machine learning systems described herein. In at least one embodiment, graphics processor 4800 may execute instructions that cause a computer system to generate a projection between two latent spaces, for example.

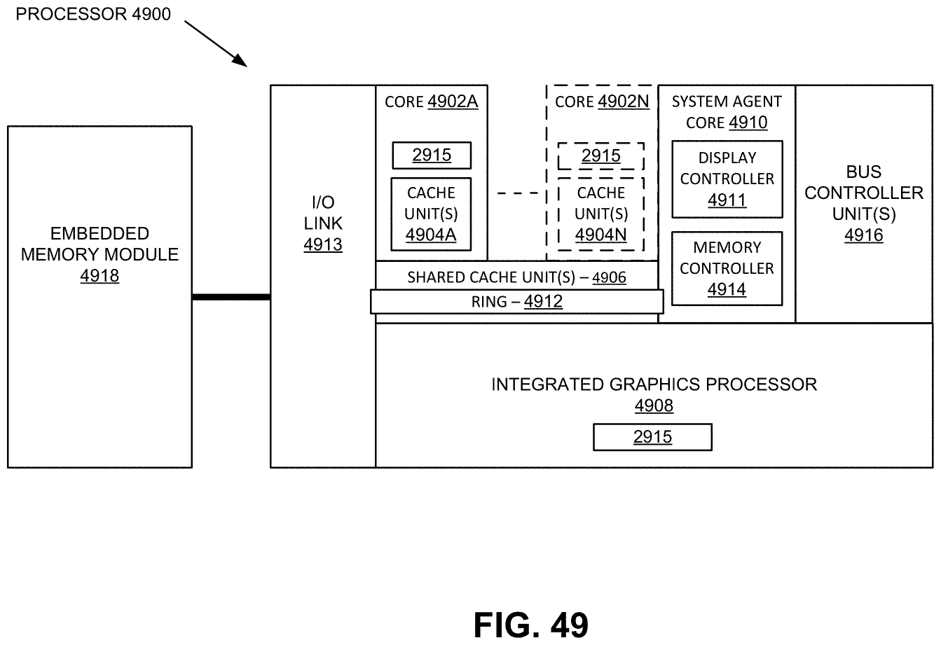

FIG. 49 is a block diagram of a processor 4900 having one or more processor cores 4902A-4902N, an integrated memory controller 4914, and an integrated graphics processor 4908, according to at least one embodiment. In at least one embodiment, processor 4900 can include additional cores up to and including additional core 4902N represented by dashed lined boxes. In at least one embodiment, each of processor cores 4902A-4902N includes one or more internal cache units 4904A-4904N. In at least one embodiment, each processor core also has access to one or more shared cached units 4906.

In at least one embodiment, internal cache units 4904A-4904N and shared cache units 4906 represent a cache memory hierarchy within processor 4900. In at least one embodiment, cache memory units 4904A-4904N may include at least one level of instruction and data cache within each processor core and one or more levels of shared mid-level cache, such as a Level 2 (L2), Level 3 (L3), Level 4 (L4), or other levels of cache, where a highest level of cache before external memory is classified as an LLC. In at least one embodiment, cache coherency logic maintains coherency between various cache units 4906 and 4904A-4904N.

In at least one embodiment, processor 4900 may also include a set of one or more bus controller units 4916 and a system agent core 4910. In at least one embodiment, bus controller units 4916 manage a set of peripheral buses, such as one or more PCI or PCI express busses. In at least one embodiment, system agent core 4910 provides management functionality for various processor components. In at least one embodiment, system agent core 4910 includes one or more integrated memory controllers 4914 to manage access to various external memory devices (not shown).

In at least one embodiment, one or more of processor cores 4902A-4902N include support for simultaneous multi-threading. In at least one embodiment, system agent core 4910 includes components for coordinating and operating cores 4902A-4902N during multi-threaded processing. In at least one embodiment, system agent core 4910 may additionally include a power control unit (PCU), which includes logic and components to regulate one or more power states of processor cores 4902A-4902N and graphics processor 4908.

In at least one embodiment, processor 4900 additionally includes graphics processor 4908 to execute graphics processing operations. In at least one embodiment, graphics processor 4908 couples with shared cache units 4906, and system agent core 4910, including one or more integrated memory controllers 4914. In at least one embodiment, system agent core 4910 also includes a display controller 4911 to drive graphics processor output to one or more coupled displays. In at least one embodiment, display controller 4911 may also be a separate module coupled with graphics processor 4908 via at least one interconnect, or may be integrated within graphics processor 4908.

In at least one embodiment, a ring-based interconnect unit 4912 is used to couple internal components of processor 4900. In at least one embodiment, an alternative interconnect unit may be used, such as a point-to-point interconnect, a switched interconnect, or other techniques. In at least one embodiment, graphics processor 4908 couples with ring interconnect 4912 via an I/O link 4913.

In at least one embodiment, I/O link 4913 represents at least one of multiple varieties of I/O interconnects, including an on package I/O interconnect which facilitates communication between various processor components and a high-performance embedded memory module 4918, such as an eDRAM module. In at least one embodiment, each of processor cores 4902A-4902N and graphics processor 4908 use embedded memory module 4918 as a shared Last Level Cache.

In at least one embodiment, processor cores 4902A-4902N are homogeneous cores executing a common instruction set architecture. In at least one embodiment, processor cores 4902A-4902N are heterogeneous in terms of instruction set architecture (ISA), where one or more of processor cores 4902A-4902N execute a common instruction set, while one or more other cores of processor cores 4902A-4902N executes a subset of a common instruction set or a different instruction set. In at least one embodiment, processor cores 4902A-4902N are heterogeneous in terms of microarchitecture, where one or more cores having a relatively higher power consumption couple with one or more power cores having a lower power consumption. In at least one embodiment, processor 4900 can be implemented on one or more chips or as an SoC integrated circuit.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment portions or all of inference and/or training logic 2915 may be incorporated into graphics processor 4910. For example, in at least one embodiment, training and/or inferencing techniques described herein may use one or more of ALUs embodied in a 3D pipeline, graphics core(s) 4902, shared function logic, or other logic in FIG. 49. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs of processor 4900 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as processor cores 4902A-4902N. In at least one embodiment, a computer system includes physical memory storing executable instructions that, as a result of being executed by processor cores 4902A-4902N, cause a computer system to implement the machine learning systems described herein. In at least one embodiment, processor cores 4902A-4902N may execute instructions that cause a computer system to generate a projection between two latent spaces, for example.

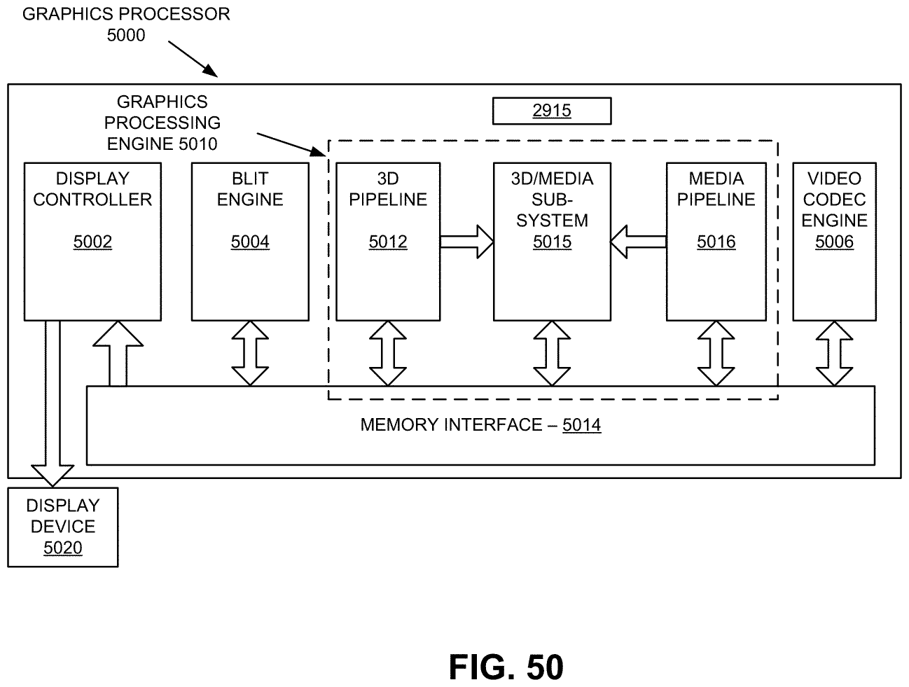

FIG. 50 is a block diagram of a graphics processor 5000, which may be a discrete graphics processing unit, or may be a graphics processor integrated with a plurality of processing cores. In at least one embodiment, graphics processor 5000 communicates via a memory mapped I/O interface to registers on graphics processor 5000 and with commands placed into memory. In at least one embodiment, graphics processor 5000 includes a memory interface 5014 to access memory. In at least one embodiment, memory interface 5014 is an interface to local memory, one or more internal caches, one or more shared external caches, and/or to system memory.

In at least one embodiment, graphics processor 5000 also includes a display controller 5002 to drive display output data to a display device 5020. In at least one embodiment, display controller 5002 includes hardware for one or more overlay planes for display device 5020 and composition of multiple layers of video or user interface elements. In at least one embodiment, display device 5020 can be an internal or external display device. In at least one embodiment, display device 5020 is a head mounted display device, such as a virtual reality (VR) display device or an augmented reality (AR) display device. In at least one embodiment, graphics processor 5000 includes a video codec engine 5006 to encode, decode, or transcode media to, from, or between one or more media encoding formats, including, but not limited to Moving Picture Experts Group (MPEG) formats such as MPEG-2, Advanced Video Coding (AVC) formats such as H.264/MPEG-4 AVC, as well as the Society of Motion Picture & Television Engineers (SMPTE) 421M/VC-1, and Joint Photographic Experts Group (JPEG) formats such as JPEG, and Motion JPEG (MJPEG) formats.

In at least one embodiment, graphics processor 5000 includes a block image transfer (BLIT) engine 5004 to perform two-dimensional (2D) rasterizer operations including, for example, bit-boundary block transfers. However, in at least one embodiment, 2D graphics operations are performed using one or more components of a graphics processing engine (GPE) 5010. In at least one embodiment, GPE 5010 is a compute engine for performing graphics operations, including three-dimensional (3D) graphics operations and media operations.

In at least one embodiment, GPE 5010 includes a 3D pipeline 5012 for performing 3D operations, such as rendering three-dimensional images and scenes using processing functions that act upon 3D primitive shapes (e.g., rectangle, triangle, etc.). In at least one embodiment, 3D pipeline 5012 includes programmable and fixed function elements that perform various tasks and/or spawn execution threads to a 3D/Media sub-system 5015. While 3D pipeline 5012 can be used to perform media operations, in at least one embodiment, GPE 5010 also includes a media pipeline 5016 that is used to perform media operations, such as video post-processing and image enhancement.

In at least one embodiment, media pipeline 5016 includes fixed function or programmable logic units to perform one or more specialized media operations, such as video decode acceleration, video de-interlacing, and video encode acceleration in place of, or on behalf of, video codec engine 5006. In at least one embodiment, media pipeline 5016 additionally includes a thread spawning unit to spawn threads for execution on 3D/Media sub-system 5015. In at least one embodiment, spawned threads perform computations for media operations on one or more graphics execution units included in 3D/Media sub-system 5015.

In at least one embodiment, 3D/Media subsystem 5015 includes logic for executing threads spawned by 3D pipeline 5012 and media pipeline 5016. In at least one embodiment, 3D pipeline 5012 and media pipeline 5016 send thread execution requests to 3D/Media subsystem 5015, which includes thread dispatch logic for arbitrating and dispatching various requests to available thread execution resources. In at least one embodiment, execution resources include an array of graphics execution units to process 3D and media threads. In at least one embodiment, 3D/Media subsystem 5015 includes one or more internal caches for thread instructions and data. In at least one embodiment, subsystem 5015 also includes shared memory, including registers and addressable memory, to share data between threads and to store output data.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment portions or all of inference and/or training logic 2915 may be incorporated into graphics processor 5000. For example, in at least one embodiment, training and/or inferencing techniques described herein may use one or more of ALUs embodied in 3D pipeline 5012. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs of graphics processor 5000 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics processor 5000. In at least one embodiment, a computer system includes physical memory storing executable instructions that, as a result of being executed by graphics processor 5000, cause a computer system to implement the machine learning systems described herein. In at least one embodiment, graphics processor 5000 may execute instructions that cause a computer system to generate a projection between two latent spaces, for example.

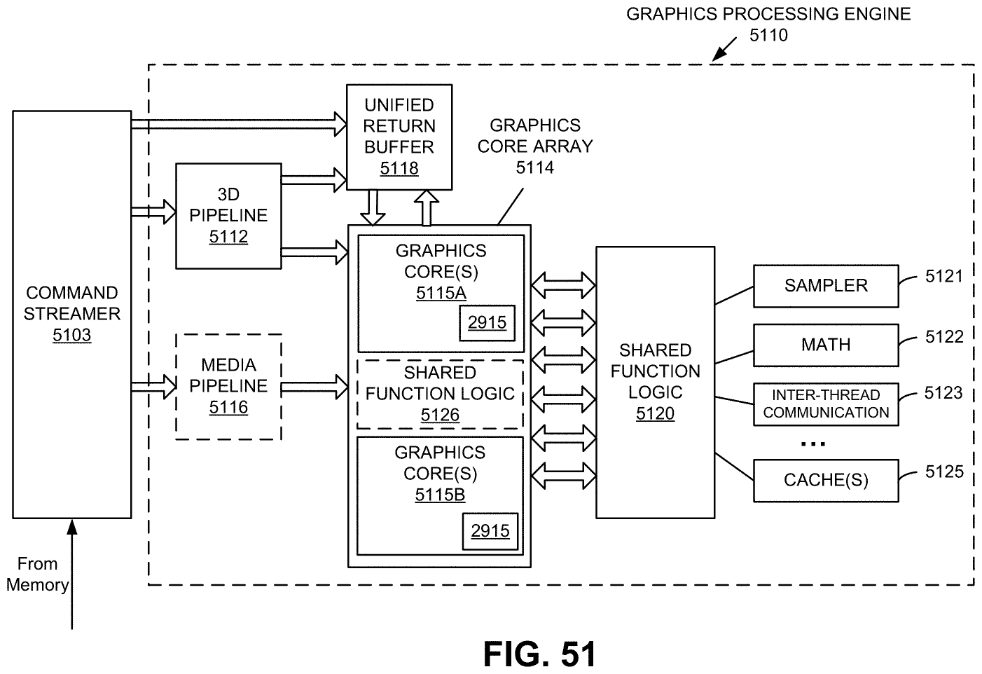

FIG. 51 is a block diagram of a graphics processing engine 5110 of a graphics processor in accordance with at least one embodiment. In at least one embodiment, graphics processing engine (GPE) 5110 is a version of GPE 5010 shown in FIG. 50. In at least one embodiment, a media pipeline 5116 is optional and may not be explicitly included within GPE 5110. In at least one embodiment, a separate media and/or image processor is coupled to GPE 5110.

In at least one embodiment, GPE 5110 is coupled to or includes a command streamer 5103, which provides a command stream to a 3D pipeline 5112 and/or media pipeline 5116. In at least one embodiment, command streamer 5103 is coupled to memory, which can be system memory, or one or more of internal cache memory and shared cache memory. In at least one embodiment, command streamer 5103 receives commands from memory and sends commands to 3D pipeline 5112 and/or media pipeline 5116. In at least one embodiment, commands are instructions, primitives, or micro-operations fetched from a ring buffer, which stores commands for 3D pipeline 5112 and media pipeline 5116. In at least one embodiment, a ring buffer can additionally include batch command buffers storing batches of multiple commands. In at least one embodiment, commands for 3D pipeline 5112 can also include references to data stored in memory, such as, but not limited to, vertex and geometry data for 3D pipeline 5112 and/or image data and memory objects for media pipeline 5116. In at least one embodiment, 3D pipeline 5112 and media pipeline 5116 process commands and data by performing operations or by dispatching one or more execution threads to a graphics core array 5114. In at least one embodiment, graphics core array 5114 includes one or more blocks of graphics cores (e.g., graphics core(s) 5115A, graphics core(s) 5115B), each block including one or more graphics cores. In at least one embodiment, each graphics core includes a set of graphics execution resources that includes general-purpose and graphics specific execution logic to perform graphics and compute operations, as well as fixed function texture processing and/or machine learning and artificial intelligence acceleration logic, including inference and/or training logic 2915 in FIG. 29A and FIG. 29B.

In at least one embodiment, 3D pipeline 5112 includes fixed function and programmable logic to process one or more shader programs, such as vertex shaders, geometry shaders, pixel shaders, fragment shaders, compute shaders, or other shader programs, by processing instructions and dispatching execution threads to graphics core array 5114. In at least one embodiment, graphics core array 5114 provides a unified block of execution resources for use in processing shader programs. In at least one embodiment, a multi-purpose execution logic (e.g., execution units) within graphics core(s) 5115A-5115B of graphic core array 5114 includes support for various 3D API shader languages and can execute multiple simultaneous execution threads associated with multiple shaders.

In at least one embodiment, graphics core array 5114 also includes execution logic to perform media functions, such as video and/or image processing. In at least one embodiment, execution units additionally include general-purpose logic that is programmable to perform parallel general-purpose computational operations, in addition to graphics processing operations.

In at least one embodiment, output data generated by threads executing on graphics core array 5114 can output data to memory in a unified return buffer (URB) 5118. In at least one embodiment, URB 5118 can store data for multiple threads. In at least one embodiment, URB 5118 may be used to send data between different threads executing on graphics core array 5114. In at least one embodiment, URB 5118 may additionally be used for synchronization between threads on graphics core array 5114 and fixed function logic within shared function logic 5120.

In at least one embodiment, graphics core array 5114 is scalable, such that graphics core array 5114 includes a variable number of graphics cores, each having a variable number of execution units based on a target power and performance level of GPE 5110. In at least one embodiment, execution resources are dynamically scalable, such that execution resources may be enabled or disabled as needed.

In at least one embodiment, graphics core array 5114 is coupled to shared function logic 5120 that includes multiple resources that are shared between graphics cores in graphics core array 5114. In at least one embodiment, shared functions performed by shared function logic 5120 are embodied in hardware logic units that provide specialized supplemental functionality to graphics core array 5114. In at least one embodiment, shared function logic 5120 includes but is not limited to a sampler unit 5121, a math unit 5122, and inter-thread communication (ITC) logic 5123. In at least one embodiment, one or more cache(s) 5125 are included in, or coupled to, shared function logic 5120.

In at least one embodiment, a shared function is used if demand for a specialized function is insufficient for inclusion within graphics core array 5114. In at least one embodiment, a single instantiation of a specialized function is used in shared function logic 5120 and shared among other execution resources within graphics core array 5114. In at least one embodiment, specific shared functions within shared function logic 5120 that are used extensively by graphics core array 5114 may be included within shared function logic 5416 within graphics core array 5114. In at least one embodiment, shared function logic 5416 within graphics core array 5114 can include some or all logic within shared function logic 5120. In at least one embodiment, all logic elements within shared function logic 5120 may be duplicated within shared function logic 5126 of graphics core array 5114. In at least one embodiment, shared function logic 5120 is excluded in favor of shared function logic 5126 within graphics core array 5114.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment portions or all of inference and/or training logic 2915 may be incorporated into graphics processor 5110. For example, in at least one embodiment, training and/or inferencing techniques described herein may use one or more of ALUs embodied in 3D pipeline 5112, graphics core(s) 5115, shared function logic 5126, shared function logic 5120, or other logic in FIG. 51. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs of graphics processor 5110 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics core array 5114. In at least one embodiment, a computer system includes physical memory storing executable instructions that, as a result of being executed by graphics core array 5114, cause a computer system to implement the machine learning systems described herein. In at least one embodiment, graphics core array 5114 may execute instructions that cause a computer system to generate a projection between two latent spaces, for example.

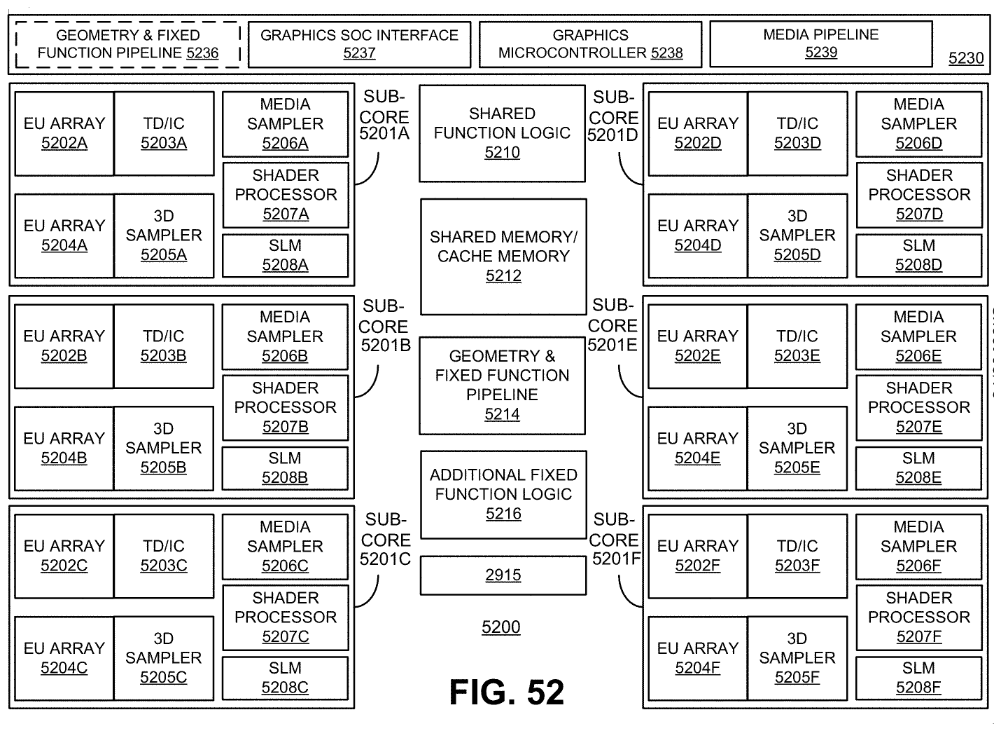

FIG. 52 is a block diagram of hardware logic of a graphics processor core 5200, according to at least one embodiment described herein. In at least one embodiment, graphics processor core 5200 is included within a graphics core array. In at least one embodiment, graphics processor core 5200, sometimes referred to as a core slice, can be one or multiple graphics cores within a modular graphics processor. In at least one embodiment, graphics processor core 5200 is exemplary of one graphics core slice, and a graphics processor as described herein may include multiple graphics core slices based on target power and performance envelopes. In at least one embodiment, each graphics core 5200 can include a fixed function block 5230 coupled with multiple sub-cores 5201A-5201F, also referred to as sub-slices, that include modular blocks of general-purpose and fixed function logic.

In at least one embodiment, fixed function block 5230 includes a geometry and fixed function pipeline 5236 that can be shared by all sub-cores in graphics processor 5200, for example, in lower performance and/or lower power graphics processor implementations. In at least one embodiment, geometry and fixed function pipeline 5236 includes a 3D fixed function pipeline, a video front-end unit, a thread spawner and thread dispatcher, and a unified return buffer manager, which manages unified return buffers.

In at least one embodiment, fixed function block 5230 also includes a graphics SoC interface 5237, a graphics microcontroller 5238, and a media pipeline 5239. In at least one embodiment, graphics SoC interface 5237 provides an interface between graphics core 5200 and other processor cores within a system on a chip integrated circuit. In at least one embodiment, graphics microcontroller 5238 is a programmable sub-processor that is configurable to manage various functions of graphics processor 5200, including thread dispatch, scheduling, and pre-emption. In at least one embodiment, media pipeline 5239 includes logic to facilitate decoding, encoding, pre-processing, and/or post-processing of multimedia data, including image and video data. In at least one embodiment, media pipeline 5239 implements media operations via requests to compute or sampling logic within sub-cores 5201A-5201F.

In at least one embodiment, SoC interface 5237 enables graphics core 5200 to communicate with general-purpose application processor cores (e.g., CPUs) and/or other components within an SoC, including memory hierarchy elements such as a shared last level cache memory, system RAM, and/or embedded on-chip or on-package DRAM. In at least one embodiment, SoC interface 5237 can also enable communication with fixed function devices within an SoC, such as camera imaging pipelines, and enables use of and/or implements global memory atomics that may be shared between graphics core 5200 and CPUs within an SoC. In at least one embodiment, graphics SoC interface 5237 can also implement power management controls for graphics processor core 5200 and enable an interface between a clock domain of graphics processor core 5200 and other clock domains within an SoC. In at least one embodiment, SoC interface 5237 enables receipt of command buffers from a command streamer and global thread dispatcher that are configured to provide commands and instructions to each of one or more graphics cores within a graphics processor. In at least one embodiment, commands and instructions can be dispatched to media pipeline 5239, when media operations are to be performed, or a geometry and fixed function pipeline (e.g., geometry and fixed function pipeline 5236, and/or a geometry and fixed function pipeline 5214) when graphics processing operations are to be performed.

In at least one embodiment, graphics microcontroller 5238 can be configured to perform various scheduling and management tasks for graphics core 5200. In at least one embodiment, graphics microcontroller 5238 can perform graphics and/or compute workload scheduling on various graphics parallel engines within execution unit (EU) arrays 5202A-5202F, 5204A-5204F within sub-cores 5201A-5201F. In at least one embodiment, host software executing on a CPU core of an SoC including graphics core 5200 can submit workloads to one of multiple graphic processor paths, which invokes a scheduling operation on an appropriate graphics engine. In at least one embodiment, scheduling operations include determining which workload to run next, submitting a workload to a command streamer, pre-empting existing workloads running on an engine, monitoring progress of a workload, and notifying host software when a workload is complete. In at least one embodiment, graphics microcontroller 5238 can also facilitate low-power or idle states for graphics core 5200, providing graphics core 5200 with an ability to save and restore registers within graphics core 5200 across low-power state transitions independently from an operating system and/or graphics driver software on a system.

In at least one embodiment, graphics core 5200 may have greater than or fewer than illustrated sub-cores 5201A-5201F, up to N modular sub-cores. For each set of N sub-cores, in at least one embodiment, graphics core 5200 can also include shared function logic 5210, shared and/or cache memory 5212, geometry/fixed function pipeline 5214, as well as additional fixed function logic 5216 to accelerate various graphics and compute processing operations. In at least one embodiment, shared function logic 5210 can include logic units (e.g., sampler, math, and/or inter-thread communication logic) that can be shared by each N sub-cores within graphics core 5200. In at least one embodiment, shared and/or cache memory 5212 can be a last-level cache for N sub-cores 5201A-5201F within graphics core 5200 and can also serve as shared memory that is accessible by multiple sub-cores. In at least one embodiment, geometry/fixed function pipeline 5214 can be included instead of geometry/fixed function pipeline 5236 within fixed function block 5230 and can include similar logic units.

In at least one embodiment, graphics core 5200 includes additional fixed function logic 5216 that can include various fixed function acceleration logic for use by graphics core 5200. In at least one embodiment, additional fixed function logic 5216 includes an additional geometry pipeline for use in position-only shading. In position-only shading, at least two geometry pipelines exist, whereas in a full geometry pipeline within geometry and fixed function pipelines 5214, 5236, and a cull pipeline, which is an additional geometry pipeline that may be included within additional fixed function logic 5216. In at least one embodiment, a cull pipeline is a trimmed down version of a full geometry pipeline. In at least one embodiment, a full pipeline and a cull pipeline can execute different instances of an application, each instance having a separate context. In at least one embodiment, position only shading can hide long cull runs of discarded triangles, enabling shading to be completed earlier in some instances. For example, in at least one embodiment, cull pipeline logic within additional fixed function logic 5216 can execute position shaders in parallel with a main application and generally generates critical results faster than a full pipeline, as a cull pipeline fetches and shades position attributes of vertices, without performing rasterization and rendering of pixels to a frame buffer. In at least one embodiment, a cull pipeline can use generated critical results to compute visibility information for all triangles without regard to whether those triangles are culled. In at least one embodiment, a full pipeline (which in this instance may be referred to as a replay pipeline) can consume visibility information to skip culled triangles to shade only visible triangles that are finally passed to a rasterization phase.

In at least one embodiment, additional fixed function logic 5216 can also include machine-learning acceleration logic, such as fixed function matrix multiplication logic, for implementations including optimizations for machine learning training or inferencing.

In at least one embodiment, within each graphics sub-core 5201A-5201F includes a set of execution resources that may be used to perform graphics, media, and compute operations in response to requests by graphics pipeline, media pipeline, or shader programs. In at least one embodiment, graphics sub-cores 5201A-5201F include multiple EU arrays 5202A-5202F, 5204A-5204F, thread dispatch and inter-thread communication (TD/IC) logic 5203A-5203F, a 3D (e.g., texture) sampler 5205A-5205F, a media sampler 5206A-5206F, a shader processor 5207A-5207F, and shared local memory (SLM) 5208A-5208F. In at least one embodiment, EU arrays 5202A-5202F, 5204A-5204F each include multiple execution units, which are general-purpose graphics processing units capable of performing floating-point and integer/fixed-point logic operations in service of a graphics, media, or compute operation, including graphics, media, or compute shader programs. In at least one embodiment, TD/IC logic 5203A-5203F performs local thread dispatch and thread control operations for execution units within a sub-core and facilitates communication between threads executing on execution units of a sub-core. In at least one embodiment, 3D samplers 5205A-5205F can read texture or other 3D graphics related data into memory. In at least one embodiment, 3D samplers can read texture data differently based on a configured sample state and texture format associated with a given texture. In at least one embodiment, media samplers 5206A-5206F can perform similar read operations based on a type and format associated with media data. In at least one embodiment, each graphics sub-core 5201A-5201F can alternately include a unified 3D and media sampler. In at least one embodiment, threads executing on execution units within each of sub-cores 5201A-5201F can make use of shared local memory 5208A-5208F within each sub-core, to enable threads executing within a thread group to execute using a common pool of on-chip memory.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, portions or all of inference and/or training logic 2915 may be incorporated into graphics processor 5210. For example, in at least one embodiment, training and/or inferencing techniques described herein may use one or more of ALUs embodied in a 3D pipeline, graphics microcontroller 5238, geometry and fixed function pipeline 5214 and 5236, or other logic in FIG. 52. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs of graphics processor 5200 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics core 5200. In at least one embodiment, a computer system includes physical memory storing executable instructions that, as a result of being executed by graphics core 5200, cause a computer system to implement the machine learning systems described herein. In at least one embodiment, graphics core 5200 may execute instructions that cause a computer system to generate a projection between two latent spaces, for example.

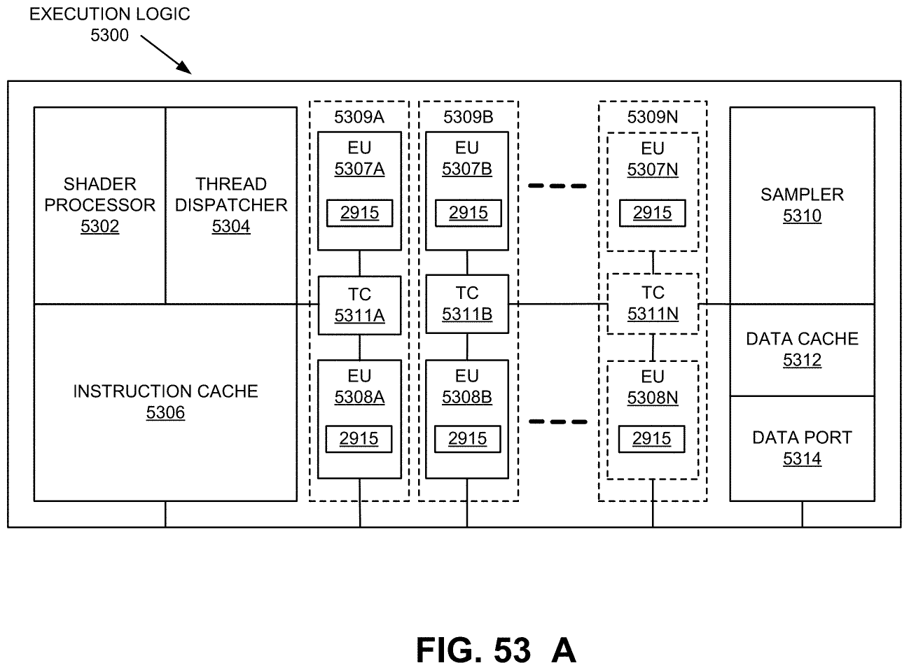

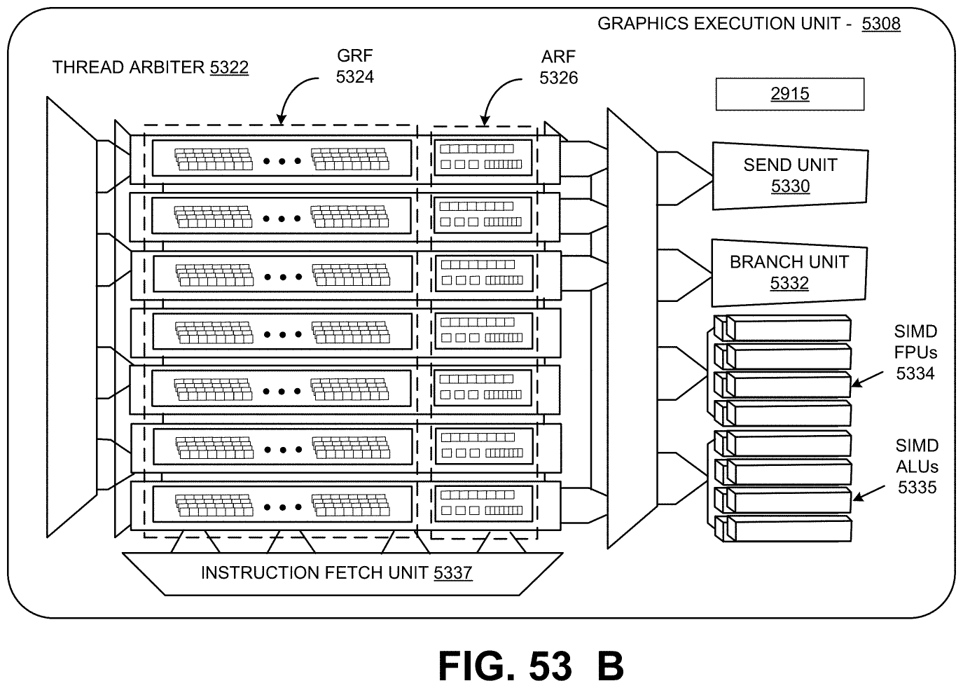

FIGS. 53A-53B illustrate thread execution logic 5300 including an array of processing elements of a graphics processor core according to at least one embodiment. FIG. 53A illustrates at least one embodiment, in which thread execution logic 5300 is used. FIG. 53B illustrates exemplary internal details of a graphics execution unit 5308, according to at least one embodiment.

As illustrated in FIG. 53A, in at least one embodiment, thread execution logic 5300 includes a shader processor 5302, a thread dispatcher 5304, an instruction cache 5306, a scalable execution unit array including a plurality of execution units 5307A-5307N and 5308A-5308N, a sampler 5310, a data cache 5312, and a data port 5314. In at least one embodiment, a scalable execution unit array can dynamically scale by enabling or disabling one or more execution units (e.g., any of execution unit 5308A-N or 5307A-N) based on computational requirements of a workload, for example. In at least one embodiment, scalable execution units are interconnected via an interconnect fabric that links to each execution unit. In at least one embodiment, thread execution logic 5300 includes one or more connections to memory, such as system memory or cache memory, through one or more of instruction cache 5306, data port 5314, sampler 5310, and execution units 5307 or 5308. In at least one embodiment, each execution unit (e.g., 5307A) is a stand-alone programmable general-purpose computational unit that is capable of executing multiple simultaneous hardware threads while processing multiple data elements in parallel for each thread. In at least one embodiment, array of execution units 5307 and/or 5308 is scalable to include any number individual execution units.

In at least one embodiment, execution units 5307 and/or 5308 are primarily used to execute shader programs. In at least one embodiment, shader processor 5302 can process various shader programs and dispatch execution threads associated with shader programs via a thread dispatcher 5304. In at least one embodiment, thread dispatcher 5304 includes logic to arbitrate thread initiation requests from graphics and media pipelines and instantiate requested threads on one or more execution units in execution units 5307 and/or 5308. For example, in at least one embodiment, a geometry pipeline can dispatch vertex, tessellation, or geometry shaders to thread execution logic for processing. In at least one embodiment, thread dispatcher 5304 can also process runtime thread spawning requests from executing shader programs.

In at least one embodiment, execution units 5307 and/or 5308 support an instruction set that includes native support for many standard 3D graphics shader instructions, such that shader programs from graphics libraries (e.g., Direct 3D and OpenGL) are executed with a minimal translation. In at least one embodiment, execution units support vertex and geometry processing (e.g., vertex programs, geometry programs, and/or vertex shaders), pixel processing (e.g., pixel shaders, fragment shaders) and general-purpose processing (e.g., compute and media shaders). In at least one embodiment, each of execution units 5307 and/or 5308, which include one or more arithmetic logic units (ALUs), is capable of multi-issue single instruction multiple data (SIMD) execution and multi-threaded operation enables an efficient execution environment despite higher latency memory accesses. In at least one embodiment, each hardware thread within each execution unit has a dedicated high-bandwidth register file and associated independent thread-state. In at least one embodiment, execution is multi-issue per clock to pipelines capable of integer, single and double precision floating point operations, SIMD branch capability, logical operations, transcendental operations, and other miscellaneous operations. In at least one embodiment, while waiting for data from memory or one of shared functions, dependency logic within execution units 5307 and/or 5308 causes a waiting thread to sleep until requested data has been returned. In at least one embodiment, while an awaiting thread is sleeping, hardware resources may be devoted to processing other threads. For example, in at least one embodiment, during a delay associated with a vertex shader operation, an execution unit can perform operations for a pixel shader, fragment shader, or another type of shader program, including a different vertex shader.

In at least one embodiment, each execution unit in execution units 5307 and/or 5308 operates on arrays of data elements. In at least one embodiment, a number of data elements is an “execution size,” or number of channels for an instruction. In at least one embodiment, an execution channel is a logical unit of execution for data element access, masking, and flow control within instructions. In at least one embodiment, a number of channels may be independent of a number of physical arithmetic logic units (ALUs) or floating point units (FPUs) for a particular graphics processor. In at least one embodiment, execution units 5307 and/or 5308 support integer and floating-point data types.

In at least one embodiment, an execution unit instruction set includes SIMD instructions. In at least one embodiment, various data elements can be stored as a packed data type in a register and execution unit will process various elements based on data size of elements. For example, in at least one embodiment, when operating on a 256-bit wide vector, 256 bits of a vector are stored in a register and an execution unit operates on a vector as four separate 64-bit packed data elements (Quad-Word (QW) size data elements), eight separate 32-bit packed data elements (Double Word (DW) size data elements), sixteen separate 16-bit packed data elements (Word (W) size data elements), or thirty-two separate 8-bit data elements (byte (B) size data elements). However, in at least one embodiment, different vector widths and register sizes are possible.

In at least one embodiment, one or more execution units can be combined into a fused execution unit 5309A-5309N having thread control logic (5311A-5311N) that is common to fused EUs such as execution unit 5307A fused with execution unit 5308A into fused execution unit 5309A. In at least one embodiment, multiple EUs can be fused into an EU group. In at least one embodiment, each EU in a fused EU group can be configured to execute a separate SIMD hardware thread, with a number of EUs in a fused EU group possibly varying according to various embodiments. In at least one embodiment, various SIMD widths can be performed per-EU, including but not limited to SIMD8, SIMD16, and SIMD32. In at least one embodiment, each fused graphics execution unit 5309A-5309N includes at least two execution units. For example, in at least one embodiment, fused execution unit 5309A includes a first EU 5307A, second EU 5308A, and thread control logic 5311A that is common to first EU 5307A and second EU 5308A. In at least one embodiment, thread control logic 5311A controls threads executed on fused graphics execution unit 5309A, allowing each EU within fused execution units 5309A-5309N to execute using a common instruction pointer register.

In at least one embodiment, one or more internal instruction caches (e.g., 5306) are included in thread execution logic 5300 to cache thread instructions for execution units. In at least one embodiment, one or more data caches (e.g., 5312) are included to cache thread data during thread execution. In at least one embodiment, sampler 5310 is included to provide texture sampling for 3D operations and media sampling for media operations. In at least one embodiment, sampler 5310 includes specialized texture or media sampling functionality to process texture or media data during sampling process before providing sampled data to an execution unit.

During execution, in at least one embodiment, graphics and media pipelines send thread initiation requests to thread execution logic 5300 via thread spawning and dispatch logic. In at least one embodiment, once a group of geometric objects has been processed and rasterized into pixel data, pixel processor logic (e.g., pixel shader logic, fragment shader logic, etc.) within shader processor 5302 is invoked to further compute output information and cause results to be written to output surfaces (e.g., color buffers, depth buffers, stencil buffers, etc.). In at least one embodiment, a pixel shader or a fragment shader calculates values of various vertex attributes that are to be interpolated across a rasterized object. In at least one embodiment, pixel processor logic within shader processor 5302 then executes an application programming interface (API)-supplied pixel or fragment shader program. In at least one embodiment, to execute a shader program, shader processor 5302 dispatches threads to an execution unit (e.g., 5308A) via thread dispatcher 5304. In at least one embodiment, shader processor 5302 uses texture sampling logic in sampler 5310 to access texture data in texture maps stored in memory. In at least one embodiment, arithmetic operations on texture data and input geometry data compute pixel color data for each geometric fragment, or discards one or more pixels from further processing.

In at least one embodiment, data port 5314 provides a memory access mechanism for thread execution logic 5300 to output processed data to memory for further processing on a graphics processor output pipeline. In at least one embodiment, data port 5314 includes or couples to one or more cache memories (e.g., data cache 5312) to cache data for memory access via a data port.

As illustrated in FIG. 53B, in at least one embodiment, a graphics execution unit 5308 can include an instruction fetch unit 5337, a general register file array (GRF) 5324, an architectural register file array (ARF) 5326, a thread arbiter 5322, a send unit 5330, a branch unit 5332, a set of SIMD floating point units (FPUs) 5334, and a set of dedicated integer SIMD ALUs 5335. In at least one embodiment, GRF 5324 and ARF 5326 includes a set of general register files and architecture register files associated with each simultaneous hardware thread that may be active in graphics execution unit 5308. In at least one embodiment, per thread architectural state is maintained in ARF 5326, while data used during thread execution is stored in GRF 5324. In at least one embodiment, execution state of each thread, including instruction pointers for each thread, can be held in thread-specific registers in ARF 5326.

In at least one embodiment, graphics execution unit 5308 has an architecture that is a combination of Simultaneous Multi-Threading (SMT) and fine-grained Interleaved Multi-Threading (IMT). In at least one embodiment, architecture has a modular configuration that can be fine-tuned at design time based on a target number of simultaneous threads and number of registers per execution unit, where execution unit resources are divided across logic used to execute multiple simultaneous threads.

In at least one embodiment, graphics execution unit 5308 can co-issue multiple instructions, which may each be different instructions. In at least one embodiment, thread arbiter 5322 of graphics execution unit thread 5308 can dispatch instructions to one of send unit 5330, branch unit 5332, or SIMD FPU(s) 5334 for execution. In at least one embodiment, each execution thread can access 128 general-purpose registers within GRF 5324, where each register can store 32 bytes, accessible as a SIMD 8-element vector of 32-bit data elements. In at least one embodiment, each execution unit thread has access to 4 kilobytes within GRF 5324, although embodiments are not so limited, and greater or fewer register resources may be provided in other embodiments. In at least one embodiment, up to seven threads can execute simultaneously, although a number of threads per execution unit can also vary according to embodiments. In at least one embodiment, in which seven threads may access 4 kilobytes, GRF 5324 can store a total of 28 kilobytes. In at least one embodiment, flexible addressing modes can permit registers to be addressed together to build effectively wider registers or to represent strided rectangular block data structures.

In at least one embodiment, memory operations, sampler operations, and other longer-latency system communications are dispatched via “send” instructions that are executed by message passing to send unit 5330. In at least one embodiment, branch instructions are dispatched to branch unit 5332 to facilitate SIMD divergence and eventual convergence.

In at least one embodiment, graphics execution unit 5308 includes one or more SIMD floating point units (FPU(s)) 5334 to perform floating-point operations. In at least one embodiment, FPU(s) 5334 also support integer computation. In at least one embodiment, FPU(s) 5334 can SIMD execute up to M number of 32-bit floating-point (or integer) operations, or SIMD execute up to 2M 16-bit integer or 16-bit floating-point operations. In at least one embodiment, at least one FPU provides extended math capability to support high-throughput transcendental math functions and double precision 64-bit floating-point. In at least one embodiment, a set of 8-bit integer SIMD ALUs 5335 are also present, and may be specifically optimized to perform operations associated with machine learning computations.

In at least one embodiment, arrays of multiple instances of graphics execution unit 5308 can be instantiated in a graphics sub-core grouping (e.g., a sub-slice). In at least one embodiment, execution unit 5308 can execute instructions across a plurality of execution channels. In at least one embodiment, each thread executed on graphics execution unit 5308 is executed on a different channel.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, portions or all of inference and/or training logic 2915 may be incorporated into thread execution logic 5300. Moreover, in at least one embodiment, inferencing and/or training operations described herein may be done using logic other than logic illustrated in FIG. 29A or 29B. In at least one embodiment, weight parameters may be stored in on-chip or off-chip memory and/or registers (shown or not shown) that configure ALUs thread of execution logic 5300 to perform one or more machine learning algorithms, neural network architectures, use cases, or training techniques described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as graphics execution unit 5308. In at least one embodiment, a computer system includes physical memory storing executable instructions that, as a result of being executed by graphics execution unit 5308, cause a computer system to implement the machine learning systems described herein. In at least one embodiment, graphics execution unit 5308 may execute instructions that cause a computer system to generate a projection between two latent spaces, for example.

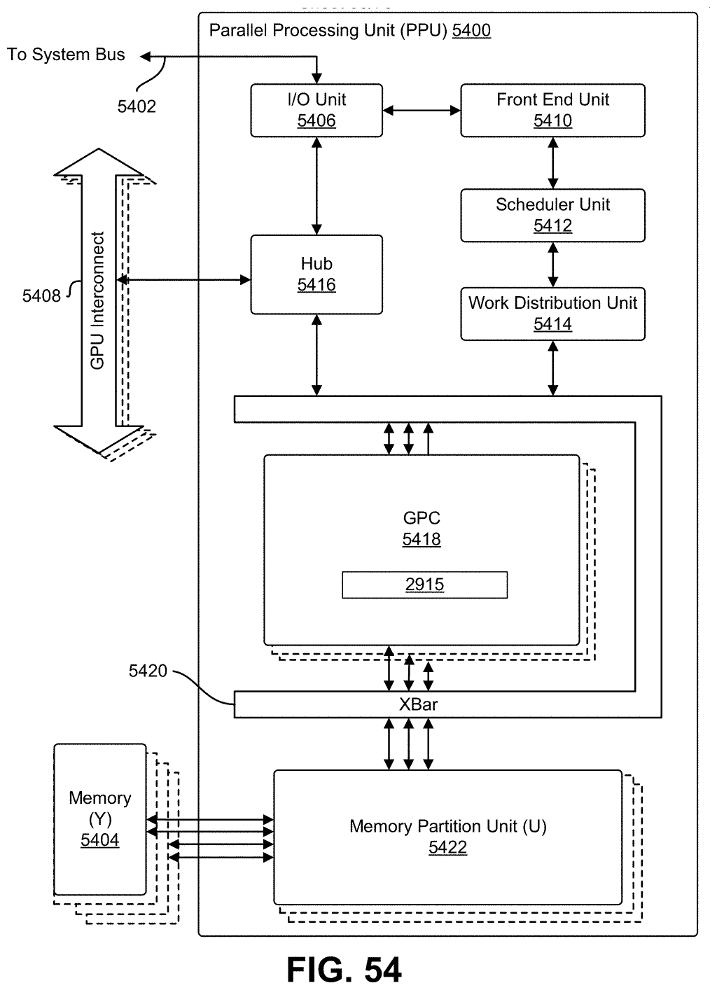

FIG. 54 illustrates a parallel processing unit (“PPU”) 5400, according to at least one embodiment. In at least one embodiment, PPU 5400 is configured with machine-readable code that, if executed by PPU 5400, causes PPU 5400 to perform some or all of processes and techniques described throughout this disclosure. In at least one embodiment, PPU 5400 is a multi-threaded processor that is implemented on one or more integrated circuit devices and that utilizes multithreading as a latency-hiding technique designed to process computer-readable instructions (also referred to as machine-readable instructions or simply instructions) on multiple threads in parallel. In at least one embodiment, a thread refers to a thread of execution and is an instantiation of a set of instructions configured to be executed by PPU 5400. In at least one embodiment, PPU 5400 is a graphics processing unit (“GPU”) configured to implement a graphics rendering pipeline for processing three-dimensional (“3D”) graphics data in order to generate two-dimensional (“2D”) image data for display on a display device such as a liquid crystal display (“LCD”) device. In at least one embodiment, PPU 5400 is utilized to perform computations such as linear algebra operations and machine-learning operations. FIG. 54 illustrates an example parallel processor for illustrative purposes only and should be construed as a non-limiting example of processor architectures contemplated within scope of this disclosure and that any suitable processor may be employed to supplement and/or substitute for same.

In at least one embodiment, one or more PPUs 5400 are configured to accelerate High Performance Computing (“HPC”), data center, and machine learning applications. In at least one embodiment, PPU 5400 is configured to accelerate deep learning systems and applications including following non-limiting examples: autonomous vehicle platforms, deep learning, high-accuracy speech, image, text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and more.

In at least one embodiment, PPU 5400 includes, without limitation, an Input/Output (“I/O”) unit 5406, a front-end unit 5410, a scheduler unit 5412, a work distribution unit 5414, a hub 5416, a crossbar (“XBar”) 5420, one or more general processing clusters (“GPCs”) 5418, and one or more partition units (“memory partition units”) 5422. In at least one embodiment, PPU 5400 is connected to a host processor or other PPUs 5400 via one or more high-speed GPU interconnects (“GPU interconnects”) 5408. In at least one embodiment, PPU 5400 is connected to a host processor or other peripheral devices via a system bus 5402. In at least one embodiment, PPU 5400 is connected to a local memory comprising one or more memory devices (“memory”) 5404. In at least one embodiment, memory devices 5404 include, without limitation, one or more dynamic random access memory (“DRAM”) devices. In at least one embodiment, one or more DRAM devices are configured and/or configurable as high-bandwidth memory (“HBM”) subsystems, with multiple DRAM dies stacked within each device.

In at least one embodiment, high-speed GPU interconnect 5408 may refer to a wire-based multi-lane communications link that is used by systems to scale and include one or more PPUs 5400 combined with one or more central processing units (“CPUs”), supports cache coherence between PPUs 5400 and CPUs, and CPU mastering. In at least one embodiment, data and/or commands are transmitted by high-speed GPU interconnect 5408 through hub 5416 to/from other units of PPU 5400 such as one or more copy engines, video encoders, video decoders, power management units, and other components which may not be explicitly illustrated in FIG. 54.

In at least one embodiment, I/O unit 5406 is configured to transmit and receive communications (e.g., commands, data) from a host processor (not illustrated in FIG. 54) over system bus 5402. In at least one embodiment, I/O unit 5406 communicates with host processor directly via system bus 5402 or through one or more intermediate devices such as a memory bridge. In at least one embodiment, I/O unit 5406 may communicate with one or more other processors, such as one or more of PPUs 5400 via system bus 5402. In at least one embodiment, I/O unit 5406 implements a Peripheral Component Interconnect Express (“PCIe”) interface for communications over a PCIe bus. In at least one embodiment, I/O unit 5406 implements interfaces for communicating with external devices.

In at least one embodiment, I/O unit 5406 decodes packets received via system bus 5402. In at least one embodiment, at least some packets represent commands configured to cause PPU 5400 to perform various operations. In at least one embodiment, I/O unit 5406 transmits decoded commands to various other units of PPU 5400 as specified by commands. In at least one embodiment, commands are transmitted to front-end unit 5410 and/or transmitted to hub 5416 or other units of PPU 5400 such as one or more copy engines, a video encoder, a video decoder, a power management unit, etc. (not explicitly illustrated in FIG. 54). In at least one embodiment, I/O unit 5406 is configured to route communications between and among various logical units of PPU 5400.

In at least one embodiment, a program executed by host processor encodes a command stream in a buffer that provides workloads to PPU 5400 for processing. In at least one embodiment, a workload comprises instructions and data to be processed by those instructions. In at least one embodiment, a buffer is a region in a memory that is accessible (e.g., read/write) by both a host processor and PPU 5400—a host interface unit may be configured to access that buffer in a system memory connected to system bus 5402 via memory requests transmitted over system bus 5402 by I/O unit 5406. In at least one embodiment, a host processor writes a command stream to a buffer and then transmits a pointer to a start of a command stream to PPU 5400 such that front-end unit 5410 receives pointers to one or more command streams and manages one or more command streams, reading commands from command streams and forwarding commands to various units of PPU 5400.

In at least one embodiment, front-end unit 5410 is coupled to scheduler unit 5412 that configures various GPCs 5418 to process tasks defined by one or more command streams. In at least one embodiment, scheduler unit 5412 is configured to track state information related to various tasks managed by scheduler unit 5412 where state information may indicate which of GPCs 5418 a task is assigned to, whether task is active or inactive, a priority level associated with task, and so forth. In at least one embodiment, scheduler unit 5412 manages execution of a plurality of tasks on one or more of GPCs 5418.

In at least one embodiment, scheduler unit 5412 is coupled to work distribution unit 5414 that is configured to dispatch tasks for execution on GPCs 5418. In at least one embodiment, work distribution unit 5414 tracks a number of scheduled tasks received from scheduler unit 5412 and work distribution unit 5414 manages a pending task pool and an active task pool for each of GPCs 5418. In at least one embodiment, pending task pool comprises a number of slots (e.g., 32 slots) that contain tasks assigned to be processed by a particular GPC 5418; an active task pool may comprise a number of slots (e.g., 4 slots) for tasks that are actively being processed by GPCs 5418 such that as one of GPCs 5418 completes execution of a task, that task is evicted from that active task pool for GPC 5418 and another task from a pending task pool is selected and scheduled for execution on GPC 5418. In at least one embodiment, if an active task is idle on GPC 5418, such as while waiting for a data dependency to be resolved, then that active task is evicted from GPC 5418 and returned to that pending task pool while another task in that pending task pool is selected and scheduled for execution on GPC 5418.

In at least one embodiment, work distribution unit 5414 communicates with one or more GPCs 5418 via XBar 5420. In at least one embodiment, XBar 5420 is an interconnect network that couples many of units of PPU 5400 to other units of PPU 5400 and can be configured to couple work distribution unit 5414 to a particular GPC 5418. In at least one embodiment, one or more other units of PPU 5400 may also be connected to XBar 5420 via hub 5416.

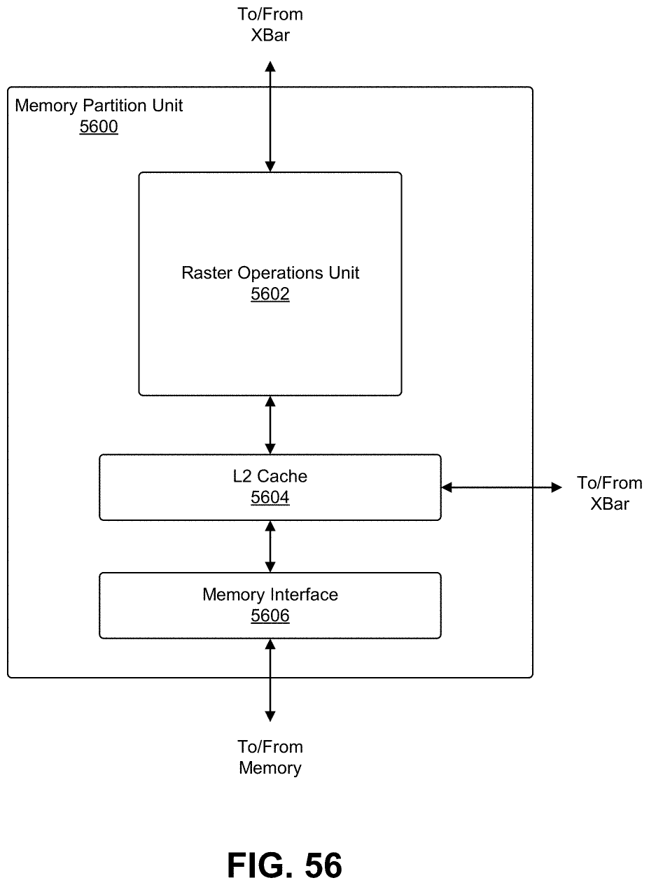

In at least one embodiment, tasks are managed by scheduler unit 5412 and dispatched to one of GPCs 5418 by work distribution unit 5414. In at least one embodiment, GPC 5418 is configured to process task and generate results. In at least one embodiment, results may be consumed by other tasks within GPC 5418, routed to a different GPC 5418 via XBar 5420, or stored in memory 5404. In at least one embodiment, results can be written to memory 5404 via partition units 5422, which implement a memory interface for reading and writing data to/from memory 5404. In at least one embodiment, results can be transmitted to another PPU 5404 or CPU via high-speed GPU interconnect 5408. In at least one embodiment, PPU 5400 includes, without limitation, a number U of partition units 5422 that is equal to a number of separate and distinct memory devices 5404 coupled to PPU 5400, as described in more detail herein in conjunction with FIG. 56.

In at least one embodiment, a host processor executes a driver kernel that implements an application programming interface (“API”) that enables one or more applications executing on a host processor to schedule operations for execution on PPU 5400. In at least one embodiment, multiple compute applications are simultaneously executed by PPU 5400 and PPU 5400 provides isolation, quality of service (“QoS”), and independent address spaces for multiple compute applications. In at least one embodiment, an application generates instructions (e.g., in form of API calls) that cause a driver kernel to generate one or more tasks for execution by PPU 5400 and that driver kernel outputs tasks to one or more streams being processed by PPU 5400. In at least one embodiment, each task comprises one or more groups of related threads, which may be referred to as a warp. In at least one embodiment, a warp comprises a plurality of related threads (e.g., 32 threads) that can be executed in parallel. In at least one embodiment, cooperating threads can refer to a plurality of threads including instructions to perform task and that exchange data through shared memory. In at least one embodiment, threads and cooperating threads are described in more detail in conjunction with FIG. 56.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, deep learning application processor is used to train a machine learning model, such as a neural network, to predict or infer information provided to PPU 5400. In at least one embodiment, deep learning application processor 5400 is used to infer or predict information based on a trained machine learning model (e.g., neural network) that has been trained by another processor or system or by PPU 5400. In at least one embodiment, PPU 5400 may be used to perform one or more neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as PPU 5400. In at least one embodiment, a computer system includes physical memory storing executable instructions that, as a result of being executed by PPU 5400, cause a computer system to implement the machine learning systems described herein. In at least one embodiment, PPU 5400 may execute instructions that cause a computer system to generate a projection between two latent spaces, for example.

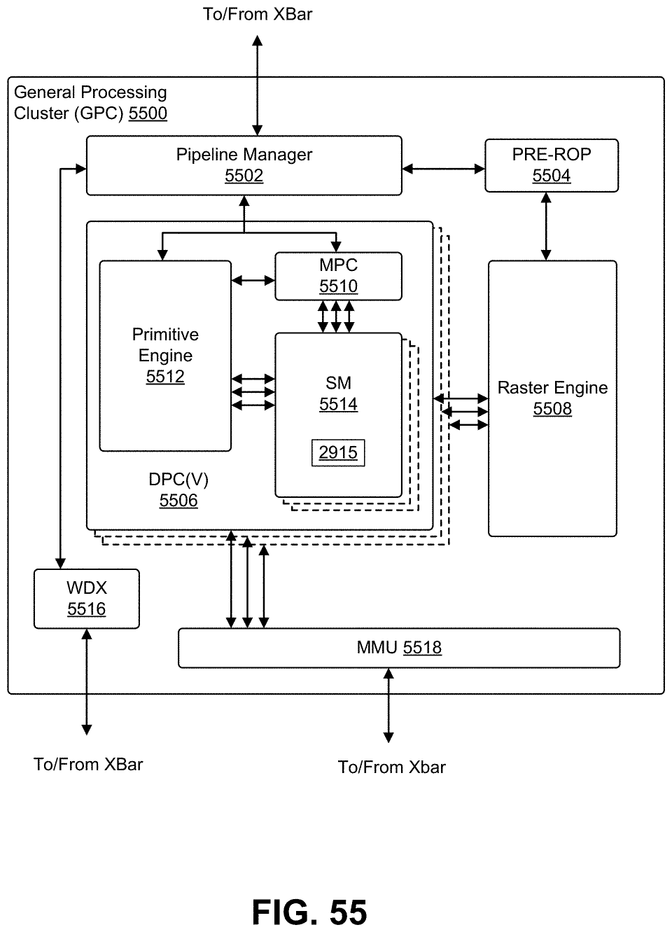

FIG. 55 illustrates a general processing cluster (“GPC”) 5500, according to at least one embodiment. In at least one embodiment, GPC 5500 is GPC 5418 of FIG. 54. In at least one embodiment, each GPC 5500 includes, without limitation, a number of hardware units for processing tasks and each GPC 5500 includes, without limitation, a pipeline manager 5502, a pre-raster operations unit (“preROP”) 5504, a raster engine 5508, a work distribution crossbar (“WDX”) 5516, a memory management unit (“MMU”) 5518, one or more Data Processing Clusters (“DPCs”) 5506, and any suitable combination of parts.

In at least one embodiment, operation of GPC 5500 is controlled by pipeline manager 5502. In at least one embodiment, pipeline manager 5502 manages configuration of one or more DPCs 5506 for processing tasks allocated to GPC 5500. In at least one embodiment, pipeline manager 5502 configures at least one of one or more DPCs 5506 to implement at least a portion of a graphics rendering pipeline. In at least one embodiment, DPC 5506 is configured to execute a vertex shader program on a programmable streaming multi-processor (“SM”) 5514. In at least one embodiment, pipeline manager 5502 is configured to route packets received from a work distribution unit to appropriate logical units within GPC 5500, in at least one embodiment, and some packets may be routed to fixed function hardware units in preROP 5504 and/or raster engine 5508 while other packets may be routed to DPCs 5506 for processing by a primitive engine 5512 or SM 5514. In at least one embodiment, pipeline manager 5502 configures at least one of DPCs 5506 to implement a neural network model and/or a computing pipeline.

In at least one embodiment, preROP unit 5504 is configured, in at least one embodiment, to route data generated by raster engine 5508 and DPCs 5506 to a Raster Operations (“ROP”) unit in partition unit 5422, described in more detail above in conjunction with FIG. 54. In at least one embodiment, preROP unit 5504 is configured to perform optimizations for color blending, organize pixel data, perform address translations, and more. In at least one embodiment, raster engine 5508 includes, without limitation, a number of fixed function hardware units configured to perform various raster operations, in at least one embodiment, and raster engine 5508 includes, without limitation, a setup engine, a coarse raster engine, a culling engine, a clipping engine, a fine raster engine, a tile coalescing engine, and any suitable combination thereof. In at least one embodiment, setup engine receives transformed vertices and generates plane equations associated with geometric primitive defined by vertices; plane equations are transmitted to a coarse raster engine to generate coverage information (e.g., an x, y coverage mask for a tile) for primitive; output of a coarse raster engine is transmitted to a culling engine where fragments associated with a primitive that fail a z-test are culled, and transmitted to a clipping engine where fragments lying outside a viewing frustum are clipped. In at least one embodiment, fragments that survive clipping and culling are passed to a fine raster engine to generate attributes for pixel fragments based on plane equations generated by a setup engine. In at least one embodiment, an output of raster engine 5508 comprises fragments to be processed by any suitable entity, such as by a fragment shader implemented within DPC 5506.

In at least one embodiment, each DPC 5506 included in GPC 5500 comprises, without limitation, an M-Pipe Controller (“MPC”) 5510; primitive engine 5512; one or more SMs 5514; and any suitable combination thereof. In at least one embodiment, MPC 5510 controls operation of DPC 5506, routing packets received from pipeline manager 5502 to appropriate units in DPC 5506. In at least one embodiment, packets associated with a vertex are routed to primitive engine 5512, which is configured to fetch vertex attributes associated with a vertex from memory; in contrast, packets associated with a shader program may be transmitted to SM 5514.

In at least one embodiment, SM 5514 comprises, without limitation, a programmable streaming processor that is configured to process tasks represented by a number of threads. In at least one embodiment, SM 5514 is multi-threaded and configured to execute a plurality of threads (e.g., 32 threads) from a particular group of threads concurrently and implements a Single-Instruction, Multiple-Data (“SIMD”) architecture where each thread in a group of threads (e.g., a warp) is configured to process a different set of data based on same set of instructions. In at least one embodiment, all threads in group of threads execute a common set of instructions. In at least one embodiment, SM 5514 implements a Single-Instruction, Multiple Thread (“SIMM”) architecture wherein each thread in a group of threads is configured to process a different set of data based on that common set of instructions, but where individual threads in a group of threads are allowed to diverge during execution. In at least one embodiment, a program counter, call stack, and execution state is maintained for each warp, enabling concurrency between warps and serial execution within warps when threads within a warp diverge. In another embodiment, a program counter, call stack, and execution state is maintained for each individual thread, enabling equal concurrency between all threads, within and between warps. In at least one embodiment, execution state is maintained for each individual thread and threads executing common instructions may be converged and executed in parallel for better efficiency. At least one embodiment of SM 5514 is described in more detail herein.

In at least one embodiment, MMU 5518 provides an interface between GPC 5500 and a memory partition unit (e.g., partition unit 5422 of FIG. 54) and MMU 5518 provides translation of virtual addresses into physical addresses, memory protection, and arbitration of memory requests. In at least one embodiment, MMU 5518 provides one or more translation lookaside buffers (“TLBs”) for performing translation of virtual addresses into physical addresses in memory.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, deep learning application processor is used to train a machine learning model, such as a neural network, to predict or infer information provided to GPC 5500. In at least one embodiment, GPC 5500 is used to infer or predict information based on a trained machine learning model (e.g., neural network) that has been trained by another processor or system or by GPC 5500. In at least one embodiment, GPC 5500 may be used to perform one or more neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as PPU 5400. In at least one embodiment, a computer system includes physical memory storing executable instructions that, as a result of being executed by PPU 5400, cause a computer system to implement the machine learning systems described herein. In at least one embodiment, PPU 5400 may execute instructions that cause a computer system to generate a projection between two latent spaces, for example.

FIG. 56 illustrates a memory partition unit 5600 of a parallel processing unit (“PPU”), in accordance with at least one embodiment. In at least one embodiment, memory partition unit 5600 includes, without limitation, a Raster Operations (“ROP”) unit 5602, a level two (“L2”) cache 5604, a memory interface 5606, and any suitable combination thereof. In at least one embodiment, memory interface 5606 is coupled to memory. In at least one embodiment, memory interface 5606 may implement 32, 64, 128, 1024-bit data buses, or like, for high-speed data transfer. In at least one embodiment, PPU incorporates U memory interfaces 5606 where U is a positive integer, with one memory interface 5606 per pair of partition units 5600, where each pair of partition units 5600 is connected to a corresponding memory device. For example, in at least one embodiment, PPU may be connected to up to Y memory devices, such as high bandwidth memory stacks or graphics double-data-rate, version 5, synchronous dynamic random access memory (“GDDR5 SDRAM”).

In at least one embodiment, memory interface 5606 implements a high bandwidth memory second generation (“HBM2”) memory interface and Y equals half of U. In at least one embodiment, HBM2 memory stacks are located on a physical package with a PPU, providing substantial power and area savings compared with conventional GDDR5 SDRAM systems. In at least one embodiment, each HBM2 stack includes, without limitation, four memory dies with Y=4, with each HBM2 stack including two 128-bit channels per die for a total of 8 channels and a data bus width of 1024 bits. In at least one embodiment, that memory supports Single-Error Correcting Double-Error Detecting (“SECDED”) Error Correction Code (“ECC”) to protect data. In at least one embodiment, ECC can provide higher reliability for compute applications that are sensitive to data corruption.

In at least one embodiment, PPU implements a multi-level memory hierarchy. In at least one embodiment, memory partition unit 5600 supports a unified memory to provide a single unified virtual address space for central processing unit (“CPU”) and PPU memory, enabling data sharing between virtual memory systems. In at least one embodiment frequency of accesses by a PPU to a memory located on other processors is traced to ensure that memory pages are moved to physical memory of PPU that is accessing pages more frequently. In at least one embodiment, high-speed GPU interconnect 5408 supports address translation services allowing PPU to directly access a CPU's page tables and providing full access to CPU memory by a PPU.

In at least one embodiment, copy engines transfer data between multiple PPUs or between PPUs and CPUs. In at least one embodiment, copy engines can generate page faults for addresses that are not mapped into page tables and memory partition unit 5600 then services page faults, mapping addresses into page table, after which copy engine performs a transfer. In at least one embodiment, memory is pinned (i.e., non-pageable) for multiple copy engine operations between multiple processors, substantially reducing available memory. In at least one embodiment, with hardware page faulting, addresses can be passed to copy engines without regard as to whether memory pages are resident, and a copy process is transparent.

Data from memory 5404 of FIG. 54 or other system memory is fetched by memory partition unit 5600 and stored in L2 cache 5604, which is located on-chip and is shared between various GPCs, in accordance with at least one embodiment. Each memory partition unit 5600, in at least one embodiment, includes, without limitation, at least a portion of L2 cache associated with a corresponding memory device. In at least one embodiment, lower level caches are implemented in various units within GPCs. In at least one embodiment, each of SMs 5514 in FIG. 55 may implement a Level 1 (“L1”) cache wherein that L1 cache is private memory that is dedicated to a particular SM 5514 and data from L2 cache 5604 is fetched and stored in each L1 cache for processing in functional units of SMs 5514. In at least one embodiment, L2 cache 5604 is coupled to memory interface 5606 and XBar 5420 shown in FIG. 54.

ROP unit 5602 performs graphics raster operations related to pixel color, such as color compression, pixel blending, and more, in at least one embodiment. ROP unit 5602, in at least one embodiment, implements depth testing in conjunction with raster engine 5508, receiving a depth for a sample location associated with a pixel fragment from a culling engine of raster engine 5508. In at least one embodiment, depth is tested against a corresponding depth in a depth buffer for a sample location associated with a fragment. In at least one embodiment, if that fragment passes that depth test for that sample location, then ROP unit 5602 updates depth buffer and transmits a result of that depth test to raster engine 5508. It will be appreciated that a number of partition units 5600 may be different than a number of GPCs and, therefore, each ROP unit 5602 can, in at least one embodiment, be coupled to each GPC. In at least one embodiment, ROP unit 5602 tracks packets received from different GPCs and determines whether a result generated by ROP unit 5602 is to be routed to through XBar 5420.

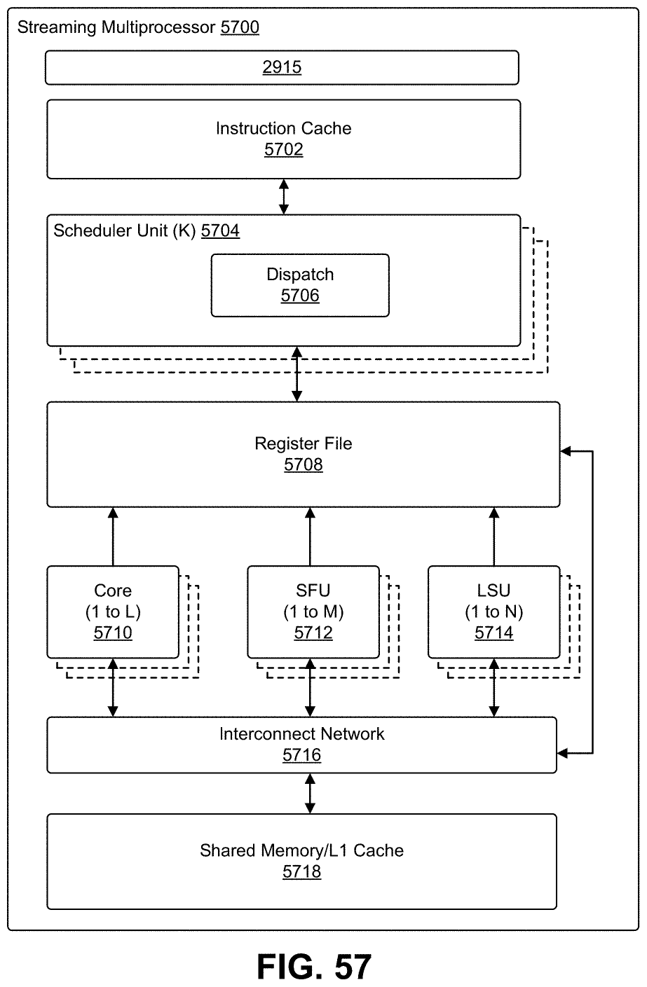

FIG. 57 illustrates a streaming multi-processor (“SM”) 5700, according to at least one embodiment. In at least one embodiment, SM 5700 is SM of FIG. 55. In at least one embodiment, SM 5700 includes, without limitation, an instruction cache 5702, one or more scheduler units 5704, a register file 5708, one or more processing cores (“cores”) 5710, one or more special function units (“SFUs”) 5712, one or more load/store units (“LSUs”) 5714, an interconnect network 5716, a shared memory/level one (“L1”) cache 5718, and/or any suitable combination thereof.

In at least one embodiment, a work distribution unit dispatches tasks for execution on general processing clusters (“GPCs”) of parallel processing units (“PPUs”) and each task is allocated to a particular Data Processing Cluster (“DPC”) within a GPC and, if a task is associated with a shader program, that task is allocated to one of SMs 5700. In at least one embodiment, scheduler unit 5704 receives tasks from a work distribution unit and manages instruction scheduling for one or more thread blocks assigned to SM 5700. In at least one embodiment, scheduler unit 5704 schedules thread blocks for execution as warps of parallel threads, wherein each thread block is allocated at least one warp. In at least one embodiment, each warp executes threads. In at least one embodiment, scheduler unit 5704 manages a plurality of different thread blocks, allocating warps to different thread blocks and then dispatching instructions from plurality of different cooperative groups to various functional units (e.g., processing cores 5710, SFUs 5712, and LSUs 5714) during each clock cycle.

In at least one embodiment, Cooperative Groups may refer to a programming model for organizing groups of communicating threads that allows developers to express granularity at which threads are communicating, enabling expression of richer, more efficient parallel decompositions. In at least one embodiment, cooperative launch APIs support synchronization amongst thread blocks for execution of parallel algorithms. In at least one embodiment, applications of conventional programming models provide a single, simple construct for synchronizing cooperating threads: a barrier across all threads of a thread block (e.g., syncthreads( ) function). However, in at least one embodiment, programmers may define groups of threads at smaller than thread block granularities and synchronize within defined groups to enable greater performance, design flexibility, and software reuse in form of collective group-wide function interfaces. In at least one embodiment, Cooperative Groups enables programmers to define groups of threads explicitly at sub-block (i.e., as small as a single thread) and multi-block granularities, and to perform collective operations such as synchronization on threads in a cooperative group. In at least one embodiment, that programming model supports clean composition across software boundaries, so that libraries and utility functions can synchronize safely within their local context without having to make assumptions about convergence. In at least one embodiment, Cooperative Groups primitives enable new patterns of cooperative parallelism, including, without limitation, producer-consumer parallelism, opportunistic parallelism, and global synchronization across an entire grid of thread blocks.

In at least one embodiment, a dispatch unit 5706 is configured to transmit instructions to one or more functional units and scheduler unit 5704 and includes, without limitation, two dispatch units 5706 that enable two different instructions from a common warp to be dispatched during each clock cycle. In at least one embodiment, each scheduler unit 5704 includes a single dispatch unit 5706 or additional dispatch units 5706.

In at least one embodiment, each SM 5700, in at least one embodiment, includes, without limitation, register file 5708 that provides a set of registers for functional units of SM 5700. In at least one embodiment, register file 5708 is divided between each functional unit such that each functional unit is allocated a dedicated portion of register file 5708. In at least one embodiment, register file 5708 is divided between different warps being executed by SM 5700 and register file 5708 provides temporary storage for operands connected to data paths of functional units. In at least one embodiment, each SM 5700 comprises, without limitation, a plurality of L processing cores 5710, where L is a positive integer. In at least one embodiment, SM 5700 includes, without limitation, a large number (e.g., 128 or more) of distinct processing cores 5710. In at least one embodiment, each processing core 5710 includes, without limitation, a fully-pipelined, single-precision, double-precision, and/or mixed precision processing unit that includes, without limitation, a floating point arithmetic logic unit and an integer arithmetic logic unit. In at least one embodiment, floating point arithmetic logic units implement IEEE 754-2008 standard for floating point arithmetic. In at least one embodiment, processing cores 5710 include, without limitation, 64 single-precision (32-bit) floating point cores, 64 integer cores, 32 double-precision (64-bit) floating point cores, and 8 tensor cores.

Tensor cores are configured to perform matrix operations in accordance with at least one embodiment. In at least one embodiment, one or more tensor cores are included in processing cores 5710. In at least one embodiment, tensor cores are configured to perform deep learning matrix arithmetic, such as convolution operations for neural network training and inferencing. In at least one embodiment, each tensor core operates on a 4×4 matrix and performs a matrix multiply and accumulate operation, D=A×B+C, where A, B, C, and D are 4×4 matrices.

In at least one embodiment, matrix multiply inputs A and B are 16-bit floating point matrices and accumulation matrices C and D are 16-bit floating point or 32-bit floating point matrices. In at least one embodiment, tensor cores operate on 16-bit floating point input data with 32-bit floating point accumulation. In at least one embodiment, 16-bit floating point multiply uses 64 operations and results in a full precision product that is then accumulated using 32-bit floating point addition with other intermediate products for a 4×4×4 matrix multiply. Tensor cores are used to perform much larger two-dimensional or higher dimensional matrix operations, built up from these smaller elements, in at least one embodiment. In at least one embodiment, an API, such as a CUDA 9 C++ API, exposes specialized matrix load, matrix multiply and accumulate, and matrix store operations to efficiently use tensor cores from a CUDA-C++ program. In at least one embodiment, at a CUDA level, a warp-level interface assumes 16×16 size matrices spanning all 32 threads of warp.

In at least one embodiment, each SM 5700 comprises, without limitation, M SFUs 5712 that perform special functions (e.g., attribute evaluation, reciprocal square root, and like). In at least one embodiment, SFUs 5712 include, without limitation, a tree traversal unit configured to traverse a hierarchical tree data structure. In at least one embodiment, SFUs 5712 include, without limitation, a texture unit configured to perform texture map filtering operations. In at least one embodiment, texture units are configured to load texture maps (e.g., a 2D array of texels) from memory and sample texture maps to produce sampled texture values for use in shader programs executed by SM 5700. In at least one embodiment, texture maps are stored in shared memory/L1 cache 5718. In at least one embodiment, texture units implement texture operations such as filtering operations using mip-maps (e.g., texture maps of varying levels of detail), in accordance with at least one embodiment. In at least one embodiment, each SM 5700 includes, without limitation, two texture units.

Each SM 5700 comprises, without limitation, N LSUs 5714 that implement load and store operations between shared memory/L1 cache 5718 and register file 5708, in at least one embodiment. Interconnect network 5716 connects each functional unit to register file 5708 and LSU 5714 to register file 5708 and shared memory/L1 cache 5718 in at least one embodiment. In at least one embodiment, interconnect network 5716 is a crossbar that can be configured to connect any functional units to any registers in register file 5708 and connect LSUs 5714 to register file 5708 and memory locations in shared memory/L1 cache 5718.

In at least one embodiment, shared memory/L1 cache 5718 is an array of on-chip memory that allows for data storage and communication between SM 5700 and primitive engine and between threads in SM 5700, in at least one embodiment. In at least one embodiment, shared memory/L1 cache 5718 comprises, without limitation, 128 KB of storage capacity and is in a path from SM 5700 to a partition unit. In at least one embodiment, shared memory/L1 cache 5718, in at least one embodiment, is used to cache reads and writes. In at least one embodiment, one or more of shared memory/L1 cache 5718, L2 cache, and memory are backing stores.

Combining data cache and shared memory functionality into a single memory block provides improved performance for both types of memory accesses, in at least one embodiment. In at least one embodiment, capacity is used or is usable as a cache by programs that do not use shared memory, such as if shared memory is configured to use half of a capacity, and texture and load/store operations can use remaining capacity. Integration within shared memory/L1 cache 5718 enables shared memory/L1 cache 5718 to function as a high-throughput conduit for streaming data while simultaneously providing high-bandwidth and low-latency access to frequently reused data, in accordance with at least one embodiment. In at least one embodiment, when configured for general purpose parallel computation, a simpler configuration can be used compared with graphics processing. In at least one embodiment, fixed function graphics processing units are bypassed, creating a much simpler programming model. In a general purpose parallel computation configuration, a work distribution unit assigns and distributes blocks of threads directly to DPCs, in at least one embodiment. In at least one embodiment, threads in a block execute a common program, using a unique thread ID in calculation to ensure each thread generates unique results, using SM 5700 to execute program and perform calculations, shared memory/L1 cache 5718 to communicate between threads, and LSU 5714 to read and write global memory through shared memory/L1 cache 5718 and memory partition unit. In at least one embodiment, when configured for general purpose parallel computation, SM 5700 writes commands that scheduler unit 5704 can use to launch new work on DPCs.

In at least one embodiment, a PPU is included in or coupled to a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, and more. In at least one embodiment, a PPU is embodied on a single semiconductor substrate. In at least one embodiment, a PPU is included in a system-on-a-chip (“SoC”) along with one or more other devices such as additional PPUs, memory, a reduced instruction set computer (“RISC”) CPU, a memory management unit (“MMU”), a digital-to-analog converter (“DAC”), and like.

In at least one embodiment, a PPU may be included on a graphics card that includes one or more memory devices. In at least one embodiment, that graphics card may be configured to interface with a PCIe slot on a motherboard of a desktop computer. In at least one embodiment, that PPU may be an integrated graphics processing unit (“iGPU”) included in chipset of a motherboard.

Inference and/or training logic 2915 are used to perform inferencing and/or training operations associated with one or more embodiments. Details regarding inference and/or training logic 2915 are provided herein in conjunction with FIGS. 29A and/or 29B. In at least one embodiment, deep learning application processor is used to train a machine learning model, such as a neural network, to predict or infer information provided to SM 5700. In at least one embodiment, SM 5700 is used to infer or predict information based on a trained machine learning model (e.g., neural network) that has been trained by another processor or system or by SM 5700. In at least one embodiment, SM 5700 may be used to perform one or more neural network use cases described herein.

In at least one embodiment, a computer system can be used to train or implement a neural network as described herein. In at least one embodiment, for example, a computer system can be used to simulate a tactile sensor to generate a latent space using unsupervised learning, and generate a latent space for electrode signals generated by the tactile sensor. In at least one embodiment, a computer system can be used to learn a mapping between these two latent spaces, allowing for projection between impressions on a tactile sensor and the signals produced by the sensor itself.

In at least one embodiment, a computer system includes one or more processors such as SM 5700. In at least one embodiment, a computer system includes physical memory storing executable instructions that, as a result of being executed by SM 5700, cause a computer system to implement the machine learning systems described herein. In at least one embodiment, SM 5700 may execute instructions that cause a computer system to generate a projection between two latent spaces, for example.

Embodiments are disclosed related a virtualized computing platform for advanced computing, such as image inferencing and image processing in medical applications. Without limitation, embodiments may include radiography, magnetic resonance imaging (MRI), nuclear medicine, ultrasound, sonography, elastography, photoacoustic imaging, tomography, echocardiography, functional near-infrared spectroscopy, and magnetic particle imaging, or a combination thereof. In at least one embodiment, a virtualized computing platform and associated processes described herein may additionally or alternatively be used, without limitation, in forensic science analysis, sub-surface detection and imaging (e.g., oil exploration, archaeology, paleontology, etc.), topography, oceanography, geology, osteology, meteorology, intelligent area or object tracking and monitoring, sensor data processing (e.g., RADAR, SONAR, LIDAR, etc.), and/or genomics and gene sequencing.

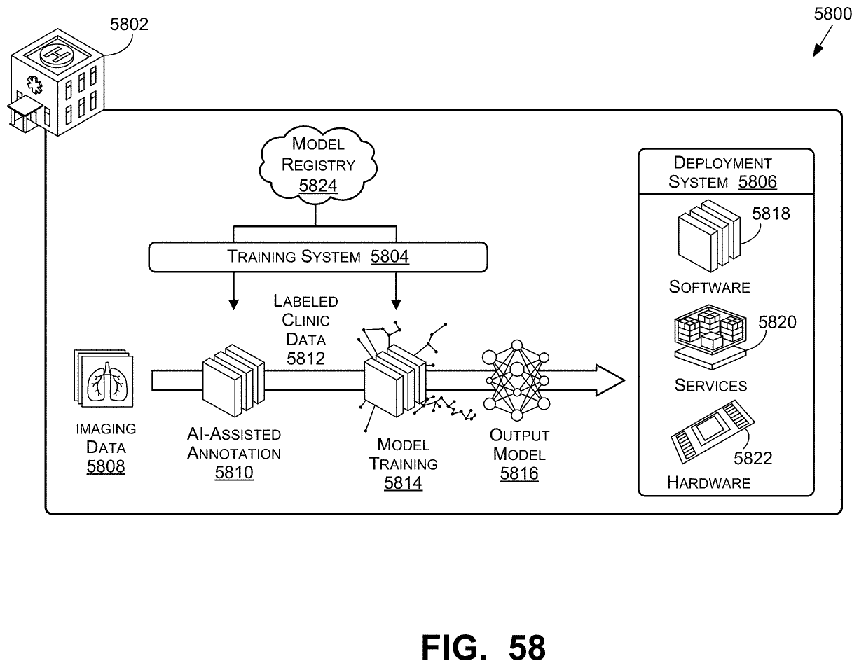

With reference to FIG. 58, FIG. 58 is an example data flow diagram for a process 5800 of generating and deploying an image processing and inferencing pipeline, in accordance with at least one embodiment. In at least one embodiment, process 5800 may be deployed for use with imaging devices, processing devices, genomics devices, gene sequencing devices, radiology devices, and/or other device types at one or more facilities 5802, such as medical facilities, hospitals, healthcare institutes, clinics, research or diagnostic labs, etc. In at least one embodiment, process 5800 may be deployed to perform genomics analysis and inferencing on sequencing data. Examples of genomic analyses that may be performed using systems and processes described herein include, without limitation, variant calling, mutation detection, and gene expression quantification.

In at least one embodiment, process 5800 may be executed within a training system 5804 and/or a deployment system 5806. In at least one embodiment, training system 5804 may be used to perform training, deployment, and implementation of machine learning models (e.g., neural networks, object detection algorithms, computer vision algorithms, etc.) for use in deployment system 5806. In at least one embodiment, deployment system 5806 may be configured to offload processing and compute resources among a distributed computing environment to reduce infrastructure requirements at facility 5802. In at least one embodiment, deployment system 5806 may provide a streamlined platform for selecting, customizing, and implementing virtual instruments for use with imaging devices (e.g., MRI, CT Scan, X-Ray, Ultrasound, etc.) or sequencing devices at facility 5802. In at least one embodiment, virtual instruments may include software-defined applications for performing one or more processing operations with respect to imaging data generated by imaging devices, sequencing devices, radiology devices, and/or other device types. In at least one embodiment, one or more applications in a pipeline may use or call upon services (e.g., inference, visualization, compute, AI, etc.) of deployment system 5806 during execution of applications.

In at least one embodiment, some of applications used in advanced processing and inferencing pipelines may use machine learning models or other AI to perform one or more processing steps. In at least one embodiment, machine learning models may be trained at facility 5802 using data 5808 (such as imaging data) generated at facility 5802 (and stored on one or more picture archiving and communication system (PACS) servers at facility 5802), may be trained using imaging or sequencing data 5808 from another facility or facilities (e.g., a different hospital, lab, clinic, etc.), or a combination thereof. In at least one embodiment, training system 5804 may be used to provide applications, services, and/or other resources for generating working, deployable machine learning models for deployment system 5806.

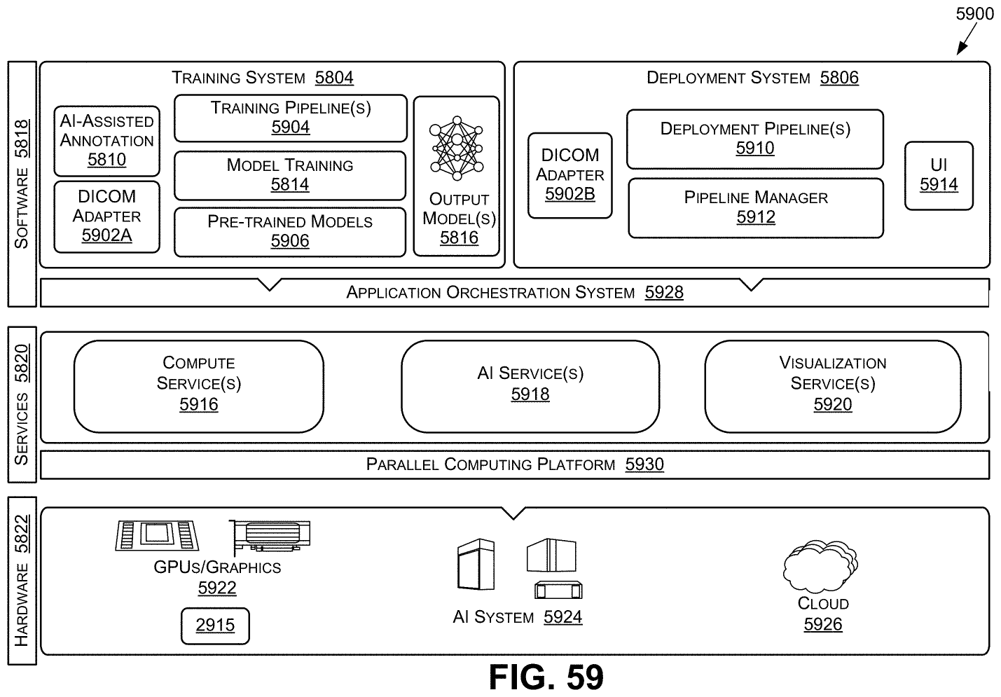

In at least one embodiment, a model registry 5824 may be backed by object storage that may support versioning and object metadata. In at least one embodiment, object storage may be accessible through, for example, a cloud storage (e.g., a cloud 5926 of FIG. 59) compatible application programming interface (API) from within a cloud platform. In at least one embodiment, machine learning models within model registry 5824 may uploaded, listed, modified, or deleted by developers or partners of a system interacting with an API. In at least one embodiment, an API may provide access to methods that allow users with appropriate credentials to associate models with applications, such that models may be executed as part of execution of containerized instantiations of applications.

In at least one embodiment, a training pipeline 5904 (FIG. 59) may include a scenario where facility 5802 is training their own machine learning model, or has an existing machine learning model that needs to be optimized or updated. In at least one embodiment, imaging data 5808 generated by imaging device(s), sequencing devices, and/or other device types may be received. In at least one embodiment, once imaging data 5808 is received, AI-assisted annotation 5810 may be used to aid in generating annotations corresponding to imaging data 5808 to be used as ground truth data for a machine learning model. In at least one embodiment, AI-assisted annotation 5810 may include one or more machine learning models (e.g., convolutional neural networks (CNNs)) that may be trained to generate annotations corresponding to certain types of imaging data 5808 (e.g., from certain devices) and/or certain types of anomalies in imaging data 5808. In at least one embodiment, AI-assisted annotations 5810 may then be used directly, or may be adjusted or fine-tuned using an annotation tool (e.g., by a researcher, a clinician, a doctor, a scientist, etc.), to generate ground truth data. In at least one embodiment, in some examples, labeled clinic data 5812 (e.g., annotations provided by a clinician, doctor, scientist, technician, etc.) may be used as ground truth data for training a machine learning model. In at least one embodiment, AI-assisted annotations 5810, labeled clinic data 5812, or a combination thereof may be used as ground truth data for training a machine learning model. In at least one embodiment, a trained machine learning model may be referred to as an output model 5816, and may be used by deployment system 5806, as described herein.

In at least one embodiment, training pipeline 5904 (FIG. 59) may include a scenario where facility 5802 needs a machine learning model for use in performing one or more processing tasks for one or more applications in deployment system 5806, but facility 5802 may not currently have such a machine learning model (or may not have a model that is optimized, efficient, or effective for such purposes). In at least one embodiment, an existing machine learning model may be selected from model registry 5824. In at least one embodiment, model registry 5824 may include machine learning models trained to perform a variety of different inference tasks on imaging data. In at least one embodiment, machine learning models in model registry 5824 may have been trained on imaging data from different facilities than facility 5802 (e.g., facilities remotely located). In at least one embodiment, machine learning models may have been trained on imaging data from one location, two locations, or any number of locations. In at least one embodiment, when being trained on imaging data from a specific location, training may take place at that location, or at least in a manner that protects confidentiality of imaging data or restricts imaging data from being transferred off-premises (e.g., to comply with HIPAA regulations, privacy regulations, etc.). In at least one embodiment, once a model is trained—or partially trained—at one location, a machine learning model may be added to model registry 5824. In at least one embodiment, a machine learning model may then be retrained, or updated, at any number of other facilities, and a retrained or updated model may be made available in model registry 5824. In at least one embodiment, a machine learning model may then be selected from model registry 5824—and referred to as output model 5816—and may be used in deployment system 5806 to perform one or more processing tasks for one or more applications of a deployment system.

In at least one embodiment, training pipeline 5904 (FIG. 59) may be used in a scenario that includes facility 5802 requiring a machine learning model for use in performing one or more processing tasks for one or more applications in deployment system 5806, but facility 5802 may not currently have such a machine learning model (or may not have a model that is optimized, efficient, or effective for such purposes). In at least one embodiment, a machine learning model selected from model registry 5824 might not be fine-tuned or optimized for imaging data 5808 generated at facility 5802 because of differences in populations, genetic variations, robustness of training data used to train a machine learning model, diversity in anomalies of training data, and/or other issues with training data. In at least one embodiment, AI-assisted annotation 5810 may be used to aid in generating annotations corresponding to imaging data 5808 to be used as ground truth data for retraining or updating a machine learning model. In at least one embodiment, labeled clinic data 5812 (e.g., annotations provided by a clinician, doctor, scientist, etc.) may be used as ground truth data for training a machine learning model. In at least one embodiment, retraining or updating a machine learning model may be referred to as model training 5814. In at least one embodiment, model training 5814—e.g., AI-assisted annotations 5810, labeled clinic data 5812, or a combination thereof—may be used as ground truth data for retraining or updating a machine learning model.

In at least one embodiment, deployment system 5806 may include software 5818, services 5820, hardware 5822, and/or other components, features, and functionality. In at least one embodiment, deployment system 5806 may include a software “stack,” such that software 5818 may be built on top of services 5820 and may use services 5820 to perform some or all of processing tasks, and services 5820 and software 5818 may be built on top of hardware 5822 and use hardware 5822 to execute processing, storage, and/or other compute tasks of deployment system 5806.

In at least one embodiment, software 5818 may include any number of different containers, where each container may execute an instantiation of an application. In at least one embodiment, each application may perform one or more processing tasks in an advanced processing and inferencing pipeline (e.g., inferencing, object detection, feature detection, segmentation, image enhancement, calibration, etc.). In at least one embodiment, for each type of imaging device (e.g., CT, MM, X-Ray, ultrasound, sonography, echocardiography, etc.), sequencing device, radiology device, genomics device, etc., there may be any number of containers that may perform a data processing task with respect to imaging data 5808 (or other data types, such as those described herein) generated by a device. In at least one embodiment, an advanced processing and inferencing pipeline may be defined based on selections of different containers that are desired or required for processing imaging data 5808, in addition to containers that receive and configure imaging data for use by each container and/or for use by facility 5802 after processing through a pipeline (e.g., to convert outputs back to a usable data type, such as digital imaging and communications in medicine (DICOM) data, radiology information system (RIS) data, clinical information system (CIS) data, remote procedure call (RPC) data, data substantially compliant with a representation state transfer (REST) interface, data substantially compliant with a file-based interface, and/or raw data, for storage and display at facility 5802). In at least one embodiment, a combination of containers within software 5818 (e.g., that make up a pipeline) may be referred to as a virtual instrument (as described in more detail herein), and a virtual instrument may leverage services 5820 and hardware 5822 to execute some or all processing tasks of applications instantiated in containers.

In at least one embodiment, a data processing pipeline may receive input data (e.g., imaging data 5808) in a DICOM, RIS, CIS, REST compliant, RPC, raw, and/or other format in response to an inference request (e.g., a request from a user of deployment system 5806, such as a clinician, a doctor, a radiologist, etc.). In at least one embodiment, input data may be representative of one or more images, video, and/or other data representations generated by one or more imaging devices, sequencing devices, radiology devices, genomics devices, and/or other device types. In at least one embodiment, data may undergo pre-processing as part of data processing pipeline to prepare data for processing by one or more applications. In at least one embodiment, post-processing may be performed on an output of one or more inferencing tasks or other processing tasks of a pipeline to prepare an output data for a next application and/or to prepare output data for transmission and/or use by a user (e.g., as a response to an inference request). In at least one embodiment, inferencing tasks may be performed by one or more machine learning models, such as trained or deployed neural networks, which may include output models 5816 of training system 5804.

In at least one embodiment, tasks of data processing pipeline may be encapsulated in a container(s) that each represent a discrete, fully functional instantiation of an application and virtualized computing environment that is able to reference machine learning models. In at least one embodiment, containers or applications may be published into a private (e.g., limited access) area of a container registry (described in more detail herein), and trained or deployed models may be stored in model registry 5824 and associated with one or more applications. In at least one embodiment, images of applications (e.g., container images) may be available in a container registry, and once selected by a user from a container registry for deployment in a pipeline, an image may be used to generate a container for an instantiation of an application for use by a user's system.

In at least one embodiment, developers (e.g., software developers, clinicians, doctors, etc.) may develop, publish, and store applications (e.g., as containers) for performing image processing and/or inferencing on supplied data. In at least one embodiment, development, publishing, and/or storing may be performed using a software development kit (SDK) associated with a system (e.g., to ensure that an application and/or container developed is compliant with or compatible with a system). In at least one embodiment, an application that is developed may be tested locally (e.g., at a first facility, on data from a first facility) with an SDK which may support at least some of services 5820 as a system (e.g., system 5900 of FIG. 59). In at least one embodiment, because DICOM objects may contain anywhere from one to hundreds of images or other data types, and due to a variation in data, a developer may be responsible for managing (e.g., setting constructs for, building pre-processing into an application, etc.) extraction and preparation of incoming DICOM data. In at least one embodiment, once validated by system 5900 (e.g., for accuracy, safety, patient privacy, etc.), an application may be available in a container registry for selection and/or implementation by a user (e.g., a hospital, clinic, lab, healthcare provider, etc.) to perform one or more processing tasks with respect to data at a facility (e.g., a second facility) of a user.

In at least one embodiment, developers may then share applications or containers through a network for access and use by users of a system (e.g., system 5900 of FIG. 59). In at least one embodiment, completed and validated applications or containers may be stored in a container registry and associated machine learning models may be stored in model registry 5824. In at least one embodiment, a requesting entity (e.g., a user at a medical facility)—who provides an inference or image processing request—may browse a container registry and/or model registry 5824 for an application, container, dataset, machine learning model, etc., select a desired combination of elements for inclusion in data processing pipeline, and submit an imaging processing request. In at least one embodiment, a request may include input data (and associated patient data, in some examples) that is necessary to perform a request, and/or may include a selection of application(s) and/or machine learning models to be executed in processing a request. In at least one embodiment, a request may then be passed to one or more components of deployment system 5806 (e.g., a cloud) to perform processing of data processing pipeline. In at least one embodiment, processing by deployment system 5806 may include referencing selected elements (e.g., applications, containers, models, etc.) from a container registry and/or model registry 5824. In at least one embodiment, once results are generated by a pipeline, results may be returned to a user for reference (e.g., for viewing in a viewing application suite executing on a local, on-premises workstation or terminal). In at least one embodiment, a radiologist may receive results from an data processing pipeline including any number of application and/or containers, where results may include anomaly detection in X-rays, CT scans, MRIs, etc.

In at least one embodiment, to aid in processing or execution of applications or containers in pipelines, services 5820 may be leveraged. In at least one embodiment, services 5820 may include compute services, artificial intelligence (AI) services, visualization services, and/or other service types. In at least one embodiment, services 5820 may provide functionality that is common to one or more applications in software 5818, so functionality may be abstracted to a service that may be called upon or leveraged by applications. In at least one embodiment, functionality provided by services 5820 may run dynamically and more efficiently, while also scaling well by allowing applications to process data in parallel (e.g., using a parallel computing platform 5930 (FIG. 59)). In at least one embodiment, rather than each application that shares a same functionality offered by a service 5820 being required to have a respective instance of service 5820, service 5820 may be shared between and among various applications. In at least one embodiment, services may include an inference server or engine that may be used for executing detection or segmentation tasks, as non-limiting examples. In at least one embodiment, a model training service may be included that may provide machine learning model training and/or retraining capabilities. In at least one embodiment, a data augmentation service may further be included that may provide GPU accelerated data (e.g., DICOM, RIS, CIS, REST compliant, RPC, raw, etc.) extraction, resizing, scaling, and/or other augmentation. In at least one embodiment, a visualization service may be used that may add image rendering effects—such as ray-tracing, rasterization, denoising, sharpening, etc.—to add realism to two-dimensional (2D) and/or three-dimensional (3D) models. In at least one embodiment, virtual instrument services may be included that provide for beam-forming, segmentation, inferencing, imaging, and/or support for other applications within pipelines of virtual instruments.

In at least one embodiment, where a service 5820 includes an AI service (e.g., an inference service), one or more machine learning models associated with an application for anomaly detection (e.g., tumors, growth abnormalities, scarring, etc.) may be executed by calling upon (e.g., as an API call) an inference service (e.g., an inference server) to execute machine learning model(s), or processing thereof, as part of application execution. In at least one embodiment, where another application includes one or more machine learning models for segmentation tasks, an application may call upon an inference service to execute machine learning models for performing one or more of processing operations associated with segmentation tasks. In at least one embodiment, software 5818 implementing advanced processing and inferencing pipeline that includes segmentation application and anomaly detection application may be streamlined because each application may call upon a same inference service to perform one or more inferencing tasks.

In at least one embodiment, hardware 5822 may include GPUs, CPUs, graphics cards, an AI/deep learning system (e.g., an AI supercomputer, such as NVIDIA's DGX supercomputer system), a cloud platform, or a combination thereof. In at least one embodiment, different types of hardware 5822 may be used to provide efficient, purpose-built support for software 5818 and services 5820 in deployment system 5806. In at least one embodiment, use of GPU processing may be implemented for processing locally (e.g., at facility 5802), within an AI/deep learning system, in a cloud system, and/or in other processing components of deployment system 5806 to improve efficiency, accuracy, and efficacy of image processing, image reconstruction, segmentation, MRI exams, stroke or heart attack detection (e.g., in real-time), image quality in rendering, etc. In at least one embodiment, a facility may include imaging devices, genomics devices, sequencing devices, and/or other device types on-premises that may leverage GPUs to generate imaging data representative of a subject's anatomy.

In at least one embodiment, software 5818 and/or services 5820 may be optimized for GPU processing with respect to deep learning, machine learning, and/or high-performance computing, as non-limiting examples. In at least one embodiment, at least some of computing environment of deployment system 5806 and/or training system 5804 may be executed in a datacenter one or more supercomputers or high performance computing systems, with GPU optimized software (e.g., hardware and software combination of NVIDIA's DGX system). In at least one embodiment, datacenters may be compliant with provisions of HIPAA, such that receipt, processing, and transmission of imaging data and/or other patient data is securely handled with respect to privacy of patient data. In at least one embodiment, hardware 5822 may include any number of GPUs that may be called upon to perform processing of data in parallel, as described herein. In at least one embodiment, cloud platform may further include GPU processing for GPU-optimized execution of deep learning tasks, machine learning tasks, or other computing tasks. In at least one embodiment, cloud platform (e.g., NVIDIA's NGC) may be executed using an AI/deep learning supercomputer(s) and/or GPU-optimized software (e.g., as provided on NVIDIA's DGX systems) as a hardware abstraction and scaling platform. In at least one embodiment, cloud platform may integrate an application container clustering system or orchestration system (e.g., KUBERNETES) on multiple GPUs to enable seamless scaling and load balancing.

In at least one embodiment, deployment system 5806 can be used to train or implement a neural network as described herein. In at least one embodiment, for example, deployment system 5806 can be used to simulate a tactile sensor to generate a latent space using unsupervised learning, and generate a latent space for electrode signals generated by the tactile sensor. In at least one embodiment, deployment system 5806 can be used to learn a mapping between these two latent spaces, allowing for projection between impressions on a tactile sensor and the signals produced by the sensor itself.

FIG. 59 is a system diagram for an example system 5900 for generating and deploying an imaging deployment pipeline, in accordance with at least one embodiment. In at least one embodiment, system 5900 may be used to implement process 5800 of FIG. 58 and/or other processes including advanced processing and inferencing pipelines. In at least one embodiment, system 5900 may include training system 5804 and deployment system 5806. In at least one embodiment, training system 5804 and deployment system 5806 may be implemented using software 5818, services 5820, and/or hardware 5822, as described herein.

In at least one embodiment, system 5900 (e.g., training system 5804 and/or deployment system 5806) may implemented in a cloud computing environment (e.g., using cloud 5926). In at least one embodiment, system 5900 may be implemented locally with respect to a healthcare services facility, or as a combination of both cloud and local computing resources. In at least one embodiment, in embodiments where cloud computing is implemented, patient data may be separated from, or unprocessed by, by one or more components of system 5900 that would render processing non-compliant with HIPAA and/or other data handling and privacy regulations or laws. In at least one embodiment, access to APIs in cloud 5926 may be restricted to authorized users through enacted security measures or protocols. In at least one embodiment, a security protocol may include web tokens that may be signed by an authentication (e.g., AuthN, AuthZ, Gluecon, etc.) service and may carry appropriate authorization. In at least one embodiment, APIs of virtual instruments (described herein), or other instantiations of system 5900, may be restricted to a set of public IPs that have been vetted or authorized for interaction.

In at least one embodiment, various components of system 5900 may communicate between and among one another using any of a variety of different network types, including but not limited to local area networks (LANs) and/or wide area networks (WANs) via wired and/or wireless communication protocols. In at least one embodiment, communication between facilities and components of system 5900 (e.g., for transmitting inference requests, for receiving results of inference requests, etc.) may be communicated over a data bus or data busses, wireless data protocols (Wi-Fi), wired data protocols (e.g., Ethernet), etc.

In at least one embodiment, training system 5804 may execute training pipelines 5904, similar to those described herein with respect to FIG. 58. In at least one embodiment, where one or more machine learning models are to be used in deployment pipelines 5910 by deployment system 5806, training pipelines 5904 may be used to train or retrain one or more (e.g., pre-trained) models, and/or implement one or more of pre-trained models 5906 (e.g., without a need for retraining or updating). In at least one embodiment, as a result of training pipelines 5904, output model(s) 5816 may be generated. In at least one embodiment, training pipelines 5904 may include any number of processing steps, such as but not limited to imaging data (or other input data) conversion or adaption (e.g., using DICOM adapter 5902A to convert DICOM images to another format suitable for processing by respective machine learning models, such as Neuroimaging Informatics Technology Initiative (NIfTI) format), AI-assisted annotation 5810, labeling or annotating of imaging data 5808 to generate labeled clinic data 5812, model selection from a model registry, model training 5814, training, retraining, or updating models, and/or other processing steps. In at least one embodiment, for different machine learning models used by deployment system 5806, different training pipelines 5904 may be used. In at least one embodiment, training pipeline 5904 similar to a first example described with respect to FIG. 58 may be used for a first machine learning model, training pipeline 5904 similar to a second example described with respect to FIG. 58 may be used for a second machine learning model, and training pipeline 5904 similar to a third example described with respect to FIG. 58 may be used for a third machine learning model. In at least one embodiment, any combination of tasks within training system 5804 may be used depending on what is required for each respective machine learning model. In at least one embodiment, one or more of machine learning models may already be trained and ready for deployment so machine learning models may not undergo any processing by training system 5804, and may be implemented by deployment system 5806.

In at least one embodiment, output model(s) 5816 and/or pre-trained model(s) 5906 may include any types of machine learning models depending on implementation or embodiment. In at least one embodiment, and without limitation, machine learning models used by system 5900 may include machine learning model(s) using linear regression, logistic regression, decision trees, support vector machines (SVM), Naïve Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

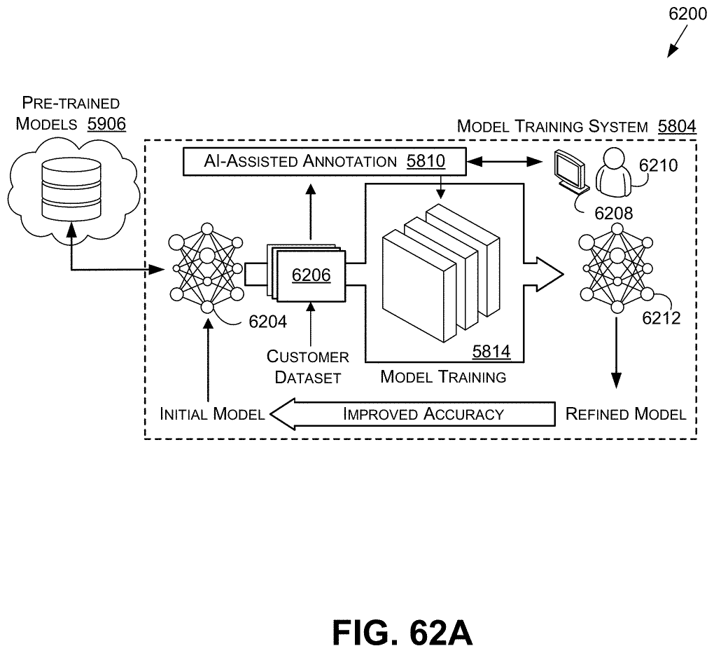

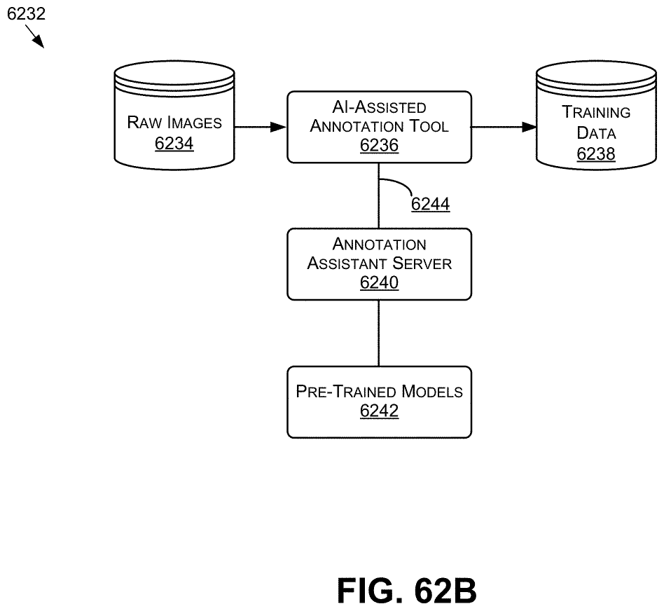

In at least one embodiment, training pipelines 5904 may include AI-assisted annotation, as described in more detail herein with respect to at least FIG. 62B. In at least one embodiment, labeled clinic data 5812 (e.g., traditional annotation) may be generated by any number of techniques. In at least one embodiment, labels or other annotations may be generated within a drawing program (e.g., an annotation program), a computer aided design (CAD) program, a labeling program, another type of program suitable for generating annotations or labels for ground truth, and/or may be hand drawn, in some examples. In at least one embodiment, ground truth data may be synthetically produced (e.g., generated from computer models or renderings), real produced (e.g., designed and produced from real-world data), machine-automated (e.g., using feature analysis and learning to extract features from data and then generate labels), human annotated (e.g., labeler, or annotation expert, defines location of labels), and/or a combination thereof. In at least one embodiment, for each instance of imaging data 5808 (or other data type used by machine learning models), there may be corresponding ground truth data generated by training system 5804. In at least one embodiment, AI-assisted annotation may be performed as part of deployment pipelines 5910; either in addition to, or in lieu of AI-assisted annotation included in training pipelines 5904. In at least one embodiment, system 5900 may include a multi-layer platform that may include a software layer (e.g., software 5818) of diagnostic applications (or other application types) that may perform one or more medical imaging and diagnostic functions. In at least one embodiment, system 5900 may be communicatively coupled to (e.g., via encrypted links) PACS server networks of one or more facilities. In at least one embodiment, system 5900 may be configured to access and referenced data (e.g., DICOM data, RIS data, raw data, CIS data, REST compliant data, RPC data, raw data, etc.) from PACS servers (e.g., via a DICOM adapter 5902, or another data type adapter such as RIS, CIS, REST compliant, RPC, raw, etc.) to perform operations, such as training machine learning models, deploying machine learning models, image processing, inferencing, and/or other operations.

In at least one embodiment, a software layer may be implemented as a secure, encrypted, and/or authenticated API through which applications or containers may be invoked (e.g., called) from an external environment(s) (e.g., facility 5802). In at least one embodiment, applications may then call or execute one or more services 5820 for performing compute, AI, or visualization tasks associated with respective applications, and software 5818 and/or services 5820 may leverage hardware 5822 to perform processing tasks in an effective and efficient manner.

In at least one embodiment, deployment system 5806 may execute deployment pipelines 5910. In at least one embodiment, deployment pipelines 5910 may include any number of applications that may be sequentially, non-sequentially, or otherwise applied to imaging data (and/or other data types) generated by imaging devices, sequencing devices, genomics devices, etc.—including AI-assisted annotation, as described above. In at least one embodiment, as described herein, a deployment pipeline 5910 for an individual device may be referred to as a virtual instrument for a device (e.g., a virtual ultrasound instrument, a virtual CT scan instrument, a virtual sequencing instrument, etc.). In at least one embodiment, for a single device, there may be more than one deployment pipeline 5910 depending on information desired from data generated by a device. In at least one embodiment, where detections of anomalies are desired from an MRI machine, there may be a first deployment pipeline 5910, and where image enhancement is desired from output of an Mill machine, there may be a second deployment pipeline 5910.

In at least one embodiment, applications available for deployment pipelines 5910 may include any application that may be used for performing processing tasks on imaging data or other data from devices. In at least one embodiment, different applications may be responsible for image enhancement, segmentation, reconstruction, anomaly detection, object detection, feature detection, treatment planning, dosimetry, beam planning (or other radiation treatment procedures), and/or other analysis, image processing, or inferencing tasks. In at least one embodiment, deployment system 5806 may define constructs for each of applications, such that users of deployment system 5806 (e.g., medical facilities, labs, clinics, etc.) may understand constructs and adapt applications for implementation within their respective facility. In at least one embodiment, an application for image reconstruction may be selected for inclusion in deployment pipeline 5910, but data type generated by an imaging device may be different from a data type used within an application. In at least one embodiment, DICOM adapter 5902B (and/or a DICOM reader) or another data type adapter or reader (e.g., RIS, CIS, REST compliant, RPC, raw, etc.) may be used within deployment pipeline 5910 to convert data to a form useable by an application within deployment system 5806. In at least one embodiment, access to DICOM, RIS, CIS, REST compliant, RPC, raw, and/or other data type libraries may be accumulated and pre-processed, including decoding, extracting, and/or performing any convolutions, color corrections, sharpness, gamma, and/or other augmentations to data. In at least one embodiment, DICOM, RIS, CIS, REST compliant, RPC, and/or raw data may be unordered and a pre-pass may be executed to organize or sort collected data. In at least one embodiment, because various applications may share common image operations, in some embodiments, a data augmentation library (e.g., as one of services 5820) may be used to accelerate these operations. In at least one embodiment, to avoid bottlenecks of conventional processing approaches that rely on CPU processing, parallel computing platform 5930 may be used for GPU acceleration of these processing tasks.

In at least one embodiment, an image reconstruction application may include a processing task that includes use of a machine learning model. In at least one embodiment, a user may desire to use their own machine learning model, or to select a machine learning model from model registry 5824. In at least one embodiment, a user may implement their own machine learning model or select a machine learning model for inclusion in an application for performing a processing task. In at least one embodiment, applications may be selectable and customizable, and by defining constructs of applications, deployment and implementation of applications for a particular user are presented as a more seamless user experience. In at least one embodiment, by leveraging other features of system 5900—such as services 5820 and hardware 5822—deployment pipelines 5910 may be even more user friendly, provide for easier integration, and produce more accurate, efficient, and timely results.

In at least one embodiment, deployment system 5806 may include a user interface 5914 (e.g., a graphical user interface, a web interface, etc.) that may be used to select applications for inclusion in deployment pipeline(s) 5910, arrange applications, modify or change applications or parameters or constructs thereof, use and interact with deployment pipeline(s) 5910 during set-up and/or deployment, and/or to otherwise interact with deployment system 5806. In at least one embodiment, although not illustrated with respect to training system 5804, user interface 5914 (or a different user interface) may be used for selecting models for use in deployment system 5806, for selecting models for training, or retraining, in training system 5804, and/or for otherwise interacting with training system 5804.

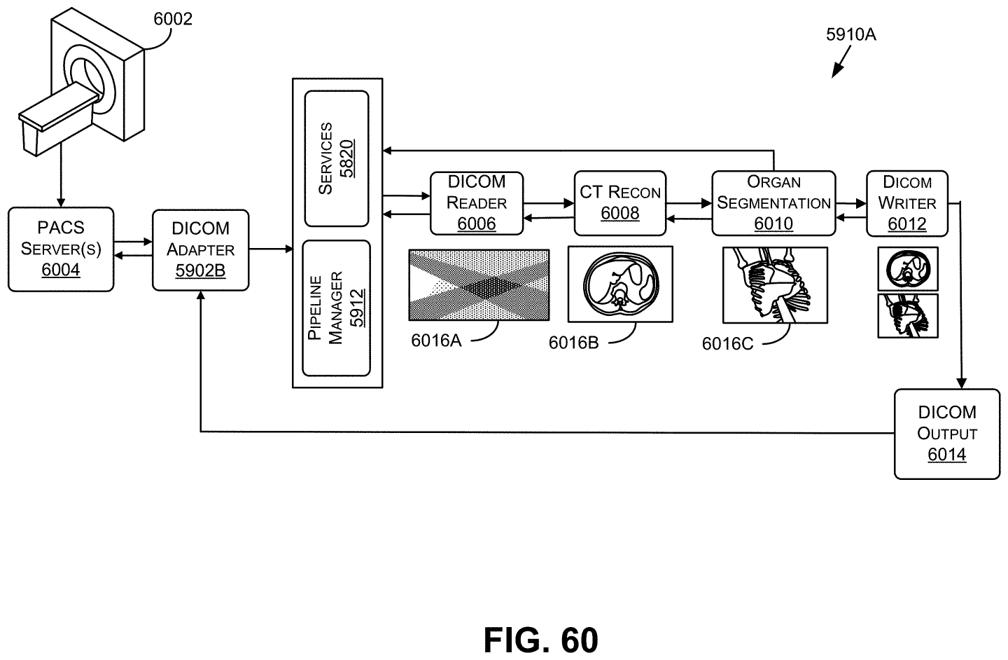

In at least one embodiment, pipeline manager 5912 may be used, in addition to an application orchestration system 5928, to manage interaction between applications or containers of deployment pipeline(s) 5910 and services 5820 and/or hardware 5822. In at least one embodiment, pipeline manager 5912 may be configured to facilitate interactions from application to application, from application to service 5820, and/or from application or service to hardware 5822. In at least one embodiment, although illustrated as included in software 5818, this is not intended to be limiting, and in some examples (e.g., as illustrated in FIG. 60) pipeline manager 5912 may be included in services 5820. In at least one embodiment, application orchestration system 5928 (e.g., Kubernetes, DOCKER, etc.) may include a container orchestration system that may group applications into containers as logical units for coordination, management, scaling, and deployment. In at least one embodiment, by associating applications from deployment pipeline(s) 5910 (e.g., a reconstruction application, a segmentation application, etc.) with individual containers, each application may execute in a self-contained environment (e.g., at a kernel level) to increase speed and efficiency.

In at least one embodiment, each application and/or container (or image thereof) may be individually developed, modified, and deployed (e.g., a first user or developer may develop, modify, and deploy a first application and a second user or developer may develop, modify, and deploy a second application separate from a first user or developer), which may allow for focus on, and attention to, a task of a single application and/or container(s) without being hindered by tasks of another application(s) or container(s). In at least one embodiment, communication, and cooperation between different containers or applications may be aided by pipeline manager 5912 and application orchestration system 5928. In at least one embodiment, so long as an expected input and/or output of each container or application is known by a system (e.g., based on constructs of applications or containers), application orchestration system 5928 and/or pipeline manager 5912 may facilitate communication among and between, and sharing of resources among and between, each of applications or containers. In at least one embodiment, because one or more of applications or containers in deployment pipeline(s) 5910 may share same services and resources, application orchestration system 5928 may orchestrate, load balance, and determine sharing of services or resources between and among various applications or containers. In at least one embodiment, a scheduler may be used to track resource requirements of applications or containers, current usage or planned usage of these resources, and resource availability. In at least one embodiment, a scheduler may thus allocate resources to different applications and distribute resources between and among applications in view of requirements and availability of a system. In some examples, a scheduler (and/or other component of application orchestration system 5928) may determine resource availability and distribution based on constraints imposed on a system (e.g., user constraints), such as quality of service (QoS), urgency of need for data outputs (e.g., to determine whether to execute real-time processing or delayed processing), etc.

In at least one embodiment, services 5820 leveraged by and shared by applications or containers in deployment system 5806 may include compute services 5916, AI services 5918, visualization services 5920, and/or other service types. In at least one embodiment, applications may call (e.g., execute) one or more of services 5820 to perform processing operations for an application. In at least one embodiment, compute services 5916 may be leveraged by applications to perform super-computing or other high-performance computing (HPC) tasks. In at least one embodiment, compute service(s) 5916 may be leveraged to perform parallel processing (e.g., using a parallel computing platform 5930) for processing data through one or more of applications and/or one or more tasks of a single application, substantially simultaneously. In at least one embodiment, parallel computing platform 5930 (e.g., NVIDIA's CUDA) may enable general purpose computing on GPUs (GPGPU) (e.g., GPUs 5922). In at least one embodiment, a software layer of parallel computing platform 5930 may provide access to virtual instruction sets and parallel computational elements of GPUs, for execution of compute kernels. In at least one embodiment, parallel computing platform 5930 may include memory and, in some embodiments, a memory may be shared between and among multiple containers, and/or between and among different processing tasks within a single container. In at least one embodiment, inter-process communication (IPC) calls may be generated for multiple containers and/or for multiple processes within a container to use same data from a shared segment of memory of parallel computing platform 5930 (e.g., where multiple different stages of an application or multiple applications are processing same information). In at least one embodiment, rather than making a copy of data and moving data to different locations in memory (e.g., a read/write operation), same data in same location of a memory may be used for any number of processing tasks (e.g., at a same time, at different times, etc.). In at least one embodiment, as data is used to generate new data as a result of processing, this information of a new location of data may be stored and shared between various applications. In at least one embodiment, location of data and a location of updated or modified data may be part of a definition of how a payload is understood within containers.

In at least one embodiment, AI services 5918 may be leveraged to perform inferencing services for executing machine learning model(s) associated with applications (e.g., tasked with performing one or more processing tasks of an application). In at least one embodiment, AI services 5918 may leverage AI system 5924 to execute machine learning model(s) (e.g., neural networks, such as CNNs) for segmentation, reconstruction, object detection, feature detection, classification, and/or other inferencing tasks. In at least one embodiment, applications of deployment pipeline(s) 5910 may use one or more of output models 5816 from training system 5804 and/or other models of applications to perform inference on imaging data (e.g., DICOM data, RIS data, CIS data, REST compliant data, RPC data, raw data, etc.). In at least one embodiment, two or more examples of inferencing using application orchestration system 5928 (e.g., a scheduler) may be available. In at least one embodiment, a first category may include a high priority/low latency path that may achieve higher service level agreements, such as for performing inference on urgent requests during an emergency, or for a radiologist during diagnosis. In at least one embodiment, a second category may include a standard priority path that may be used for requests that may be non-urgent or where analysis may be performed at a later time. In at least one embodiment, application orchestration system 5928 may distribute resources (e.g., services 5820 and/or hardware 5822) based on priority paths for different inferencing tasks of AI services 5918.

In at least one embodiment, shared storage may be mounted to AI services 5918 within system 5900. In at least one embodiment, shared storage may operate as a cache (or other storage device type) and may be used to process inference requests from applications. In at least one embodiment, when an inference request is submitted, a request may be received by a set of API instances of deployment system 5806, and one or more instances may be selected (e.g., for best fit, for load balancing, etc.) to process a request. In at least one embodiment, to process a request, a request may be entered into a database, a machine learning model may be located from model registry 5824 if not already in a cache, a validation step may ensure appropriate machine learning model is loaded into a cache (e.g., shared storage), and/or a copy of a model may be saved to a cache. In at least one embodiment, a scheduler (e.g., of pipeline manager 5912) may be used to launch an application that is referenced in a request if an application is not already running or if there are not enough instances of an application. In at least one embodiment, if an inference server is not already launched to execute a model, an inference server may be launched. In at least one embodiment, any number of inference servers may be launched per model. In at least one embodiment, in a pull model, in which inference servers are clustered, models may be cached whenever load balancing is advantageous. In at least one embodiment, inference servers may be statically loaded in corresponding, distributed servers.

In at least one embodiment, inferencing may be performed using an inference server that runs in a container. In at least one embodiment, an instance of an inference server may be associated with a model (and optionally a plurality of versions of a model). In at least one embodiment, if an instance of an inference server does not exist when a request to perform inference on a model is received, a new instance may be loaded. In at least one embodiment, when starting an inference server, a model may be passed to an inference server such that a same container may be used to serve different models so long as inference server is running as a different instance.

In at least one embodiment, during application execution, an inference request for a given application may be received, and a container (e.g., hosting an instance of an inference server) may be loaded (if not already), and a start procedure may be called. In at least one embodiment, pre-processing logic in a container may load, decode, and/or perform any additional pre-processing on incoming data (e.g., using a CPU(s) and/or GPU(s)). In at least one embodiment, once data is prepared for inference, a container may perform inference as necessary on data. In at least one embodiment, this may include a single inference call on one image (e.g., a hand X-ray), or may require inference on hundreds of images (e.g., a chest CT). In at least one embodiment, an application may summarize results before completing, which may include, without limitation, a single confidence score, pixel level-segmentation, voxel-level segmentation, generating a visualization, or generating text to summarize findings. In at least one embodiment, different models or applications may be assigned different priorities. For example, some models may have a real-time (TAT less than one minute) priority while others may have lower priority (e.g., TAT less than 10 minutes). In at least one embodiment, model execution times may be measured from requesting institution or entity and may include partner network traversal time, as well as execution on an inference service.

In at least one embodiment, transfer of requests between services 5820 and inference applications may be hidden behind a software development kit (SDK), and robust transport may be provide through a queue. In at least one embodiment, a request will be placed in a queue via an API for an individual application/tenant ID combination and an SDK will pull a request from a queue and give a request to an application. In at least one embodiment, a name of a queue may be provided in an environment from where an SDK will pick it up. In at least one embodiment, asynchronous communication through a queue may be useful as it may allow any instance of an application to pick up work as it becomes available. In at least one embodiment, results may be transferred back through a queue, to ensure no data is lost. In at least one embodiment, queues may also provide an ability to segment work, as highest priority work may go to a queue with most instances of an application connected to it, while lowest priority work may go to a queue with a single instance connected to it that processes tasks in an order received. In at least one embodiment, an application may run on a GPU-accelerated instance generated in cloud 5926, and an inference service may perform inferencing on a GPU.

In at least one embodiment, visualization services 5920 may be leveraged to generate visualizations for viewing outputs of applications and/or deployment pipeline(s) 5910. In at least one embodiment, GPUs 5922 may be leveraged by visualization services 5920 to generate visualizations. In at least one embodiment, rendering effects, such as ray-tracing, may be implemented by visualization services 5920 to generate higher quality visualizations. In at least one embodiment, visualizations may include, without limitation, 2D image renderings, 3D volume renderings, 3D volume reconstruction, 2D tomographic slices, virtual reality displays, augmented reality displays, etc. In at least one embodiment, virtualized environments may be used to generate a virtual interactive display or environment (e.g., a virtual environment) for interaction by users of a system (e.g., doctors, nurses, radiologists, etc.). In at least one embodiment, visualization services 5920 may include an internal visualizer, cinematics, and/or other rendering or image processing capabilities or functionality (e.g., ray tracing, rasterization, internal optics, etc.).

In at least one embodiment, hardware 5822 may include GPUs 5922, AI system 5924, cloud 5926, and/or any other hardware used for executing training system 5804 and/or deployment system 5806. In at least one embodiment, GPUs 5922 (e.g., NVIDIA's TESLA and/or QUADRO GPUs) may include any number of GPUs that may be used for executing processing tasks of compute services 5916, AI services 5918, visualization services 5920, other services, and/or any of features or functionality of software 5818. For example, with respect to AI services 5918, GPUs 5922 may be used to perform pre-processing on imaging data (or other data types used by machine learning models), post-processing on outputs of machine learning models, and/or to perform inferencing (e.g., to execute machine learning models). In at least one embodiment, cloud 5926, AI system 5924, and/or other components of system 5900 may use GPUs 5922. In at least one embodiment, cloud 5926 may include a GPU-optimized platform for deep learning tasks. In at least one embodiment, AI system 5924 may use GPUs, and cloud 5926—or at least a portion tasked with deep learning or inferencing—may be executed using one or more AI systems 5924. As such, although hardware 5822 is illustrated as discrete components, this is not intended to be limiting, and any components of hardware 5822 may be combined with, or leveraged by, any other components of hardware 5822.

In at least one embodiment, AI system 5924 may include a purpose-built computing system (e.g., a super-computer or an HPC) configured for inferencing, deep learning, machine learning, and/or other artificial intelligence tasks. In at least one embodiment, AI system 5924 (e.g., NVIDIA's DGX) may include GPU-optimized software (e.g., a software stack) that may be executed using a plurality of GPUs 5922, in addition to CPUs, RAM, storage, and/or other components, features, or functionality. In at least one embodiment, one or more AI systems 5924 may be implemented in cloud 5926 (e.g., in a data center) for performing some or all of AI-based processing tasks of system 5900.

In at least one embodiment, cloud 5926 may include a GPU-accelerated infrastructure (e.g., NVIDIA's NGC) that may provide a GPU-optimized platform for executing processing tasks of system 5900. In at least one embodiment, cloud 5926 may include an AI system(s) 5924 for performing one or more of AI-based tasks of system 5900 (e.g., as a hardware abstraction and scaling platform). In at least one embodiment, cloud 5926 may integrate with application orchestration system 5928 leveraging multiple GPUs to enable seamless scaling and load balancing between and among applications and services 5820. In at least one embodiment, cloud 5926 may tasked with executing at least some of services 5820 of system 5900, including compute services 5916, AI services 5918, and/or visualization services 5920, as described herein. In at least one embodiment, cloud 5926 may perform small and large batch inference (e.g., executing NVIDIA's TENSOR RT), provide an accelerated parallel computing API and platform 5930 (e.g., NVIDIA's CUDA), execute application orchestration system 5928 (e.g., KUBERNETES), provide a graphics rendering API and platform (e.g., for ray-tracing, 2D graphics, 3D graphics, and/or other rendering techniques to produce higher quality cinematics), and/or may provide other functionality for system 5900.

In at least one embodiment, in an effort to preserve patient confidentiality (e.g., where patient data or records are to be used off-premises), cloud 5926 may include a registry—such as a deep learning container registry. In at least one embodiment, a registry may store containers for instantiations of applications that may perform pre-processing, post-processing, or other processing tasks on patient data. In at least one embodiment, cloud 5926 may receive data that includes patient data as well as sensor data in containers, perform requested processing for just sensor data in those containers, and then forward a resultant output and/or visualizations to appropriate parties and/or devices (e.g., on-premises medical devices used for visualization or diagnoses), all without having to extract, store, or otherwise access patient data. In at least one embodiment, confidentiality of patient data is preserved in compliance with HIPAA and/or other data regulations.

In at least one embodiment, hardware 5822 can be used to train or implement a neural network as described herein. In at least one embodiment, for example, hardware 5822 can be used to simulate a tactile sensor to generate a latent space using unsupervised learning, and generate a latent space for electrode signals generated by the tactile sensor. In at least one embodiment, hardware 5822 can be used to learn a mapping between these two latent spaces, allowing for projection between impressions on a tactile sensor and the signals produced by the sensor itself.

FIG. 60 includes an example illustration of a deployment pipeline 5910A for processing imaging data, in accordance with at least one embodiment. In at least one embodiment, system 5900—and specifically deployment system 5806—may be used to customize, update, and/or integrate deployment pipeline(s) 5910A into one or more production environments. In at least one embodiment, deployment pipeline 5910A of FIG. 60 includes a non-limiting example of a deployment pipeline 5910A that may be custom defined by a particular user (or team of users) at a facility (e.g., at a hospital, clinic, lab, research environment, etc.). In at least one embodiment, to define deployment pipelines 5910A for a CT scanner 6002, a user may select—from a container registry, for example—one or more applications that perform specific functions or tasks with respect to imaging data generated by CT scanner 6002. In at least one embodiment, applications may be applied to deployment pipeline 5910A as containers that may leverage services 5820 and/or hardware 5822 of system 5900. In addition, deployment pipeline 5910A may include additional processing tasks or applications that may be implemented to prepare data for use by applications (e.g., DICOM adapter 5902B and DICOM reader 6006 may be used in deployment pipeline 5910A to prepare data for use by CT reconstruction 6008, organ segmentation 6010, etc.). In at least one embodiment, deployment pipeline 5910A may be customized or selected for consistent deployment, one time use, or for another frequency or interval. In at least one embodiment, a user may desire to have CT reconstruction 6008 and organ segmentation 6010 for several subjects over a specific interval, and thus may deploy pipeline 5910A for that period of time. In at least one embodiment, a user may select, for each request from system 5900, applications that a user wants to perform processing on that data for that request. In at least one embodiment, deployment pipeline 5910A may be adjusted at any interval and, because of adaptability and scalability of a container structure within system 5900, this may be a seamless process.

In at least one embodiment, deployment pipeline 5910A of FIG. 60 may include CT scanner 6002 generating imaging data of a patient or subject. In at least one embodiment, imaging data from CT scanner 6002 may be stored on a PACS server(s) 6004 associated with a facility housing CT scanner 6002. In at least one embodiment, PACS server(s) 6004 may include software and/or hardware components that may directly interface with imaging modalities (e.g., CT scanner 6002) at a facility. In at least one embodiment, DICOM adapter 5902B may enable sending and receipt of DICOM objects using DICOM protocols. In at least one embodiment, DICOM adapter 5902B may aid in preparation or configuration of DICOM data from PACS server(s) 6004 for use by deployment pipeline 5910A. In at least one embodiment, once DICOM data is processed through DICOM adapter 5902B, pipeline manager 5912 may route data through to deployment pipeline 5910A. In at least one embodiment, DICOM reader 6006 may extract image files and any associated metadata from DICOM data (e.g., raw sinogram data, as illustrated in visualization 6016A). In at least one embodiment, working files that are extracted may be stored in a cache for faster processing by other applications in deployment pipeline 5910A. In at least one embodiment, once DICOM reader 6006 has finished extracting and/or storing data, a signal of completion may be communicated to pipeline manager 5912. In at least one embodiment, pipeline manager 5912 may then initiate or call upon one or more other applications or containers in deployment pipeline 5910A.

In at least one embodiment, CT reconstruction 6008 application and/or container may be executed once data (e.g., raw sinogram data) is available for processing by CT reconstruction 6008 application. In at least one embodiment, CT reconstruction 6008 may read raw sinogram data from a cache, reconstruct an image file out of raw sinogram data (e.g., as illustrated in visualization 6016B), and store resulting image file in a cache. In at least one embodiment, at completion of reconstruction, pipeline manager 5912 may be signaled that reconstruction task is complete. In at least one embodiment, once reconstruction is complete, and a reconstructed image file may be stored in a cache (or other storage device), organ segmentation 6010 application and/or container may be triggered by pipeline manager 5912. In at least one embodiment, organ segmentation 6010 application and/or container may read an image file from a cache, normalize or convert an image file to format suitable for inference (e.g., convert an image file to an input resolution of a machine learning model), and run inference against a normalized image. In at least one embodiment, to run inference on a normalized image, organ segmentation 6010 application and/or container may rely on services 5820, and pipeline manager 5912 and/or application orchestration system 5928 may facilitate use of services 5820 by organ segmentation 6010 application and/or container. In at least one embodiment, for example, organ segmentation 6010 application and/or container may leverage AI services 5918 to perform inference on a normalized image, and AI services 5918 may leverage hardware 5822 (e.g., AI system 5924) to execute AI services 5918. In at least one embodiment, a result of an inference may be a mask file (e.g., as illustrated in visualization 6016C) that may be stored in a cache (or other storage device).

In at least one embodiment, once applications that process DICOM data and/or data extracted from DICOM data have completed processing, a signal may be generated for pipeline manager 5912. In at least one embodiment, pipeline manager 5912 may then execute DICOM writer 6012 to read results from a cache (or other storage device), package results into a DICOM format (e.g., as DICOM output 6014) for use by users at a facility who generated a request. In at least one embodiment, DICOM output 6014 may then be transmitted to DICOM adapter 5902B to prepare DICOM output 6014 for storage on PACS server(s) 6004 (e.g., for viewing by a DICOM viewer at a facility). In at least one embodiment, in response to a request for reconstruction and segmentation, visualizations 6016B and 6016C may be generated and available to a user for diagnoses, research, and/or for other purposes.

Although illustrated as consecutive application in deployment pipeline 5910A, CT reconstruction 6008 and organ segmentation 6010 applications may be processed in parallel in at least one embodiment. In at least one embodiment, where applications do not have dependencies on one another, and data is available for each application (e.g., after DICOM reader 6006 extracts data), applications may be executed at a same time, substantially at a same time, or with some overlap. In at least one embodiment, where two or more applications require similar services 5820, a scheduler of system 5900 may be used to load balance and distribute compute or processing resources between and among various applications. In at least one embodiment, in some embodiments, parallel computing platform 5930 may be used to perform parallel processing for applications to decrease run-time of deployment pipeline 5910A to provide real-time results.

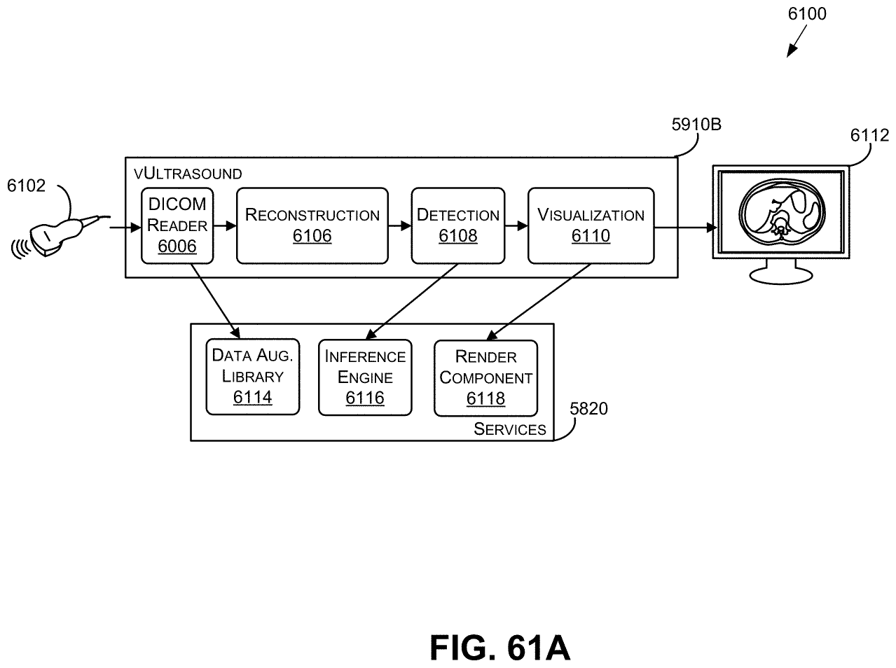

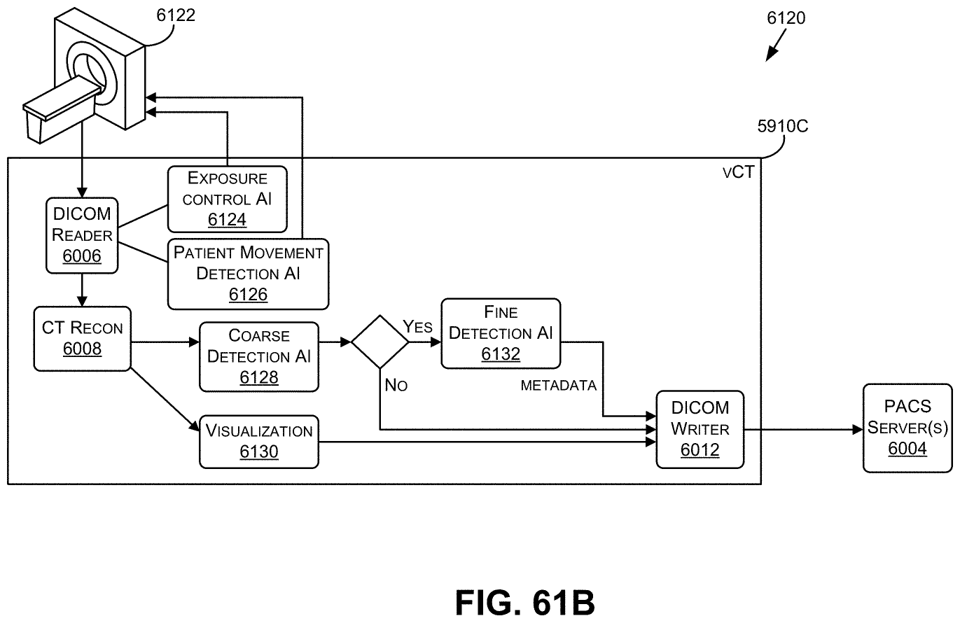

In at least one embodiment, and with reference to FIGS. 61A-61B, deployment system 5806 may be implemented as one or more virtual instruments to perform different functionalities—such as image processing, segmentation, enhancement, AI, visualization, and inferencing—with imaging devices (e.g., CT scanners, X-ray machines, MRI machines, etc.), sequencing devices, genomics devices, and/or other device types. In at least one embodiment, system 5900 may allow for creation and provision of virtual instruments that may include a software-defined deployment pipeline 5910 that may receive raw/unprocessed input data generated by a device(s) and output processed/reconstructed data. In at least one embodiment, deployment pipelines 5910 (e.g., 5910A and 5910B) that represent virtual instruments may implement intelligence into a pipeline, such as by leveraging machine learning models, to provide containerized inference support to a system. In at least one embodiment, virtual instruments may execute any number of containers each including instantiations of applications. In at least one embodiment, such as where real-time processing is desired, deployment pipelines 5910 representing virtual instruments may be static (e.g., containers and/or applications may be set), while in other examples, container and/or applications for virtual instruments may be selected (e.g., on a per-request basis) from a pool of applications or resources (e.g., within a container registry).

In at least one embodiment, system 5900 may be instantiated or executed as one or more virtual instruments on-premise at a facility in, for example, a computing system deployed next to or otherwise in communication with a radiology machine, an imaging device, and/or another device type at a facility. In at least one embodiment, however, an on-premise installation may be instantiated or executed within a computing system of a device itself (e.g., a computing system integral to an imaging device), in a local datacenter (e.g., a datacenter on-premise), and/or in a cloud-environment (e.g., in cloud 5926). In at least one embodiment, deployment system 5806, operating as a virtual instrument, may be instantiated by a supercomputer or other HPC system in some examples. In at least one embodiment, on-premise installation may allow for high-bandwidth uses (via, for example, higher throughput local communication interfaces, such as RF over Ethernet) for real-time processing. In at least one embodiment, real-time or near real-time processing may be particularly useful where a virtual instrument supports an ultrasound device or other imaging modality where immediate visualizations are expected or required for accurate diagnoses and analyses. In at least one embodiment, a cloud-computing architecture may be capable of dynamic bursting to a cloud computing service provider, or other compute cluster, when local demand exceeds on-premise capacity or capability. In at least one embodiment, a cloud architecture, when implemented, may be tuned for training neural networks or other machine learning models, as described herein with respect to training system 5804. In at least one embodiment, with training pipelines in place, machine learning models may be continuously learn and improve as they process additional data from devices they support. In at least one embodiment, virtual instruments may be continually improved using additional data, new data, existing machine learning models, and/or new or updated machine learning models.

In at least one embodiment, a computing system may include some or all of hardware 5822 described herein, and hardware 5822 may be distributed in any of a number of ways including within a device, as part of a computing device coupled to and located proximate a device, in a local datacenter at a facility, and/or in cloud 5926. In at least one embodiment, because deployment system 5806 and associated applications or containers are created in software (e.g., as discrete containerized instantiations of applications), behavior, operation, and configuration of virtual instruments, as well as outputs generated by virtual instruments, may be modified or customized as desired, without having to change or alter raw output of a device that a virtual instrument supports.

In at least one embodiment, system 5900 can be used to train or implement a neural network as described herein. In at least one embodiment, for example, system 5900 can be used to simulate a tactile sensor to generate a latent space using unsupervised learning, and generate a latent space for electrode signals generated by the tactile sensor. In at least one embodiment, system 5900 can be used to learn a mapping between these two latent spaces, allowing for projection between impressions on a tactile sensor and the signals produced by the sensor itself.

FIG. 61A includes an example data flow diagram of a virtual instrument supporting an ultrasound device, in accordance with at least one embodiment. In at least one embodiment, deployment pipeline 5910B may leverage one or more of services 5820 of system 5900. In at least one embodiment, deployment pipeline 5910B and services 5820 may leverage hardware 5822 of a system either locally or in cloud 5926. In at least one embodiment, although not illustrated, process 6100 may be facilitated by pipeline manager 5912, application orchestration system 5928, and/or parallel computing platform 5930.

In at least one embodiment, process 6100 may include receipt of imaging data from an ultrasound device 6102. In at least one embodiment, imaging data may be stored on PACS server(s) in a DICOM format (or other format, such as RIS, CIS, REST compliant, RPC, raw, etc.), and may be received by system 5900 for processing through deployment pipeline 5910 selected or customized as a virtual instrument (e.g., a virtual ultrasound) for ultrasound device 6102. In at least one embodiment, imaging data may be received directly from an imaging device (e.g., ultrasound device 6102) and processed by a virtual instrument. In at least one embodiment, a transducer or other signal converter communicatively coupled between an imaging device and a virtual instrument may convert signal data generated by an imaging device to image data that may be processed by a virtual instrument. In at least one embodiment, raw data and/or image data may be applied to DICOM reader 6006 to extract data for use by applications or containers of deployment pipeline 5910B. In at least one embodiment, DICOM reader 6006 may leverage data augmentation library 6114 (e.g., NVIDIA's DALI) as a service 5820 (e.g., as one of compute service(s) 5916) for extracting, resizing, rescaling, and/or otherwise preparing data for use by applications or containers.

In at least one embodiment, once data is prepared, a reconstruction 6106 application and/or container may be executed to reconstruct data from ultrasound device 6102 into an image file. In at least one embodiment, after reconstruction 6106, or at a same time as reconstruction 6106, a detection 6108 application and/or container may be executed for anomaly detection, object detection, feature detection, and/or other detection tasks related to data. In at least one embodiment, an image file generated during reconstruction 6106 may be used during detection 6108 to identify anomalies, objects, features, etc. In at least one embodiment, detection 6108 application may leverage an inference engine 6116 (e.g., as one of AI service(s) 5918) to perform inference on data to generate detections. In at least one embodiment, one or more machine learning models (e.g., from training system 5804) may be executed or called by detection 6108 application.

In at least one embodiment, once reconstruction 6106 and/or detection 6108 is/are complete, data output from these application and/or containers may be used to generate visualizations 6110, such as visualization 6112 (e.g., a grayscale output) displayed on a workstation or display terminal. In at least one embodiment, visualization may allow a technician or other user to visualize results of deployment pipeline 5910B with respect to ultrasound device 6102. In at least one embodiment, visualization 6110 may be executed by leveraging a render component 6118 of system 5900 (e.g., one of visualization service(s) 5920). In at least one embodiment, render component 6118 may execute a 2D, OpenGL, or ray-tracing service to generate visualization 6112.

In at least one embodiment, deployment pipeline 5910B can be used to train or implement a neural network as described herein. In at least one embodiment, for example, deployment pipeline 5910B can be used to simulate a tactile sensor to generate a latent space using unsupervised learning, and generate a latent space for electrode signals generated by the tactile sensor. In at least one embodiment, [deployment pipeline 5910B can be used to learn a mapping between these two latent spaces, allowing for projection between impressions on a tactile sensor and the signals produced by the sensor itself.

FIG. 61B includes an example data flow diagram of a virtual instrument supporting a CT scanner, in accordance with at least one embodiment. In at least one embodiment, deployment pipeline 5910C may leverage one or more of services 5820 of system 5900. In at least one embodiment, deployment pipeline 5910C and services 5820 may leverage hardware 5822 of a system either locally or in cloud 5926. In at least one embodiment, although not illustrated, process 6120 may be facilitated by pipeline manager 5912, application orchestration system 5928, and/or parallel computing platform 5930.

In at least one embodiment, process 6120 may include CT scanner 6122 generating raw data that may be received by DICOM reader 6006 (e.g., directly, via a PACS server 6004, after processing, etc.). In at least one embodiment, a Virtual CT (instantiated by deployment pipeline 5910C) may include a first, real-time pipeline for monitoring a patient (e.g., patient movement detection AI 6126) and/or for adjusting or optimizing exposure of CT scanner 6122 (e.g., using exposure control AI 6124). In at least one embodiment, one or more of applications (e.g., 6124 and 6126) may leverage a service 5820, such as AI service(s) 5918. In at least one embodiment, outputs of exposure control AI 6124 application (or container) and/or patient movement detection AI 6126 application (or container) may be used as feedback to CT scanner 6122 and/or a technician for adjusting exposure (or other settings of CT scanner 6122) and/or informing a patient to move less.

In at least one embodiment, deployment pipeline 5910C may include a non-real-time pipeline for analyzing data generated by CT scanner 6122. In at least one embodiment, a second pipeline may include CT reconstruction 6008 application and/or container, a coarse detection AI 6128 application and/or container, a fine detection AI 6132 application and/or container (e.g., where certain results are detected by coarse detection AI 6128), a visualization 6130 application and/or container, and a DICOM writer 6012 (and/or other data type writer, such as RIS, CIS, REST compliant, RPC, raw, etc.) application and/or container. In at least one embodiment, raw data generated by CT scanner 6122 may be passed through pipelines of deployment pipeline 5910C (instantiated as a virtual CT instrument) to generate results. In at least one embodiment, results from DICOM writer 6012 may be transmitted for display and/or may be stored on PACS server(s) 6004 for later retrieval, analysis, or display by a technician, practitioner, or other user.

In at least one embodiment, deployment pipeline 5910C can be used to train or implement a neural network as described herein. In at least one embodiment, for example, deployment pipeline 5910C can be used to simulate a tactile sensor to generate a latent space using unsupervised learning, and generate a latent space for electrode signals generated by the tactile sensor. In at least one embodiment, deployment pipeline 5910C can be used to learn a mapping between these two latent spaces, allowing for projection between impressions on a tactile sensor and the signals produced by the sensor itself.

FIG. 62A illustrates a data flow diagram for a process 6200 to train, retrain, or update a machine learning model, in accordance with at least one embodiment. In at least one embodiment, process 6200 may be executed using, as a non-limiting example, system 5900 of FIG. 59. In at least one embodiment, process 6200 may leverage services 5820 and/or hardware 5822 of system 5900, as described herein. In at least one embodiment, refined models 6212 generated by process 6200 may be executed by deployment system 5806 for one or more containerized applications in deployment pipelines 5910.

In at least one embodiment, model training 5814 may include retraining or updating an initial model 6204 (e.g., a pre-trained model) using new training data (e.g., new input data, such as customer dataset 6206, and/or new ground truth data associated with input data). In at least one embodiment, to retrain, or update, initial model 6204, output or loss layer(s) of initial model 6204 may be reset, or deleted, and/or replaced with an updated or new output or loss layer(s). In at least one embodiment, initial model 6204 may have previously fine-tuned parameters (e.g., weights and/or biases) that remain from prior training, so training or retraining 5814 may not take as long or require as much processing as training a model from scratch. In at least one embodiment, during model training 5814, by having reset or replaced output or loss layer(s) of initial model 6204, parameters may be updated and re-tuned for a new data set based on loss calculations associated with accuracy of output or loss layer(s) at generating predictions on new, customer dataset 6206 (e.g., image data 5808 of FIG. 58).

In at least one embodiment, pre-trained models 5906 may be stored in a data store, or registry (e.g., model registry 5824 of FIG. 58). In at least one embodiment, pre-trained models 5906 may have been trained, at least in part, at one or more facilities other than a facility executing process 6200. In at least one embodiment, to protect privacy and rights of patients, subjects, or clients of different facilities, pre-trained models 5906 may have been trained, on-premise, using customer or patient data generated on-premise. In at least one embodiment, pre-trained models 5906 may be trained using cloud 5926 and/or other hardware 5822, but confidential, privacy protected patient data may not be transferred to, used by, or accessible to any components of cloud 5926 (or other off premise hardware). In at least one embodiment, where a pre-trained model 5906 is trained at using patient data from more than one facility, pre-trained model 5906 may have been individually trained for each facility prior to being trained on patient or customer data from another facility. In at least one embodiment, such as where a customer or patient data has been released of privacy concerns (e.g., by waiver, for experimental use, etc.), or where a customer or patient data is included in a public data set, a customer or patient data from any number of facilities may be used to train pre-trained model 5906 on-premise and/or off premise, such as in a datacenter or other cloud computing infrastructure.

In at least one embodiment, when selecting applications for use in deployment pipelines 5910, a user may also select machine learning models to be used for specific applications. In at least one embodiment, a user may not have a model for use, so a user may select a pre-trained model 5906 to use with an application. In at least one embodiment, pre-trained model 5906 may not be optimized for generating accurate results on customer dataset 6206 of a facility of a user (e.g., based on patient diversity, demographics, types of medical imaging devices used, etc.). In at least one embodiment, prior to deploying pre-trained model 5906 into deployment pipeline 5910 for use with an application(s), pre-trained model 5906 may be updated, retrained, and/or fine-tuned for use at a respective facility.

In at least one embodiment, a user may select pre-trained model 5906 that is to be updated, retrained, and/or fine-tuned, and pre-trained model 5906 may be referred to as initial model 6204 for training system 5804 within process 6200. In at least one embodiment, customer dataset 6206 (e.g., imaging data, genomics data, sequencing data, or other data types generated by devices at a facility) may be used to perform model training 5814 (which may include, without limitation, transfer learning) on initial model 6204 to generate refined model 6212. In at least one embodiment, ground truth data corresponding to customer dataset 6206 may be generated by training system 5804. In at least one embodiment, ground truth data may be generated, at least in part, by clinicians, scientists, doctors, practitioners, at a facility (e.g., as labeled clinic data 5812 of FIG. 58).

In at least one embodiment, AI-assisted annotation 5810 may be used in some examples to generate ground truth data. In at least one embodiment, AI-assisted annotation 5810 (e.g., implemented using an AI-assisted annotation SDK) may leverage machine learning models (e.g., neural networks) to generate suggested or predicted ground truth data for a customer dataset. In at least one embodiment, user 6210 may use annotation tools within a user interface (a graphical user interface (GUI)) on computing device 6208.

In at least one embodiment, user 6210 may interact with a GUI via computing device 6208 to edit or fine-tune annotations or auto-annotations. In at least one embodiment, a polygon editing feature may be used to move vertices of a polygon to more accurate or fine-tuned locations.

In at least one embodiment, once customer dataset 6206 has associated ground truth data, ground truth data (e.g., from AI-assisted annotation, manual labeling, etc.) may be used by during model training 5814 to generate refined model 6212. In at least one embodiment, customer dataset 6206 may be applied to initial model 6204 any number of times, and ground truth data may be used to update parameters of initial model 6204 until an acceptable level of accuracy is attained for refined model 6212. In at least one embodiment, once refined model 6212 is generated, refined model 6212 may be deployed within one or more deployment pipelines 5910 at a facility for performing one or more processing tasks with respect to medical imaging data.

In at least one embodiment, refined model 6212 may be uploaded to pre-trained models 5906 in model registry 5824 to be selected by another facility. In at least one embodiment, his process may be completed at any number of facilities such that refined model 6212 may be further refined on new datasets any number of times to generate a more universal model.

In at least one embodiment, process 6200 can be used to train or implement a neural network as described herein. In at least one embodiment, for example, process 6200 can be used to simulate a tactile sensor to generate a latent space using unsupervised learning, and generate a latent space for electrode signals generated by the tactile sensor. In at least one embodiment, process 6200 can be used to learn a mapping between these two latent spaces, allowing for projection between impressions on a tactile sensor and the signals produced by the sensor itself.

FIG. 62B is an example illustration of a client-server architecture 6232 to enhance annotation tools with pre-trained annotation models, in accordance with at least one embodiment. In at least one embodiment, AI-assisted annotation tools 6236 may be instantiated based on a client-server architecture 6232. In at least one embodiment, annotation tools 6236 in imaging applications may aid radiologists, for example, identify organs and abnormalities. In at least one embodiment, imaging applications may include software tools that help user 6210 to identify, as a non-limiting example, a few extreme points on a particular organ of interest in raw images 6234 (e.g., in a 3D MRI or CT scan) and receive auto-annotated results for all 2D slices of a particular organ. In at least one embodiment, results may be stored in a data store as training data 6238 and used as (for example and without limitation) ground truth data for training. In at least one embodiment, when computing device 6208 sends extreme points for AI-assisted annotation 5810, a deep learning model, for example, may receive this data as input and return inference results of a segmented organ or abnormality. In at least one embodiment, pre-instantiated annotation tools, such as AI-Assisted Annotation Tool 6236B in FIG. 62B, may be enhanced by making API calls (e.g., API Call 6244) to a server, such as an Annotation Assistant Server 6240 that may include a set of pre-trained models 6242 stored in an annotation model registry, for example. In at least one embodiment, an annotation model registry may store pre-trained models 6242 (e.g., machine learning models, such as deep learning models) that are pre-trained to perform AI-assisted annotation on a particular organ or abnormality. In at least one embodiment, these models may be further updated by using training pipelines 5904. In at least one embodiment, pre-installed annotation tools may be improved over time as new labeled clinic data 5812 is added.

Inference and/or training logic 2915 are used to perform inferencing and/or training operations associated with one or more embodiments. Details regarding inference and/or training logic 2915 are provided herein in conjunction with FIGS. 29A and/or 29B.

In at least one embodiment, client-server architecture 6232 can be used to train or implement a neural network as described herein. In at least one embodiment, for example, client-server architecture 6232 can be used to simulate a tactile sensor to generate a latent space using unsupervised learning, and generate a latent space for electrode signals generated by the tactile sensor. In at least one embodiment, client-server architecture 6232 can be used to learn a mapping between these two latent spaces, allowing for projection between impressions on a tactile sensor and the signals produced by the sensor itself.

At least one embodiment of the disclosure can be described in view of the following clauses:

1. A processor comprising one or more circuits that use a physics model to simulate an impression on a simulated tactile sensor, perform the impression on a physical tactile sensor to obtain a set of signals corresponding to the impression, and train one or more neural networks to estimate behavior of a tactile sensor using the signals and a predicted deformation of the simulated tactile sensor.

2. The processor of clause 1, wherein the one or more neural networks is trained by at least learning a first latent space that represents the physics model of the tactile sensor, learning a second latent space that represents the set of electrode signals generated by the tactile sensor, and learning a translation between the first latent space and the second latent space.

3. The processor of clause 1 or 2, wherein the one or more neural networks is trained to estimate a deformation of the tactile sensor from a set of signals produced by the tactile sensor.

4. The processor of any of clauses 1 to 3, wherein the one or more neural networks is trained to estimate a set of signals produced by the tactile sensor from a deformation of the tactile sensor.

5. The processor of any of clauses 1 to 4, wherein the physics model is a finite element model, and the finite element model is simulated on a GPU.

6. The processor of any of clauses 1 to 5, wherein the impression is performed with a set of indenters and the tactile sensor is mounted to a test fixture, the test fixture includes a force torque sensor, and the simulation includes the test fixture and the indenters.

7. The processor of any of clauses 1 to 6, wherein the one or more networks includes a first neural network and a second neural network, the first neural network is trained to estimate a deformation of the tactile sensor from a set of signals produced by the tactile sensor, the second neural network is trained to estimate a set of signals produced by the tactile sensor from a deformation of the tactile sensor, and the one or more circuits further generate a latent space projection from both the first neural network and the second neural network.

8. The processor of clause 7, wherein the latent space projection enables conversion between a set of signals and a deformation of the tactile sensor.

9. The processor of any of clauses 1 to 8, wherein the one or more neural networks determines a contact patch of the tactile sensor.

10. A system comprising one or more processors and memory storing executable instructions that, as a result of being executed by the one or more processors, cause the system to implement one or more neural networks trained by at least, using a physics model to simulate an impression on a simulated tactile sensor, performing the impression on a physical tactile sensor to obtain a set of signals corresponding to the impression, and training the one or more neural networks to estimate behavior of a tactile sensor using the signals and a predicted deformation of the simulated tactile sensor.

11. The system of clause 10, wherein the one or more neural networks is trained by at least, learning a first latent space that represents the physics model of the tactile sensor, learning a second latent space that represents the set of electrode signals generated by the tactile sensor, and learning a translation between the first latent space and the second latent space.

12. The system of clause 10 or 11, wherein the one or more neural networks is trained to estimate a deformation of the tactile sensor from a set of signals produced by the tactile sensor.

13. The system of any of clauses 10 to 12, wherein the one or more neural networks is trained to estimate a set of signals produced by the tactile sensor from a deformation of the tactile sensor.

14. The system of any of clauses 10 to 13, wherein the tactile sensor comprises a rigid core and a flexible outer skin.

15. The system of any of clauses 10 to 14, wherein the impression is performed with a set of indenters and the tactile sensor is mounted to a test fixture, and the simulation includes the test fixture and the indenters.

16. The system of any of clauses 10 to 15, wherein the one or more networks includes a first neural network and a second neural network, the first neural network is trained to estimate a deformation of the tactile sensor from a set of signals produced by the tactile sensor, the second neural network is trained to estimate a set of signals produced by the tactile sensor from a deformation of the tactile sensor, and the one or more circuits further generate a latent space projection from both the first neural network and the second neural network.

17. The system of clause 16, wherein the latent space projection enables conversion between a set of signals and a deformation of the tactile sensor.

18. The system of any of clauses 10 to 17, wherein the one or more neural networks determines a contact patch of the tactile sensor.

19. A computer-implemented method of training a machine-learned model comprising using a physics model to simulate an impression on a simulated tactile sensor, performing the impression on a physical tactile sensor to obtain a set of signals corresponding to the impression, and training one or more neural networks to estimate behavior of a tactile sensor using the signals and a predicted deformation of the simulated tactile sensor.

20. The computer-implemented method of clause 19, wherein the one or more neural networks is trained by at least, learning a first latent space that represents the physics model of the tactile sensor, learning a second latent space that represents the set of electrode signals generated by the tactile sensor, and learning a translation between the first latent space and the second latent space.

21. The computer-implemented method of clause 19 or 20, wherein the one or more neural networks is trained to estimate a deformation of the tactile sensor from a set of signals produced by the tactile sensor.

22. The computer-implemented method of any of clauses 19 to 21, wherein the one or more neural networks is trained to estimate a set of signals produced by the tactile sensor from a deformation of the tactile sensor.

23. The computer-implemented method of any of clauses 19 to 22, wherein physics model is simulated on a GPU.

24. The computer-implemented method of any of clauses 19 to 23, wherein the impression is performed with a set of indenters and the tactile sensor is mounted to a test fixture, and the simulation includes the test fixture and the indenters.

25. The computer-implemented method of any of clauses 19 to 24, wherein the one or more networks includes a first neural network and a second neural network, the first neural network is trained to estimate a deformation of the tactile sensor from a set of signals produced by the tactile sensor, the second neural network is trained to estimate a set of signals produced by the tactile sensor from a deformation of the tactile sensor, and the one or more circuits further generate a latent space projection from both the first neural network and the second neural network.

26. The computer-implemented method of clause 25, wherein the latent space projection enables conversion between a set of signals and a deformation of the tactile sensor.

27. The computer-implemented method of any of clauses 19 to 26, wherein the one or more neural networks determines a contact patch of the tactile sensor.

28. A machine-readable medium having stored thereon executable instructions, that, as a result of being performed by one or more processors, cause the one or more processors to at least implement a machine-learned model, the machine-learned model trained by at least using a physics model to simulate an impression on a simulated tactile sensor, performing the impression on a physical tactile sensor to obtain a set of signals corresponding to the impression, and training one or more neural networks to estimate behavior of a tactile sensor using the signals and a predicted deformation of the simulated tactile sensor.

29. The machine-readable medium of clause 28, wherein the one or more neural networks is trained by at least learning a first latent space that represents the physics model of the tactile sensor, learning a second latent space that represents the set of electrode signals generated by the tactile sensor, and learning a translation between the first latent space and the second latent space.

30. The machine-readable medium of clause 28 or 29, wherein the one or more neural networks is trained to estimate a deformation of the tactile sensor from a set of signals produced by the tactile sensor.

31. The machine-readable medium of any of clauses 28 to 30, wherein the one or more neural networks is trained to estimate a set of signals produced by the tactile sensor from a deformation of the tactile sensor.

32. The machine-readable medium of any of clauses 28 to 31, wherein the tactile sensor comprises a rigid core and a flexible outer skin.

33. The machine-readable medium of any of clauses 28 to 32, wherein the impression is performed with a set of indenters and the tactile sensor is mounted to a test fixture, and the simulation includes the test fixture and the indenters.

34. The machine-readable medium of any of clauses 28 to 33, wherein the one or more networks includes a first neural network and a second neural network, the first neural network is trained to estimate a deformation of the tactile sensor from a set of signals produced by the tactile sensor, the second neural network is trained to estimate a set of signals produced by the tactile sensor from a deformation of the tactile sensor, and the one or more circuits further generate a latent space projection from both the first neural network and the second neural network.

35. The machine-readable medium of clause 34, wherein the latent space projection enables conversion between a set of signals and a deformation of the tactile sensor.

36. The machine-readable medium of any of clauses 28 to 35, wherein the one or more neural networks determines a contact patch of the tactile sensor.

In at least one embodiment, a single semiconductor platform may refer to a sole unitary semiconductor-based integrated circuit or chip. In at least one embodiment, multi-chip modules may be used with increased connectivity which simulate on-chip operation, and make substantial improvements over utilizing a conventional central processing unit (“CPU”) and bus implementation. In at least one embodiment, various modules may also be situated separately or in various combinations of semiconductor platforms per desires of user.

In at least one embodiment, referring back to FIG. 35, computer programs in form of machine-readable executable code or computer control logic algorithms are stored in main memory 3504 and/or secondary storage. Computer programs, if executed by one or more processors, enable system 3500 to perform various functions in accordance with at least one embodiment. In at least one embodiment, memory 3504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 3502, parallel processing system 3512, an integrated circuit capable of at least a portion of capabilities of both CPU 3502, parallel processing system 3512, a chipset (e.g., a group of integrated circuits designed to work and sold as a unit for performing related functions, etc.), and/or any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 3500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 3512 includes, without limitation, a plurality of parallel processing units (“PPUs”) 3514 and associated memories 3516. In at least one embodiment, PPUs 3514 are connected to a host processor or other peripheral devices via an interconnect 3518 and a switch 3520 or multiplexer. In at least one embodiment, parallel processing system 3512 distributes computational tasks across PPUs 3514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 3514, although such shared memory may incur performance penalties relative to use of local memory and registers resident to a PPU 3514. In at least one embodiment, operation of PPUs 3514 is synchronized through use of a command such as _syncthreads( ), wherein all threads in a block (e.g., executed across multiple PPUs 3514) to reach a certain point of execution of code before proceeding.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A processor comprising one or more circuits that:
use a physics model to simulate an impression on a simulated tactile sensor;
perform the impression on a physical tactile sensor to obtain a set of signals corresponding to the impression; and
train one or more neural networks to estimate behavior of a tactile sensor using the set of signals and a predicted deformation of the simulated tactile sensor.

2. The processor of claim 1, wherein the one or more neural networks is trained by at least:
learning a first latent space that represents the physics model of the tactile sensor;
learning a second latent space that represents the set of signals generated by the tactile sensor; and
learning a translation between the first latent space and the second latent space.

3. The processor of claim 1, wherein the one or more neural networks is trained to estimate a deformation of the tactile sensor from a set of signals produced by the tactile sensor.

4. The processor of claim 1, wherein the one or more neural networks is trained to estimate a set of signals produced by the tactile sensor from a deformation of the tactile sensor.

5. The processor of claim 1, wherein:
the physics model is a finite element model; and
the finite element model is simulated on a GPU.

6. The processor of claim 1, wherein:
the impression is performed with a set of indenters and the tactile sensor is mounted to a test fixture;
the test fixture includes a force torque sensor; and
the simulation includes the test fixture and the set of indenters.

7. The processor of claim 1, wherein:
the one or more networks includes a first neural network and a second neural network;
the first neural network is trained to estimate a deformation of the tactile sensor from a set of signals produced by the tactile sensor;
the second neural network is trained to estimate a set of signals produced by the tactile sensor from a deformation of the tactile sensor; and
the one or more circuits further generate a latent space projection from both the first neural network and the second neural network.

8. The processor of claim 7, wherein the latent space projection enables conversion between a set of signals and a deformation of the tactile sensor.

9. The processor of claim 1, wherein the one or more neural networks determines a contact patch of the tactile sensor.

10. A system comprising:
one or more processors; and
memory storing executable instructions that, as a result of being executed by the one or more processors, cause the system to implement one or more neural networks trained by at least:
using a physics model to simulate an impression on a simulated tactile sensor;
performing the impression on a physical tactile sensor to obtain a set of signals corresponding to the impression; and
training the one or more neural networks to estimate behavior of a tactile sensor using the set of signals and a predicted deformation of the simulated tactile sensor.

11. The system of claim 10, wherein the one or more neural networks is trained by at least:
learning a first latent space that represents the physics model of the tactile sensor;
learning a second latent space that represents the set of signals generated by the tactile sensor; and
learning a translation between the first latent space and the second latent space.

12. The system of claim 10, wherein the one or more neural networks is trained to estimate a deformation of the tactile sensor from a set of signals produced by the tactile sensor.

13. The system of claim 10, wherein the one or more neural networks is trained to estimate a set of signals produced by the tactile sensor from a deformation of the tactile sensor.

14. The system of claim 10, wherein the tactile sensor comprises a rigid core and a flexible outer skin.

15. The system of claim 10, wherein:
the impression is performed with a set of indenters and the tactile sensor is mounted to a test fixture; and
the simulation includes the test fixture and the set of indenters.

16. The system of claim 10, wherein:
the one or more networks includes a first neural network and a second neural network;
the first neural network is trained to estimate a deformation of the tactile sensor from a set of signals produced by the tactile sensor;
the second neural network is trained to estimate a set of signals produced by the tactile sensor from a deformation of the tactile sensor; and
the one or more circuits further generate a latent space projection from both the first neural network and the second neural network.

17. The system of claim 16, wherein the latent space projection enables conversion between a set of signals and a deformation of the tactile sensor.

18. The system of claim 10, wherein the one or more neural networks determines a contact patch of the tactile sensor.

19. A computer-implemented method of training a machine-learned model comprising:
using a physics model to simulate an impression on a simulated tactile sensor;
performing the impression on a physical tactile sensor to obtain a set of signals corresponding to the impression; and
training one or more neural networks to estimate behavior of a tactile sensor using the set of signals and a predicted deformation of the simulated tactile sensor.

20. The computer-implemented method of claim 19, wherein the one or more neural networks is trained by at least:
learning a first latent space that represents the physics model of the tactile sensor;
learning a second latent space that represents the set of signals generated by the tactile sensor; and
learning a translation between the first latent space and the second latent space.

21. The computer-implemented method of claim 19, wherein the one or more neural networks is trained to estimate a deformation of the tactile sensor from a set of signals produced by the tactile sensor.

22. The computer-implemented method of claim 19, wherein the one or more neural networks is trained to estimate a set of signals produced by the tactile sensor from a deformation of the tactile sensor.

23. The computer-implemented method of claim 19, wherein physics model is simulated on a GPU.

24. The computer-implemented method of claim 19, wherein:
the impression is performed with a set of indenters and the tactile sensor is mounted to a test fixture; and
the simulation includes the test fixture and the set of indenters.

25. The computer-implemented method of claim 19, wherein:
the one or more networks includes a first neural network and a second neural network;
the first neural network is trained to estimate a deformation of the tactile sensor from a set of signals produced by the tactile sensor;
the second neural network is trained to estimate a set of signals produced by the tactile sensor from a deformation of the tactile sensor; and
the one or more circuits further generate a latent space projection from both the first neural network and the second neural network.

26. The computer-implemented method of claim 25, wherein the latent space projection enables conversion between a set of signals and a deformation of the tactile sensor.

27. The computer-implemented method of claim 19, wherein the one or more neural networks determines a contact patch of the tactile sensor.

28. A machine-readable medium having stored thereon executable instructions, that, as a result of being performed by one or more processors, cause the one or more processors to at least implement a machine-learned model, the machine-learned model trained by at least:
using a physics model to simulate an impression on a simulated tactile sensor;
performing the impression on a physical tactile sensor to obtain a set of signals corresponding to the impression; and
training one or more neural networks to estimate behavior of a tactile sensor using the set of signals and a predicted deformation of the simulated tactile sensor.

29. The machine-readable medium of claim 28, wherein the one or more neural networks is trained by at least:
learning a first latent space that represents the physics model of the tactile sensor;
learning a second latent space that represents the set of signals generated by the tactile sensor; and
learning a translation between the first latent space and the second latent space.

30. The machine-readable medium of claim 28, wherein the one or more neural networks is trained to estimate a deformation of the tactile sensor from a set of signals produced by the tactile sensor.

31. The machine-readable medium of claim 28, wherein the one or more neural networks is trained to estimate a set of signals produced by the tactile sensor from a deformation of the tactile sensor.

32. The machine-readable medium of claim 28, wherein the tactile sensor comprises a rigid core and a flexible outer skin.

33. The machine-readable medium of claim 28, wherein:
the impression is performed with a set of indenters and the tactile sensor is mounted to a test fixture; and
the simulation includes the test fixture and the set of indenters.

34. The machine-readable medium of claim 28, wherein:
the one or more networks includes a first neural network and a second neural network;
the first neural network is trained to estimate a deformation of the tactile sensor from a set of signals produced by the tactile sensor;
the second neural network is trained to estimate a set of signals produced by the tactile sensor from a deformation of the tactile sensor; and
the one or more circuits further generate a latent space projection from both the first neural network and the second neural network.

35. The machine-readable medium of claim 34, wherein the latent space projection enables conversion between a set of signals and a deformation of the tactile sensor.

36. The machine-readable medium of claim 28, wherein the one or more neural networks determines a contact patch of the tactile sensor.
